(19) United States
(12) Patent Application Publication
(10) Pub. No.: US 2025/0164882 A1
(43) Pub. Date: May 22, 2025

(54) POSITIVE RESIST COMPOSITION AND PATTERN FORMING PROCESS

(71) Applicant: Shin-Etsu Chemical Co., Ltd., Tokyo (JP)

(72) Inventor: Jun Hatakeyama, Joetsu-shi (JP)

(73) Assignee: Shin-Etsu Chemical Co., Ltd., Tokyo (JP)

(21) Appl. No.: 18/933,372

(22) Filed: Oct. 31, 2024

(30) Foreign Application Priority Data
Nov. 17, 2023 (JP) 2023-195593

(51) Int. Cl. G03F 7/039; G03F 7/00

(52) U.S. Cl. CPC G03F 7/0392; G03F 7/70025; G03F 7/70033

(57) ABSTRACT

The positive resist composition comprises a base polymer comprising repeat units (a) having a sulfonium salt structure of an iodized phenol compound. The positive resist composition comprising a base polymer comprising repeat units having a sulfonium salt structure of an iodized phenol exhibits a high sensitivity and resolution, and forms a pattern of satisfactory profile with reduced edge roughness and dimensional variation.

### CROSS-REFERENCE TO RELATED APPLICATIONS

This non-provisional application claims priority under 35 U.S.C. § 119(a) on Patent Application No. 2023-195593 filed in Japan on Nov. 17, 2023, the entire contents of which are hereby incorporated by reference.

### TECHNICAL FIELD

This invention relates to a positive resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using EUV of wavelength 13.5 nm has been implemented in a mass scale. Studies are made on the application of EUV lithography to 3-nm node devices of the next generation and 2-nm node devices of the next-but-one generation. IMEC in Belgium announced its successful development of 2 Å node devices.

As the feature size reduces, image blurs due to acid diffusion become a problem. To insure resolution for fine patterns with a size of 45 nm et seq., not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

A triangular tradeoff relationship among sensitivity, resolution, and edge roughness (LWR) has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate repeat units derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond, capable of generating a specific sulfonic acid. Patent Document 2 discloses a sulfonium salt having a sulfonic acid directly attached to the backbone.

To restrain acid diffusion, Patent Document 3 discloses a resist composition comprising a polymer-bound quencher wherein a polymer containing a polymerizable group and having a sulfonium salt structure of a weak acid having a pKa of −0.8 or larger is used as a base polymer. Carboxylic acid, sulfonamide, phenol, and hexafluoroalcohol compounds are exemplified as the weak acid. In general, phenol and hexafluoroalcohol compounds have too weak acidity. Their sulfonium salts are less stable and awkward to synthesize. The resist composition comprising a base polymer having a sulfonium salt structure of weak acid undergoes substantial swell in an alkaline developer. The substantial swell during development raises a problem that contact hole patterns have poor dimension uniformity (CDU) or line-and-space patterns are liable to collapse after formation.

Patent Document 4 discloses a resist material comprising a polymer-bound quencher in the form of a base polymer having a sulfonium salt structure of a fluorinated phenol. The sulfonium salt of phenol is characterized by low swell, but is insufficiently absorptive to EUV. A further improvement in performance is necessary.

### CITATION LIST

Patent Document 1: JP-A 2006-045311 (U.S. Pat. No. 7,482,108)
Patent Document 2: JP-A 2006-178317
Patent Document 3: WO 2019/167737
Patent Document 4: JP-A 2022-115071
Non-Patent Document 1: SPIE Vol. 6520 65203L-1 (2007)

### SUMMARY OF THE INVENTION

An object of the invention is to provide a positive resist composition which exhibits a higher sensitivity and resolution than prior art positive resist compositions and forms patterns of satisfactory profile having reduced edge roughness or dimensional variation after exposure, and a pattern forming process using the same.

Searching for the desirable positive resist composition having a high resolution and reduced edge roughness or dimensional variation, the inventor has found that for that purpose, the acid diffusion distance must be minimized and made uniform on the molecular level. When a polymer comprising repeat units having a sulfonium salt structure of an iodized phenol compound is used as the base polymer, the acid diffusion is minimized because the iodine atom is of large size, the physical contrast is enhanced by highly absorptive iodine atom, and the dissolution contrast is enhanced by the effect of iodine increasing the acidity of phenol group. Because of these three effects, the polymer is effective as a base polymer to formulate a chemically amplified positive resist composition having reduced LWR or improved CDU.

When repeat units having a carboxy or phenolic hydroxy group whose hydrogen is substituted by an acid labile group are incorporated into the polymer in order to further improve the dissolution contrast, there are obtained many advantages including a high sensitivity, a significantly high contrast of alkaline dissolution rate before and after light exposure, and formation of a pattern of satisfactory profile after exposure, having reduced LWR or improved CDU. The resulting positive resist composition is useful as a small-size pattern forming material for the manufacture of VLSIs and photomasks.

In one aspect, the invention provides a positive resist composition comprising a base polymer comprising repeat units (a) having a sulfonium salt structure of an iodized phenol compound.

In one preferred embodiment, the repeat units (a) have the formula (a).

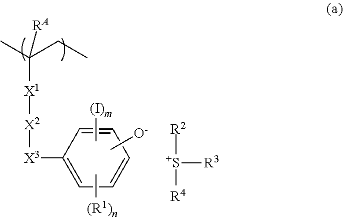

Herein R^{A} is hydrogen or methyl,
X¹ is a single bond, ester bond, ether bond, phenylene group or naphthylene group,
X² is a single bond, C₁-C₁₂ saturated hydrocarbylene group or phenylene group, the saturated hydrocarbylene group may contain at least one moiety selected from ether bond, ester bond, amide bond, lactone ring and sultone ring,
X³ is a single bond, ester bond or ether bond,
R¹ is hydrogen, a C₁-C₄ alkyl group, halogen exclusive of iodine, nitro group or cyano group,
R² to R⁴ are each independently halogen or a C₁-C₂₀ hydrocarbyl group which may contain a heteroatom, R² and R³ may bond together to form a ring with the sulfur atom to which they are attached,
m is an integer of 1 to 4, n is an integer of 0 to 3, and m+n is from 1 to 4.

In one preferred embodiment, the base polymer comprises repeat units of at least one type selected from repeat units (b1) having a carboxy group whose hydrogen is substituted by an acid labile group and repeat units (b2) having a phenolic hydroxy group whose hydrogen is substituted by an acid labile group.

Specifically, the repeat units (b1) have the formula (b1) and the repeat units (b2) have the formula (b2).

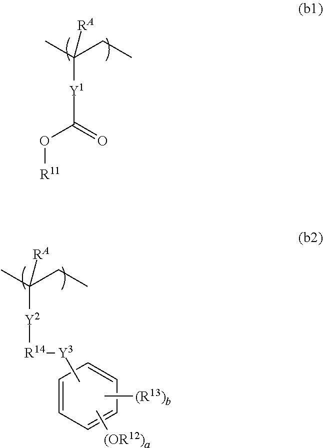

Herein R^{A} is each independently hydrogen or methyl,
Y¹ is a single bond, phenylene, naphthylene, or a C₁-C₁₂ linking group containing at least one moiety selected from ester bond, ether bond and lactone ring, the phenylene, naphthylene and linking groups may have at least one moiety selected from halogen, hydroxy, C₁-C₈ saturated hydrocarbyloxy moiety, and C₂-C₈ saturated hydrocarbylcarbonyloxy moiety,
Y² is a single bond, ester bond or amide bond,
Y³ is a single bond, ether bond or ester bond,
R¹¹ and R¹² are each independently an acid labile group,
R¹³ is hydroxy, halogen, trifluoromethyl, cyano, a C₁-C₆ saturated hydrocarbyl group, C₁-C₆ saturated hydrocarbyloxy group, or C₂-C₇ saturated hydrocarbylcarbonyloxy group,
R¹⁴ is a single bond or a C₁-C₆ alkanediyl group in which some —CH₂— may be replaced by an ether bond or ester bond,
a is 1 or 2, b is an integer of 0 to 4, and a+b is from 1 to 5.

In one preferred embodiment, the base polymer further comprises repeat units (c) having an adhesive group selected from hydroxy group, carboxy group, lactone ring, carbonate bond, thiocarbonate bond, carbonyl group, cyclic acetal group, ether bond, ester bond, sulfonate ester bond, cyano group, amide bond, —O—C(═O)—S—, and —O—C(═O)—NH—.

In one preferred embodiment, the base polymer further comprises repeat units of at least one type selected from repeat units having the formula (d1), repeat units having the formula (d2), repeat units having the formula (d3), repeat units having the formula (d4), and repeat units having the formula (d5).

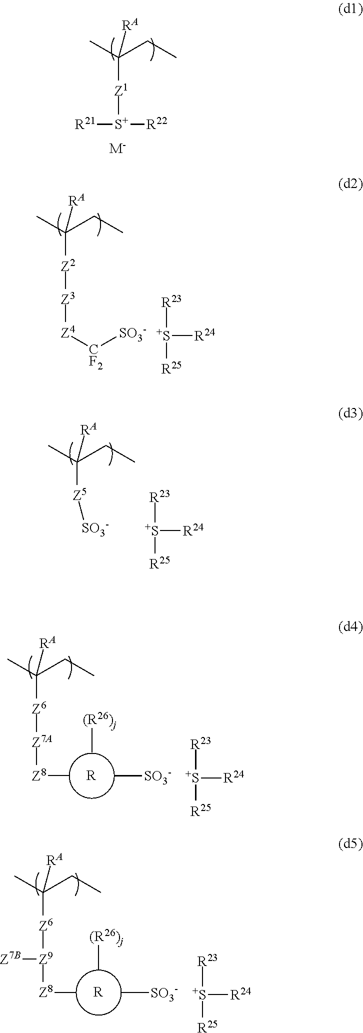

Herein R^{A} is each independently hydrogen or methyl,

Z¹ is a single bond, a C₁-C₆ aliphatic hydrocarbylene group, phenylene group, naphthylene group, or C₇-C₁₈ group obtained by combining the foregoing, or —O—Z¹¹—, —C(═O)—O—Z¹¹— or —C(═O)—NH—Z¹¹—, Z¹¹ is a C₁-C₆ aliphatic hydrocarbylene group, phenylene group, naphthylene group, or C₇-C₁₈ group obtained by combining the foregoing, which may contain a carbonyl moiety, ester bond, ether bond or hydroxy moiety,
Z² is a single bond or ester bond,
Z³ is a single bond, —Z³¹—C(═O)—O—, —Z³¹—O— or —Z³¹—O—C(═O)—, Z³¹ is a C₁-C₁₂ aliphatic hydrocarbylene group, phenylene group, or C₇-C₁₈ group obtained by combining the foregoing, which may contain a carbonyl moiety, ester bond, ether bond, iodine or bromine,
Z⁴ is methylene, 2,2,2-trifluoro-1,1-ethanediyl or carbonyl,
Z⁵ is a single bond, methylene, ethylene, phenylene, fluorinated phenylene, trifluoromethyl-substituted phenylene group, —O—Z¹¹—, —C(═O)—O—Z¹¹—, or —C(═O)—NH—Z⁵¹—, Z⁵¹ is a C₁-C₆ aliphatic hydrocarbylene group, phenylene group, fluorinated phenylene group, or trifluoromethyl-substituted phenylene group, which may contain a carbonyl moiety, ester bond, ether bond, halogen or hydroxy moiety,
Z⁶ is a single bond, phenylene, naphthylene, ester bond or amide bond,
Z^{7A} is a single bond or a C₁-C₂₄ divalent organic group which may contain at least one element selected from halogen, oxygen, nitrogen and sulfur,
Z^{7B} is a C₁-C₁₀ monovalent organic group which may contain at least one element selected from halogen, oxygen, nitrogen and sulfur,
Z⁸ is a single bond, ether bond, ester bond, thioether bond, or C₁-C₆ alkanediyl group,
Z⁹ is a C₁-C₁₂ trivalent organic group which may contain at least one element selected from oxygen, nitrogen and sulfur,
R²¹ to R²⁵ are each independently halogen or a C₁-C₂₀ hydrocarbyl group which may contain a heteroatom, R²³ and R²⁴ may bond together to form a ring with the sulfur atom to which they are attached,
R²⁶ is each independently a C₁-C₁₀ saturated hydrocarbyl group, C₆-C₁₀ aryl group, fluorine, iodine, trifluoromethoxy, difluoromethoxy, cyano or nitro group,
the circle R is a C₆-C₁₀ (j+2)-valent aromatic hydrocarbon group,
j is each independently an integer of 0 to 5, and
M⁻ is a non-nucleophilic counter ion.

The resist composition may further comprise an acid generator capable of generating a strong acid, an organic solvent, a quencher, and/or a surfactant.

In another aspect, the invention provides a pattern forming process comprising the steps of applying the positive resist composition defined herein onto a substrate to form a resist film thereon, exposing the resist film to high-energy radiation, and developing the exposed resist film in a developer.

Typically, the high-energy radiation is i-line, KrF excimer laser, ArF excimer laser, EB or EUV of wavelength 3 to 15 nm.

### Advantageous Effects of Invention

Because of the high decomposition efficiency of the acid generator, the positive resist composition of the invention is effective for restraining acid diffusion, exhibits a high sensitivity and resolution, and forms a pattern of satisfactory profile after exposure, with reduced edge roughness and dimensional variation. The positive resist composition is useful as a micropatterning material for the fabrication of VLSI and photomasks and a pattern-forming material adapted for the EB or EUV lithography. The positive resist composition is useful not only in the lithography for forming semiconductor circuits, but also in the lithography for forming mask circuit patterns, micro-machines, thin-film magnetic head circuits, and the like.

### DETAILED DESCRIPTION OF THE INVENTION

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, the broken line (---) or asterisk (*) designates a point of attachment or valence bond. As used herein, the term “fluorinated” refers to a fluorine-substituted or fluorine-containing compound or group, and “iodized” refers to an iodine-substituted or iodine-containing compound or group. The terms “group” and “moiety” are interchangeable.

The abbreviations and acronyms have the following meaning.
EB: electron beam
EUV: extreme ultraviolet
Mw: weight average molecular weight
Mn: number average molecular weight
Mw/Mn: molecular weight distribution or dispersity
GPC: gel permeation chromatography
PEB: post-exposure bake
PAG: photoacid generator
LWR: line width roughness
CDU: critical dimension uniformity

### [Resist Composition]

One embodiment of the invention is a positive resist composition comprising a base polymer comprising repeat units (a) having a sulfonium salt structure of an iodized phenol compound.

The preferred repeat units (a) have the formula (a).

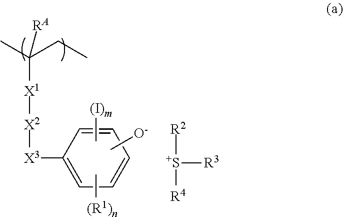

In formula (a), R^{A} is hydrogen or methyl.

In formula (a), X¹ is a single bond, ester bond, ether bond, phenylene group or naphthylene group.

In formula (a), X² is a single bond, C₁-C₁₂ saturated hydrocarbylene group or phenylene group. The saturated hydrocarbylene group may contain at least one moiety selected from ether bond, ester bond, amide bond, lactone ring and sultone ring. The saturated hydrocarbylene group may be straight, branched or cyclic. Examples thereof include C₁-C₁₂ alkanediyl groups such as methanediyl, ethane-1,1-diyl, ethane-1,2-diyl, propane-1,2-diyl, propane-1,3-diyl, propane-2,2-diyl, butane-1,2-diyl, butane-1,3-diyl, butane-1,4-diyl, butane-2,2-diyl, butane-2,3-diyl, 2-methylpropane-1,3-diyl, pentane-1,5-diyl, hexane-1,6-diyl, heptane-1,7-diyl, octane-1,8-diyl, nonane-1,9-diyl, and decane-1,10-diyl; C₃-C₁₂ cyclic saturated hydrocarbylene groups such as cyclopentanediyl, cyclohexanediyl, norbornanediyl and adamantanediyl; and combinations thereof.

In formula (a), X³ is a single bond, ester bond or ether bond.

In formula (a), R¹ is hydrogen, a C₁-C₄ alkyl group, halogen exclusive of iodine, nitro group or cyano group. Exemplary alkyl groups include methyl, ethyl, n-propyl, isopropyl, n-butyl, isobutyl, sec-butyl and tert-butyl.

In formula (a), m is an integer of 1 to 4, n is an integer of 0 to 3, and m+n is from 1 to 4. Preferably, m is 2, 3 or 4, more preferably 2 or 3, and n is 0, 1 or 2, more preferably 0 or 1.

Examples of the anion in the monomer from which repeat units (a) are derived are shown below, but not limited thereto. R^{A} is as defined above.

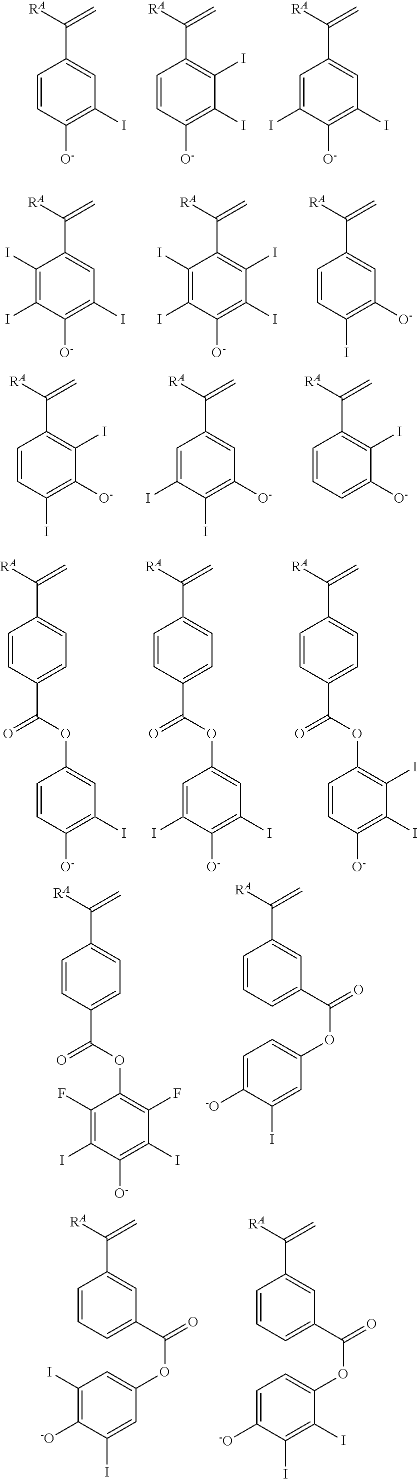

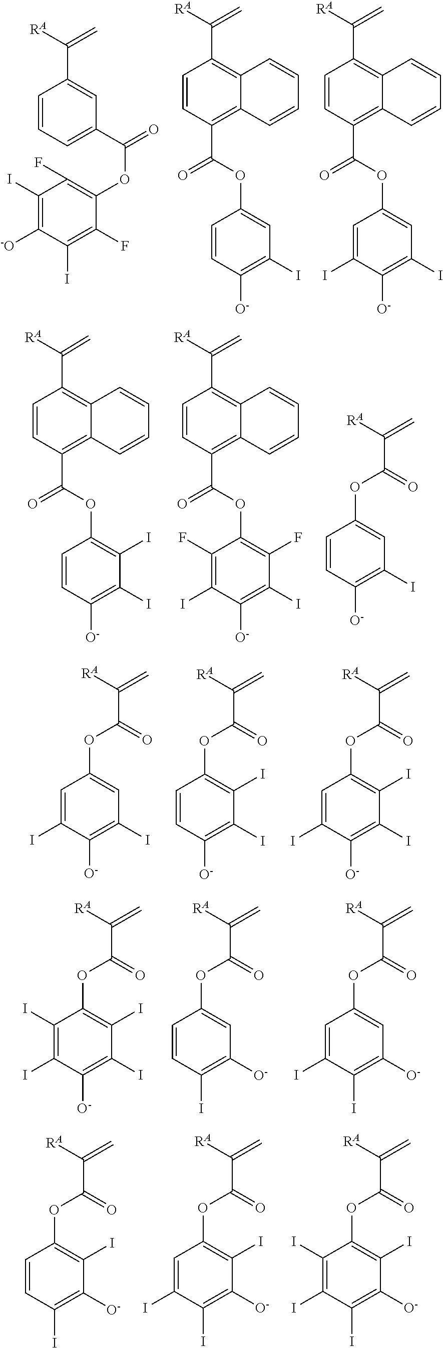

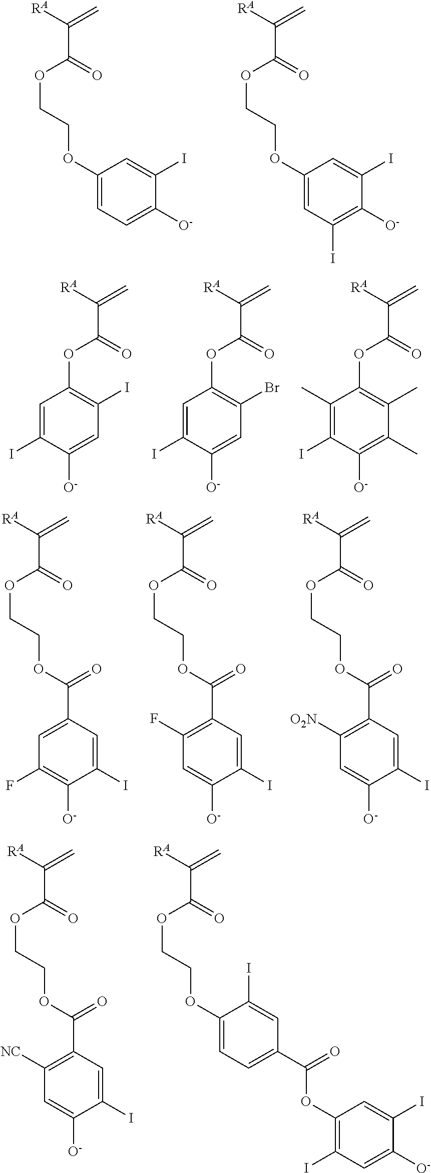

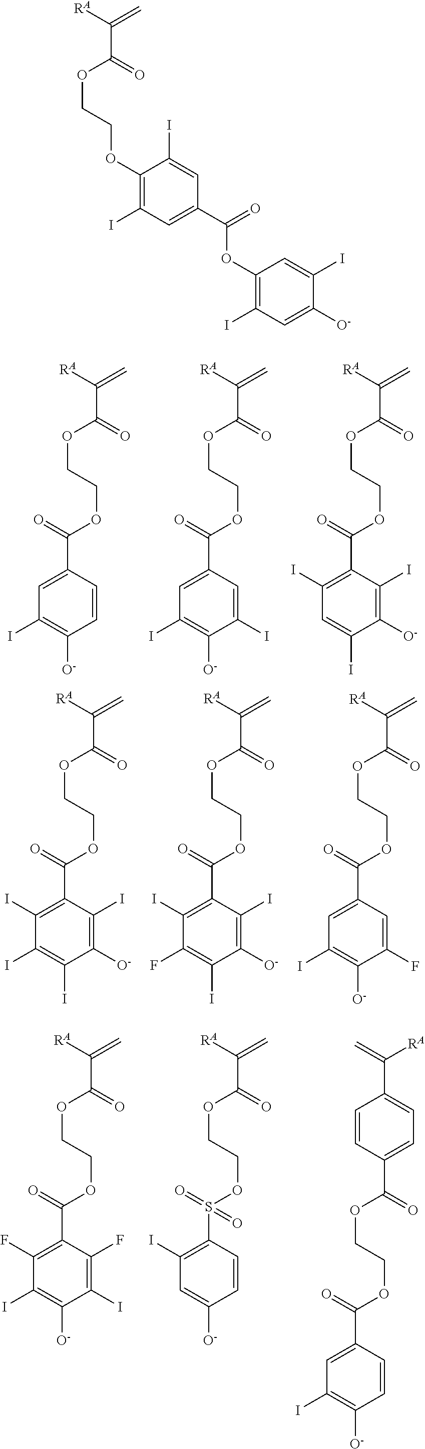

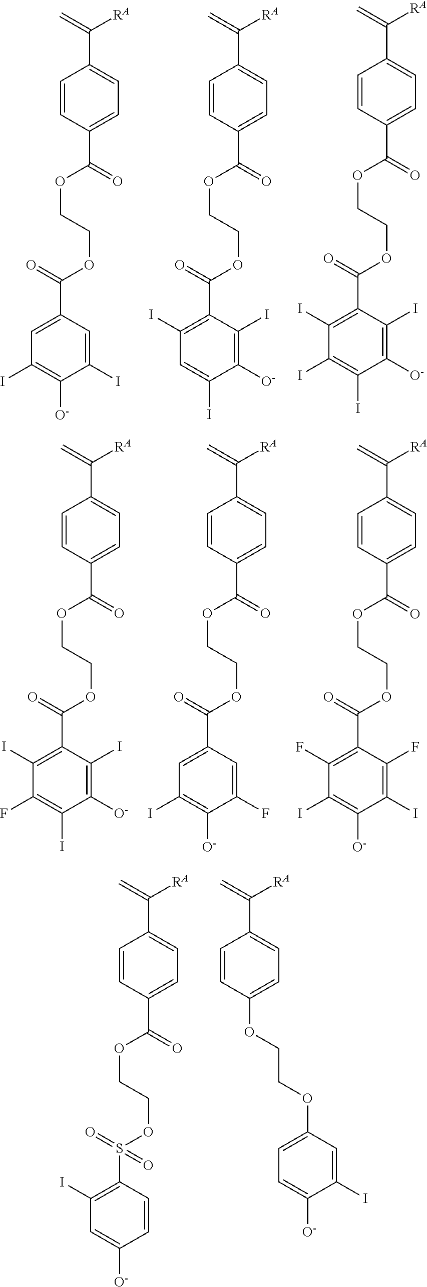

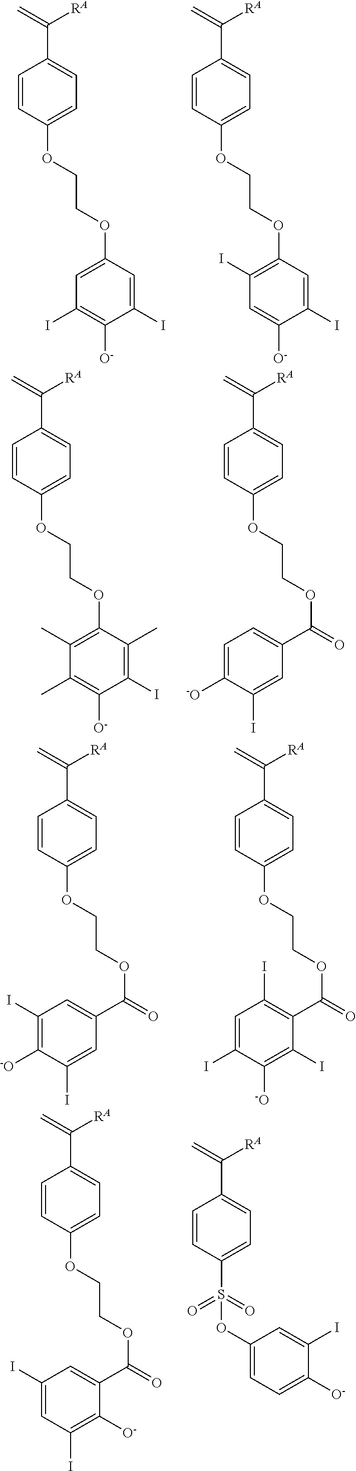

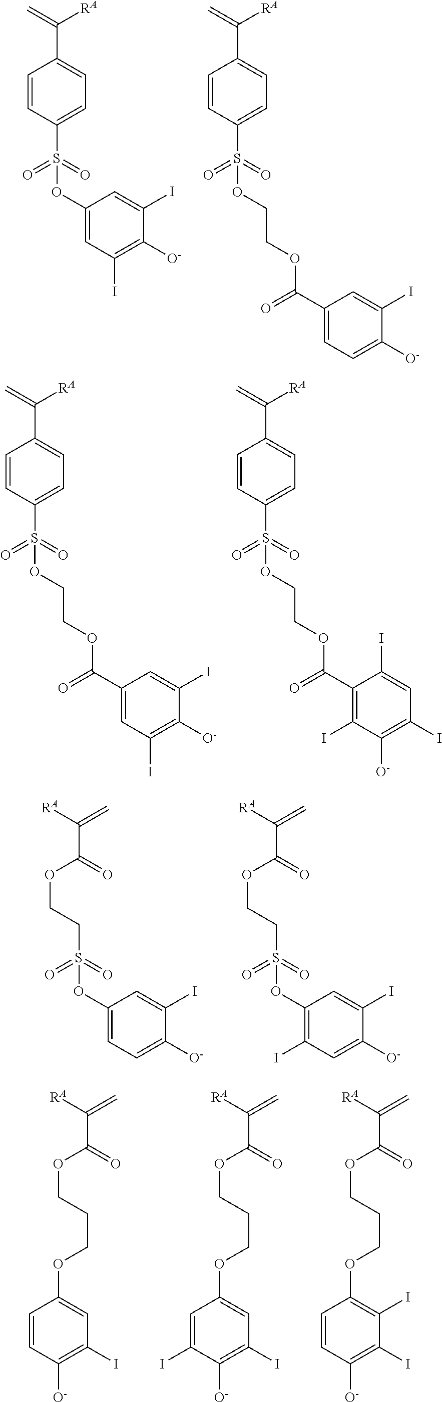

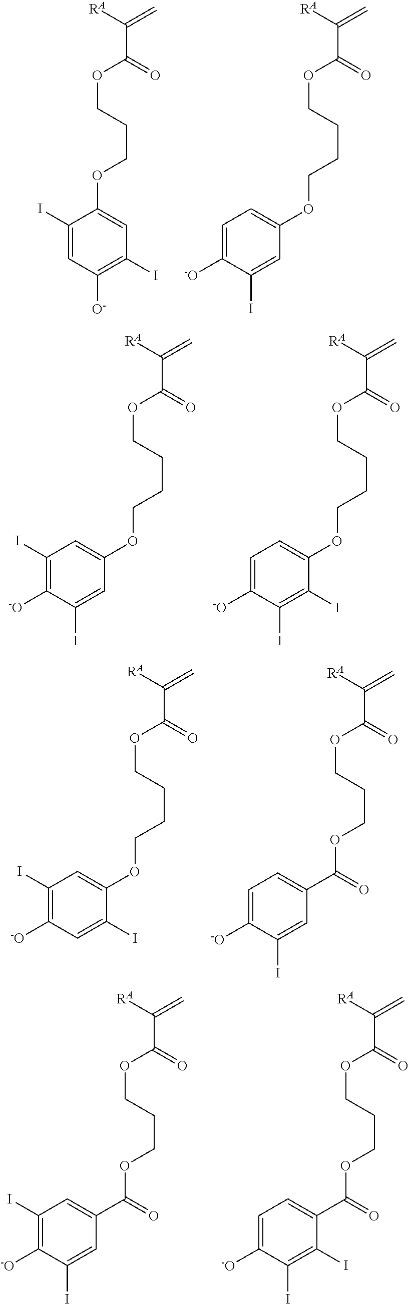

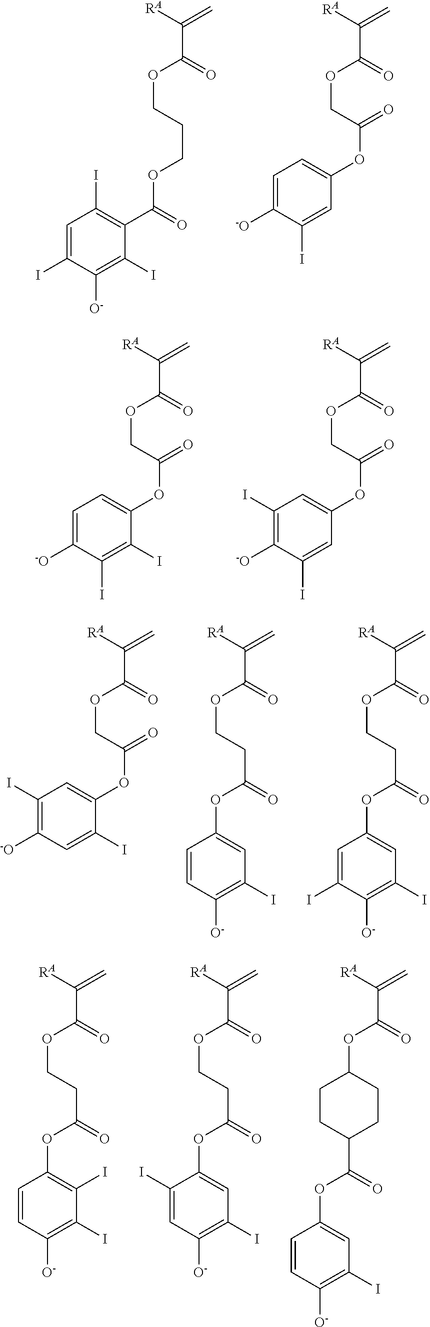

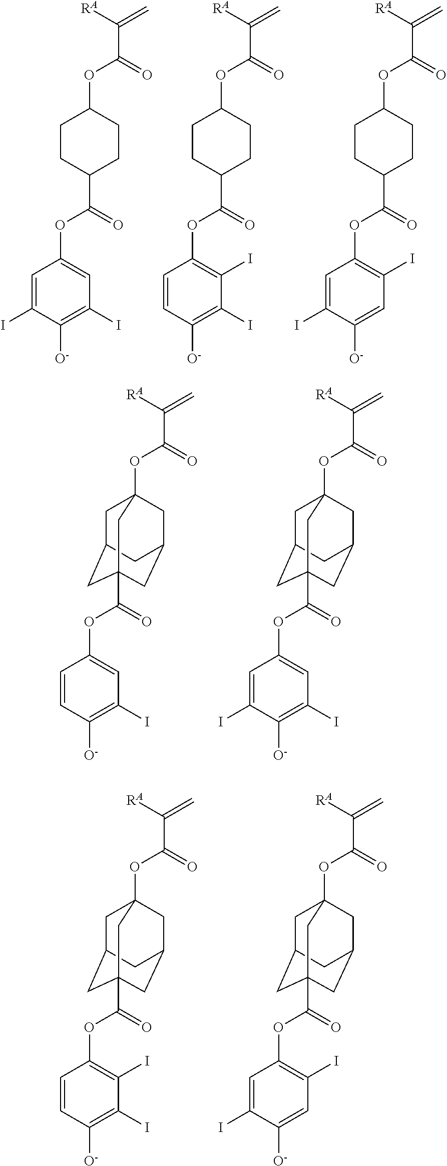

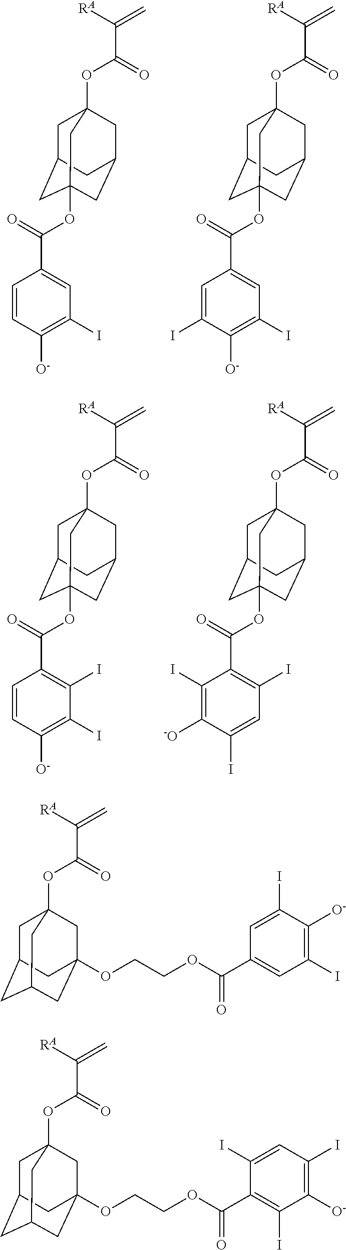

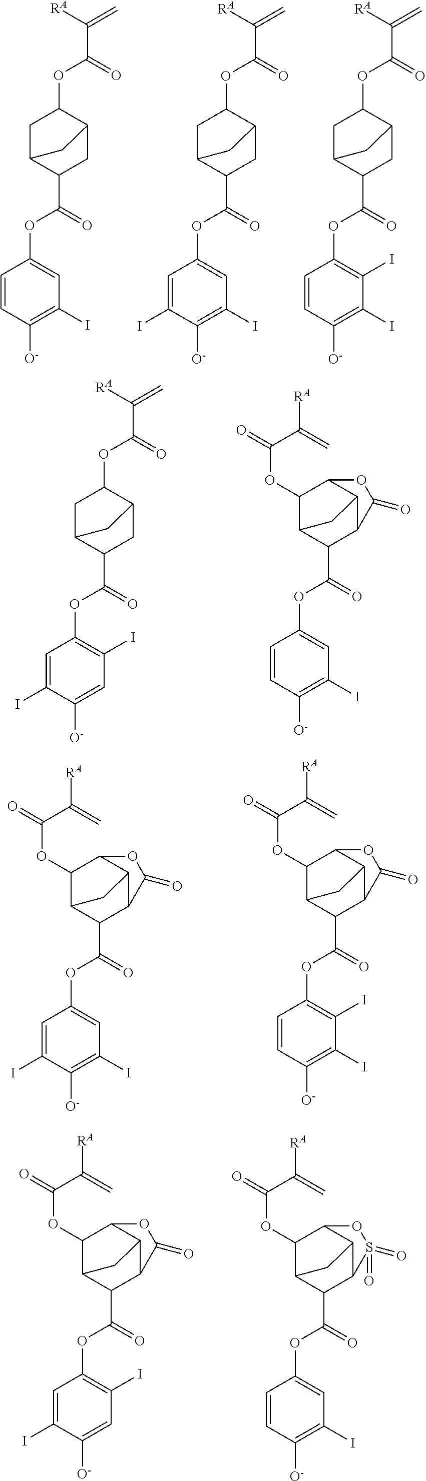

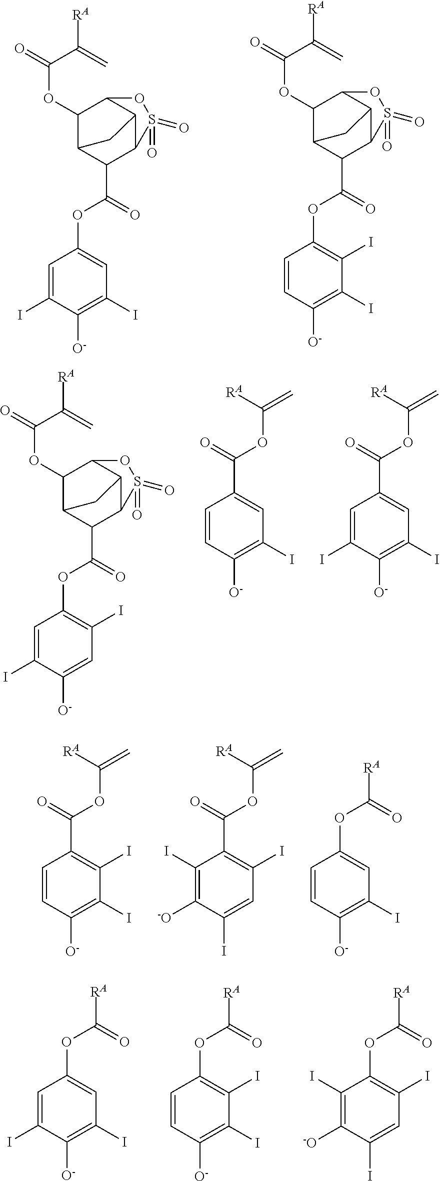

In formula (a), R² to R⁴ are each independently halogen or a C₁-C₂₀ hydrocarbyl group which may contain a heteroatom.

Suitable halogen atoms represented by R² to R⁴ include fluorine, chlorine, bromine and iodine.

The C₁-C₂₀ hydrocarbyl group represented by R² to R⁴ may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl and icosyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, propenyl, butenyl, and hexenyl; C₂-C₂₀ alkynyl groups such as ethynyl, propynyl, and butynyl; C₃-C₂₀ cyclic unsaturated aliphatic hydrocarbyl groups such as cyclohexenyl and norbornenyl; C₆-C₂₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, and tert-butylnaphthyl; C₇-C₂₀ aralkyl groups such as benzyl and phenethyl; and combinations thereof.

In the hydrocarbyl group, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, nitro, mercapto, pentafluorosulfanyl, carbonyl, ether bond, ester bond, sulfonate ester bond, carbonate bond, lactone ring, sultone ring, carboxylic anhydride (—C(═O)—O—C(═O)—), or haloalkyl moiety.

Also, R² and R³ may bond together to form a ring with the sulfur atom to which they are attached. Rings of the structure shown below are preferred.

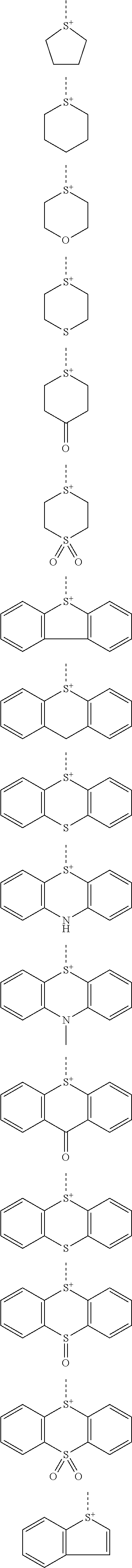

Herein, the broken line denotes a point of attachment to R⁴.

Examples of the sulfonium cation in repeat units (a) are shown below, but not limited thereto.

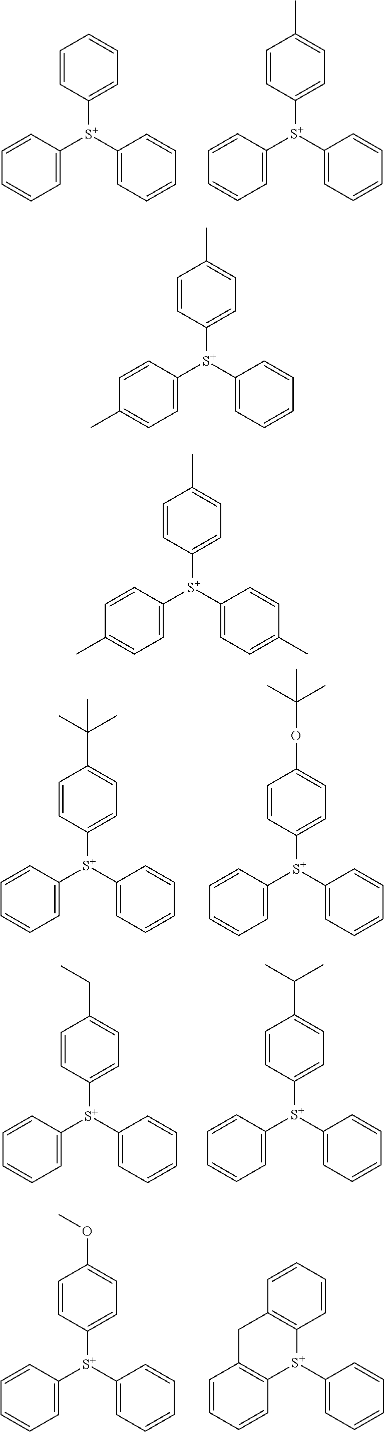

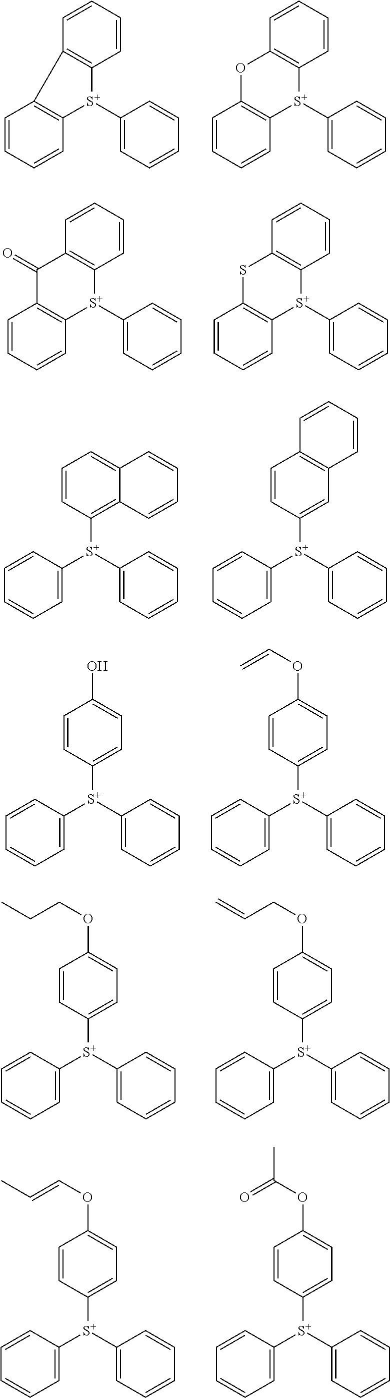

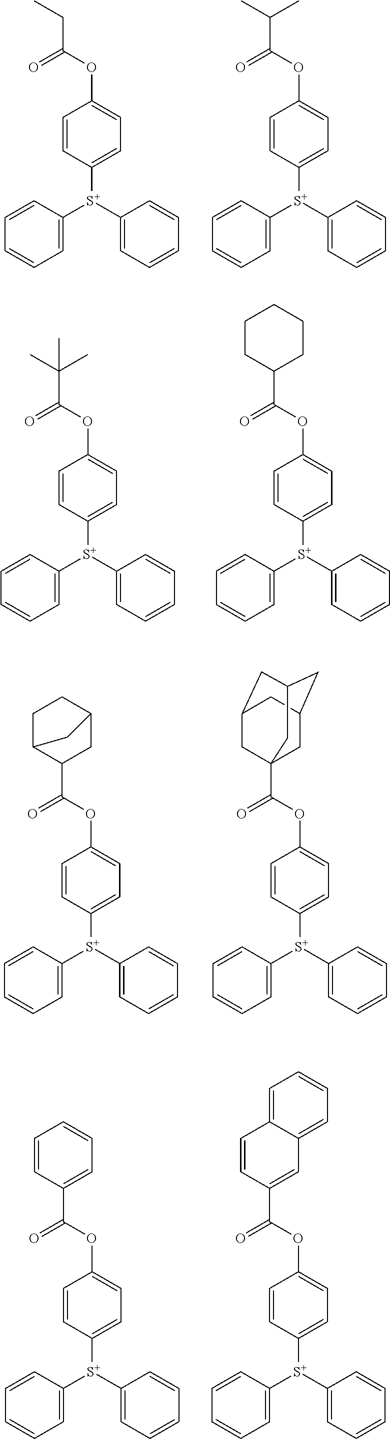

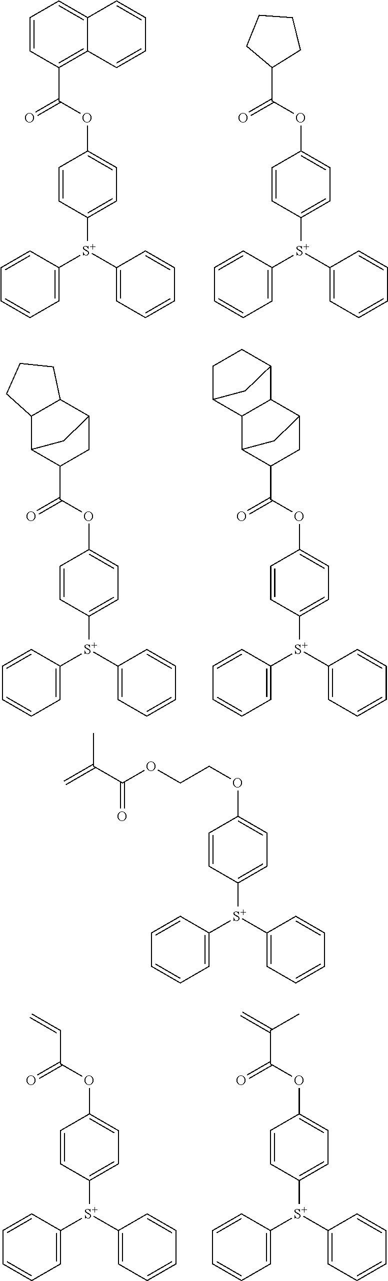

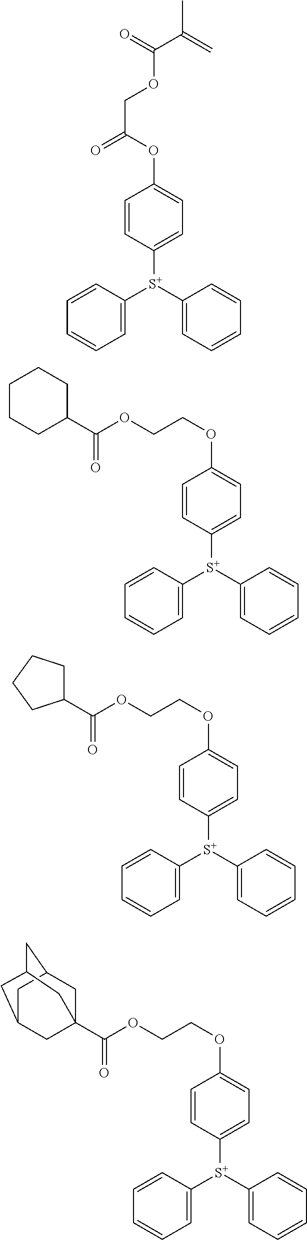

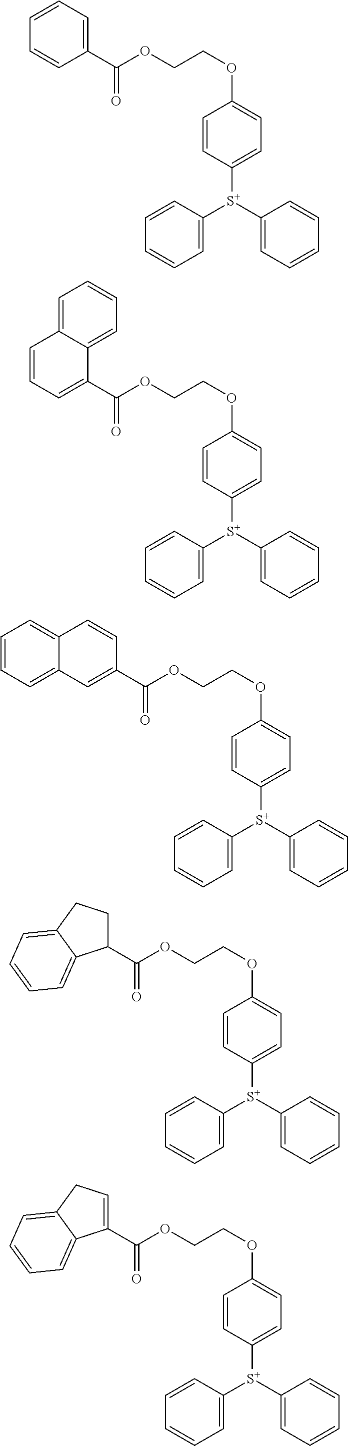

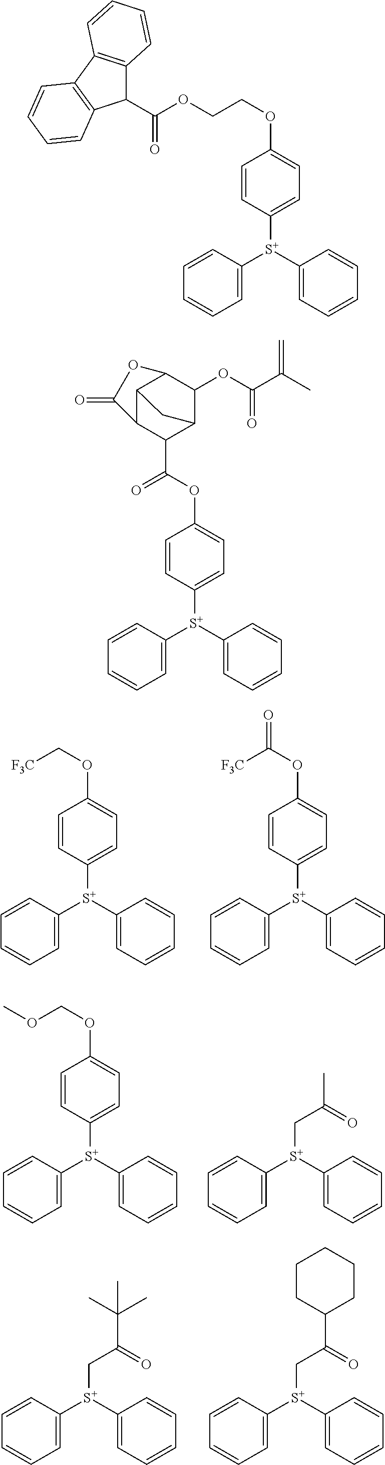

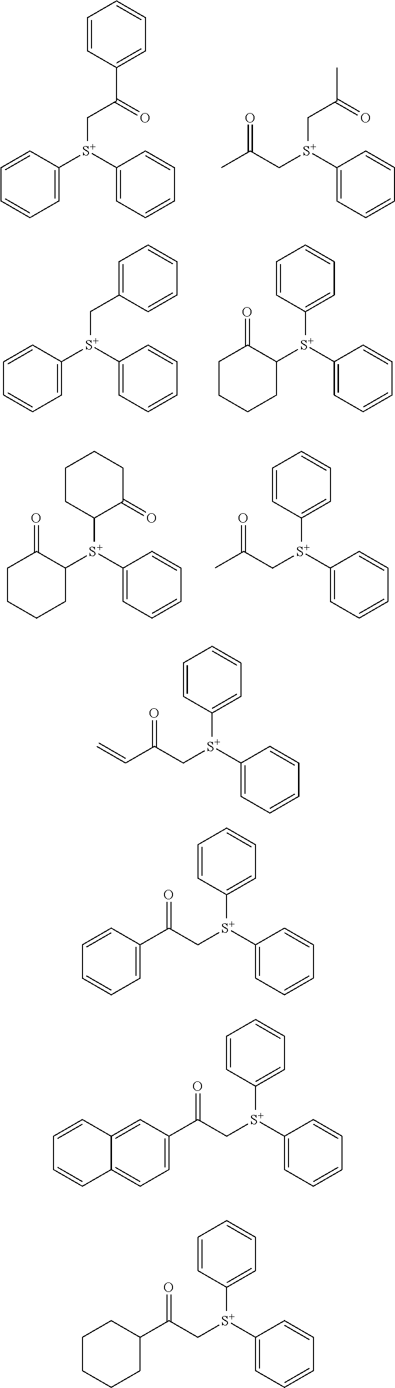

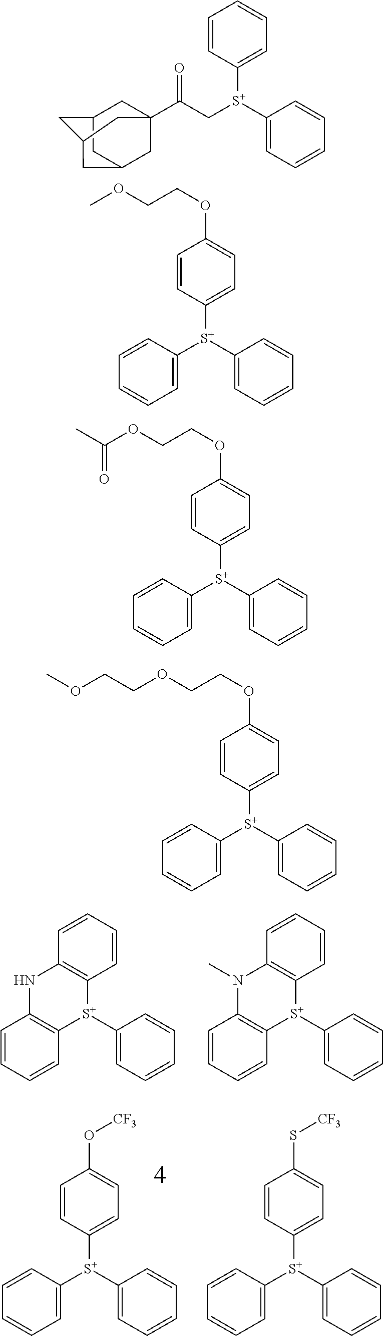

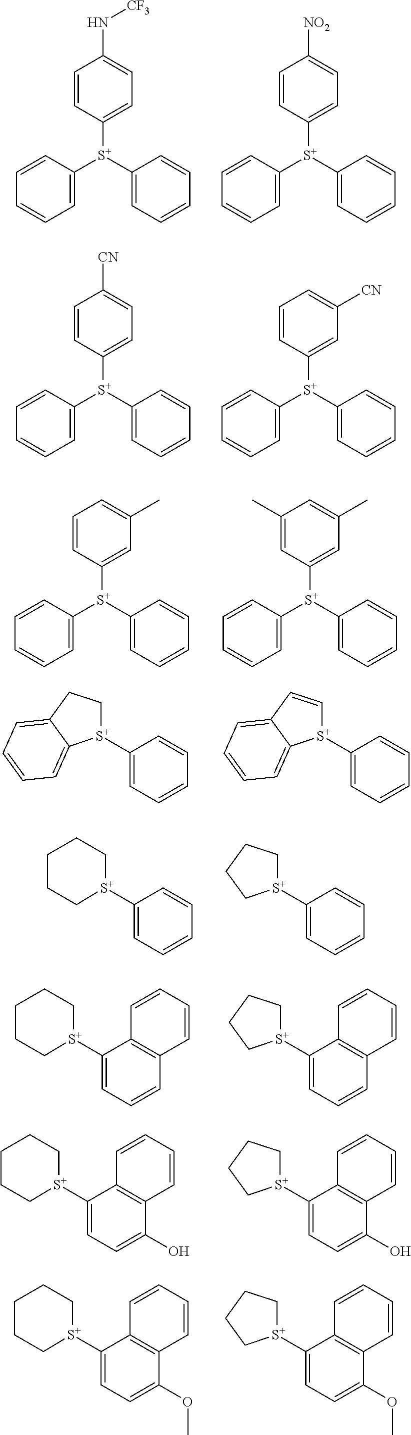

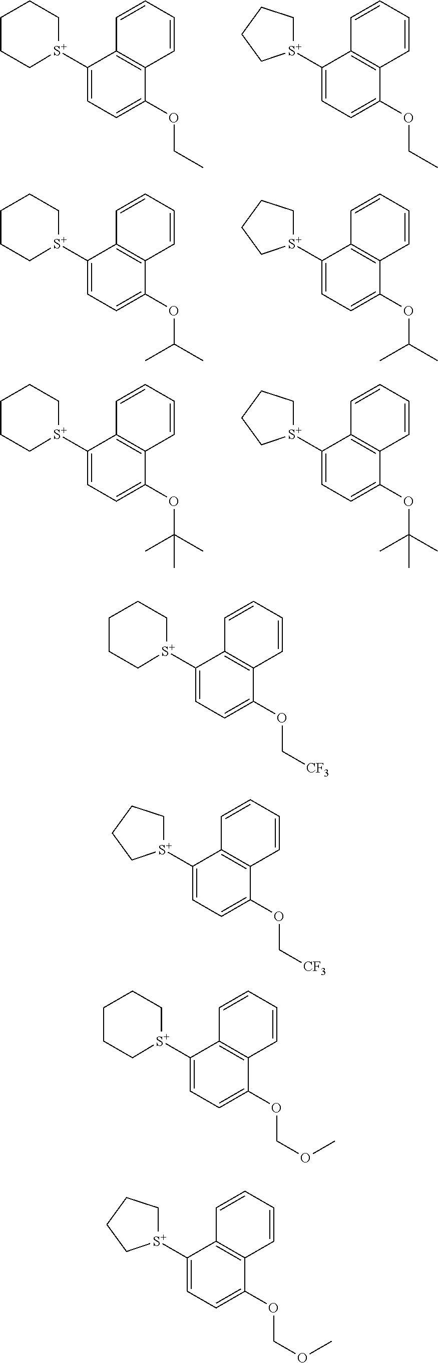

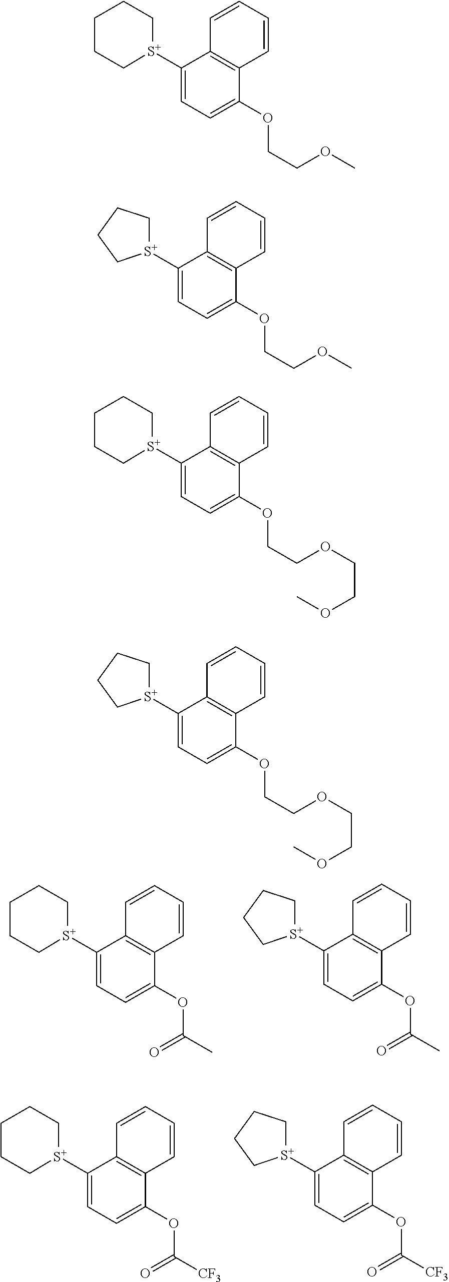

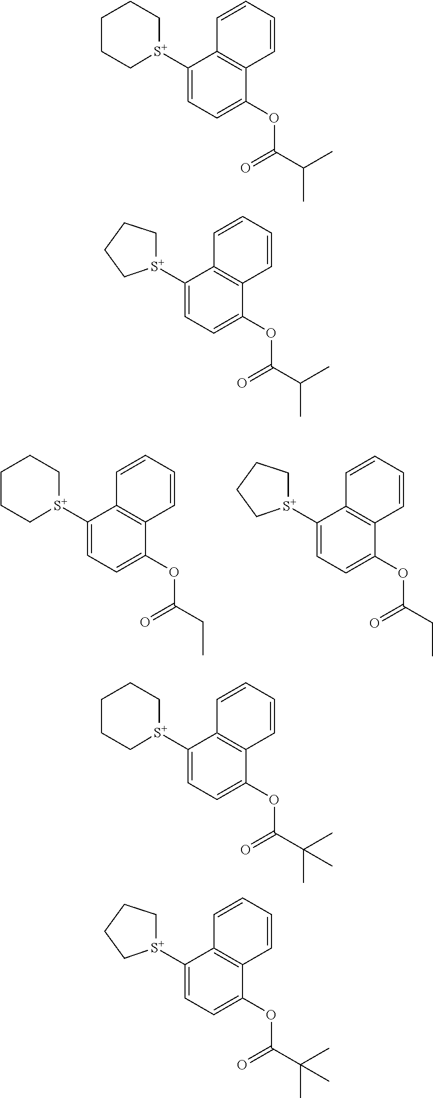

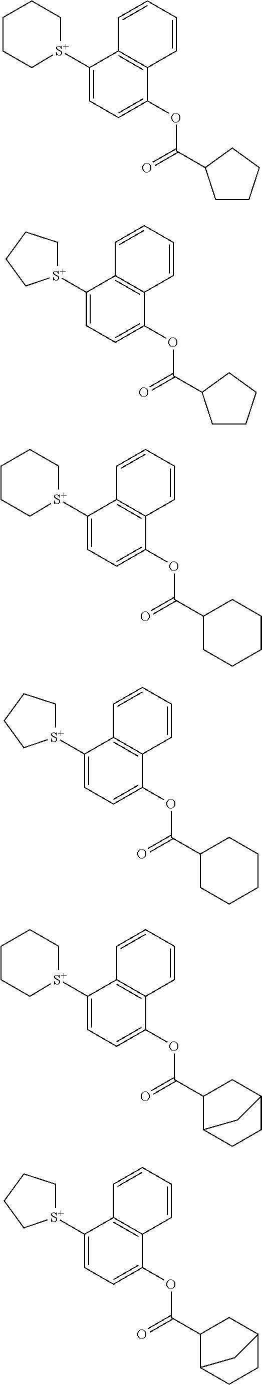

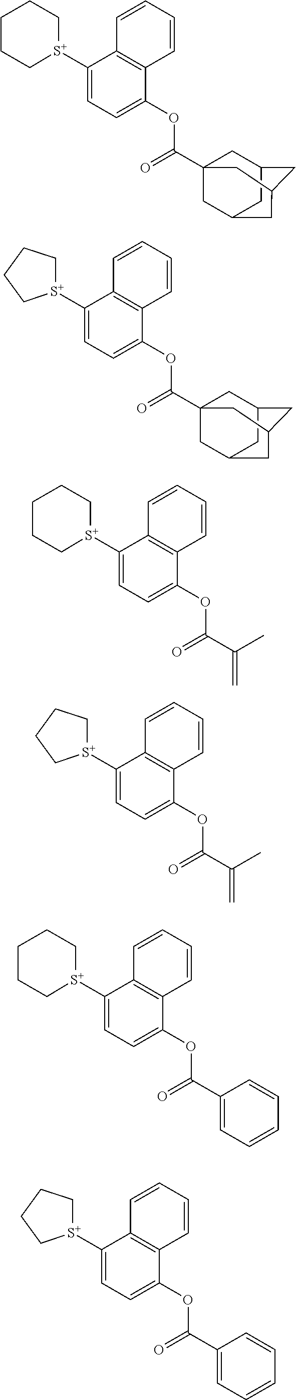

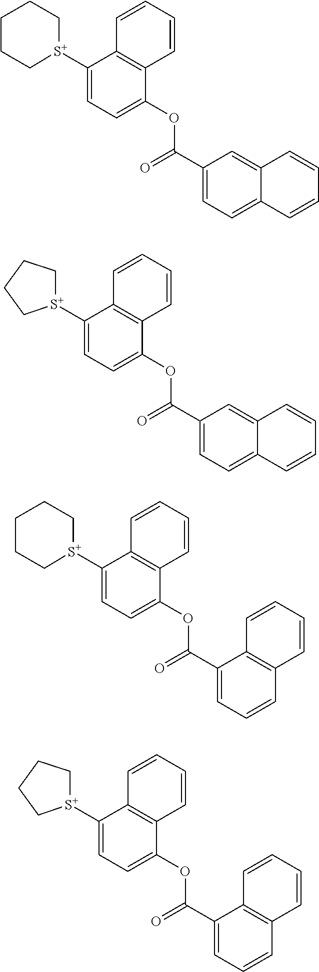

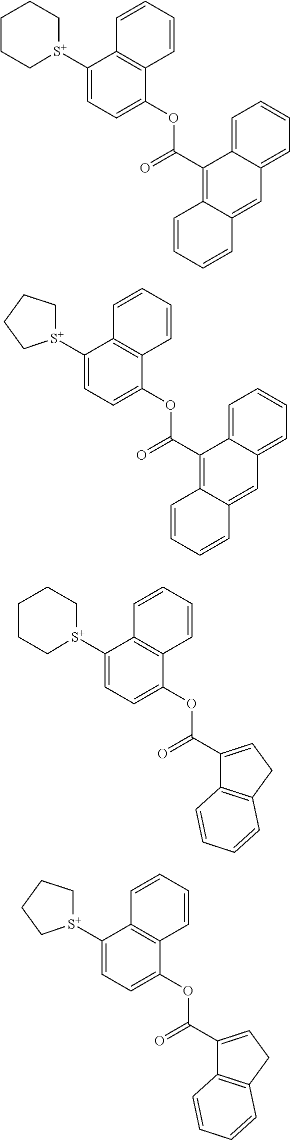

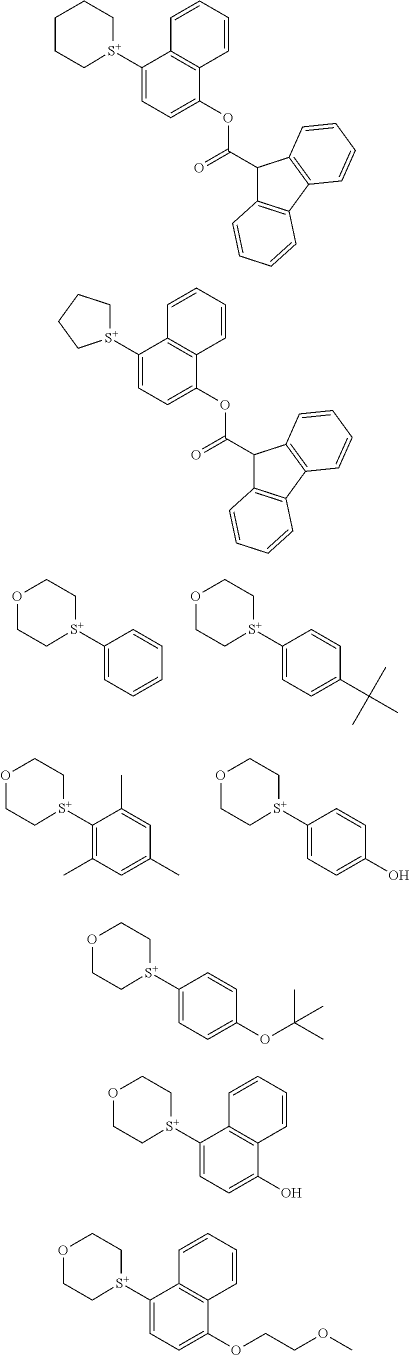

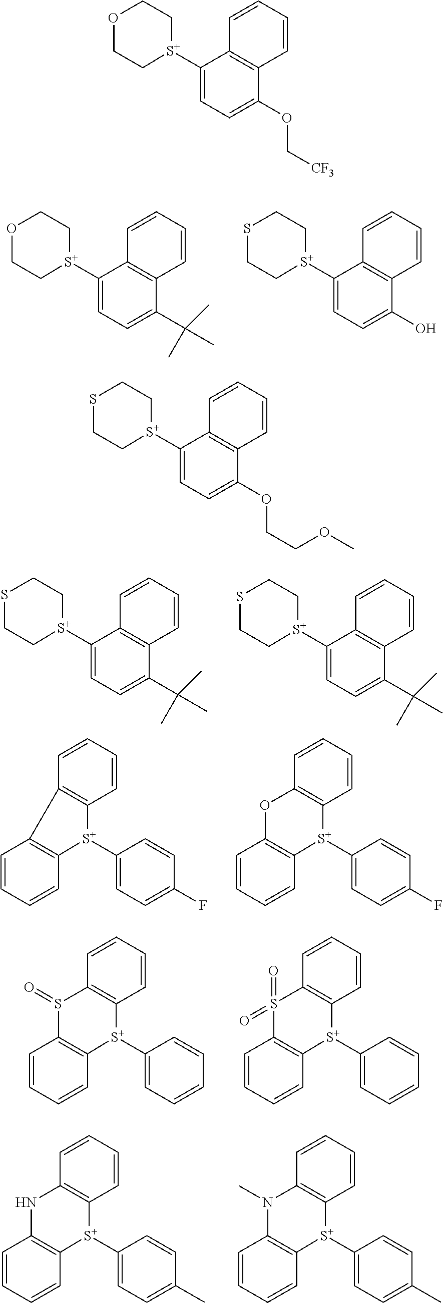

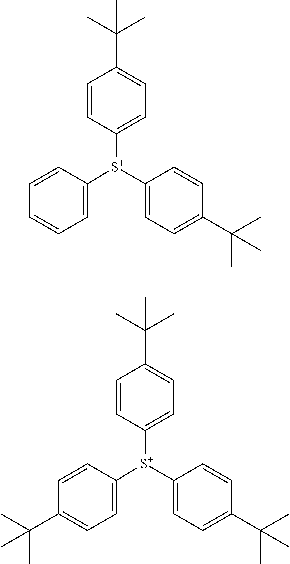

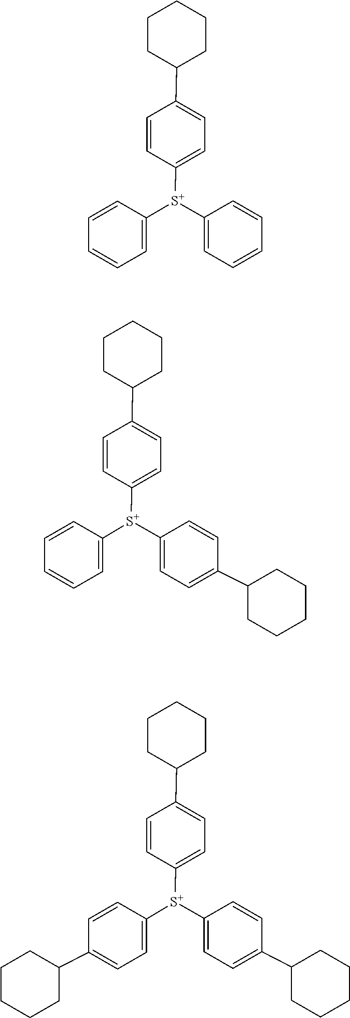

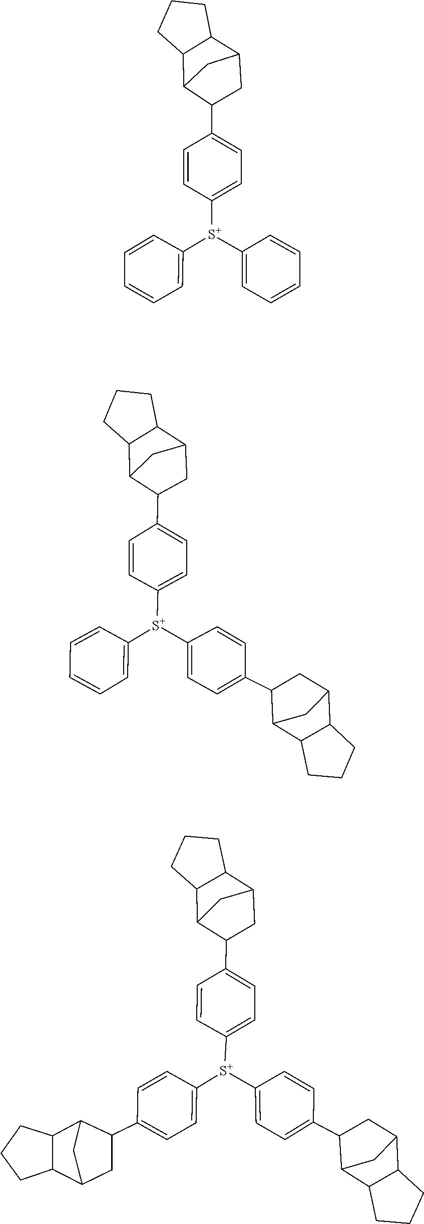

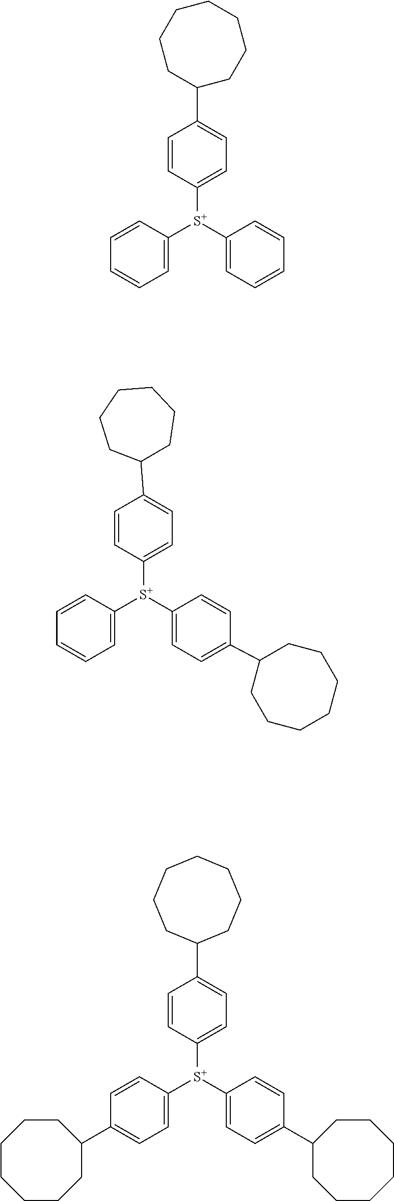

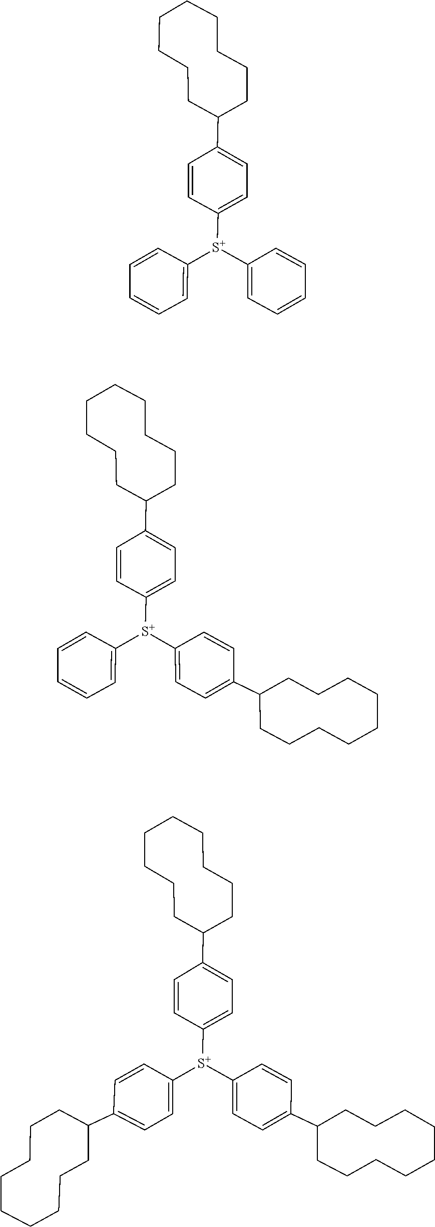

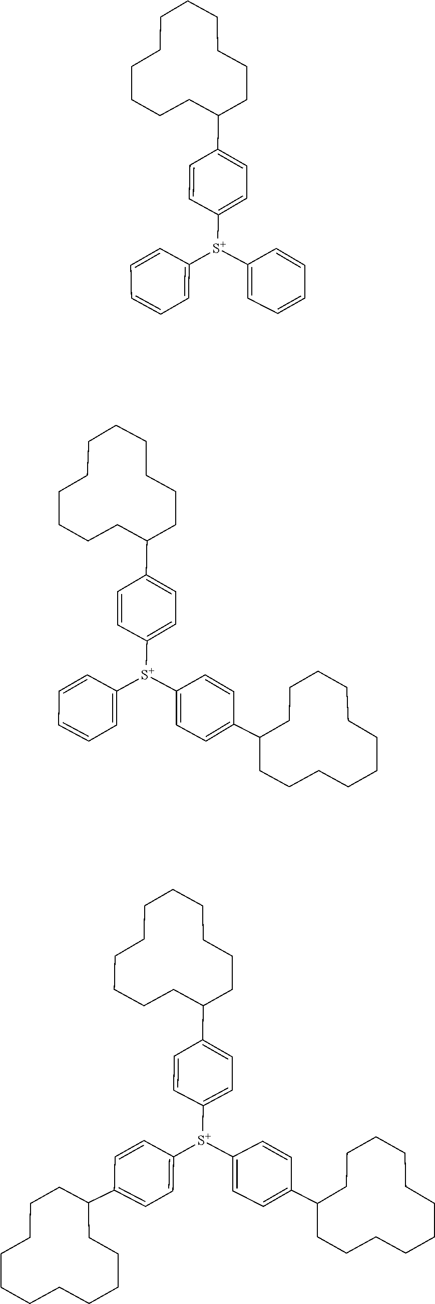

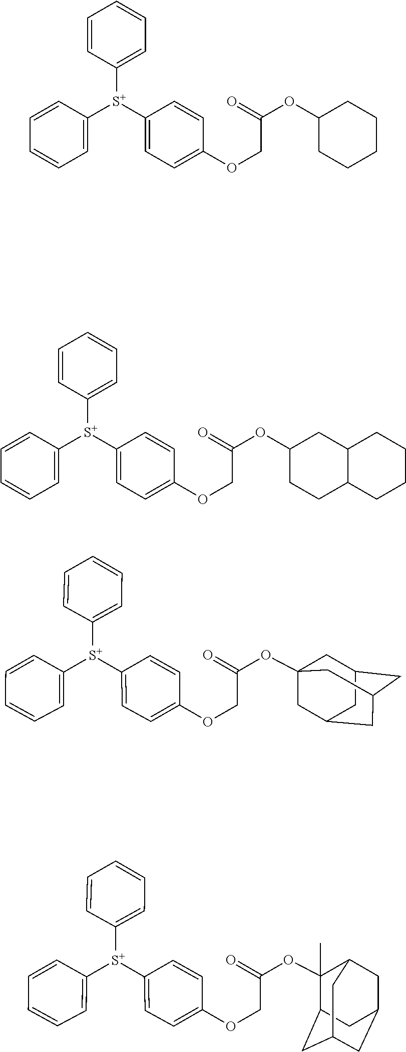

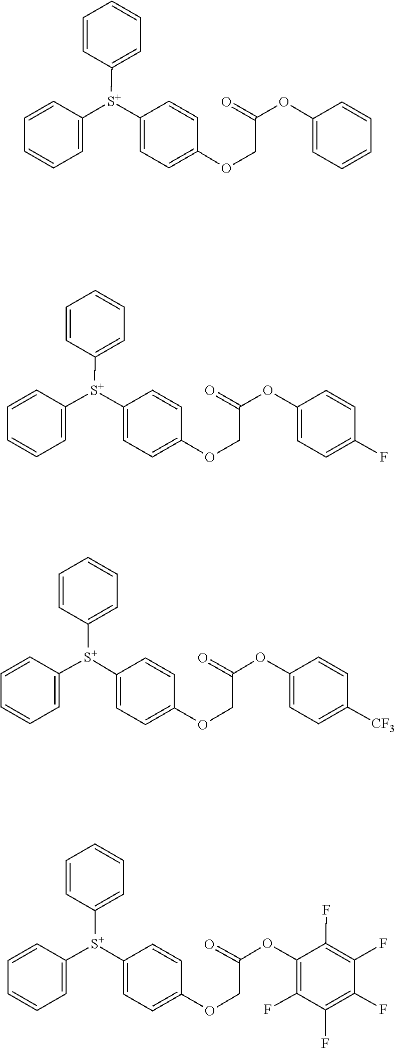

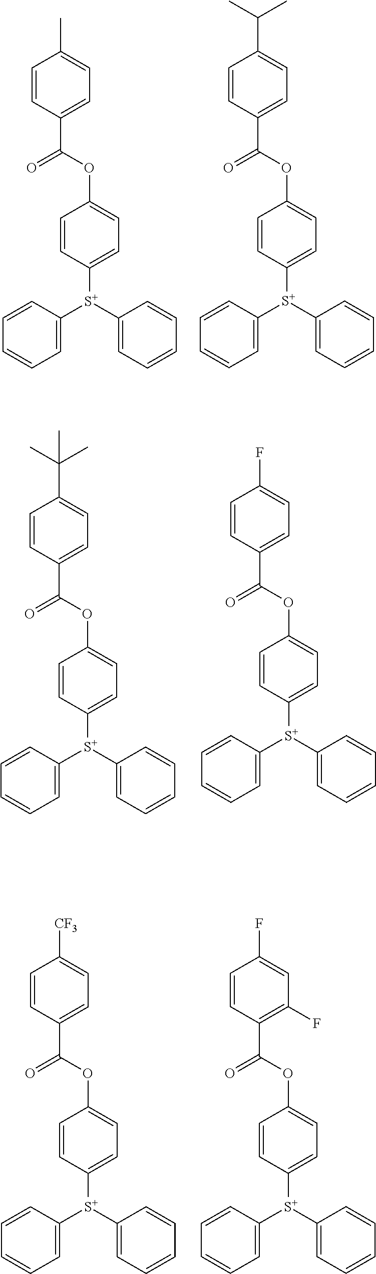

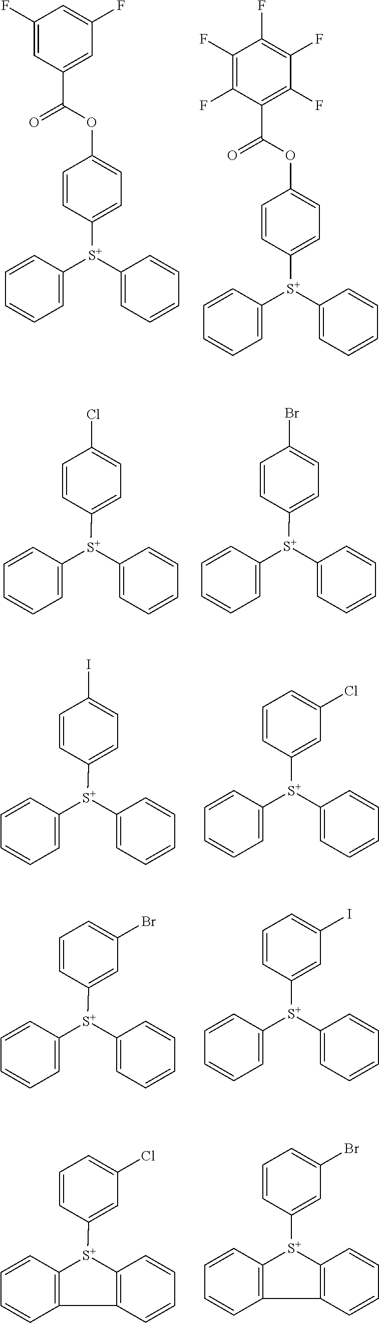

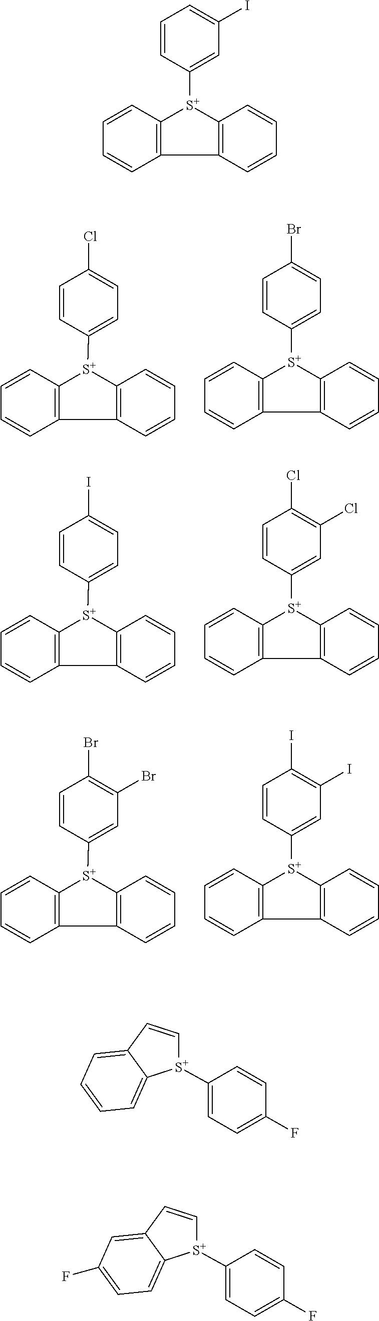

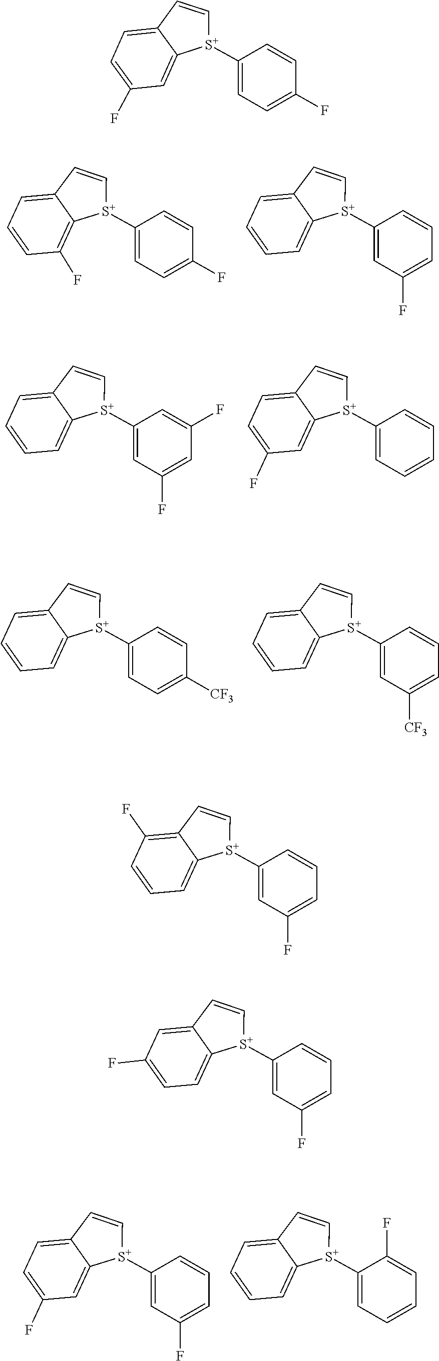

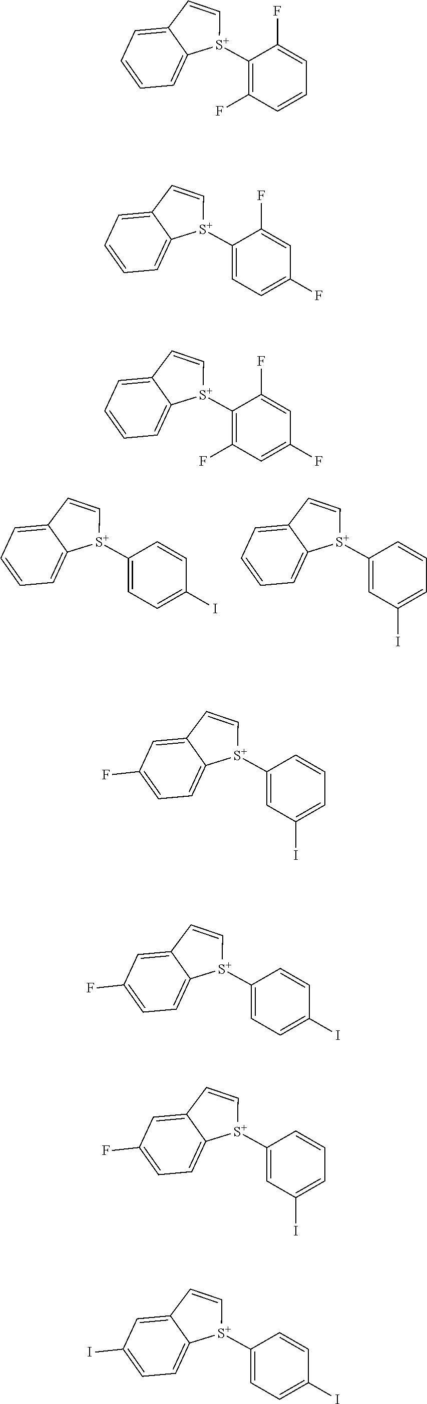

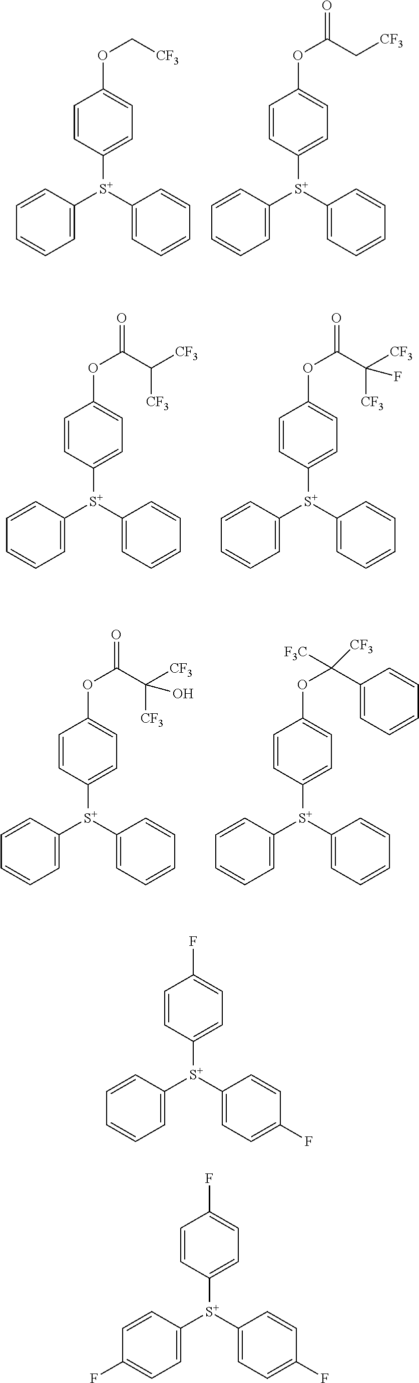

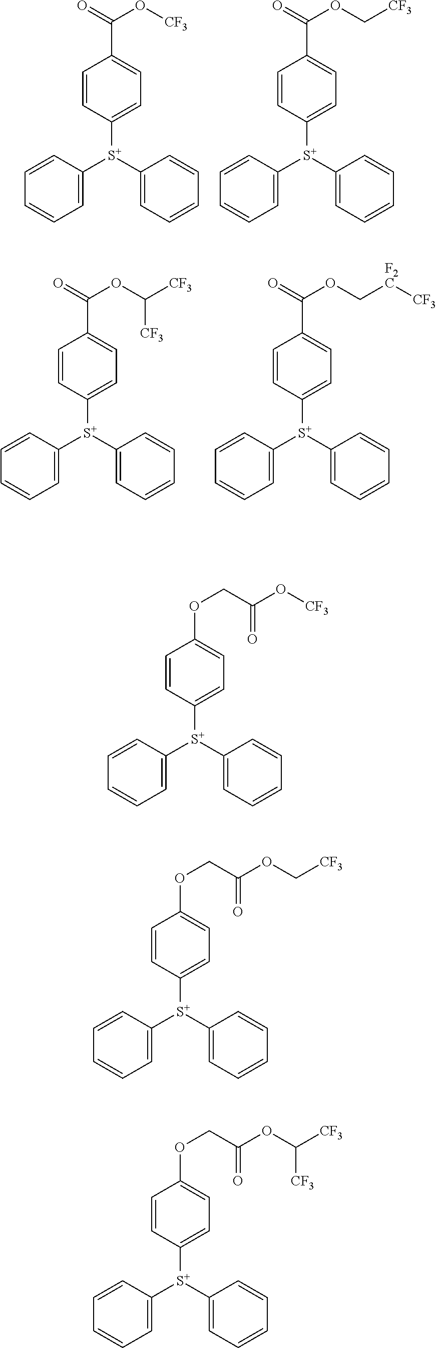

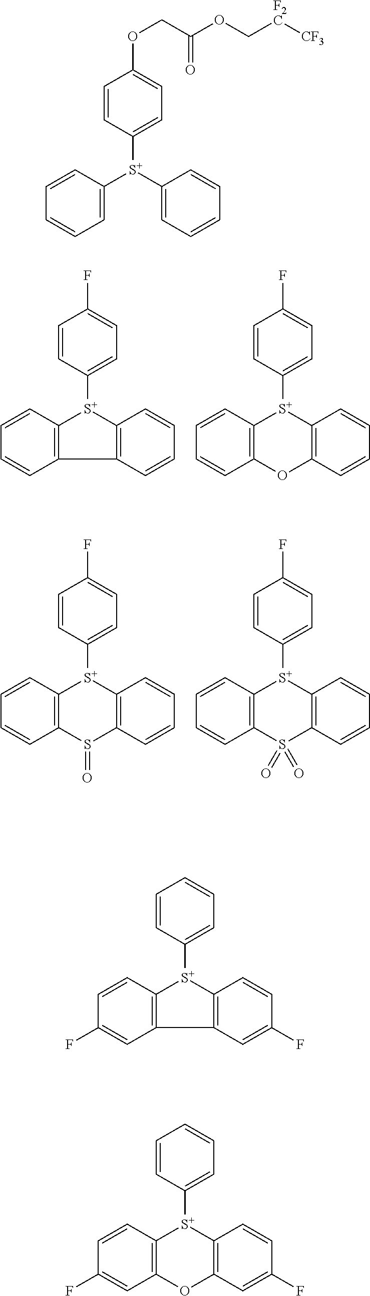

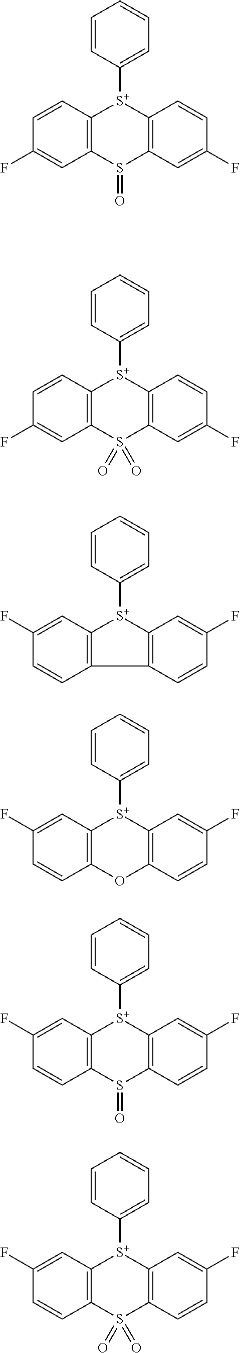

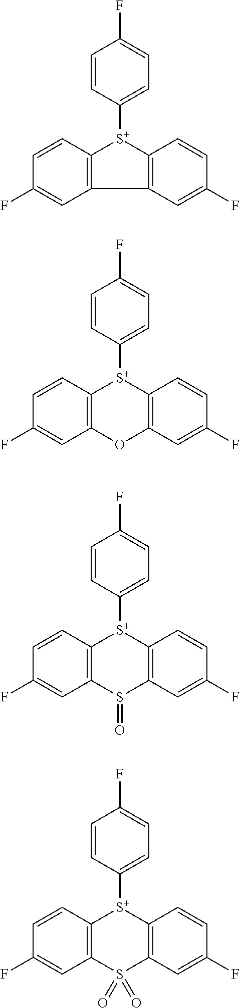

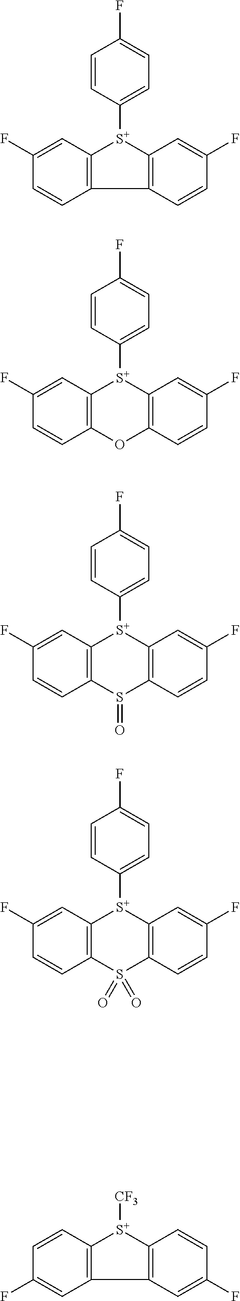

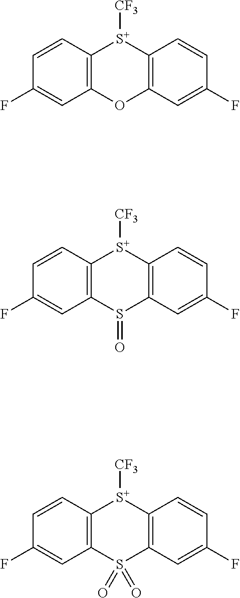

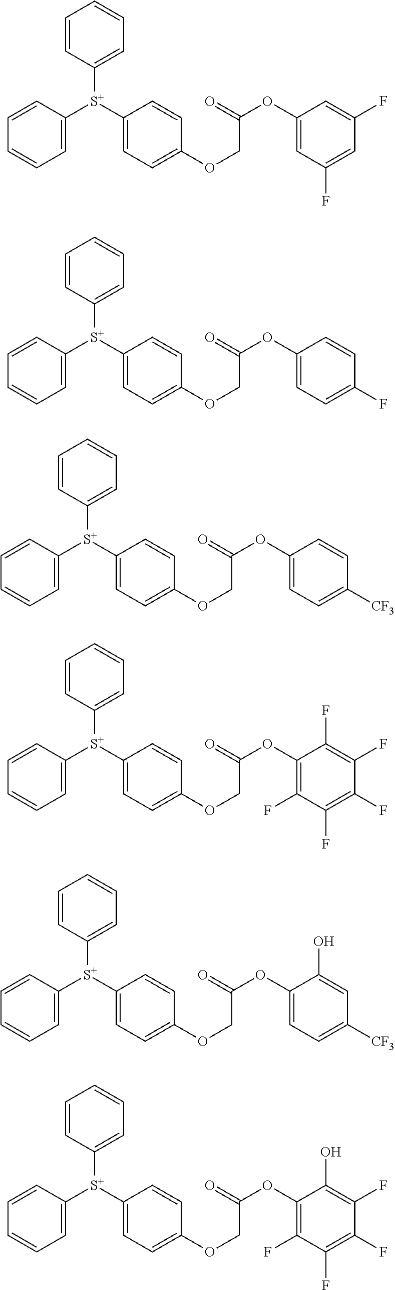

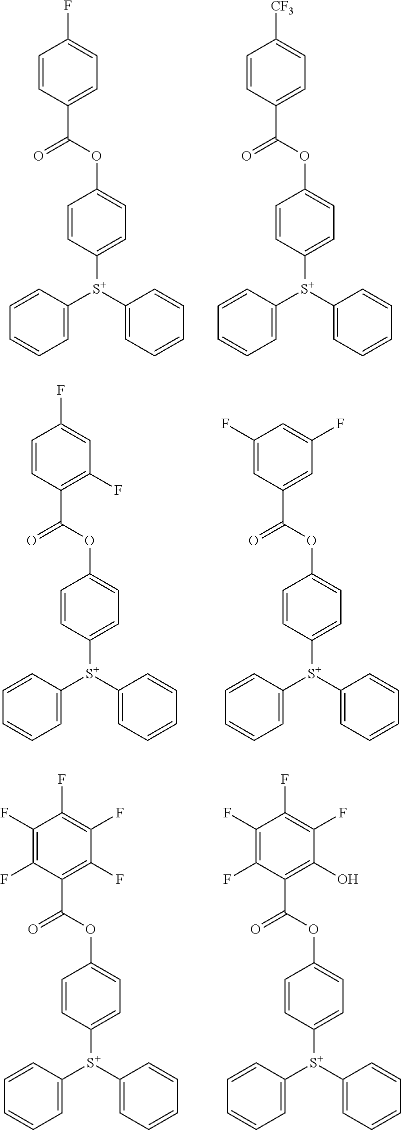

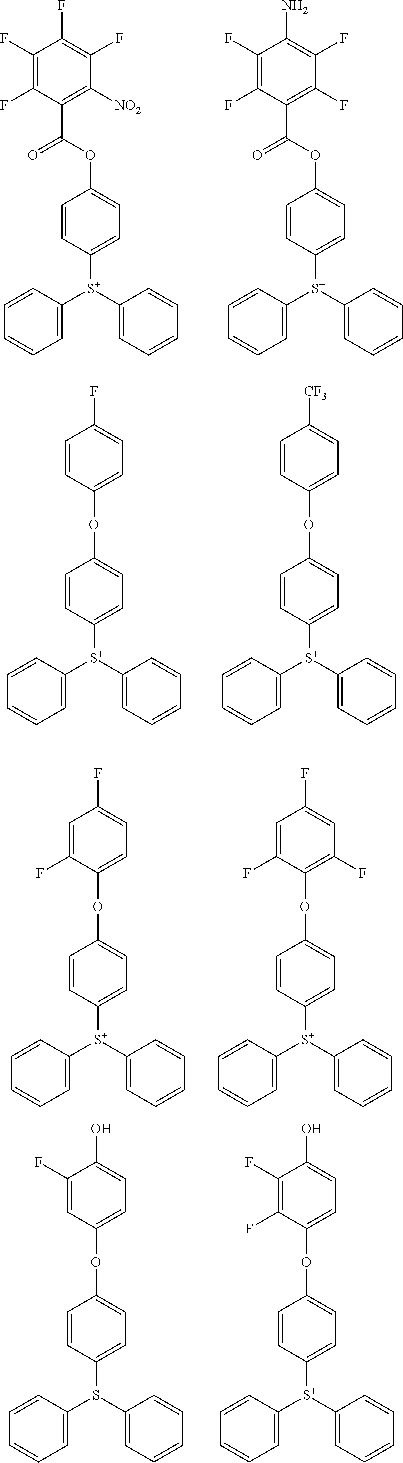

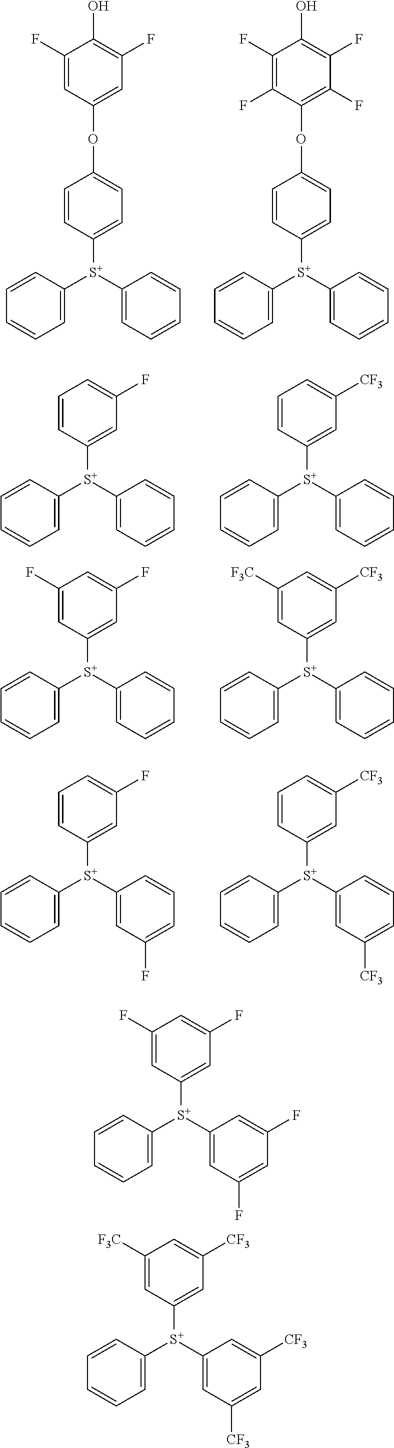

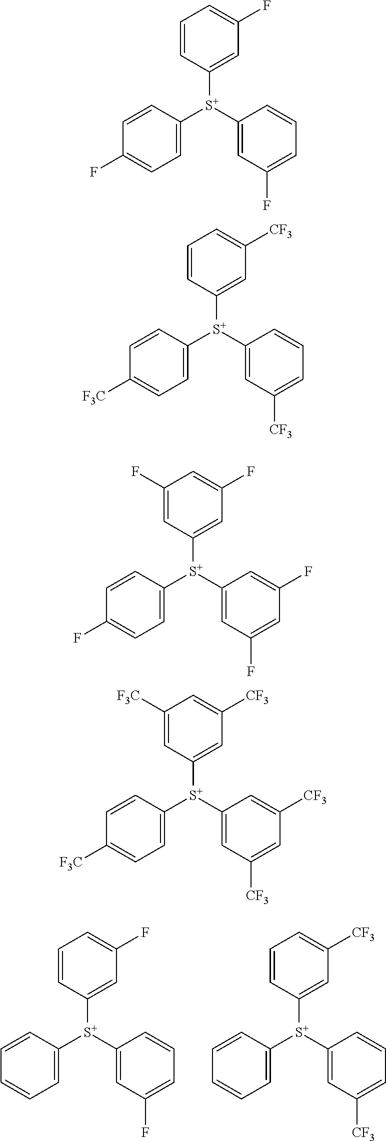

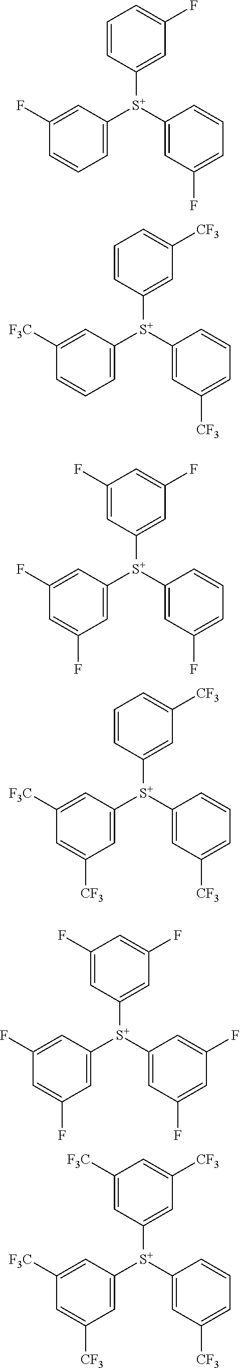

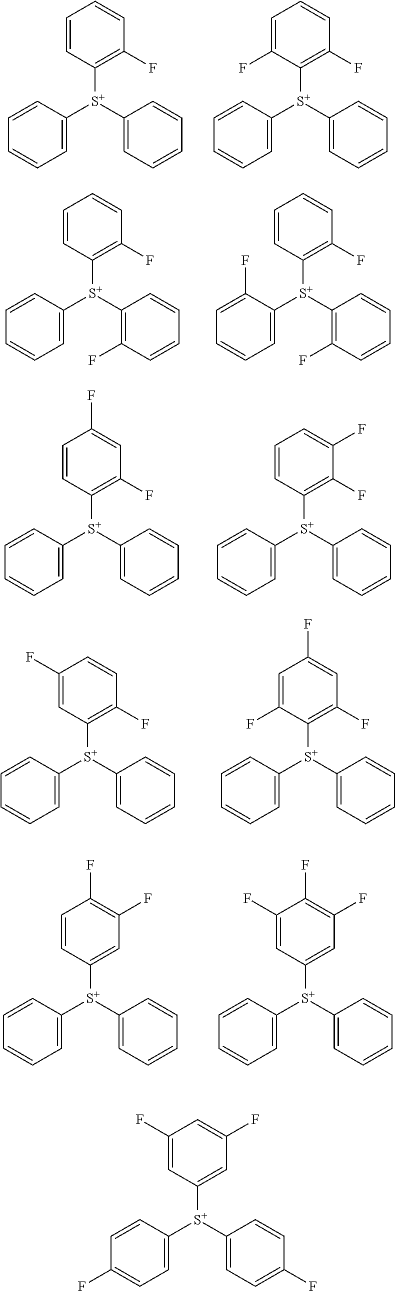

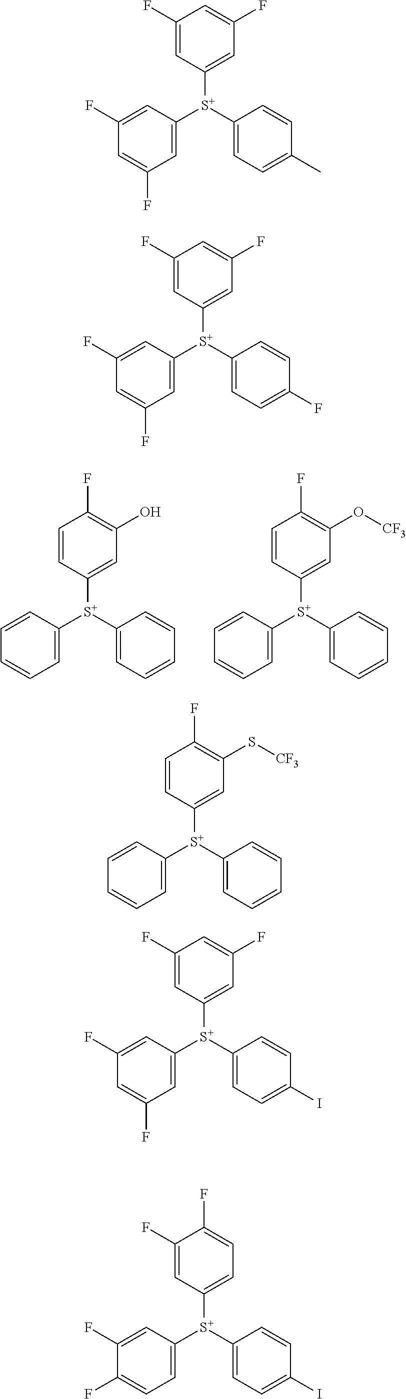

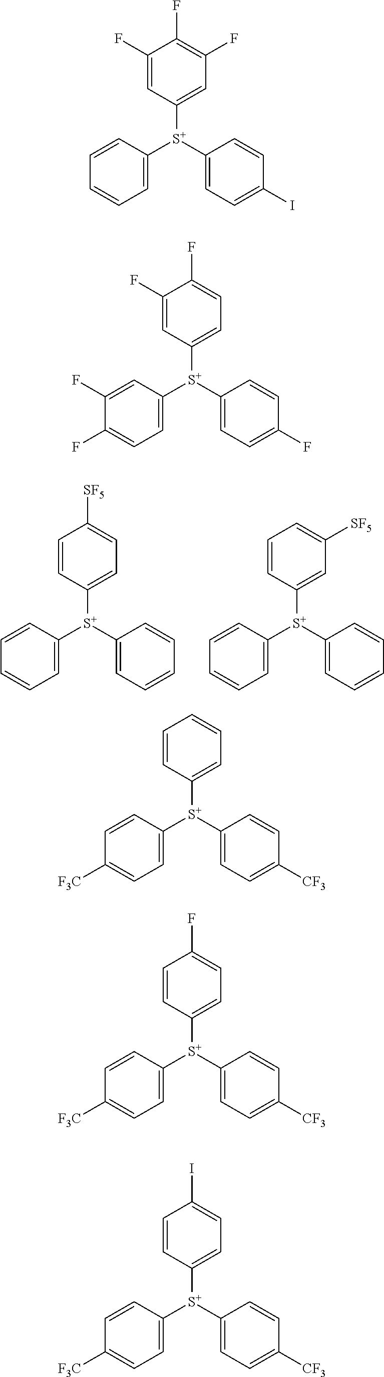

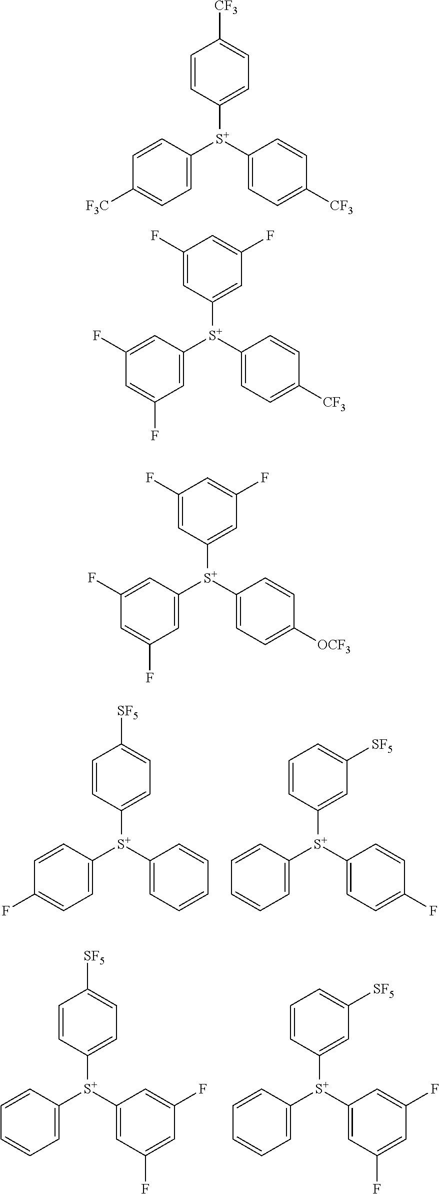

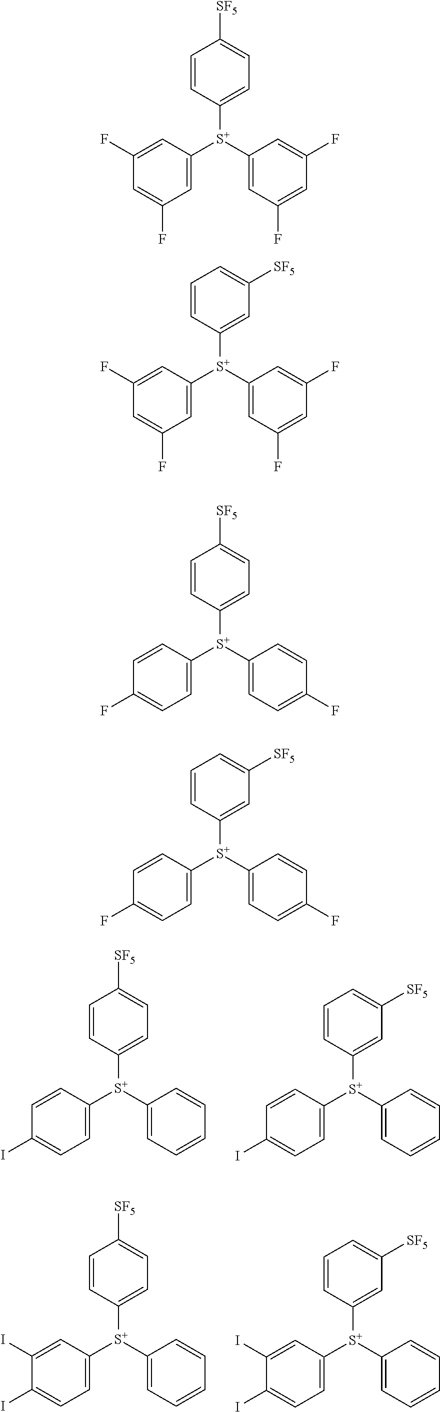

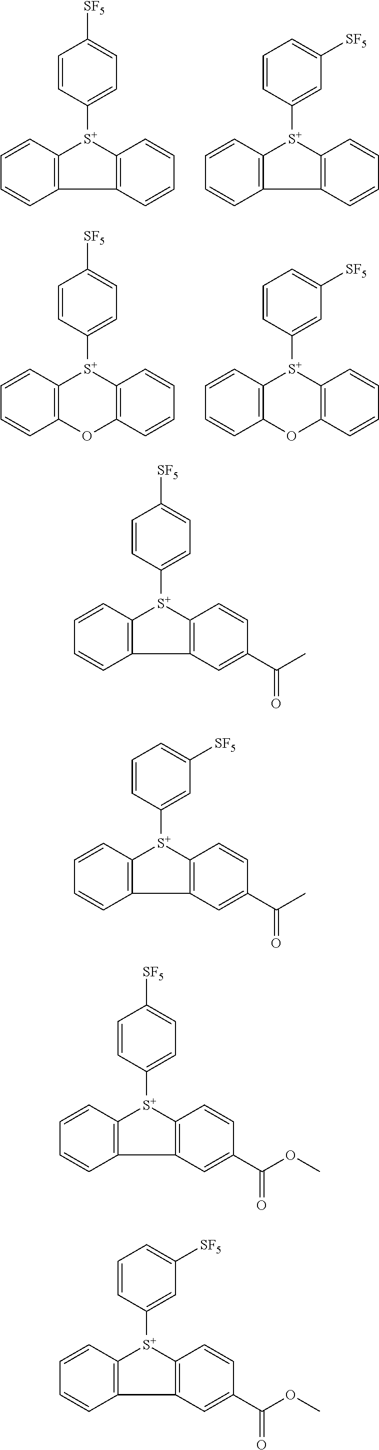

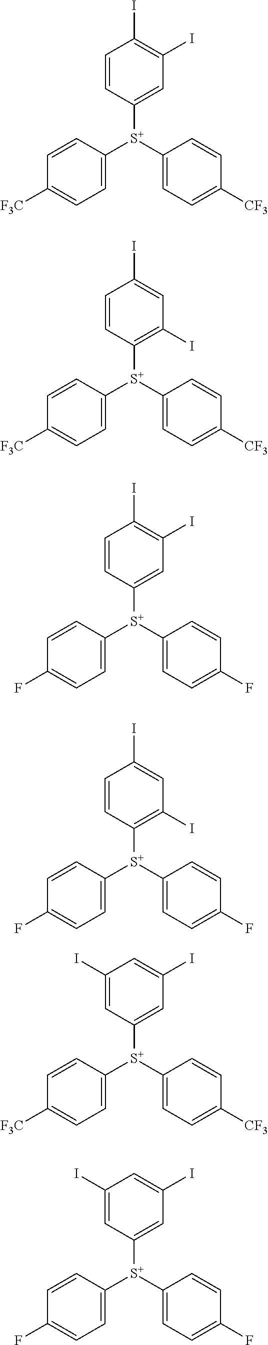

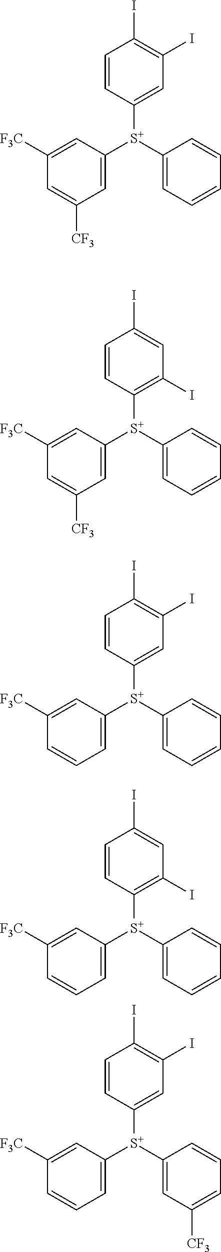

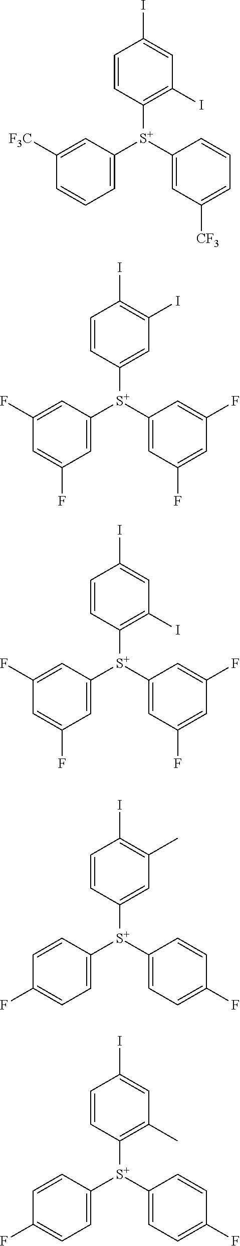

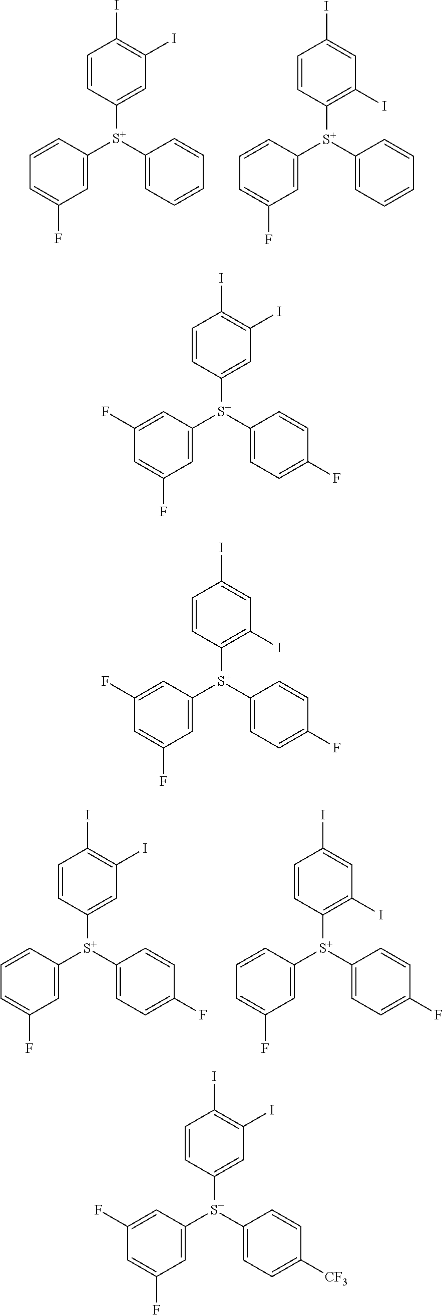

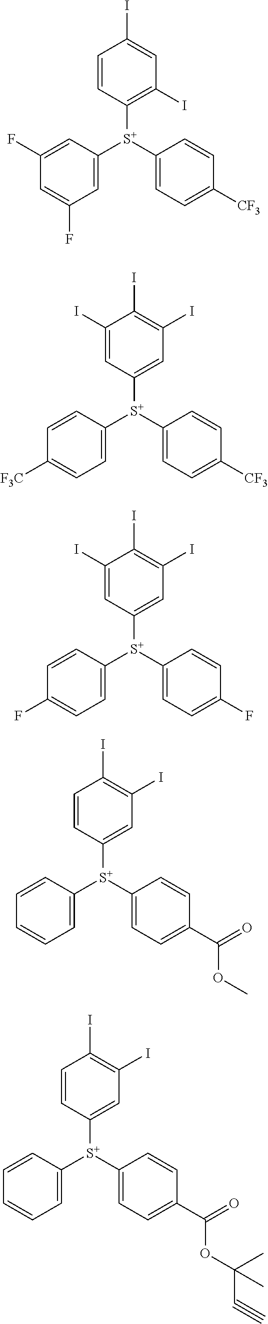

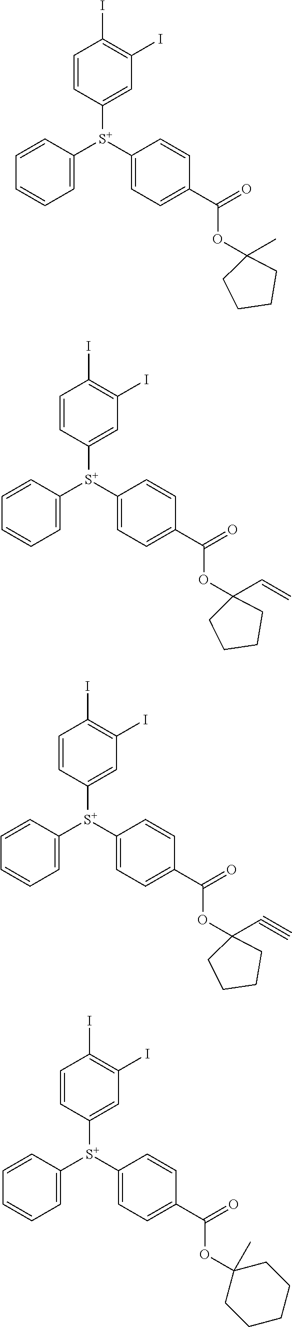

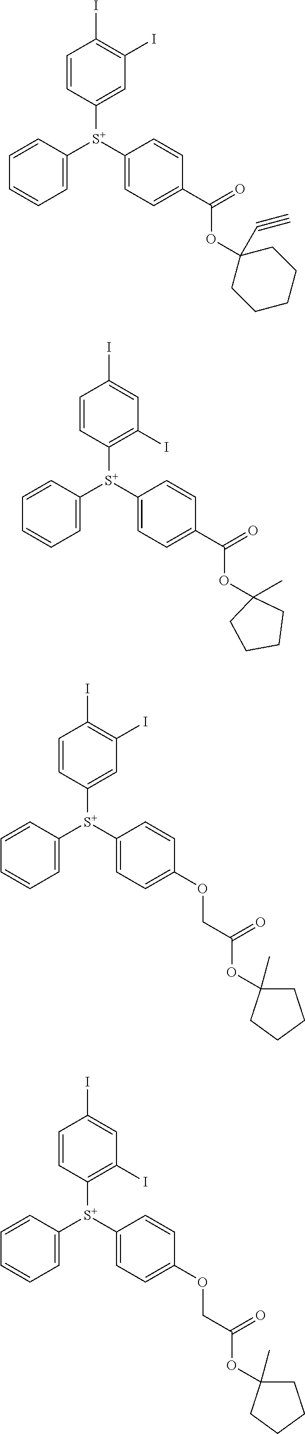

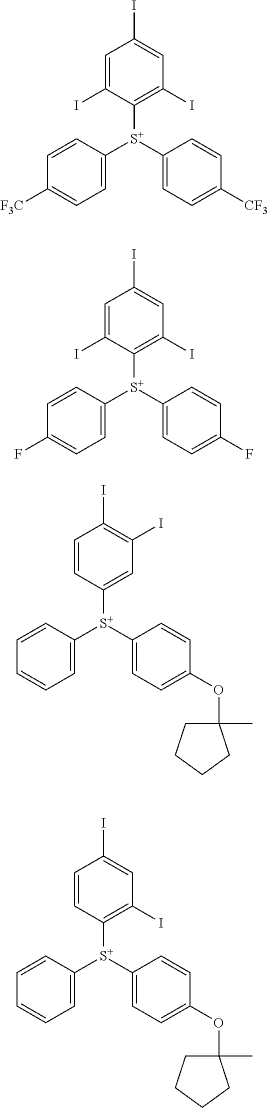

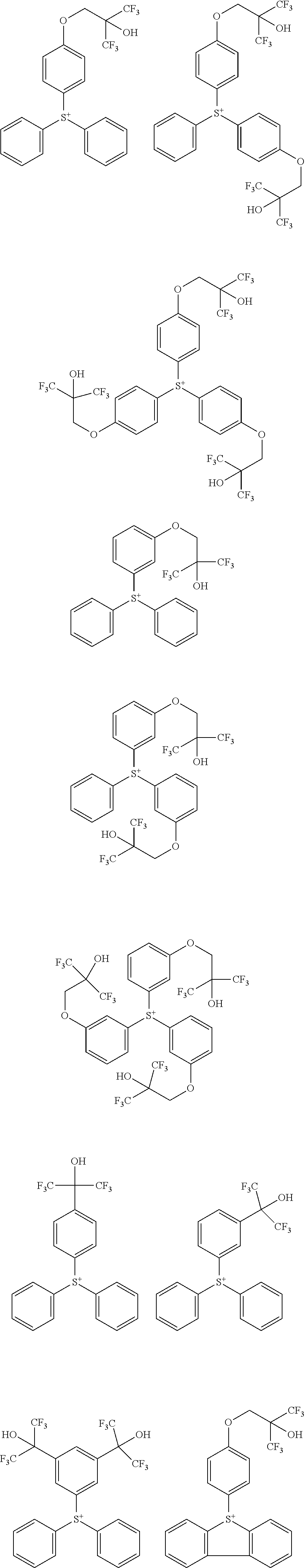

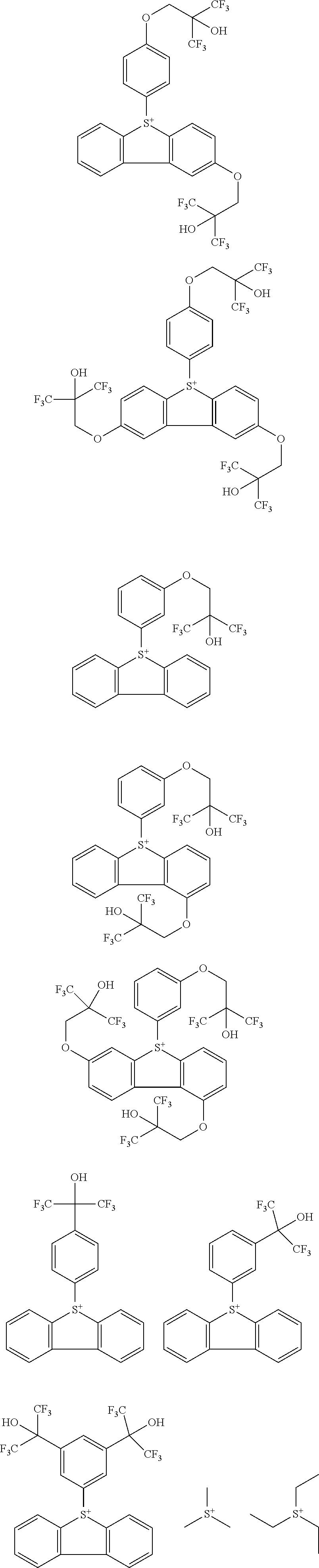

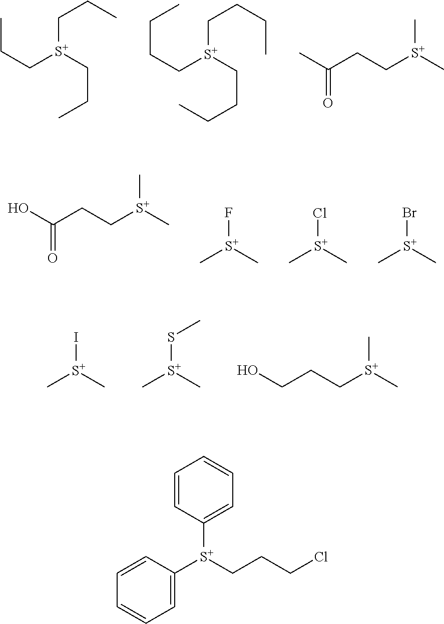

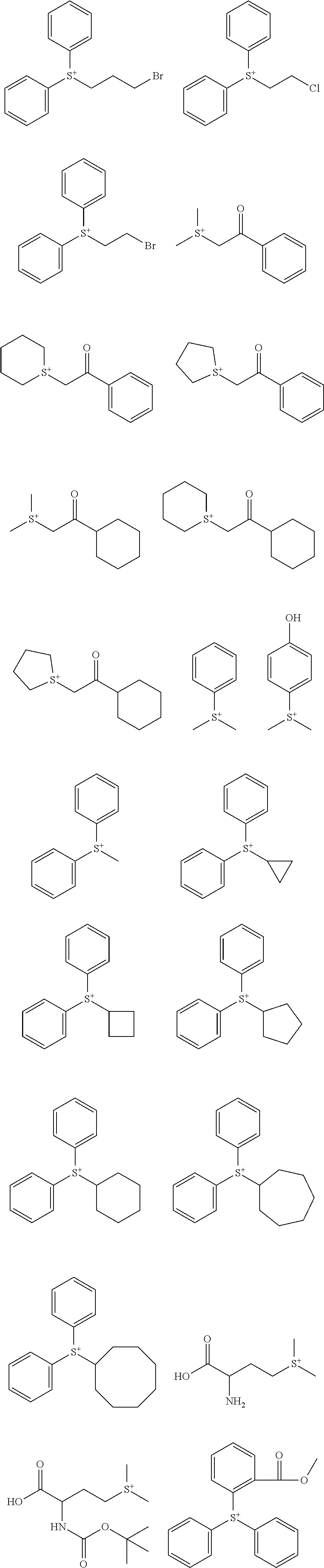

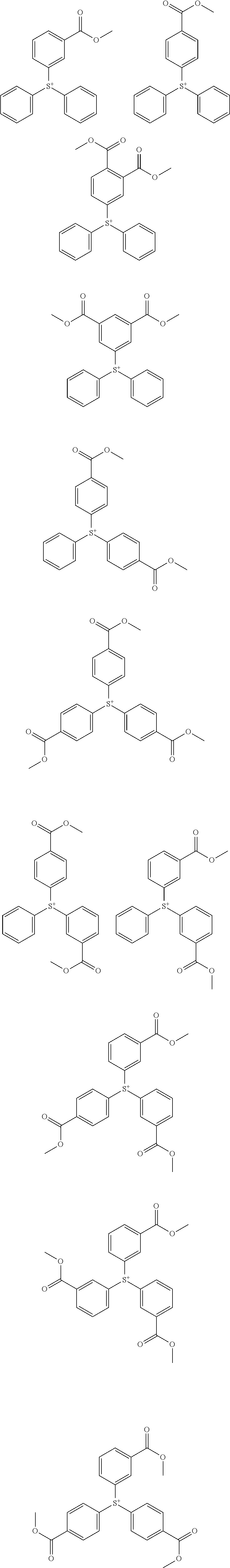

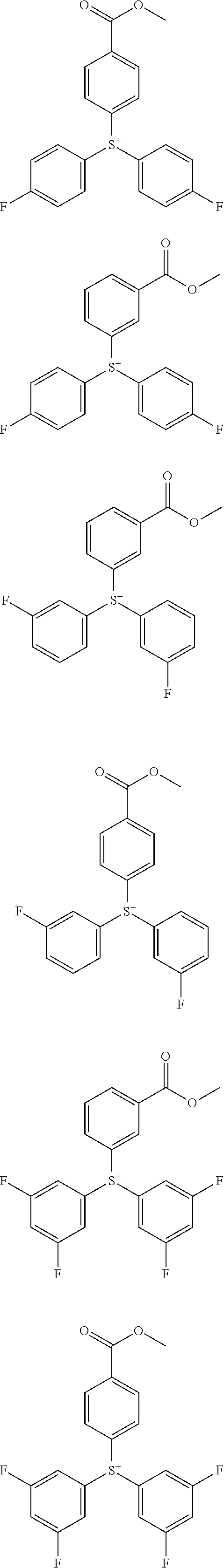

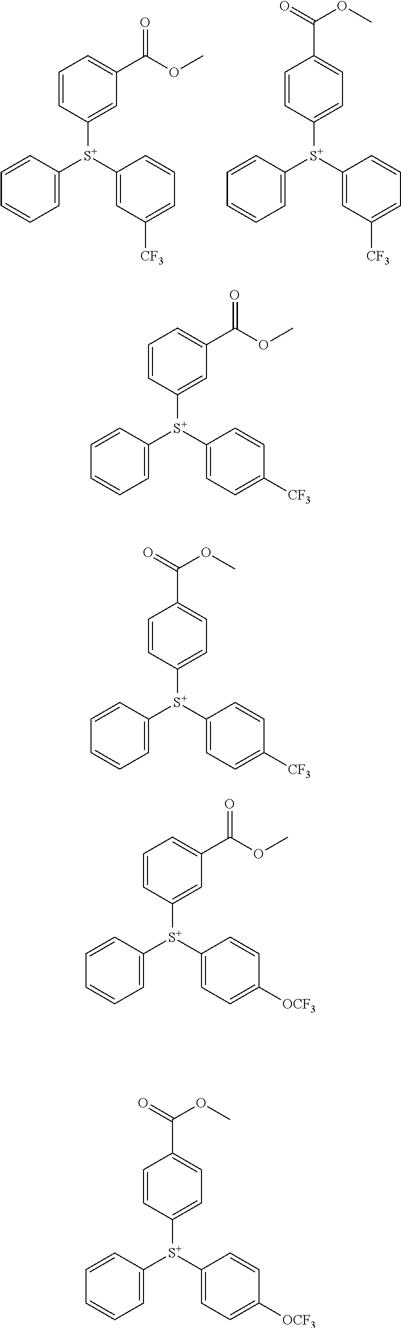

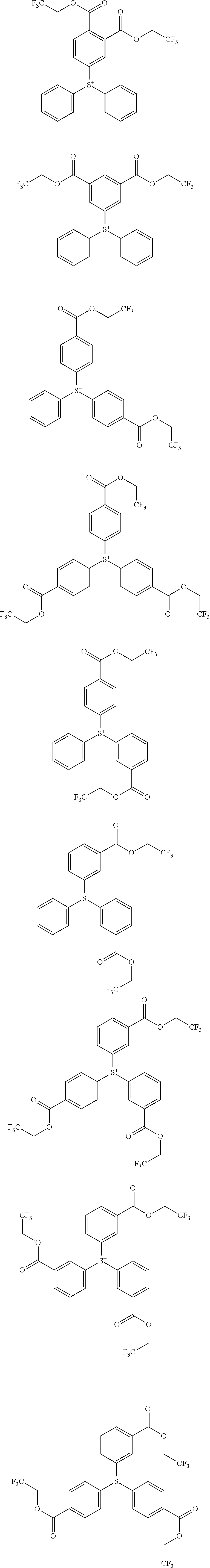

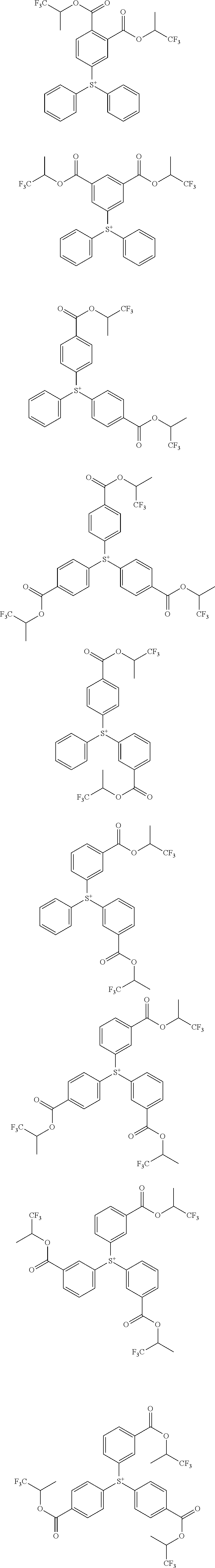

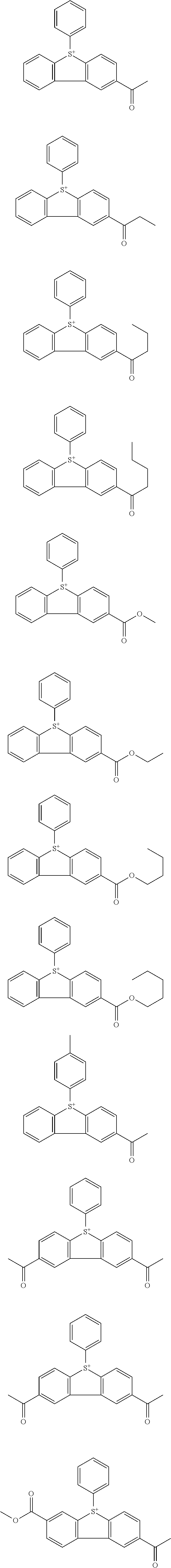

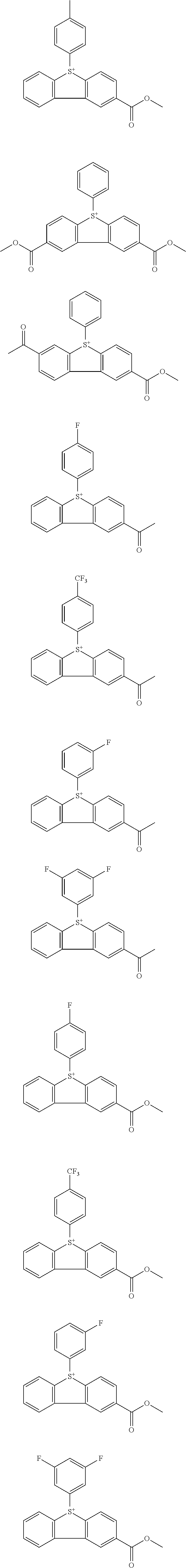

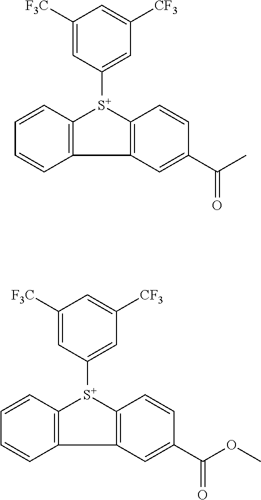

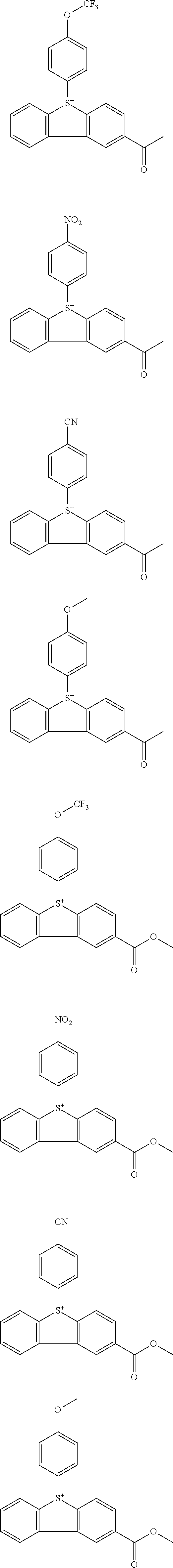

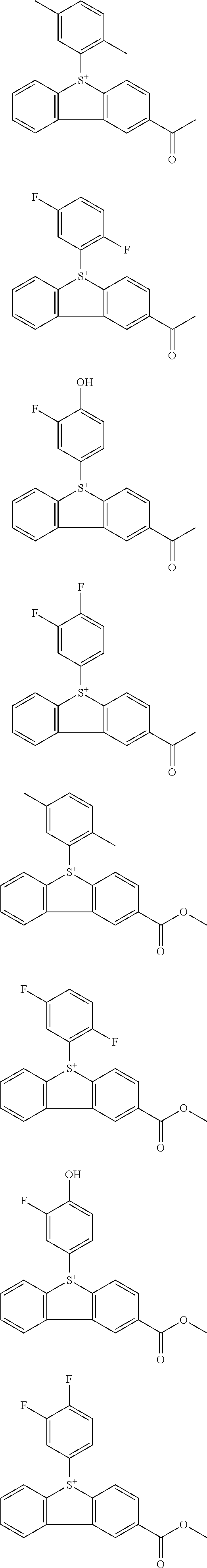

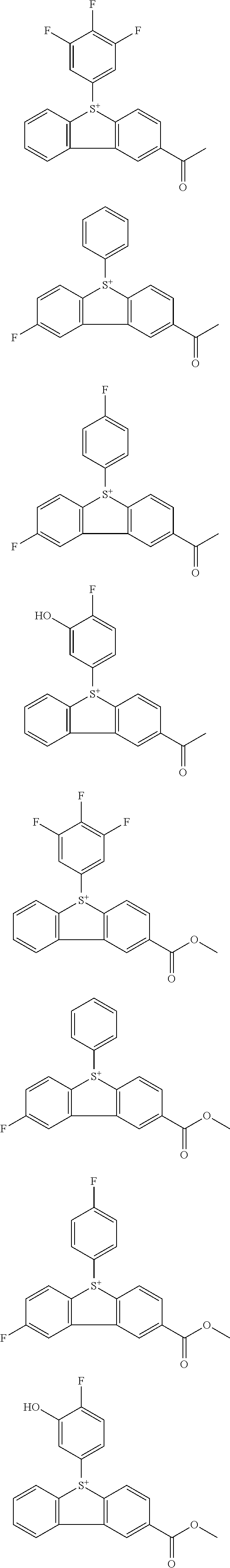

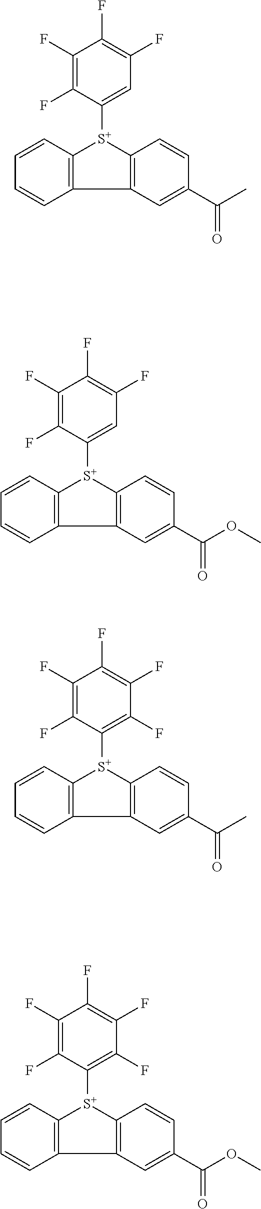

Through photolysis, the sulfonium cation is decomposed into a polymer-bound iodized phenol group. The iodized phenol group is characterized by small swell in alkaline developer as compared with weak acid groups such as carboxylic acid, sulfonamide and hexafluoroalcohol groups. By virtue of this feature, contact hole patterns are improved in CDU. Also, when line-and-space patterns are rinsed with pure water and spin dried, the stress applied to the L/S patterns during spin drying is reduced. This substantially prevents the patterns from collapsing after formation.

The repeat unit (a) is a quencher having a sulfonium salt structure of an iodized phenol compound, that is, quencher-bound polymer. As mentioned above, the quencher-bound polymer has the significant effect of restraining acid diffusion, achieving an improved resolution. At the same time, the repeat units (a) contain iodine atoms. The repulsion of negatively charged iodine atoms prevents the quencher from agglomerating together, making the acid diffusion distance uniform. Upon radiation exposure, iodine atoms absorb the energy to generate secondary electrons to promote decomposition of the acid generator, achieving a higher sensitivity. In this way, high sensitivity, high resolution, and low LWR or improved CDU are accomplished at the same time.

To enhance a dissolution contrast, the base polymer may comprise repeat units having a carboxy group whose hydrogen is substituted by an acid labile group, referred to as repeat units (b1), hereinafter, and/or repeat units having a phenolic hydroxy group whose hydrogen is substituted by an acid labile group, referred to as repeat units (b2), hereinafter.

The repeat units (b1) and (b2) typically have the following formulae (b1) and (b2), respectively.

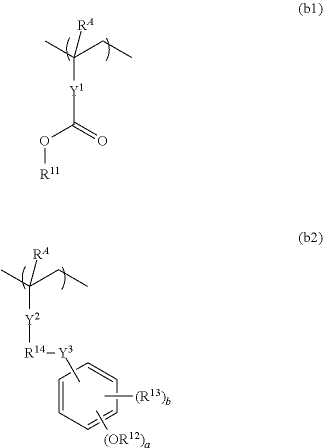

In formulae (b1) and (b2), R^{A} is each independently hydrogen or methyl. Y¹ is a single bond, phenylene group, naphthylene group, or a C₁-C₁₂ linking group containing at least one moiety selected from ester bond, ether bond and lactone ring. The phenylene, naphthylene and linking groups may contain at least one moiety selected from halogen, hydroxy, C₁-C₈ saturated hydrocarbyloxy moiety and C₂-C₈ saturated hydrocarbylcarbonyloxy moiety. Y² is a single bond, ester bond or amide bond. Y³ is a single bond, ether bond or ester bond. R¹¹ and R¹² are each independently an acid labile group. R¹³ is hydroxy, halogen, trifluoromethyl, cyano or a C₁-C₆ saturated hydrocarbyl group, C₁-C₆ saturated hydrocarbyloxy group or C₂-C₇ saturated hydrocarbylcarbonyloxy group. R¹⁴ is a single bond or a C₁-C₆ alkanediyl group in which some —CH₂— may be replaced by an ether bond or ester bond. The subscript “a” is 1 or 2, “b” is an integer of 0 to 4, and the sum of a+b is from 1 to 5.

Examples of the monomer from which repeat units (b1) are derived are shown below, but not limited thereto. Herein R^{A} and R¹¹ are as defined above.

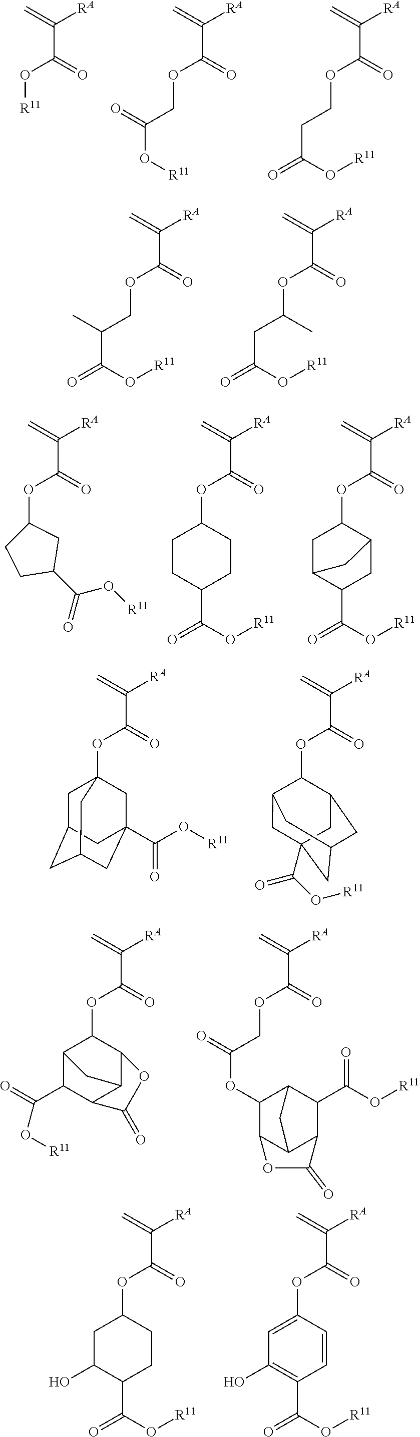

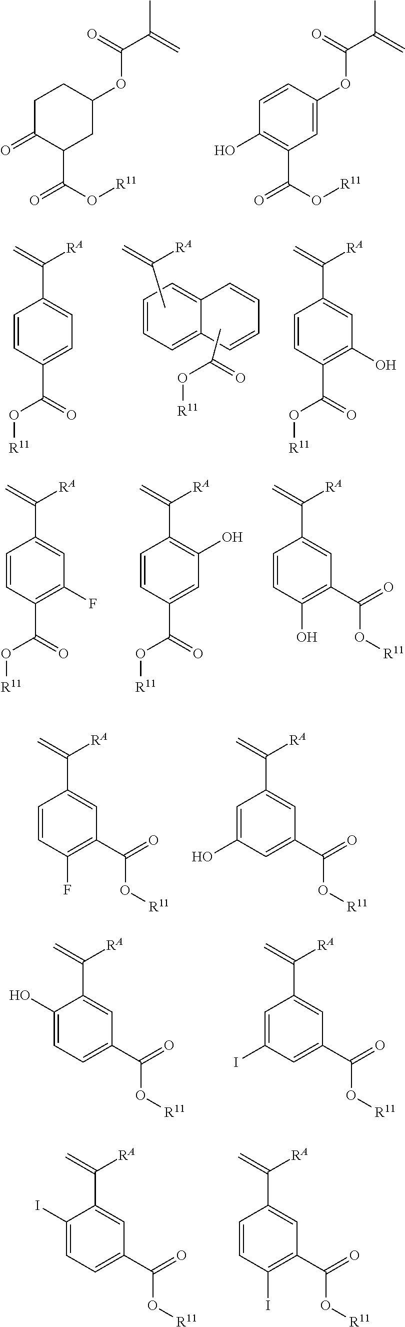

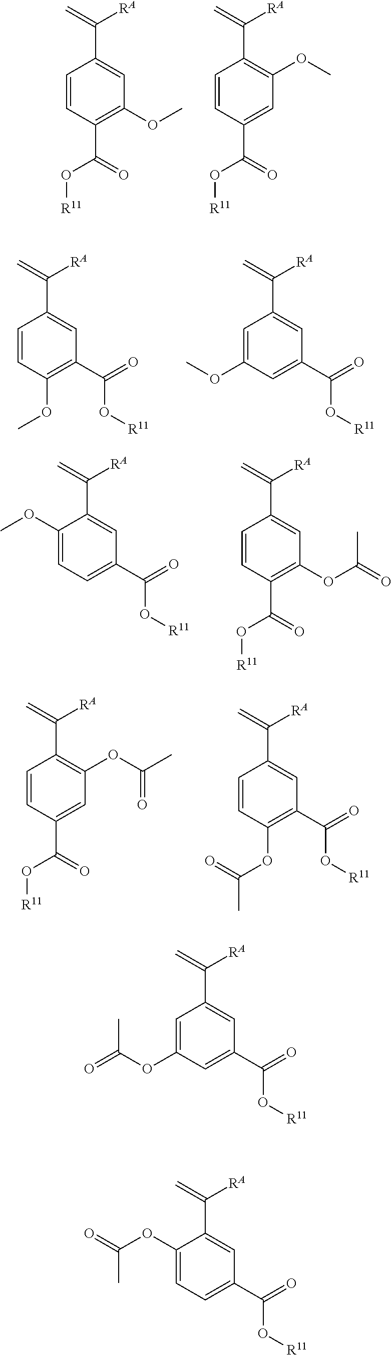

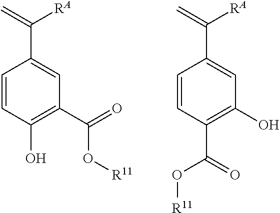

Examples of the monomer from which repeat units (b2) are derived are shown below, but not limited thereto. Herein R^{A} and R¹² are as defined above.

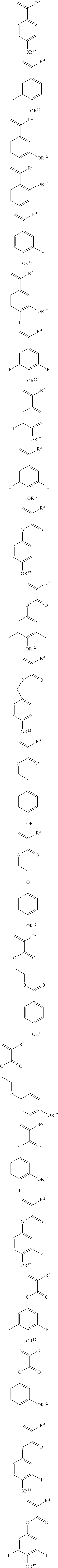

The acid labile groups represented by R¹¹ and R¹² may be selected from a variety of such groups, for example, groups having the following formulae (AL-1) to (AL-3).

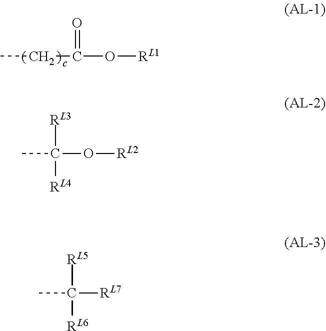

In formula (AL-1), c is an integer of 0 to 6. R^{L1} is a C₄-C₂₀, preferably C₄-C₁₅ tertiary hydrocarbyl group, a trihydrocarbylsilyl group in which each hydrocarbyl moiety is a C₁-C₆ saturated one, a C₄-C₂₀ saturated hydrocarbyl group containing a carbonyl moiety, ether bond or ester bond, or a group of formula (AL-3). Notably, the tertiary hydrocarbyl group is a group obtained from a tertiary hydrocarbon by eliminating hydrogen on the tertiary carbon.

The tertiary hydrocarbyl group R^{L1} may be saturated or unsaturated and branched or cyclic. Examples thereof include tert-butyl, tert-pentyl, 1,1-diethylpropyl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, and 2-methyl-2-adamantyl. Examples of the trihydrocarbylsilyl group include trialkylsilyl groups such as trimethylsilyl, triethylsilyl, and dimethyl-tert-butylsilyl. The saturated hydrocarbyl group containing a carbonyl moiety, ether bond or ester bond may be straight, branched or cyclic, preferably cyclic and examples thereof include 3-oxocyclohexyl, 4-methyl-2-oxooxan-4-yl, 5-methyl-2-oxooxolan-5-yl, 2-tetrahydropyranyl, and 2-tetrahydrofuranyl.

Examples of the acid labile group having formula (AL-1) include tert-butoxycarbonyl, tert-butoxycarbonylmethyl, tert-pentyloxycarbonyl, tert-pentyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl.

Other examples of the acid labile group having formula (AL-1) include groups having the formulae (AL-1)-1 to (AL-1)-10.

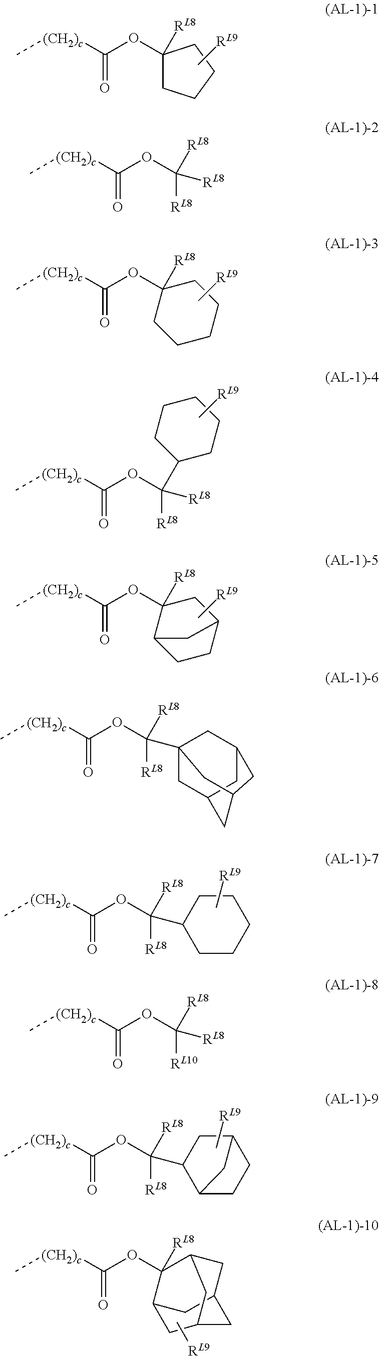

In formulae (AL-1)-1 to (AL-1)-10, c is as defined above. R^{L8} is each independently a C₁-C₁₀ saturated hydrocarbyl group or C₆-C₂₀ aryl group. R^{L9} is hydrogen or a C₁-C₁₀ saturated hydrocarbyl group. R^{L10} is a C₂-C₁₀ saturated hydrocarbyl group or C₆-C₂₀ aryl group. The saturated hydrocarbyl group may be straight, branched or cyclic.

In formula (AL-2), R^{L2} and R^{L3} are each independently hydrogen or a C₁-C₁₈, preferably C₁-C₁₀ saturated hydrocarbyl group. The saturated hydrocarbyl group may be straight, branched or cyclic and examples thereof include methyl, ethyl, n-propyl, isopropyl, n-butyl, isobutyl, sec-butyl, tert-butyl, cyclopentyl, cyclohexyl, 2-ethylhexyl and n-octyl.

R^{L} is a C₁-C₁₈, preferably C₁-C₁₀ hydrocarbyl group which may contain a heteroatom. The hydrocarbyl group may be saturated or unsaturated and straight, branched or cyclic. Typical are C₁-C₁₈ saturated hydrocarbyl groups, in which some hydrogen may be substituted by hydroxy, alkoxy, oxo, amino or alkylamino. Examples of the substituted saturated hydrocarbyl group are shown below.

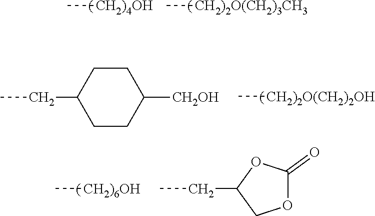

A pair of R^{L2} and R^{L3}, R^{L2} and R^{L4}, or R^{L3} and R^{L4} may bond together to form a ring with the carbon atom or carbon and oxygen atoms to which they are attached. R^{L2} and R^{L3}, R^{L2} and R^{L4}, or R^{L3} and R^{L4} that form a ring are each independently a C₁-C₁₈, preferably C₁-C₁₀ alkanediyl group. The ring thus formed is preferably of 3 to 10, more preferably 4 to 10 carbon atoms.

Of the acid labile groups having formula (AL-2), suitable straight or branched groups include those having formulae (AL-2)-1 to (AL-2)-69, but are not limited thereto.

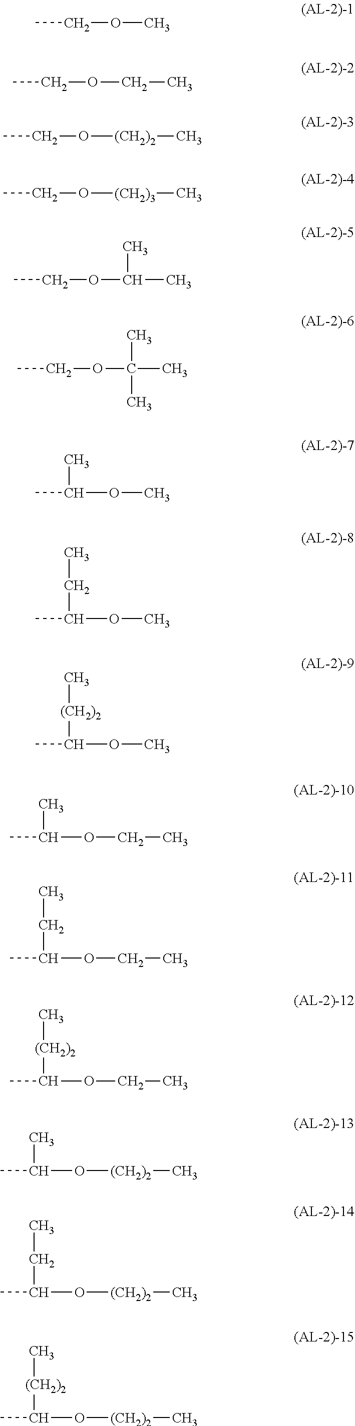

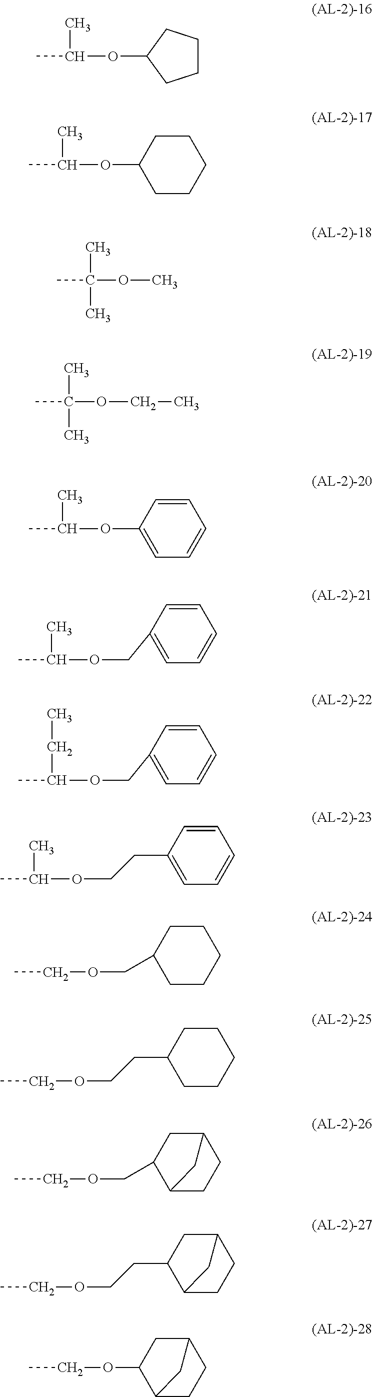

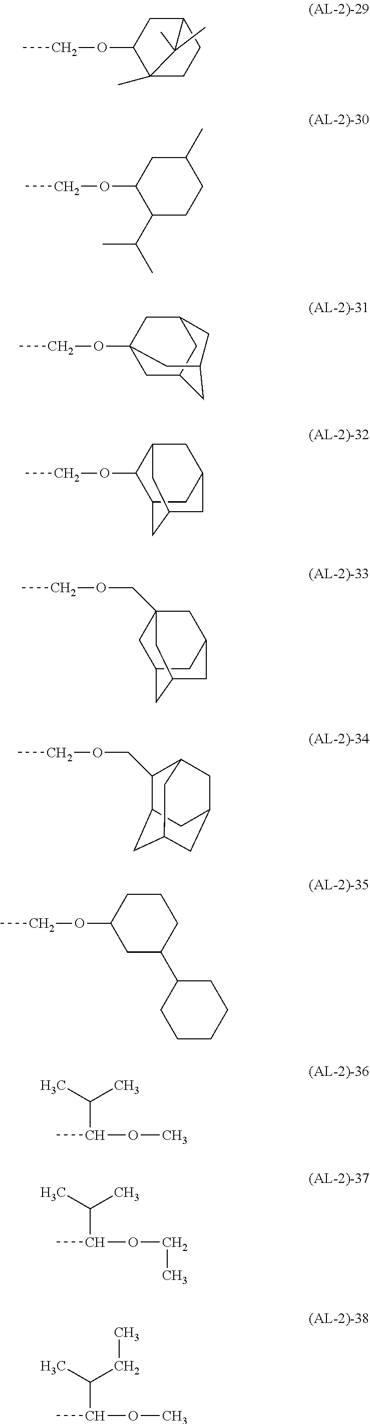

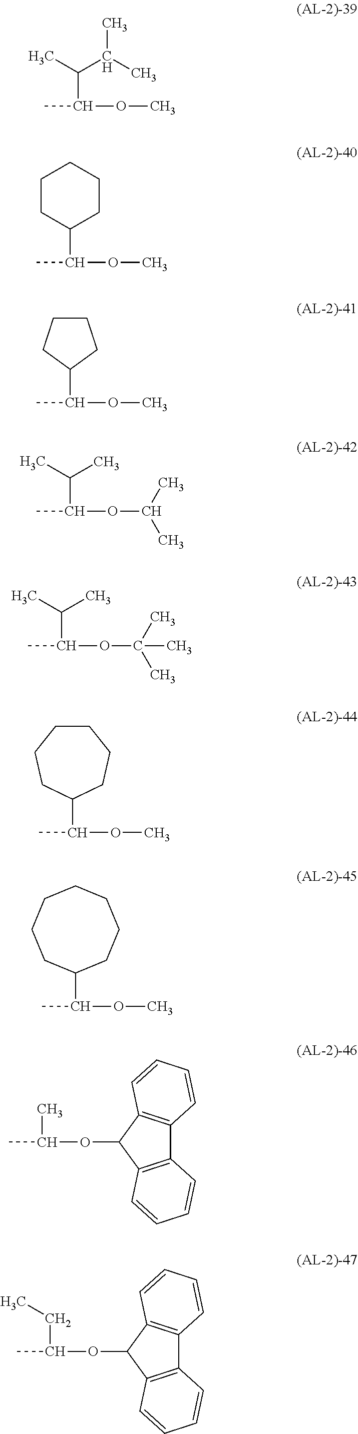

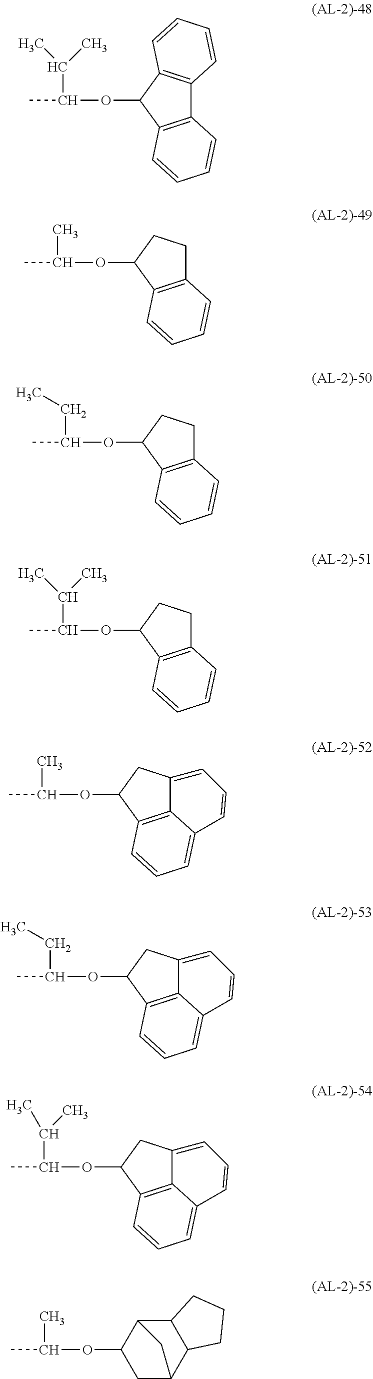

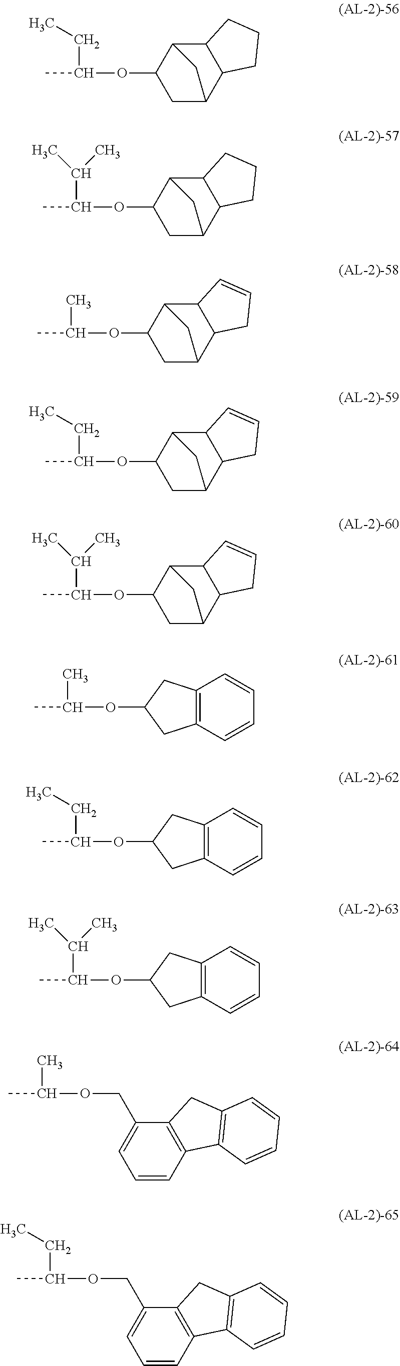

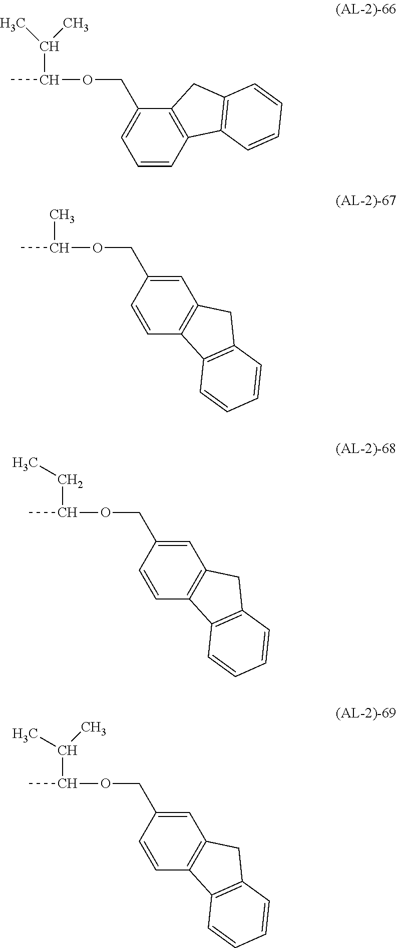

Of the acid labile groups having formula (AL-2), suitable cyclic groups include tetrahydrofuran-2-yl, 2-methyltetrahydrofuran-2-yl, tetrahydropyran-2-yl, and 2-methyltetrahydropyran-2-yl.

Also included are acid labile groups having the following formulae (AL-2a) and (AL-2b). The base polymer may be crosslinked within the molecule or between molecules with these acid labile groups.

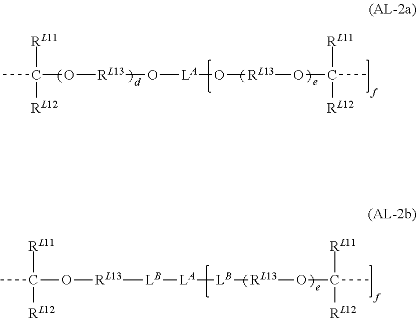

In formulae (AL-2a) and (AL-2b), R^{L11} and R^{L12} are each independently hydrogen or a C₁-C₈ saturated hydrocarbyl group which may be straight, branched or cyclic. Also, R^{L11} and R^{L12} may bond together to form a ring with the carbon atom to which they are attached, and in this case, R^{L11} and R^{L12} are each independently a C₁-C₈ alkanediyl group. R^{L13} is each independently a C₁-C₁₀ saturated hydrocarbylene group which may be straight, branched or cyclic. The subscripts d and e are each independently an integer of 0 to 10, preferably 0 to 5, and f is an integer of 1 to 7, preferably 1 to 3.

In formulae (AL-2a) and (AL-2b), L^{A} is a (f+1)-valent C₁-C₅₀ aliphatic saturated hydrocarbon group, (f+1)-valent C₃-C₅₀ alicyclic saturated hydrocarbon group, (f+1)-valent C₆-C₅₀ aromatic hydrocarbon group or (f+1)-valent C₃-C₅₀ heterocyclic group. In these groups, some constituent —CH₂— may be replaced by a heteroatom-containing moiety, or some hydrogen may be substituted by a hydroxy, carboxy, acyl moiety or fluorine. L^{A} is preferably a C₁-C₂₀ saturated hydrocarbylene, saturated hydrocarbon group (e.g., tri- or tetravalent saturated hydrocarbon group), or C₆-C₃₀ arylene group. The saturated hydrocarbon group may be straight, branched or cyclic. L^{B} is —C(═O)—O—, —NH—C(═O)—O— or —NH—C(═O)—NH—.

Examples of the crosslinking acetal groups having formulae (AL-2a) and (AL-2b) include groups having the formulae (AL-2)-70 to (AL-2)-77.

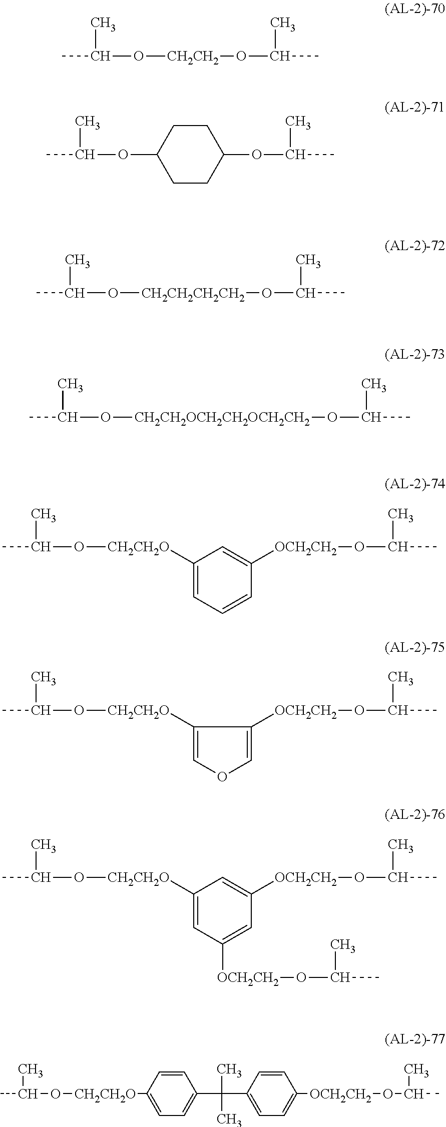

In formula (AL-3), R^{L5} is hydrogen or a C₁-C₂₀ hydrocarbyl group which may contain a heteroatom such as oxygen, sulfur, nitrogen or fluorine. R^{L6} and R^{L7} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic. Examples thereof include C₁-C₂₀ alkyl groups, C₃-C₂₀ cyclic saturated hydrocarbyl groups, C₂-C₂₀ alkenyl groups, C₃-C₂₀ cyclic unsaturated hydrocarbyl groups, and C₆-C₁₀ aryl groups. A pair of R^{L5} and R^{L6}, R^{L5} and R^{L7}, or R^{L6} and R^{L7} may bond together to form a C₃-C₂₀ aliphatic ring with the carbon atom to which they are attached.

Examples of the group having formula (AL-3) include tert-butyl, 1,1-diethylpropyl, 1-ethylnorbornyl, 1-methylcyclopentyl, 1-ethylcyclopentyl, 1-isopropylcyclopentyl, 1-methylcyclohexyl, 2-(2-methyl)adamantyl, 2-(2-ethyl)adamantyl, and tert-pentyl.

Examples of the group having formula (AL-3) also include groups having the formulae (AL-3)-1 to (AL-3)-22.

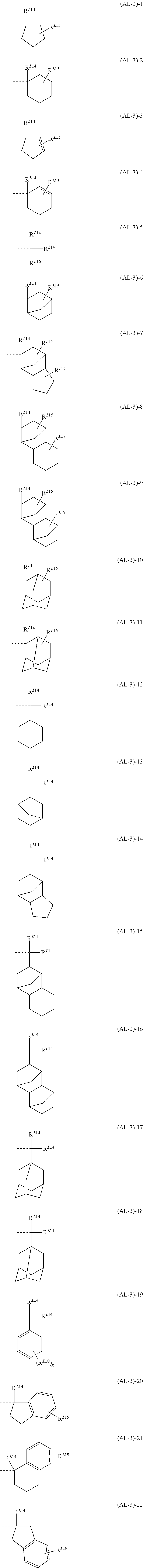

In formulae (AL-3)-1 to (AL-3)-22, R^{L14} is each independently hydrogen, a C₁-C₈ aliphatic hydrocarbyl group or C₆-C₂₀ aryl group. R^{L15} and R^{L17} are each independently hydrogen or a C₁-C₂₀ saturated hydrocarbyl group. R^{L16} is a C₆-C₂₀ aryl group. The saturated hydrocarbyl group may be straight, branched or cyclic. Typical of the aryl group is phenyl. R^{L18} is fluorine, iodine, nitro or trifluoromethyl. R^{L19} is each independently hydrogen, fluorine, iodine, nitro, a C₁-C₈ saturated hydrocarbyl group or C₁-C₈ hydrocarbyloxy group, and g is an integer of 1 to 5.

Other examples of the acid labile group having formula (AL-3) include groups having the formulae (AL-3)-23 and (AL-3)-24. The base polymer may be crosslinked within the molecule or between molecules with these acid labile groups.

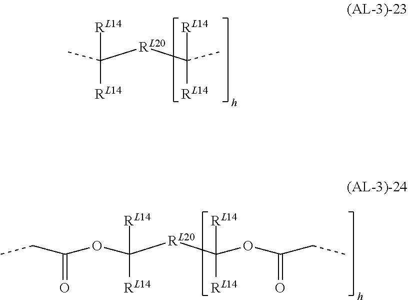

In formulae (AL-3)-23 and (AL-3)-24, R^{L14} is as defined above. R^{L20} is a C₁-C₂₀ (h+1)-valent saturated or unsaturated hydrocarbylene group or C₆-C₂₀ (h+1)-valent arylene group, which may contain a heteroatom such as oxygen, sulfur or nitrogen. The saturated or unsaturated hydrocarbylene group may be straight, branched or cyclic. The subscript h is an integer of 1 to 3.

Besides the foregoing acid labile groups, the aromatic-bearing acid labile groups described in JP 5407941, JP 5434983, JP 5565293, JP 5655755, and JP 5655756 are also useful.

The base polymer may further comprise a repeat unit (c) having an adhesive group. The adhesive group is selected from hydroxy, carboxy, lactone ring, carbonate bond, thiocarbonate bond, carbonyl, cyclic acetal, ether bond, ester bond, sulfonate ester bond, cyano, amide bond, —O—C(═O)—S— and —O—C(═O)—NH—.

Examples of the monomer from which repeat unit (c) is derived are given below, but not limited thereto. Herein R^{A} is as defined above.

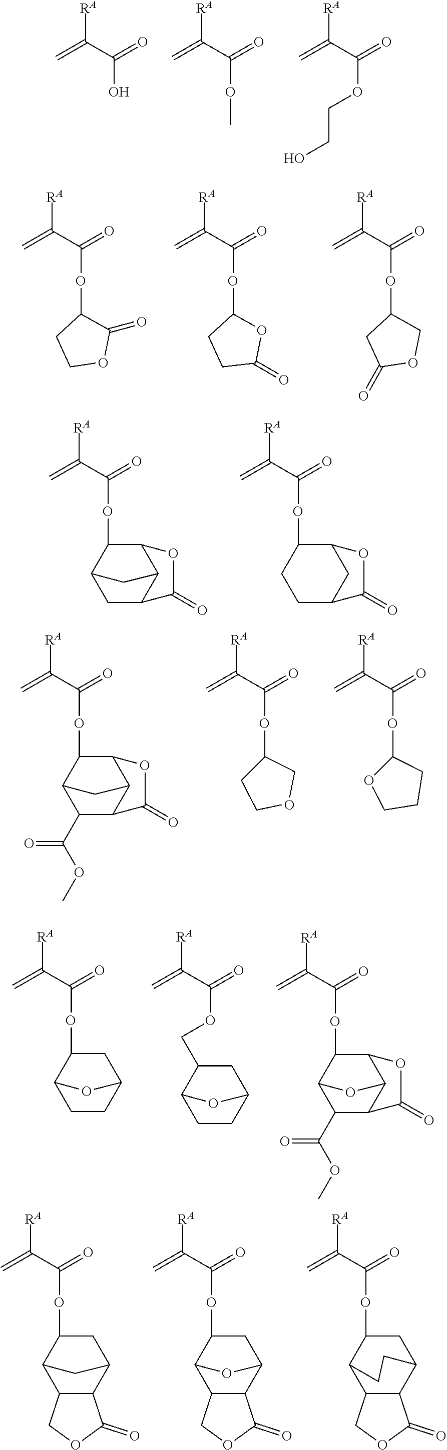

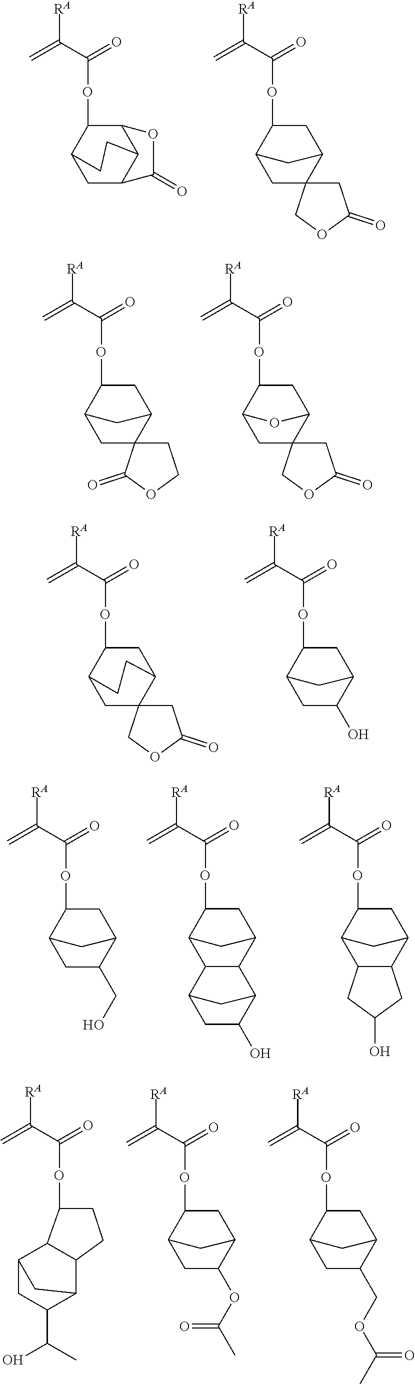

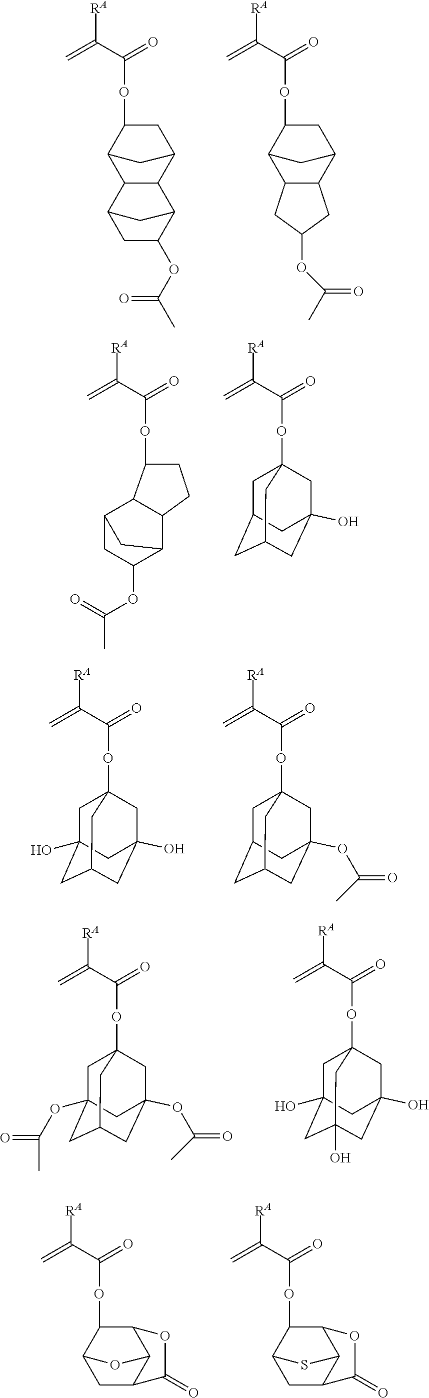

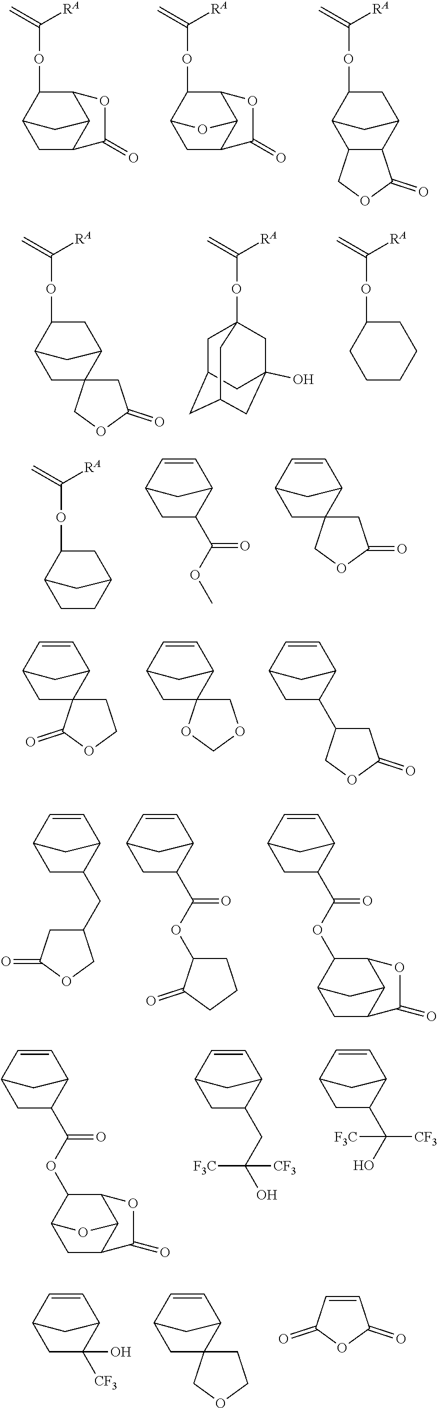

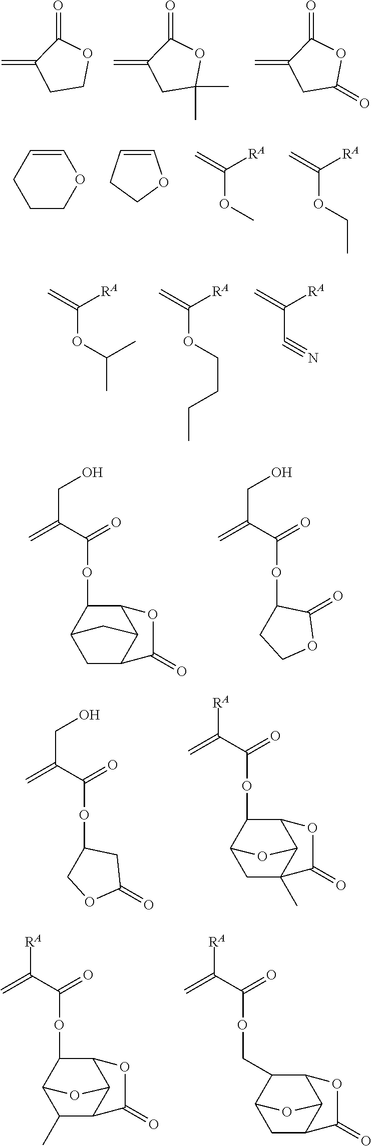

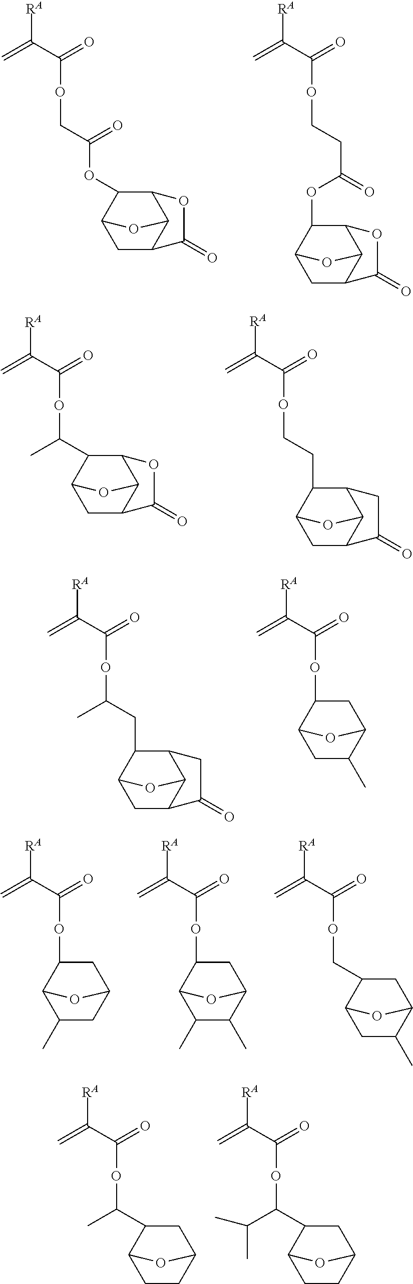

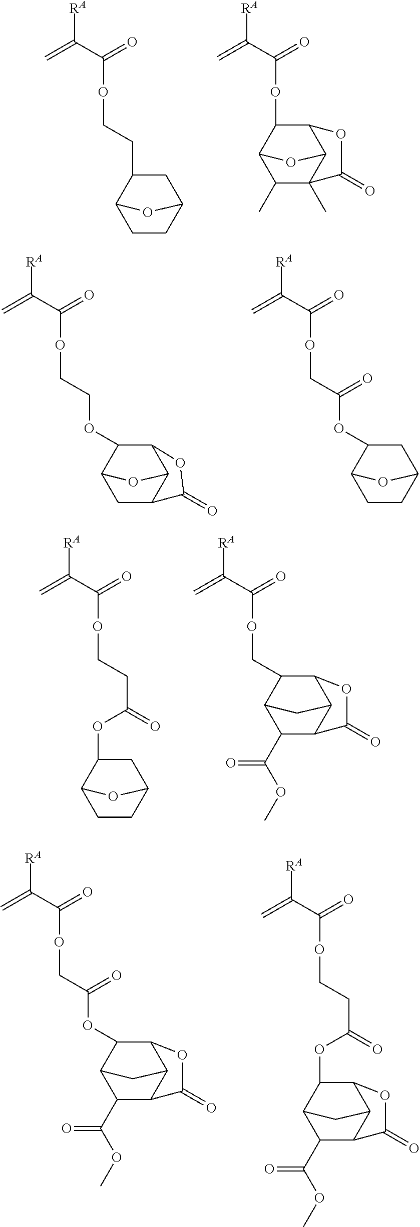

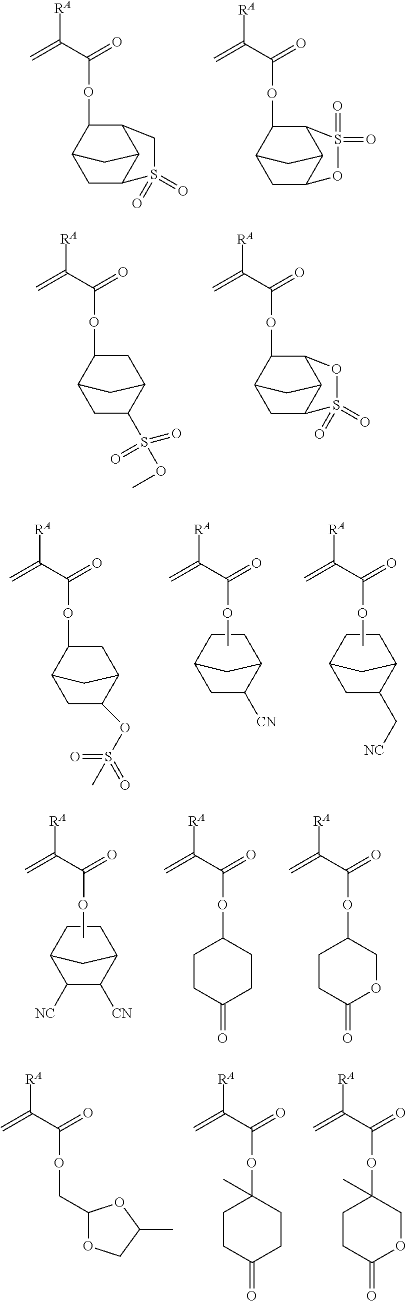

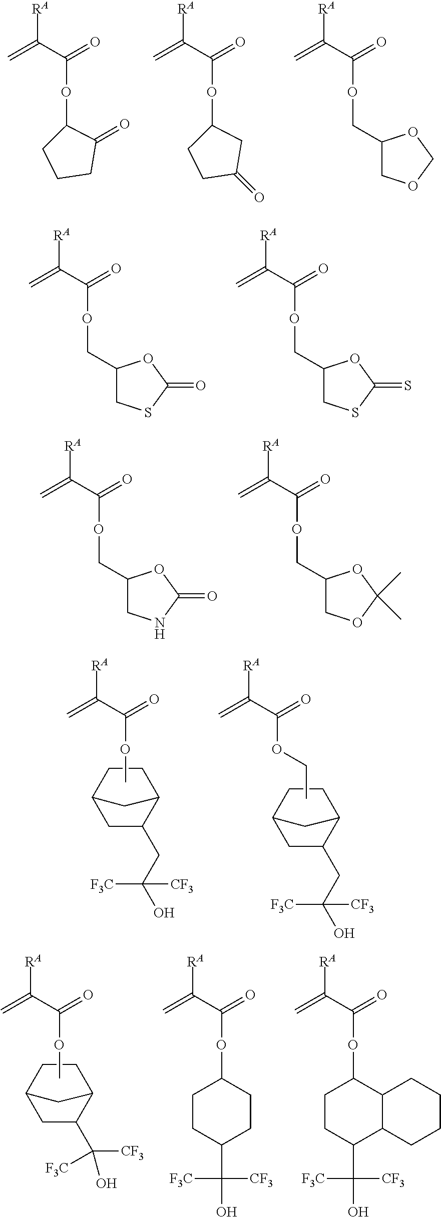

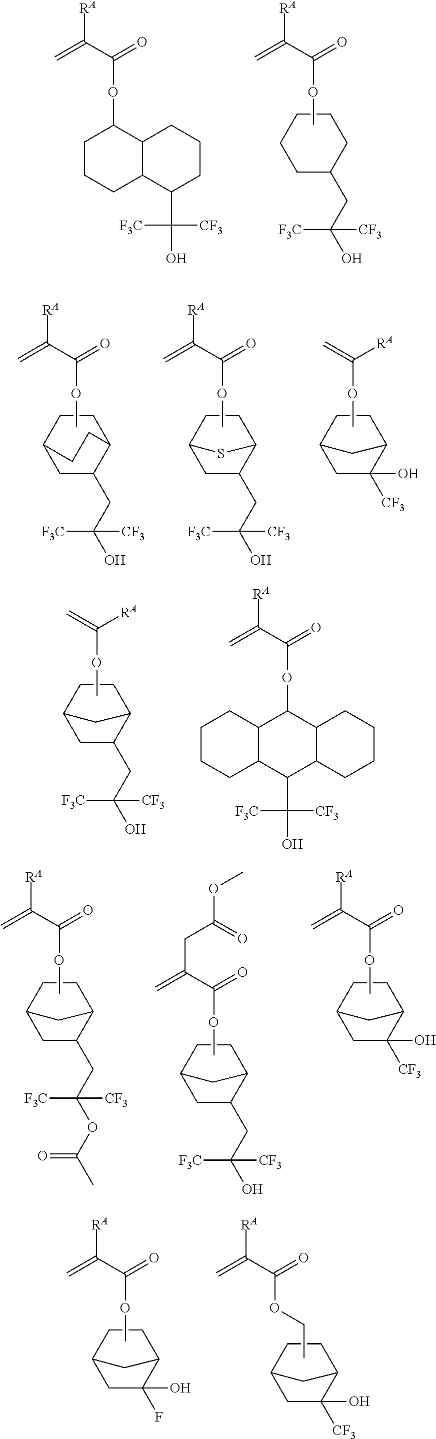

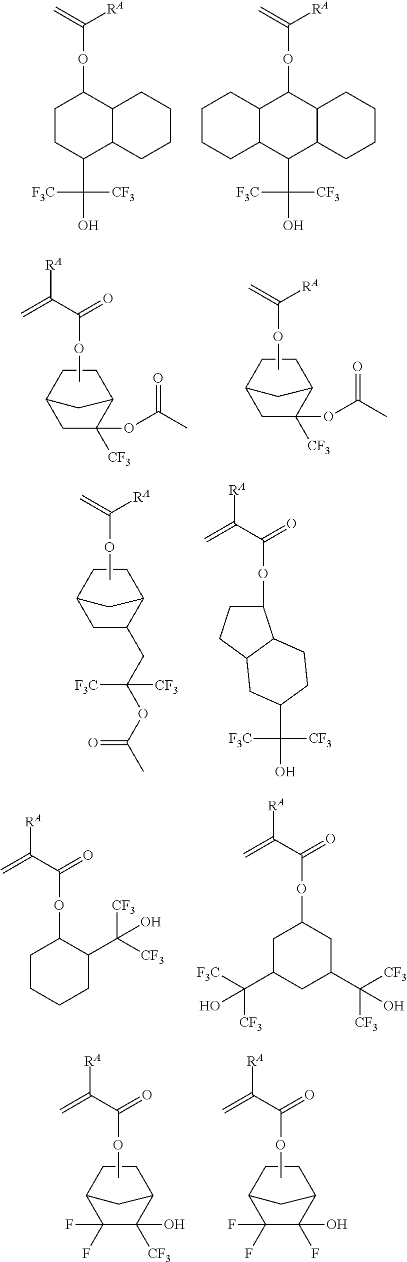

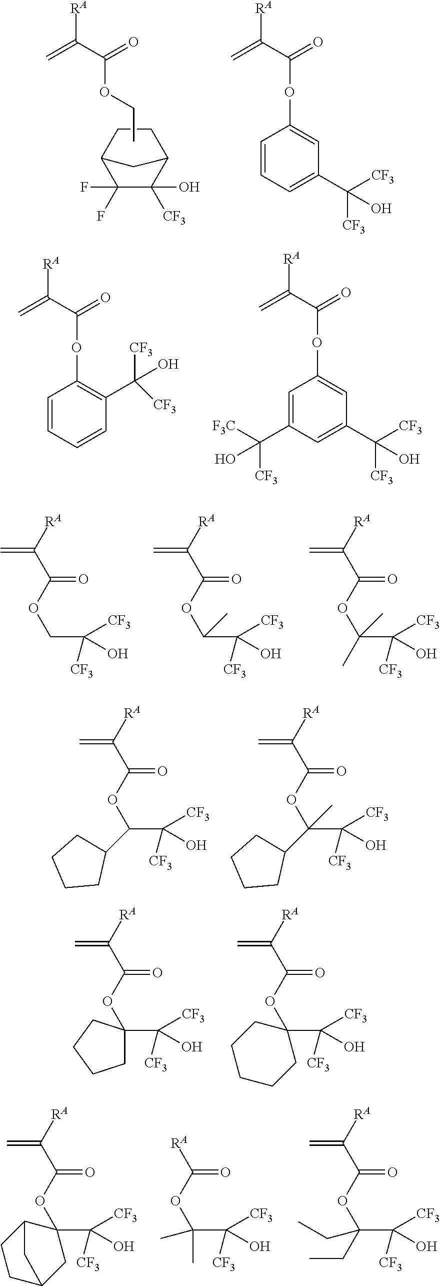

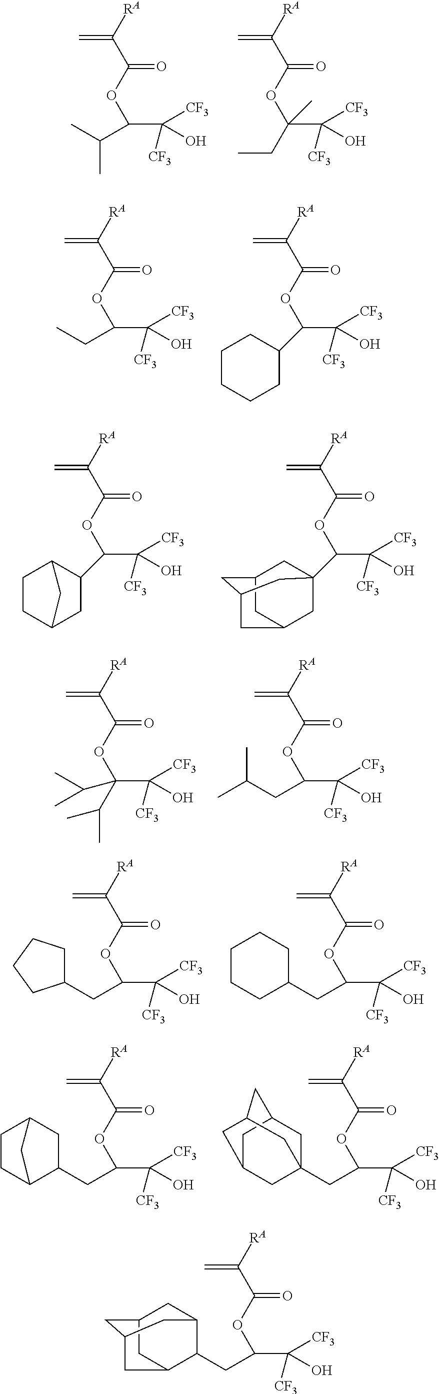

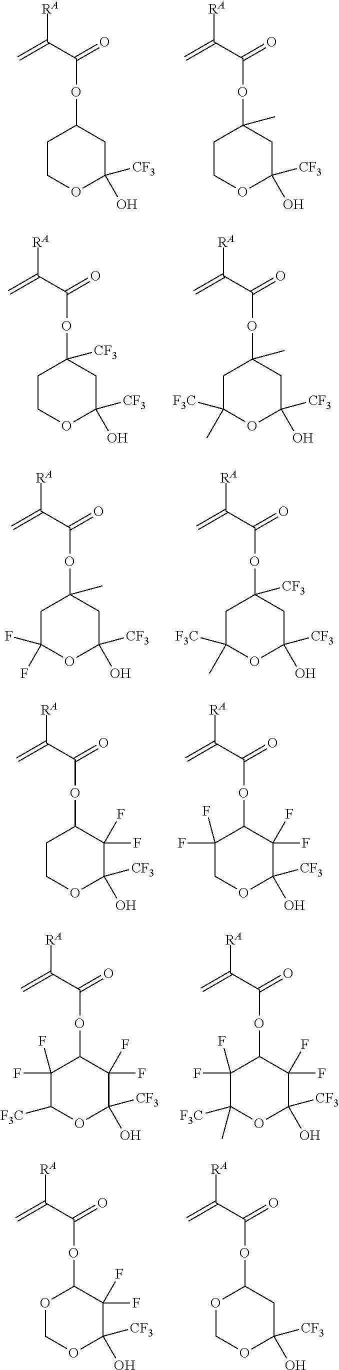

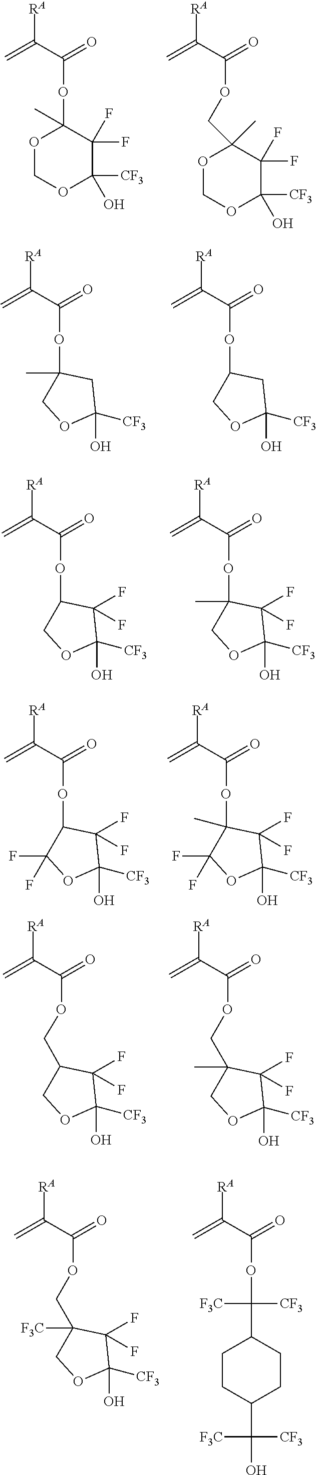

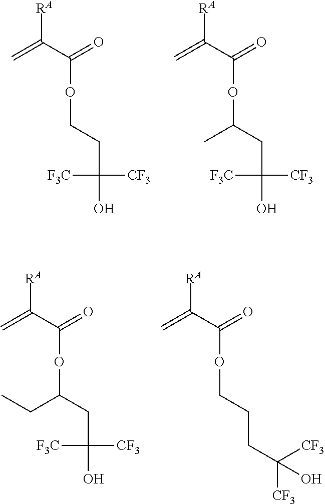

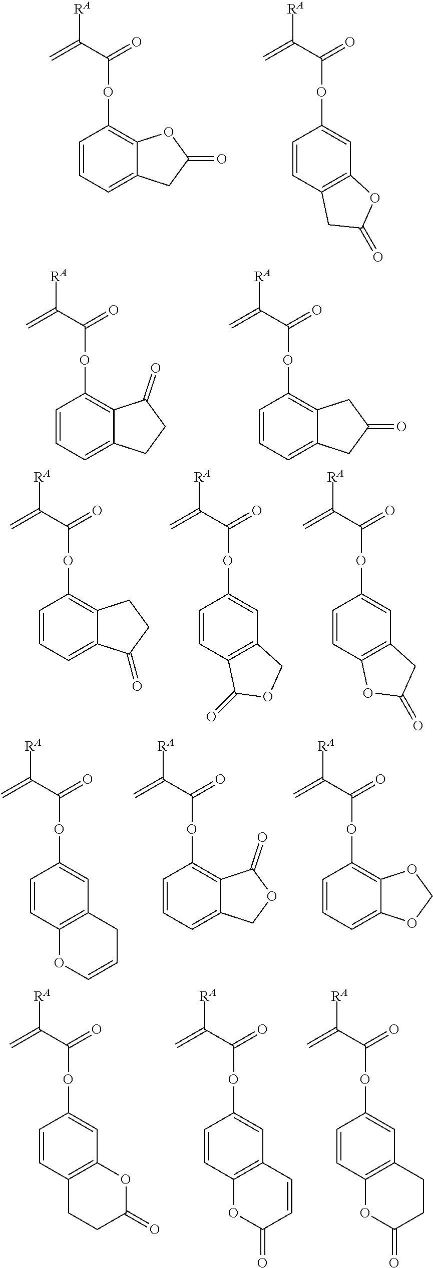

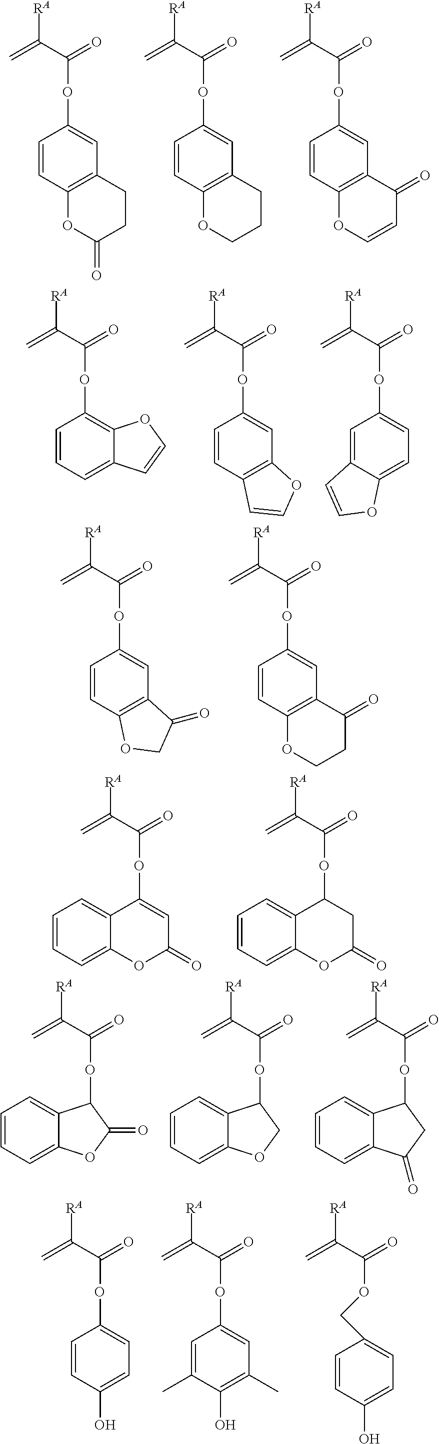

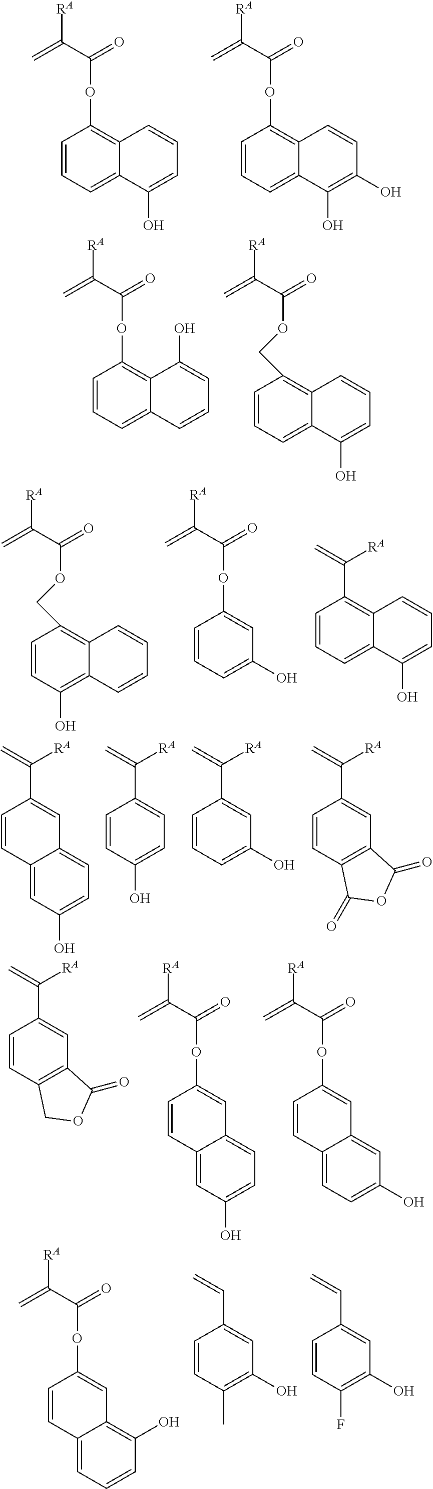

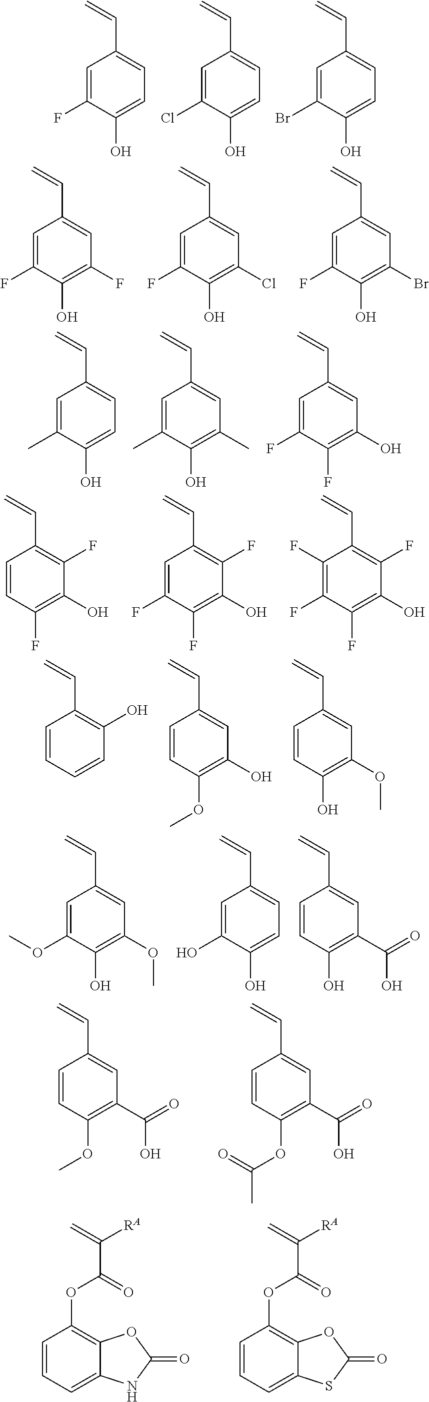

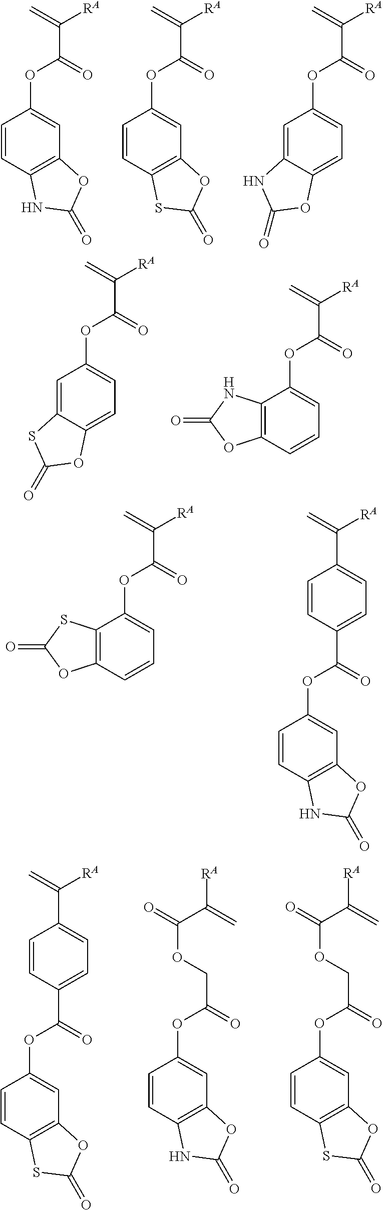

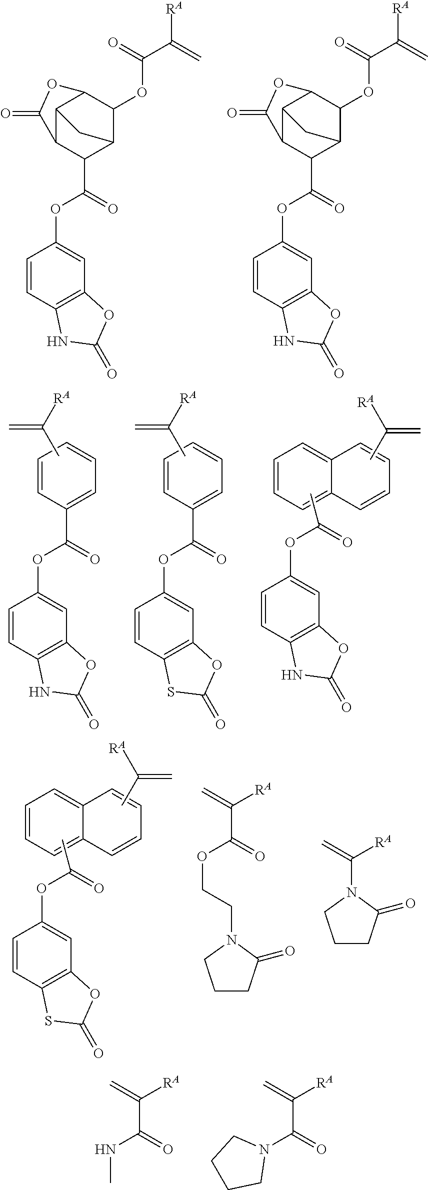

In a further embodiment, the base polymer may comprise repeat units (d) of at least one type selected from repeat units having the following formulae (d1), (d2), (d3), (d4), and (d5). These units are also referred to as repeat units (d1) to (d5).

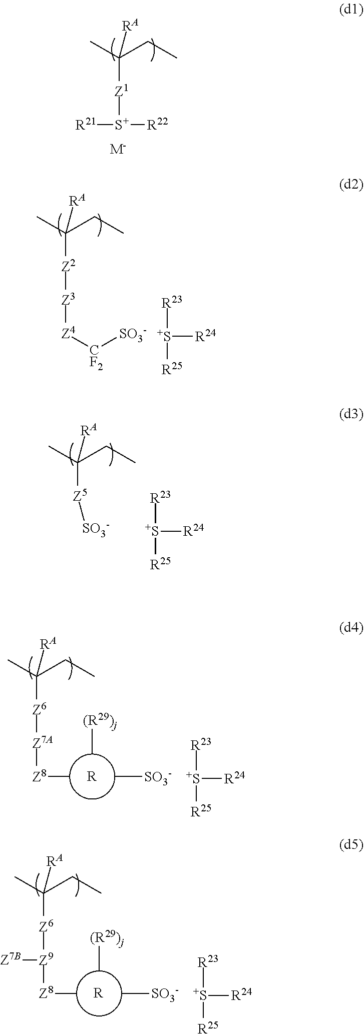

In formulae (d1) to (d5), R^{A} is each independently hydrogen or methyl.

In formulae (d1) to (d3), Z¹ is a single bond, C₁-C₆ aliphatic hydrocarbylene group, phenylene, naphthylene, or a C₇-C₁₈ group obtained by combining the foregoing, or —O—Z¹¹—C(═O)—O—Z¹¹— or —C(═O)—NH—Z¹¹—, Z¹¹ is a C₁-C₆ aliphatic hydrocarbylene group, phenylene, naphthylene, or a C₇-C₁₈ group obtained by combining the foregoing, which may contain a carbonyl moiety, ester bond, ether bond or hydroxy moiety. Z² is a single bond or ester bond. Z³ is a single bond, —Z³¹—C(═O)—O—, —Z³¹—O—, or —Z³¹—O—C(═O)—. Z³¹ is a C₁-C₁₂ aliphatic hydrocarbylene group, phenylene group, or a C₇-C₁₈ group obtained by combining the foregoing, which may contain a carbonyl moiety, ester bond, ether bond, bromine or iodine. Z⁴ is methylene, 2,2,2-trifluoro-1,1-ethanediyl or carbonyl. Z⁵ is a single bond, methylene, ethylene, phenylene, fluorinated phenylene, trifluoromethyl-substituted phenylene, —O—Z⁵¹—, —C(═O)—O—Z⁵¹—, or —C(═O)—NH—Z⁵¹—. Z⁵¹ is a C₁-C₆ aliphatic hydrocarbylene group, phenylene, fluorinated phenylene, or trifluoromethyl-substituted phenylene group, which may contain a carbonyl moiety, ester bond, ether bond, halogen or hydroxy moiety. The aliphatic hydrocarbylene group represented by Z¹, Z¹¹, Z³¹ and Z¹¹ may be saturated or unsaturated and straight, branched or cyclic.

In formulae (d4) and (d5), Z⁶ is a single bond, phenylene group, naphthylene ring, ester bond or amide bond.

In formula (d4), Z^{7A} is a single bond or a C₁-C₂₄ divalent organic group which may contain at least one element selected from halogen, oxygen, nitrogen and sulfur.

The divalent organic group Z^{7A} may be saturated or unsaturated and straight, branched or cyclic. Also included are C₁-C₂₄ hydrocarbylene groups in which some or all of the hydrogen atoms are substituted by iodine or bromine. Examples of the C₁-C₂₄ hydrocarbylene group include alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, heptadecane-1,17-diyl, octadecane-1,18-diyl, nonadecane-1,19-diyl, and eicosane-1,20-diyl; cyclic saturated hydrocarbylene groups such as cyclopentanediyl, methylcyclopentanediyl, dimethylcyclopentanediyl, trimethylcyclopentanediyl, tetramethylcyclopentanediyl, cyclohexanediyl, methylcyclohexanediyl, dimethylcyclohexanediyl, trimethylcyclohexanediyl, tetramethylcyclohexanediyl, norbornanediyl and adamantanediyl; arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, tert-butylnaphthylene, biphenyldiyl, methylbiphenyldiyl and dimethylbiphenyldiyl; and combinations thereof. In the hydrocarbylene group Z^{7A}, some or all of the hydrogen atoms may be substituted by a moiety containing at least one element selected from oxygen, nitrogen and sulfur, or some —CH₂— may be replaced by a moiety containing at least one element selected from oxygen, nitrogen and sulfur, so that the group may contain a hydroxy moiety, ester bond, ether bond, amide bond, carbamate bond or urea bond.

In formula (d5), Z^{7B} is a C₁-C₁₀ monovalent organic group which may contain at least one element selected from halogen, oxygen, nitrogen and sulfur.

The monovalent organic group Z^{7B} may be saturated or unsaturated and straight, branched or cyclic. Also included are C₁-C₁₀ hydrocarbyl groups in which some or all of the hydrogen atoms are substituted by iodine or bromine. Examples of the C₁-C₁₀ hydrocarbyl group include C₁-C₁₀ alkyl groups such as methyl, ethyl, n-propyl, isopropyl, n-butyl, isobutyl, sec-butyl, tert-butyl, n-pentyl, isopentyl, sec-pentyl, 3-pentyl, tert-pentyl, neopentyl, n-hexyl, n-octyl, n-nonyl, and n-decyl; C₃-C₁₀ cyclic saturated hydrocarbyl groups such as cyclopropyl, cyclobutyl, cyclopentyl, cyclohexyl, adamantyl, norbornyl, cyclopropylmethyl, cyclopropylethyl, cyclobutylmethyl, cyclobutylethyl, cyclopentylmethyl, cyclopentylethyl, cyclohexylmethyl, cyclohexylethyl, methylcyclopropyl, methylcyclobutyl, methylcyclopentyl, methylcyclohexyl, ethylcyclopropyl, ethylcyclobutyl, ethylcyclopentyl, and ethylcyclohexyl; C₂-C₁₀ alkenyl groups such as vinyl, 1-propenyl, 2-propenyl, butenyl, pentenyl, hexenyl, heptenyl, nonenyl, and decenyl; C₂-C₁₀ alkynyl groups such as ethynyl, propynyl, butynyl, pentynyl, hexynyl, heptynyl, octynyl, nonynyl, and decynyl; C₃-C₁₀ cyclic unsaturated aliphatic hydrocarbyl groups such as cyclopentenyl, cyclohexenyl, methylcyclopentenyl, methylcyclohexenyl, ethylcyclopentenyl, ethylcyclohexenyl, and norbornenyl; C₆-C₁₀ aryl groups such as phenyl, methylphenyl, ethylphenyl, n-propylphenyl, isopropylphenyl, n-butylphenyl, isobutylphenyl, sec-butylphenyl, tert-butylphenyl, and naphthyl; C₇-C₁₀ aralkyl groups such as benzyl, phenethyl, phenylpropyl and phenylbutyl; and combinations thereof. In the hydrocarbyl group Z^{7B}, some or all of the hydrogen atoms may be substituted by a moiety containing at least one element selected from oxygen, nitrogen and sulfur, and some —CH₂— may be replaced by a moiety containing at least one element selected from oxygen, nitrogen and sulfur, so that the group may contain a hydroxy, ester bond, ether bond, amide bond, carbamate bond, or urea bond.

In formulae (d4) and (d5), Z⁸ is a single bond, ether bond, ester bond, thioether bond, or a C₁-C₆ alkanediyl group.

In formula (d5), Z⁹ is a C₁-C₁₂ trivalent organic group which may contain at least one element selected from oxygen, nitrogen and sulfur. The trivalent organic group may be saturated or unsaturated and straight, branched or cyclic. Examples thereof include groups obtained from C₁-C₁₂ hydrocarbylene groups by further eliminating one hydrogen. Examples of the C₁-C₁₂ hydrocarbylene groups include those exemplified above for the C₁-C₂₄ hydrocarbylene group, but of 1 to 12 carbon atoms. In the group Z⁹, some or all of the hydrogen atoms may be substituted by a moiety containing at least one element selected from oxygen, nitrogen and sulfur, and some —CH₂— may be replaced by a moiety containing at least one element selected from oxygen, nitrogen and sulfur, so that the group may contain a hydroxy, ester bond, ether bond, amide bond, carbamate bond, or urea bond.

In formulae (d1) to (d5), R²¹ to R²⁵ are each independently halogen or a C₁-C₂₀ hydrocarbyl group which may contain a heteroatom. Suitable halogen atoms include fluorine, chlorine, bromine and iodine. The hydrocarbyl group may be saturated or unsaturated and straight, branched or cyclic. Examples thereof are as exemplified above for R² to R⁴ in formula (a). In the foregoing hydrocarbyl groups, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety. R²³ and R²⁴ may bond together to form a ring with the sulfur atom to which they are attached. Examples of the ring are as exemplified above for the ring that R² and R³ in formula (a), taken together, form with the sulfur atom to which they are attached.

In formulae (d4) and (d5), R²⁶ is each independently a C₁-C₁₀ saturated hydrocarbyl group, C₆-C₁₀ aryl group, fluorine, iodine, trifluoromethoxy, difluoromethoxy, cyano or nitro group.

In formulae (d4) and (d5), the circle R is a C₆-C₁₀ (j+2)-valent aromatic hydrocarbon group. Examples of the (j+2)-valent aromatic hydrocarbon group include groups obtained from aromatic hydrocarbons such as benzene and naphthalene by eliminating (j+2) number of hydrogen atoms.

In formulae (d4) and (d5), j is each independently an integer of 0 to 5.

In formula (d1), M⁻ is a non-nucleophilic counter ion. Examples of the non-nucleophilic counter ion include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; methide ions such as tris(trifluoromethylsulfonyl)methide and tris(perfluoroethylsulfonyl)methide.

Also included are sulfonate ions having fluorine substituted at α-position as represented by the formula (d1-1) and sulfonate ions having fluorine substituted at α-position and trifluoromethyl at P-position as represented by the formula (d1-2).

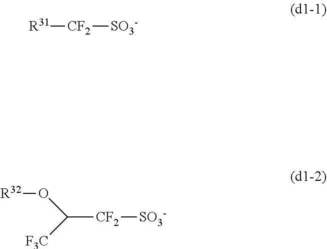

In formula (d1-1), R³¹ is hydrogen or a C₁-C₂₀ hydrocarbyl group which may contain an ether bond, ester bond, carbonyl moiety, lactone ring, or fluorine atom. The hydrocarbyl group may be saturated or unsaturated and straight, branched or cyclic. Examples thereof are as will be exemplified later for the hydrocarbyl group R^{fa1} in formula (1A′).

In formula (d1-2), R³² is hydrogen, or a C₁-C₃₀ hydrocarbyl group or C₂-C₃₀ hydrocarbylcarbonyl group, which may contain an ether bond, ester bond, carbonyl moiety or lactone ring. The hydrocarbyl group and the hydrocarbyl moiety in the hydrocarbylcarbonyl group may be saturated or unsaturated and straight, branched or cyclic. Examples thereof are as will be exemplified later for the hydrocarbyl group R^{fa1} in formula (1A′).

Examples of the cation in the monomer from which repeat unit (d1) is derived are shown below, but not limited thereto. R^{A} is as defined above.

[chemical structure]

Examples of the cation in repeat units (d2) to (d5) are as exemplified above for the cation in repeat unit (a).

Examples of the anion in the monomer from which repeat unit (d2) is derived are shown below, but not limited thereto. R^{A} is as defined above.

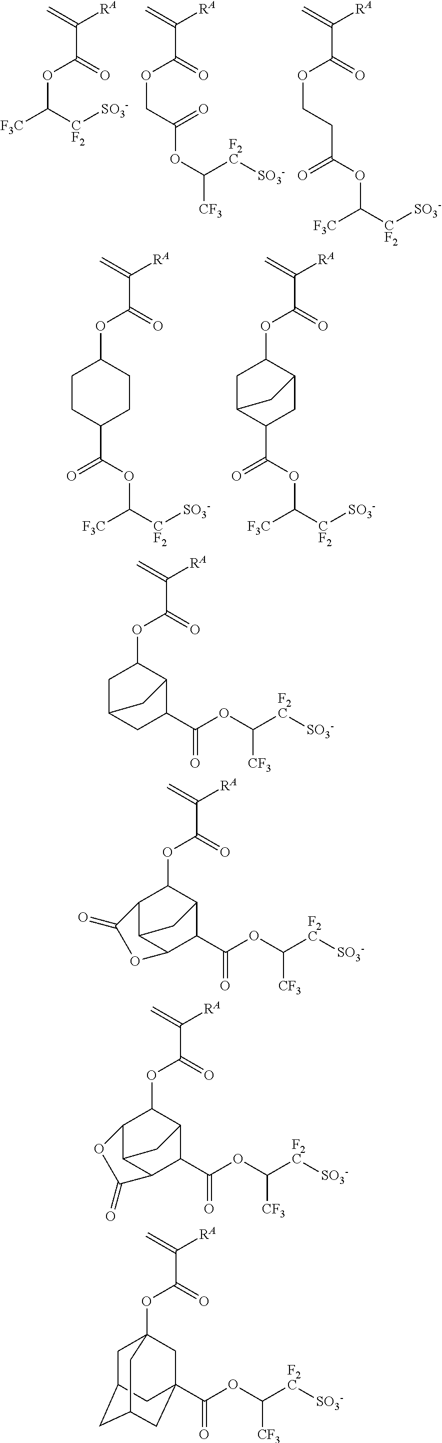

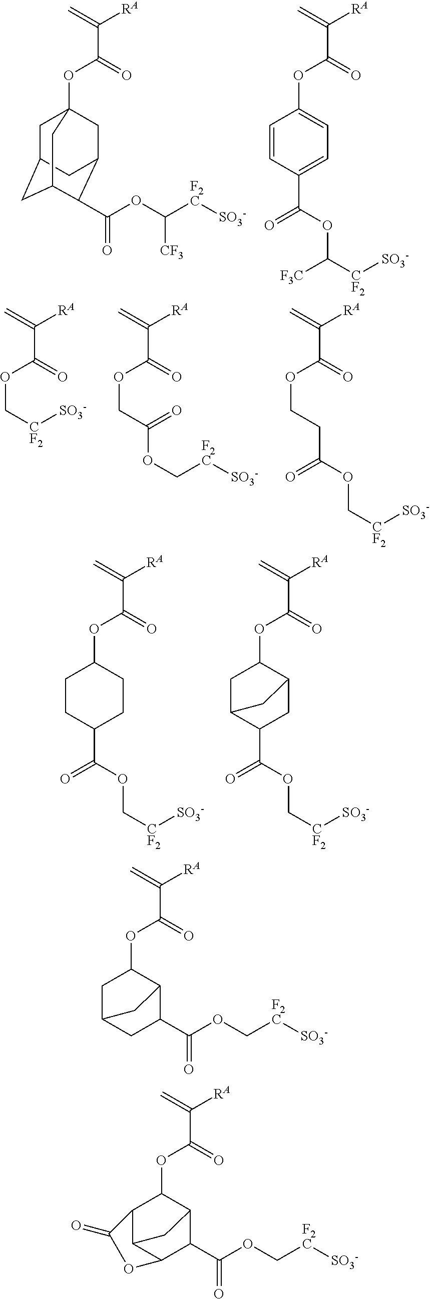

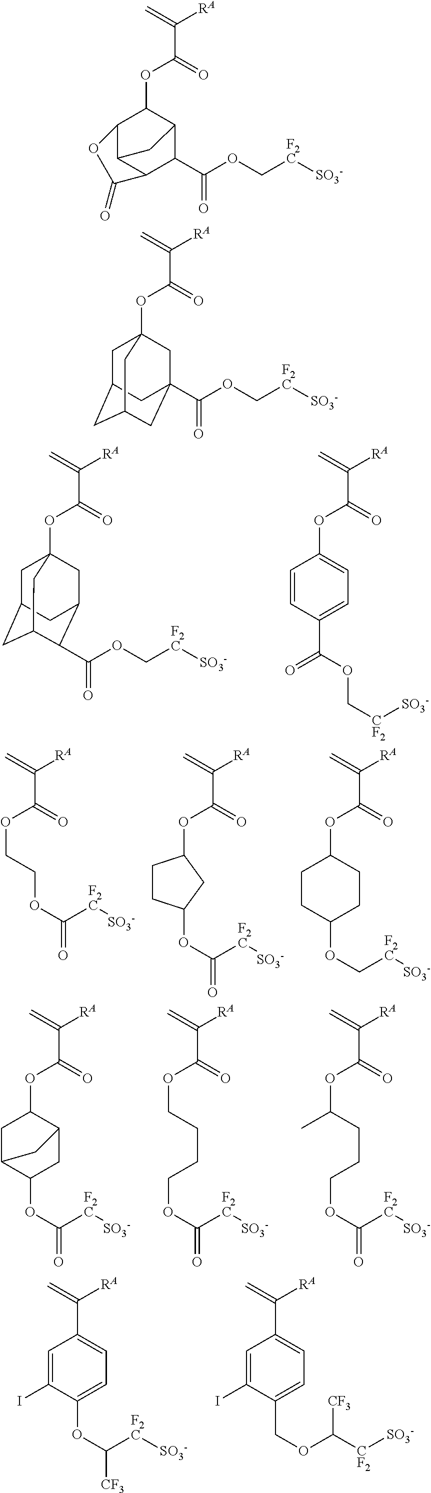

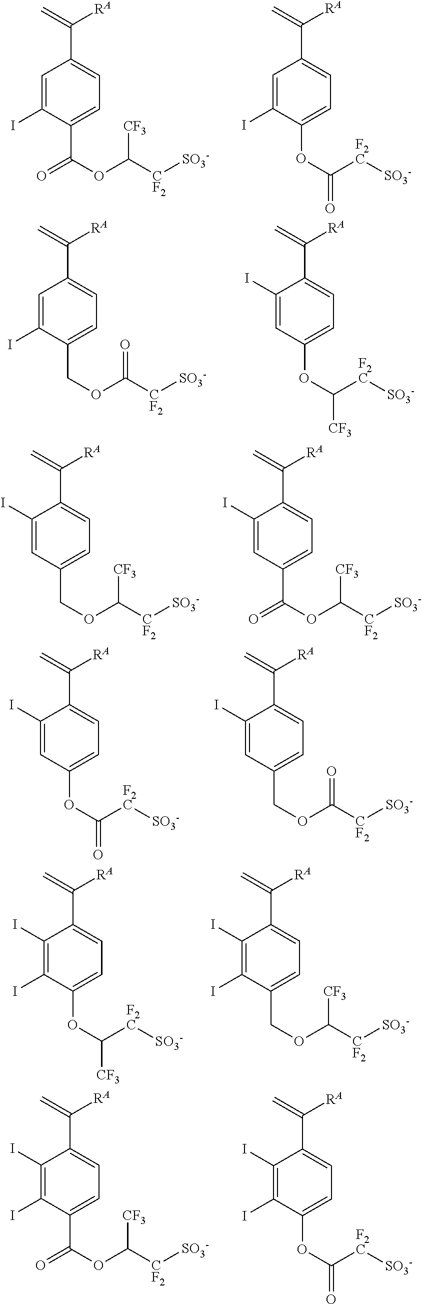

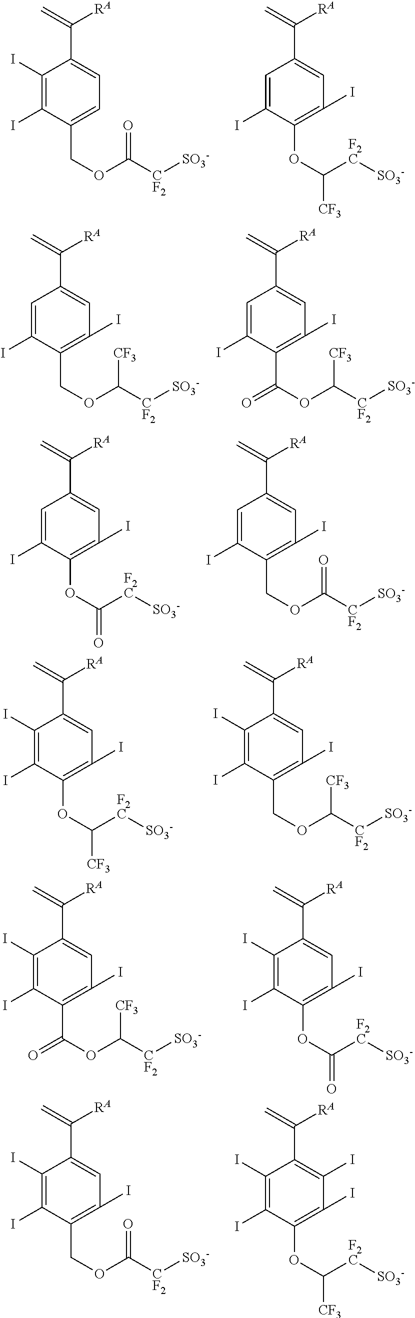

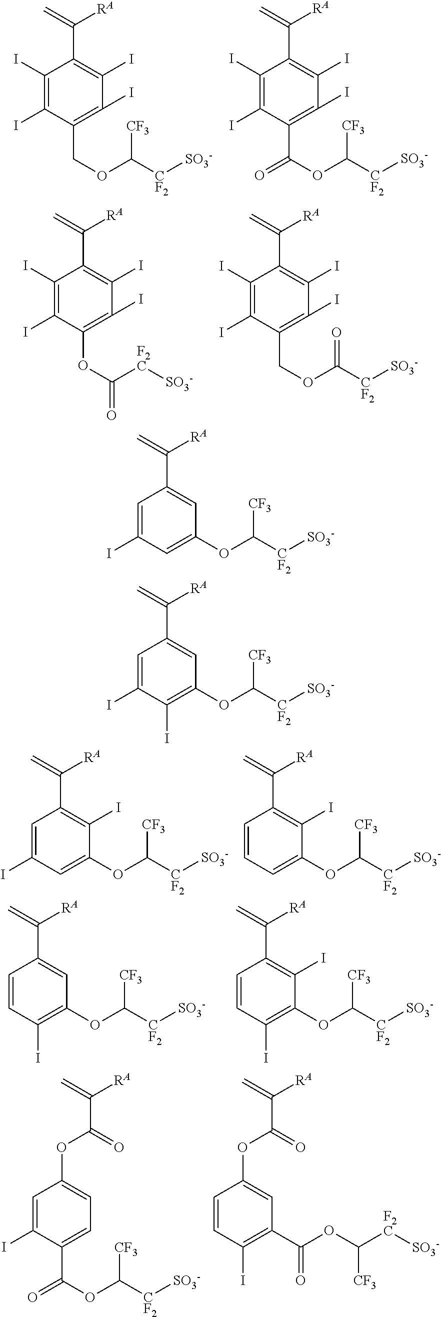

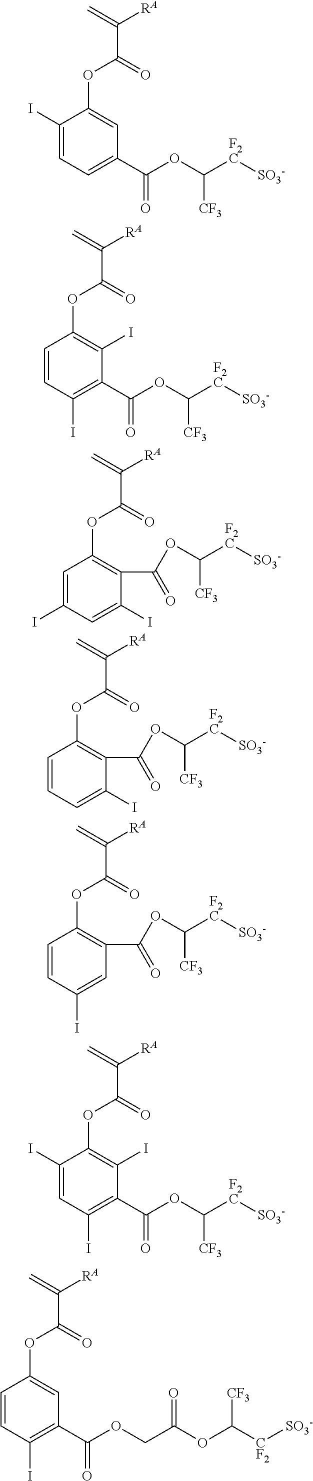

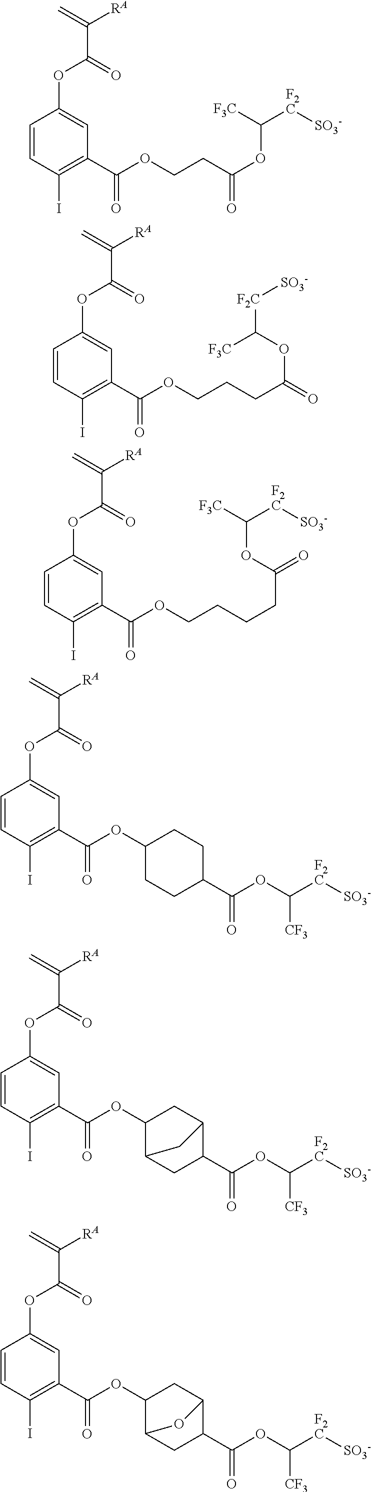

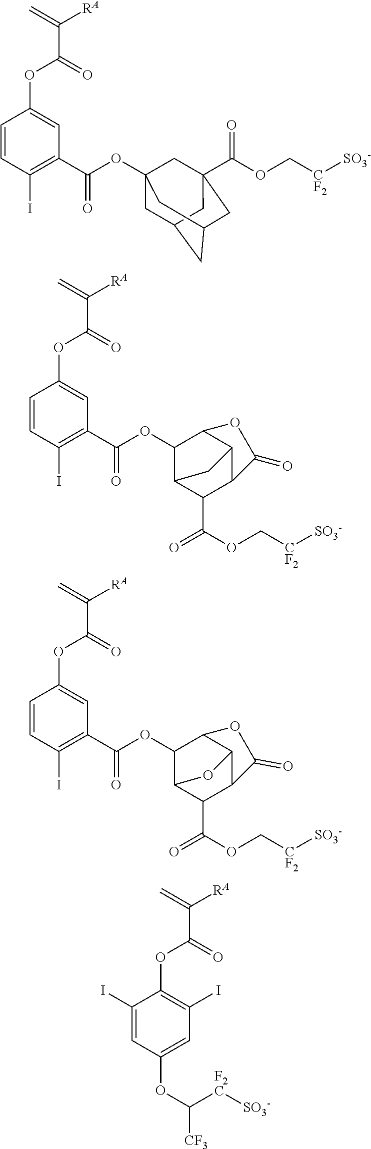

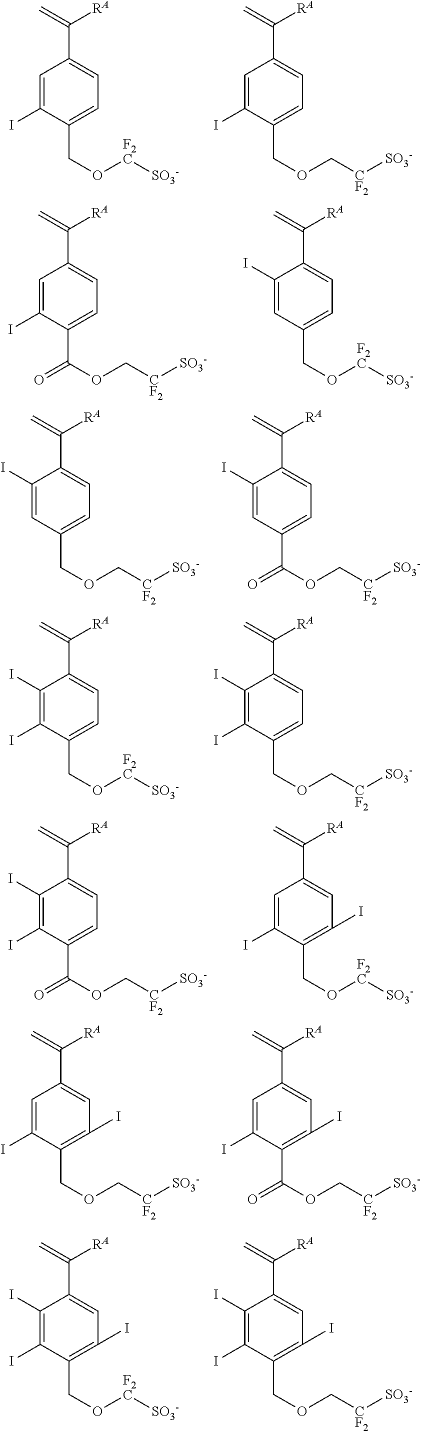

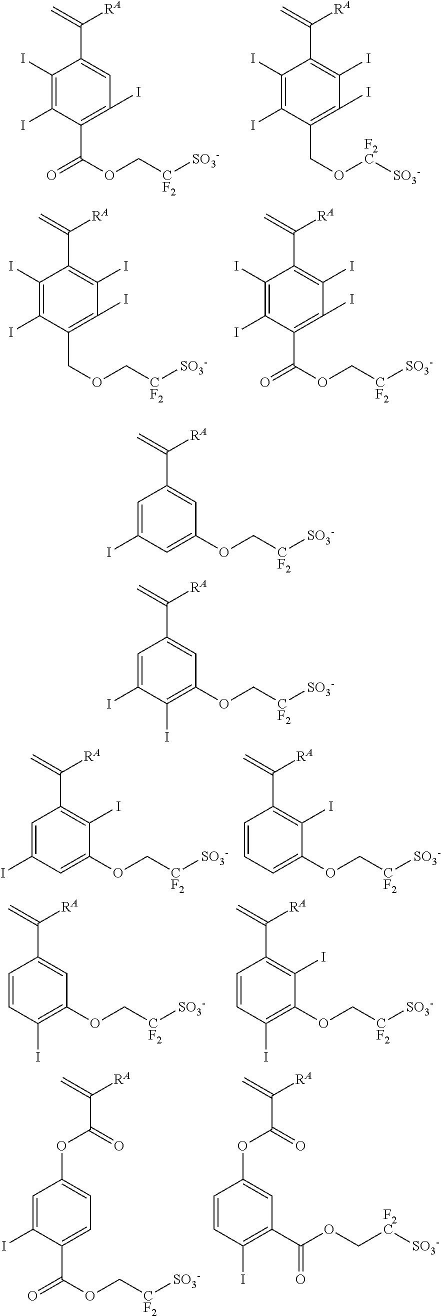

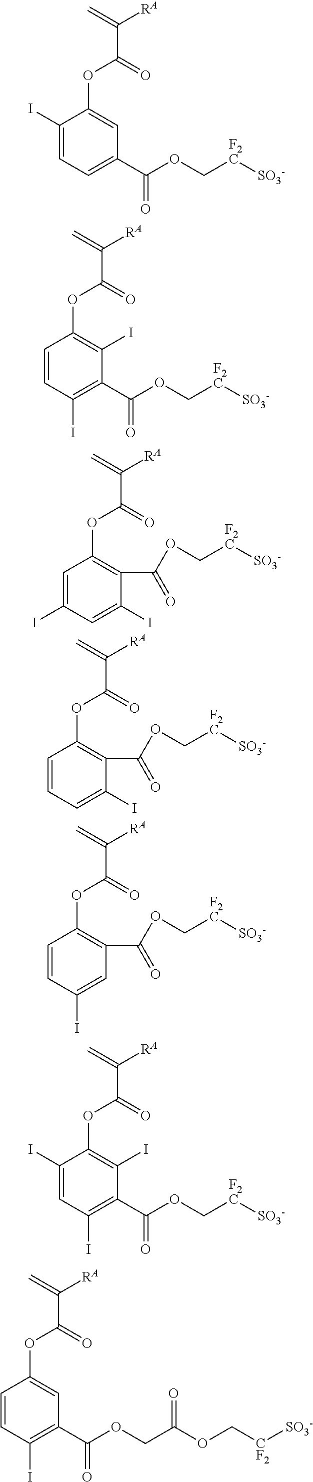

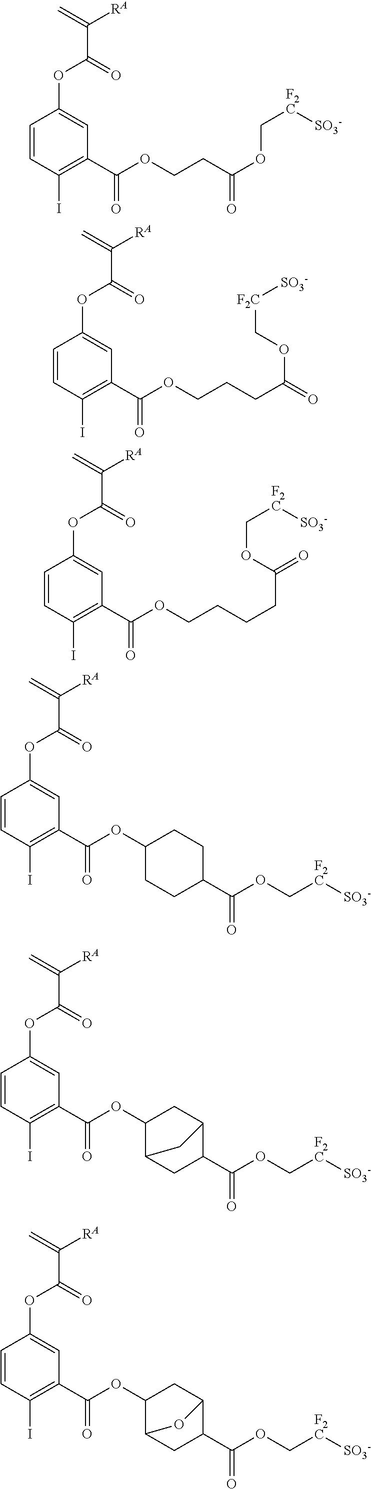

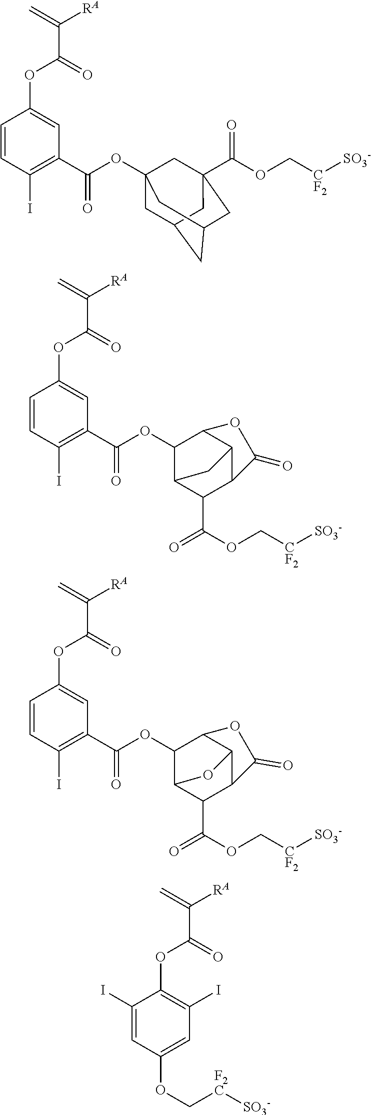

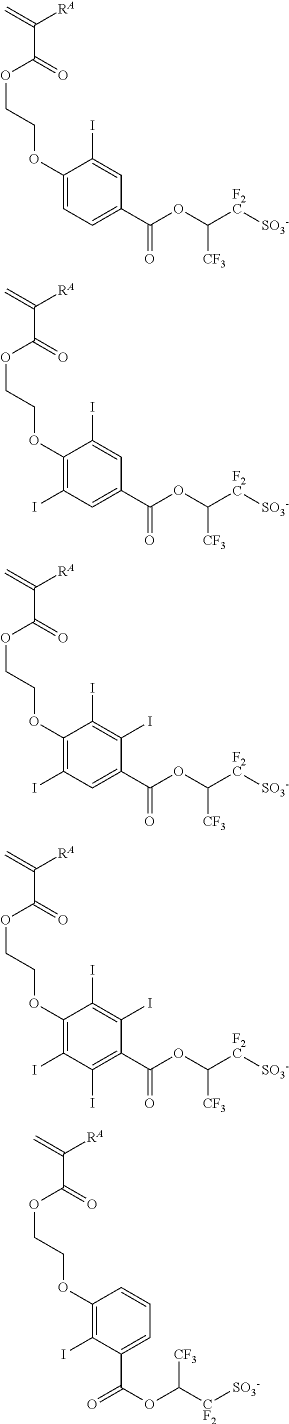

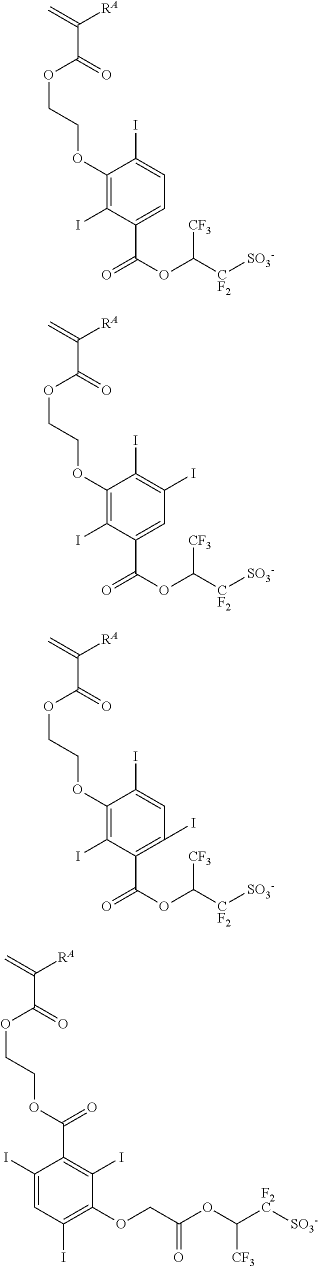

Examples of the anion in the monomer from which repeat unit (B) is derived are shown below, but not limited thereto. R^{A} is as defined above.

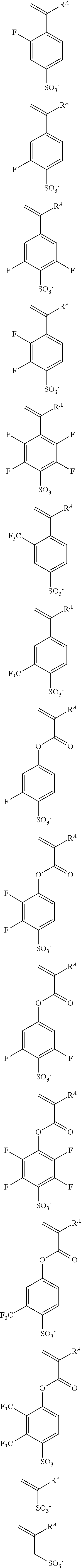

Examples of the anion in the monomer from which repeat unit (d4) or (d5) is derived are shown below, but not limited thereto. R^{A} and X^{BI} are as defined above.

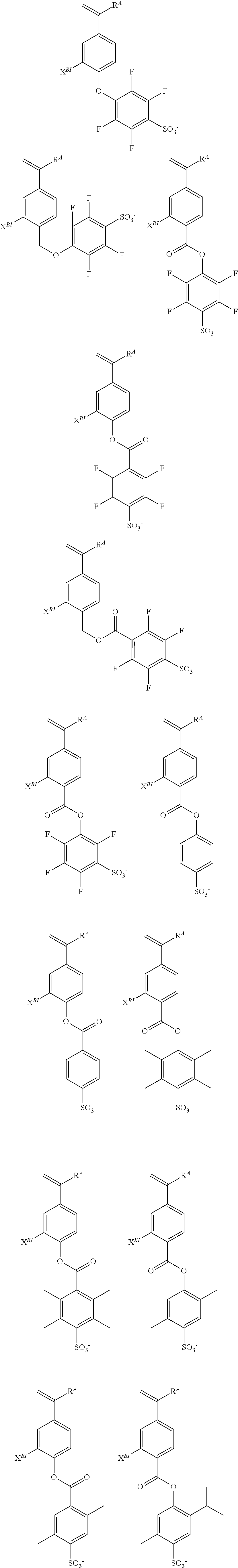

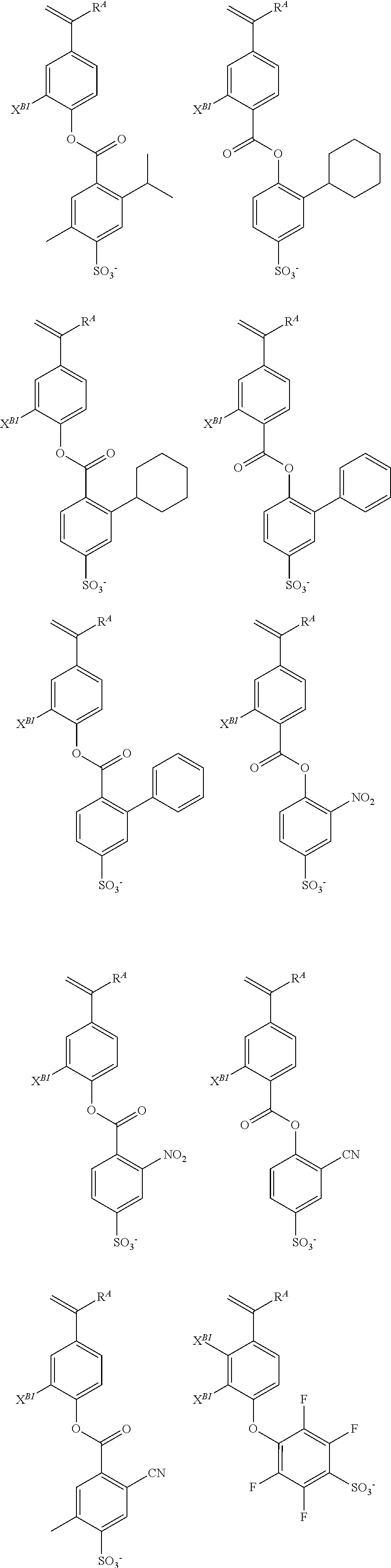

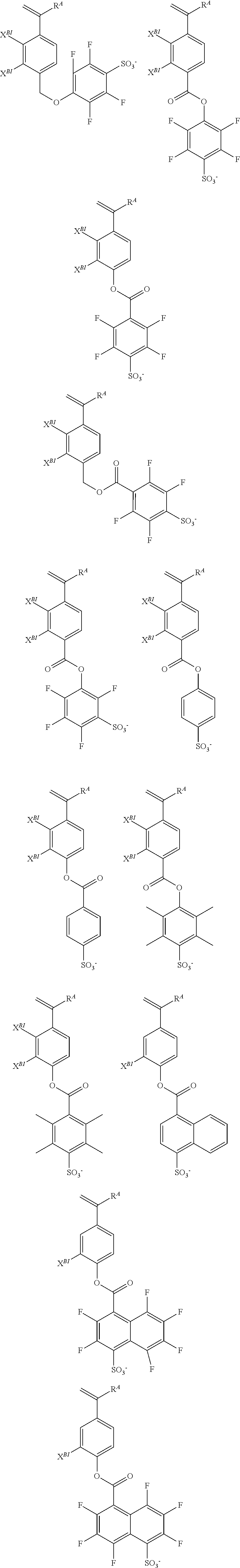

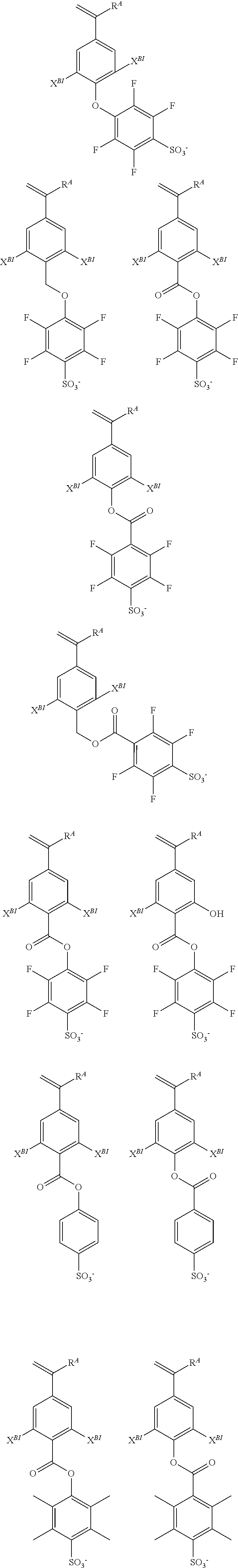

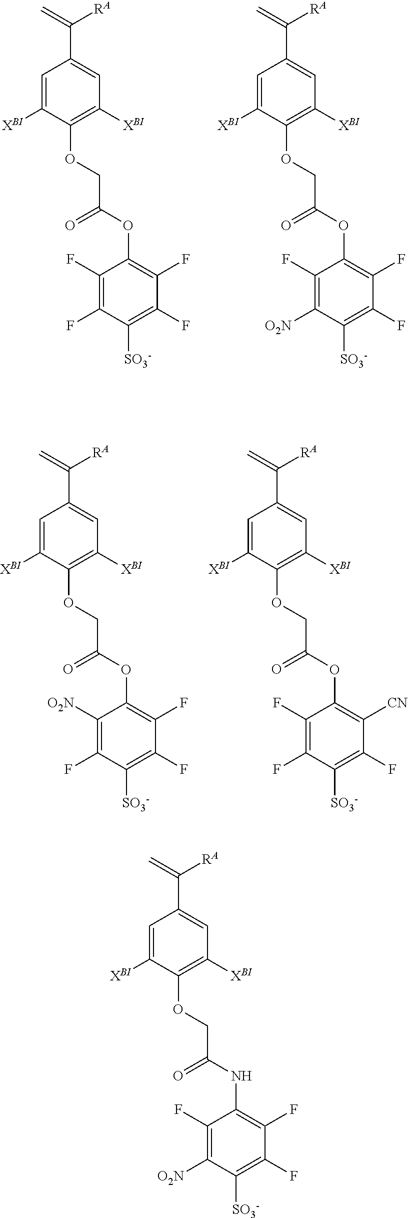

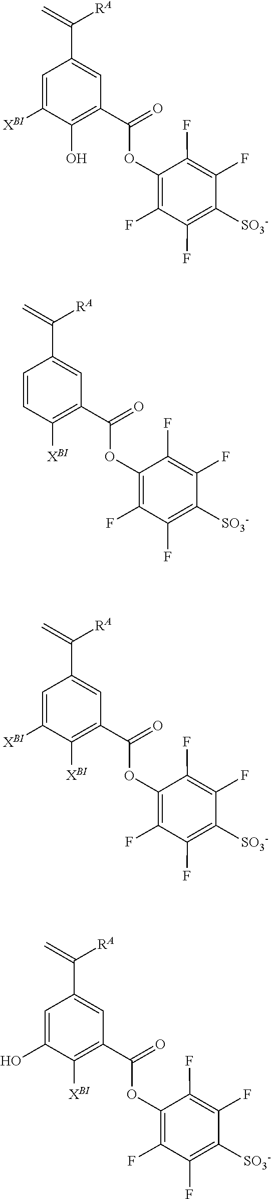

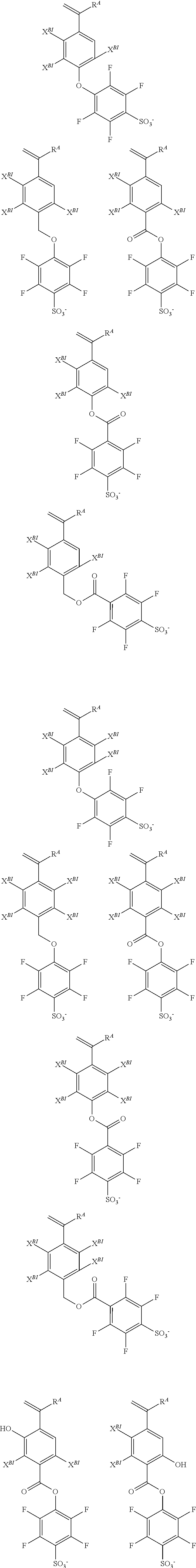

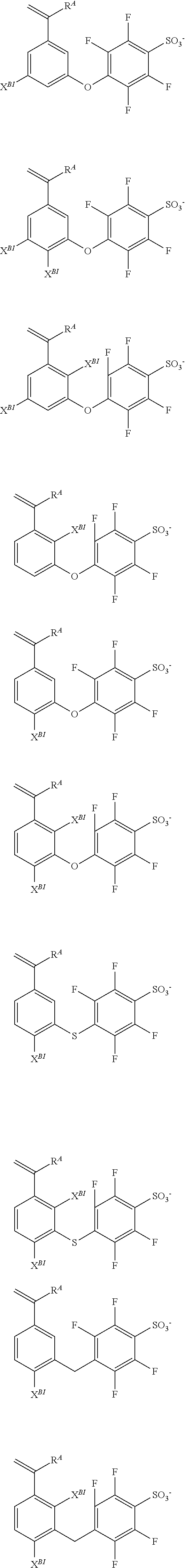

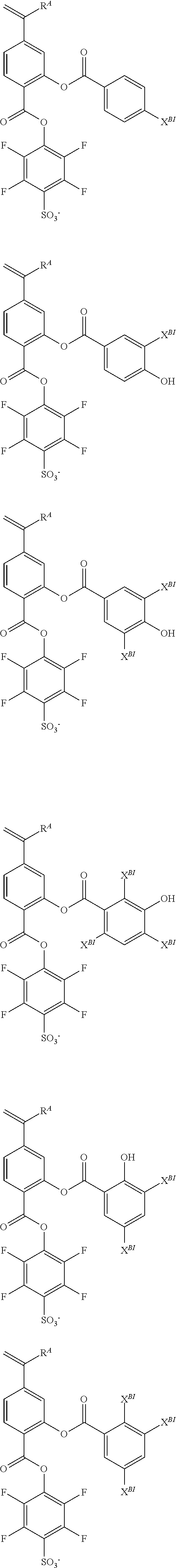

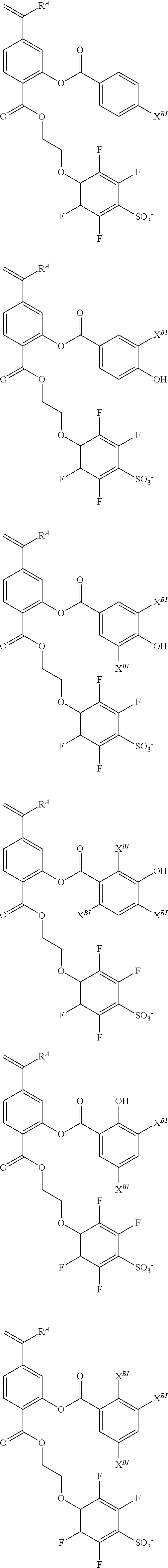

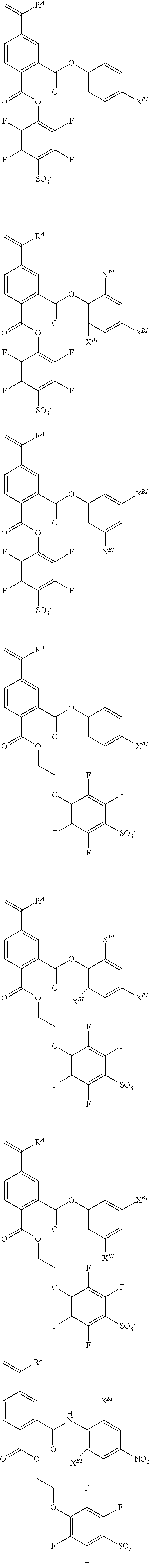

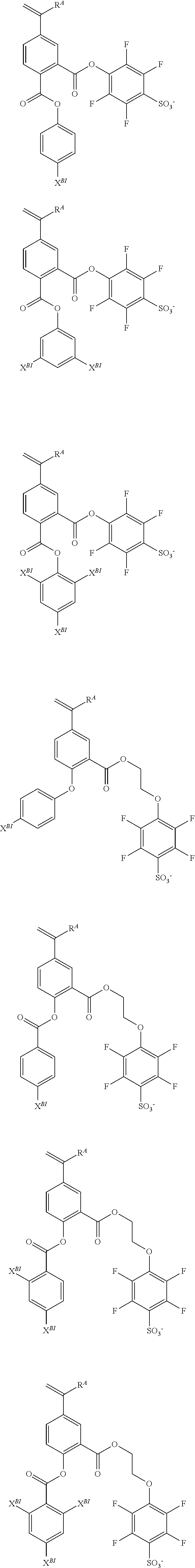

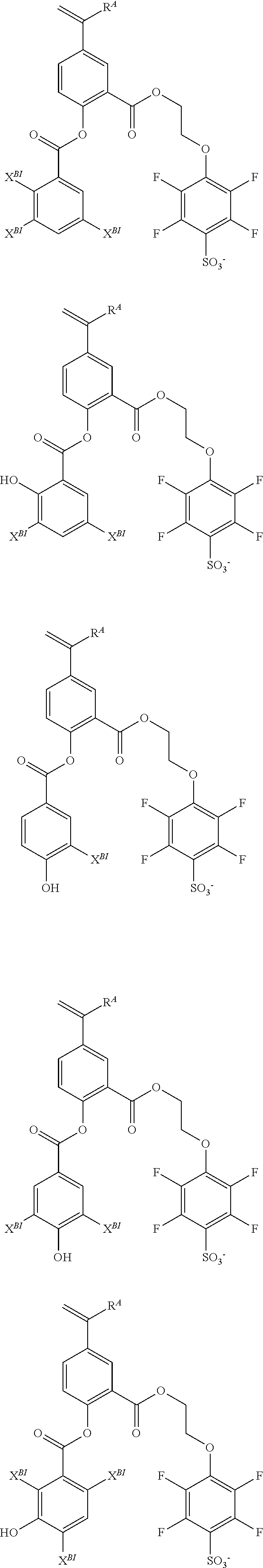

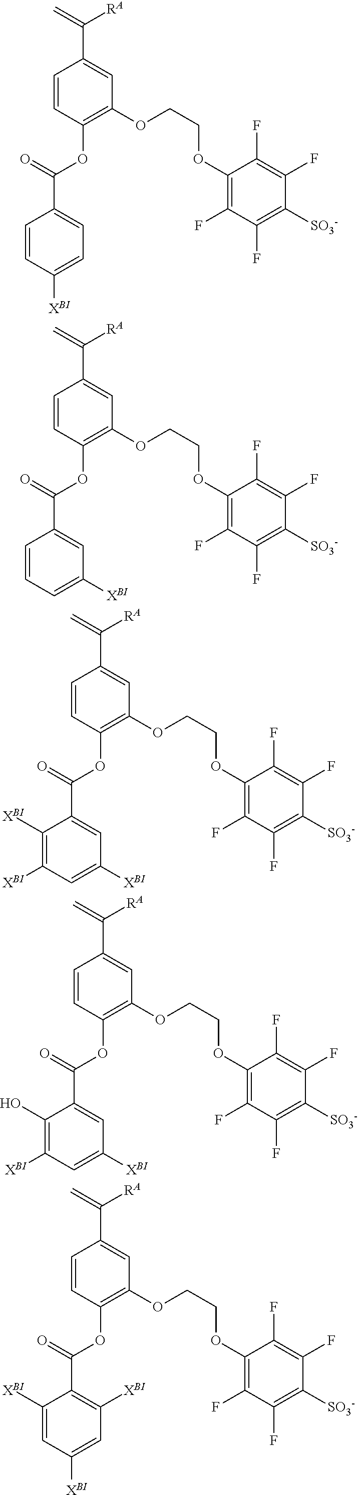

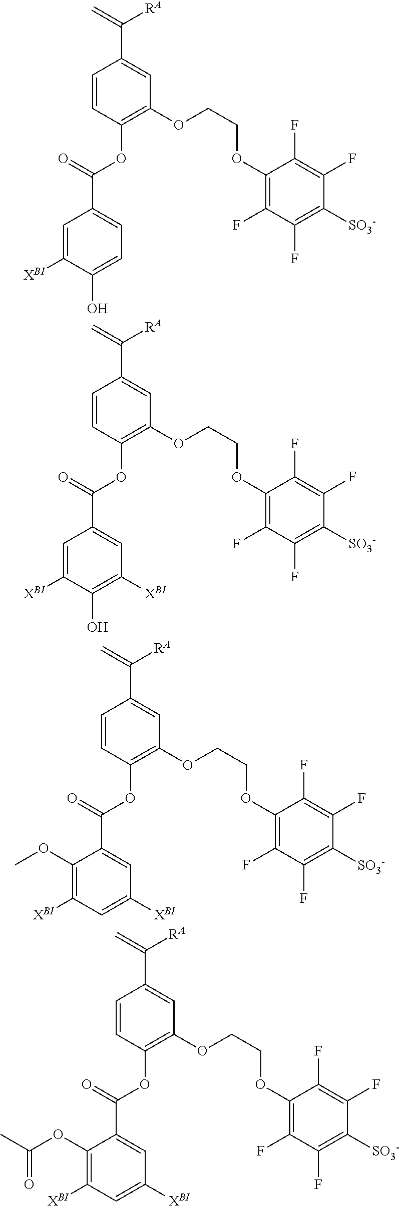

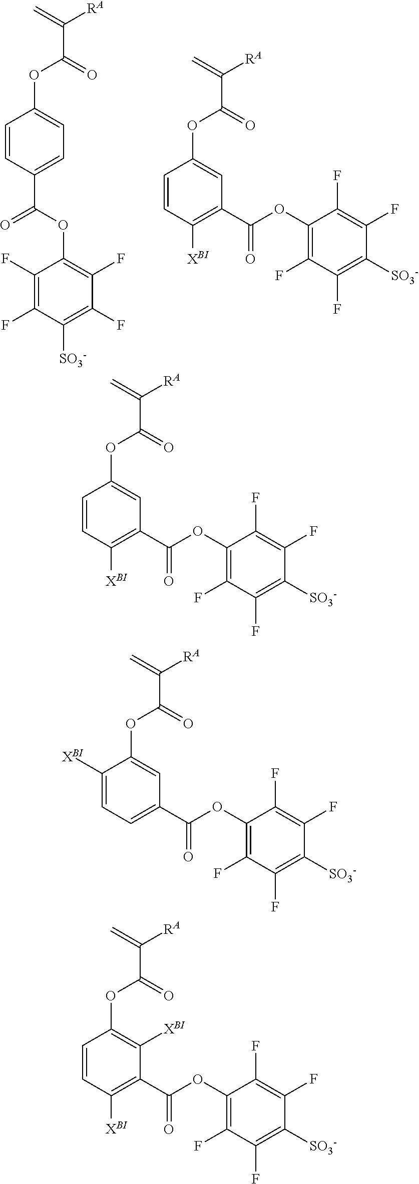

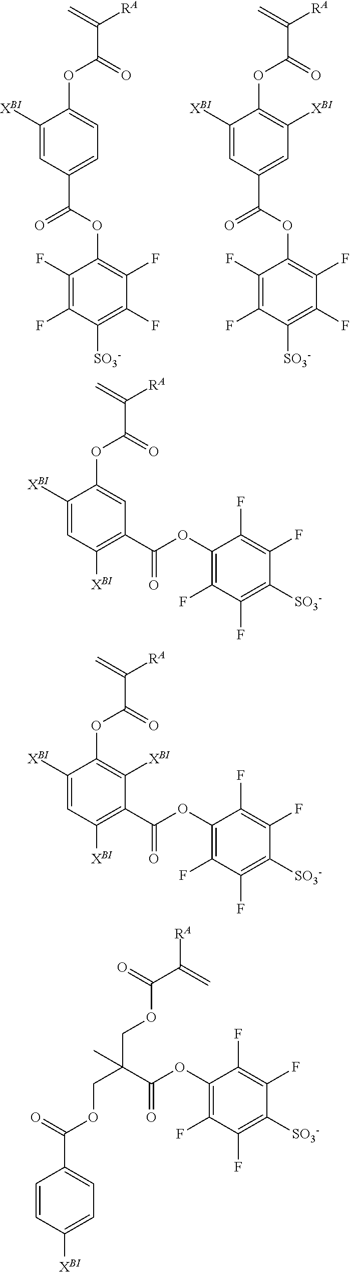

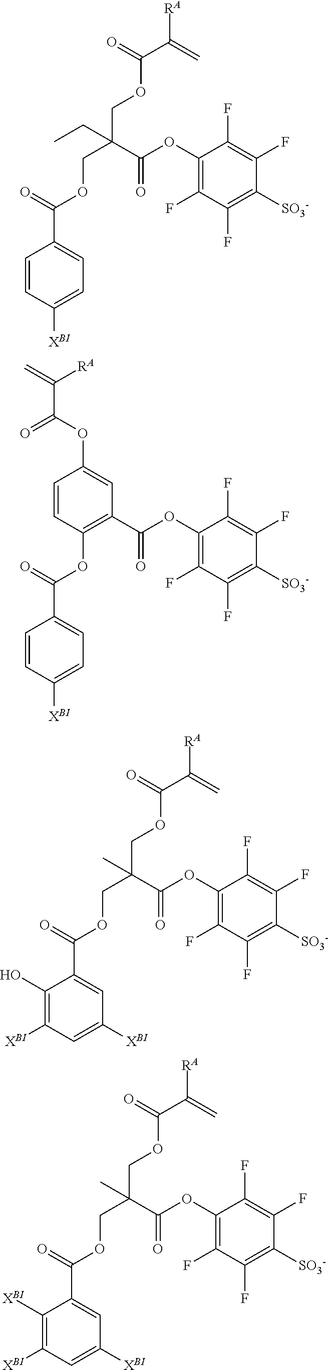

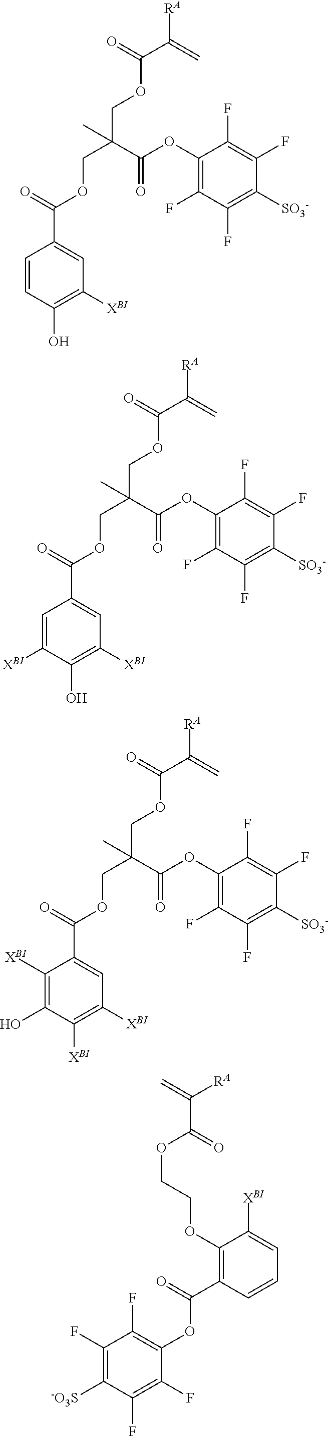

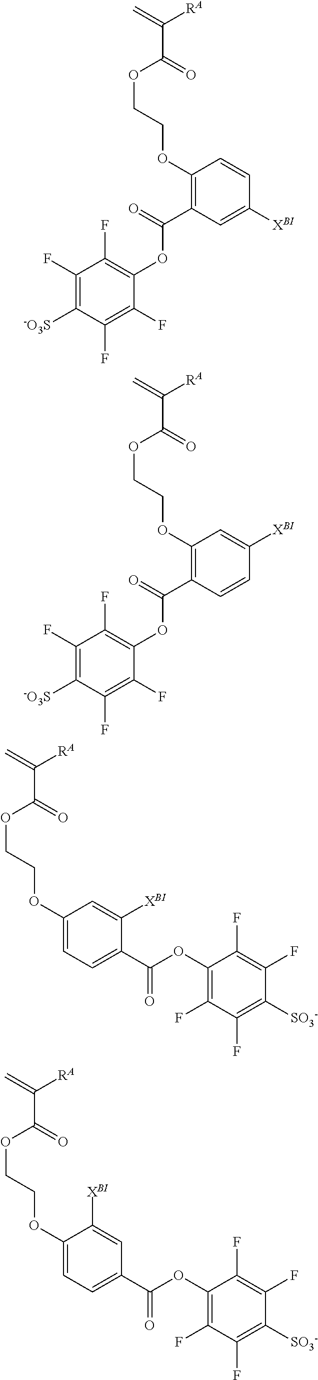

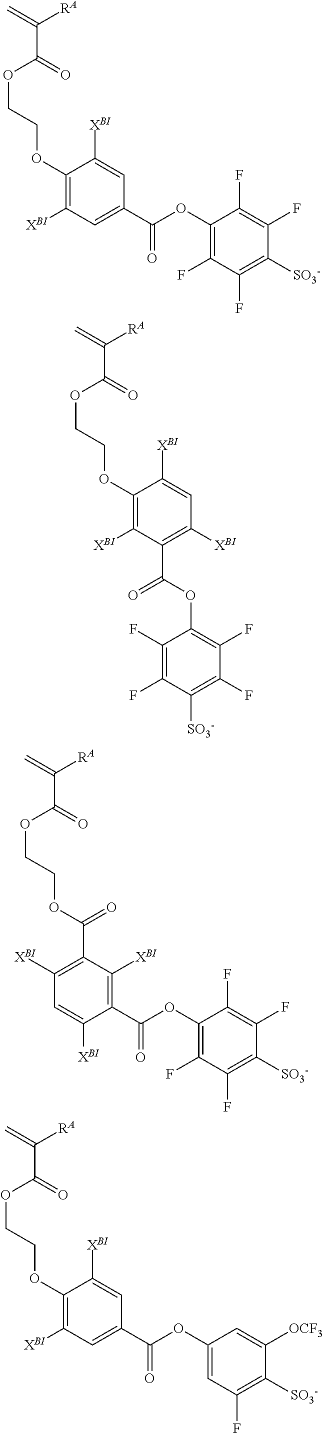

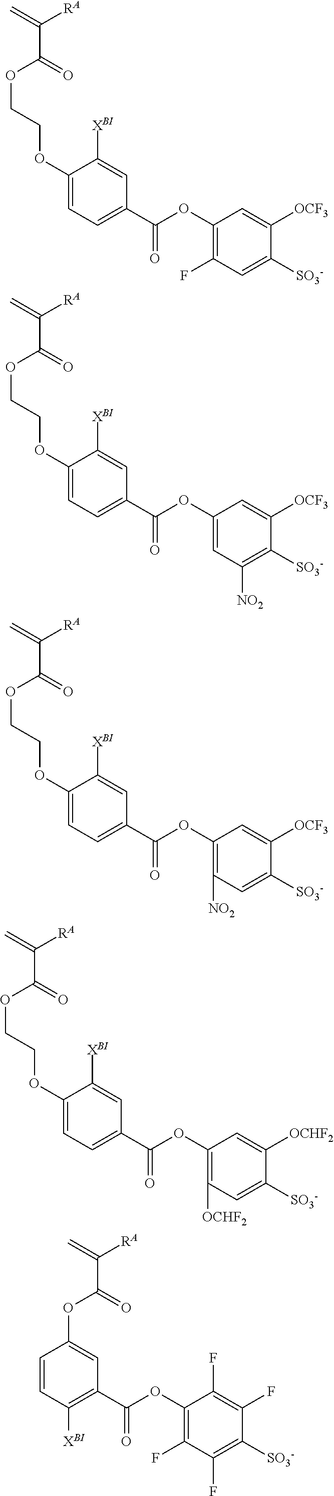

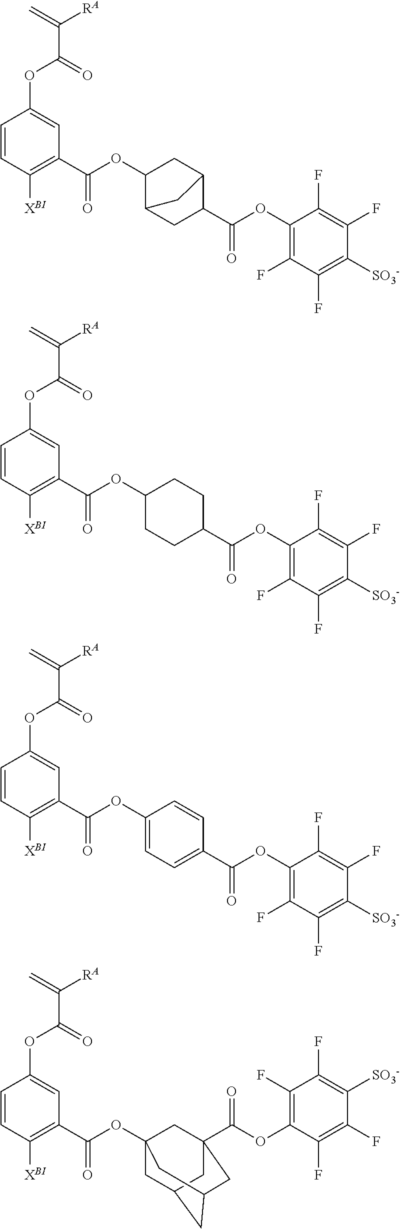

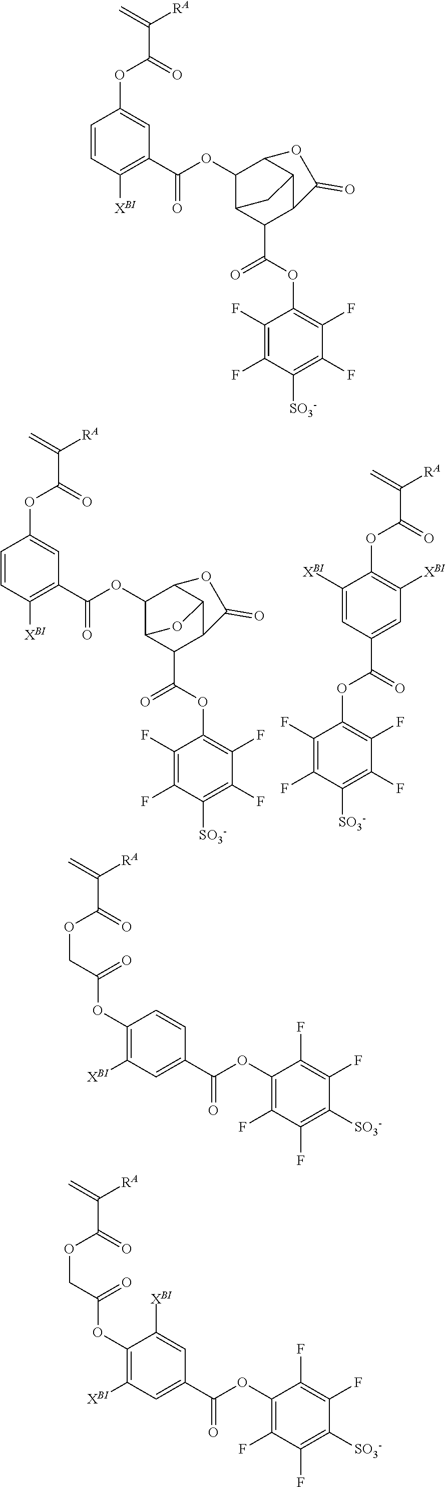

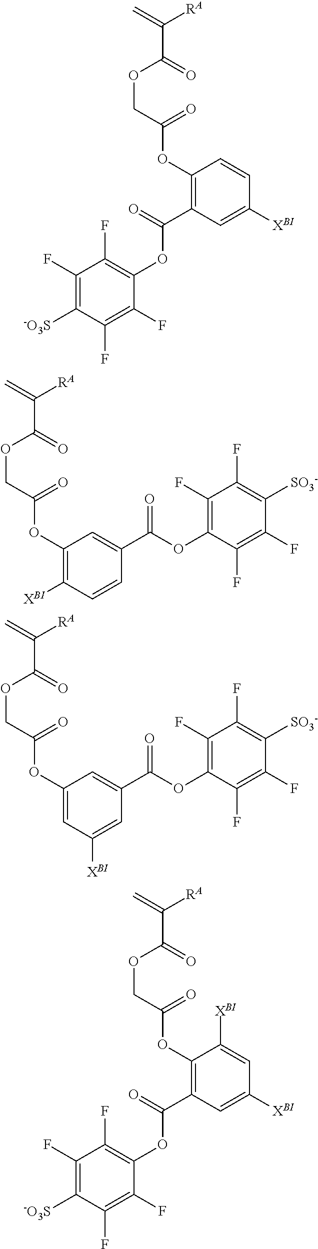

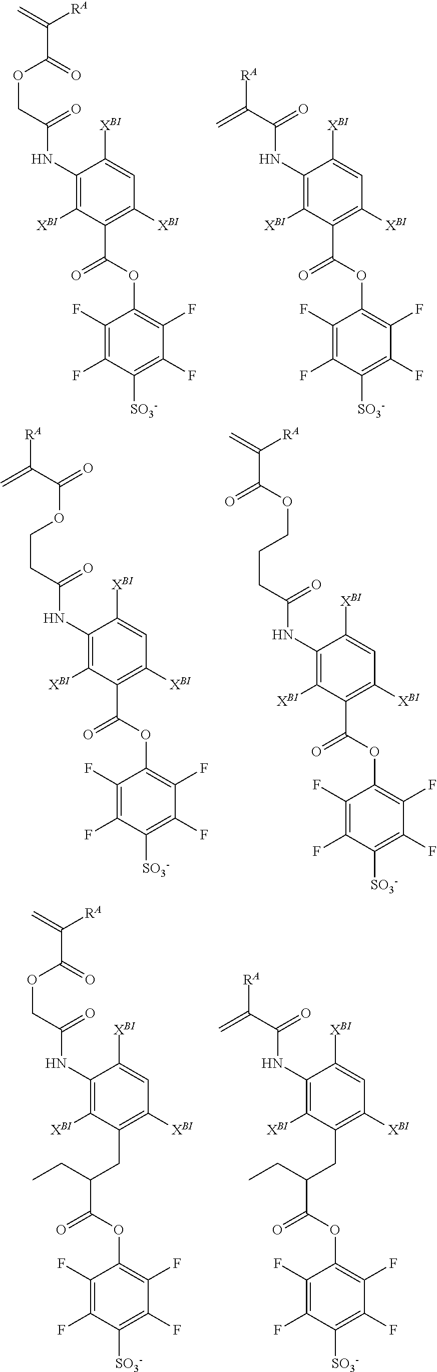

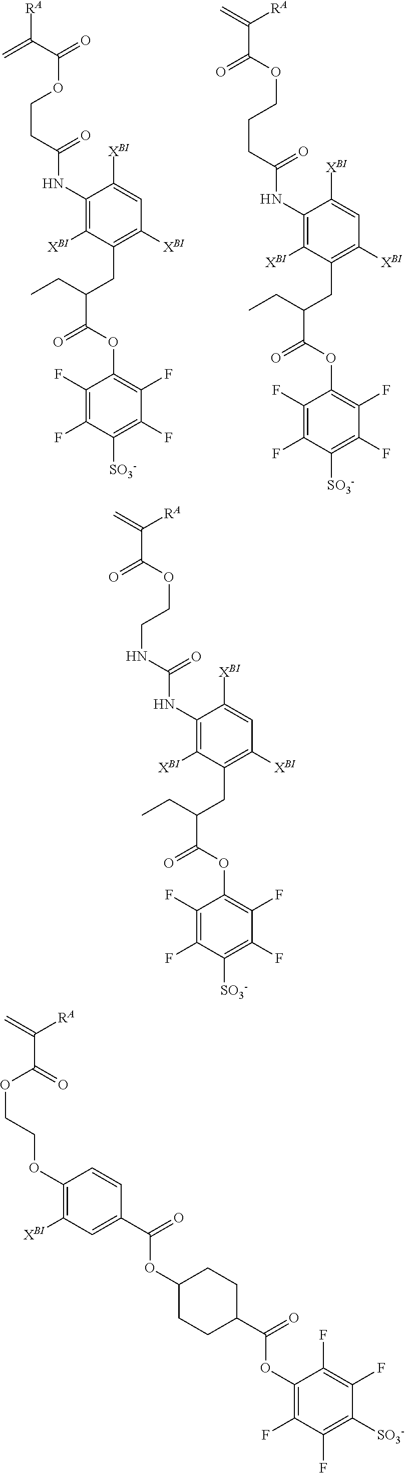

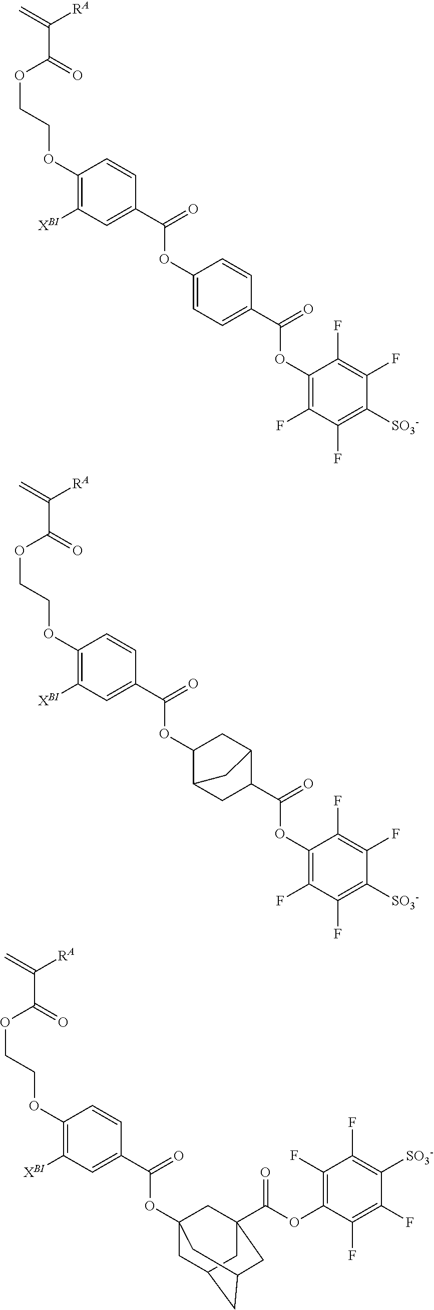

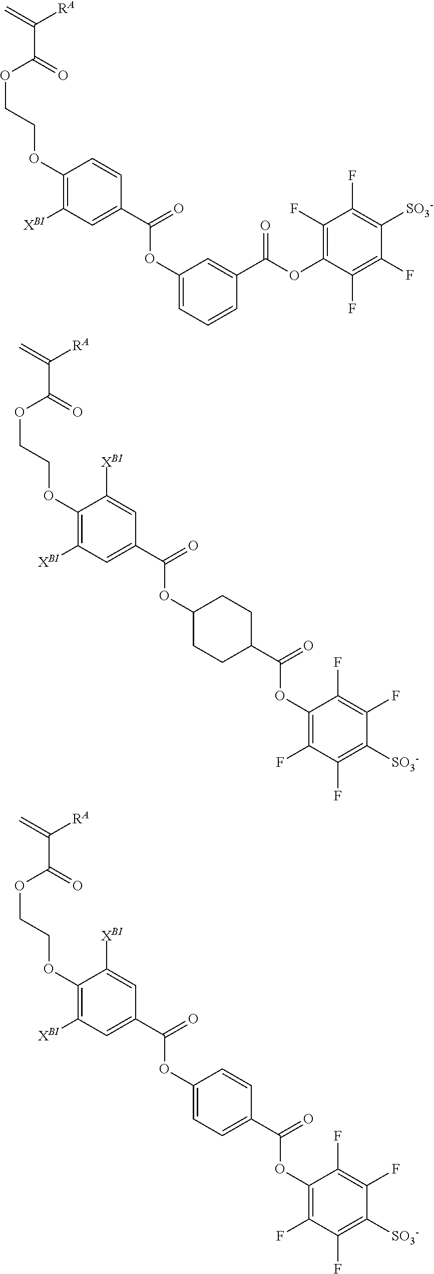

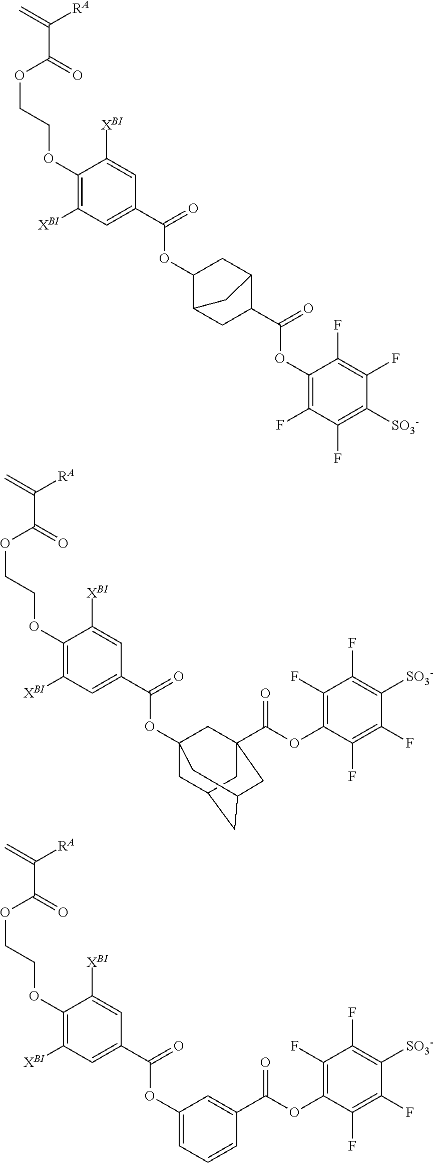

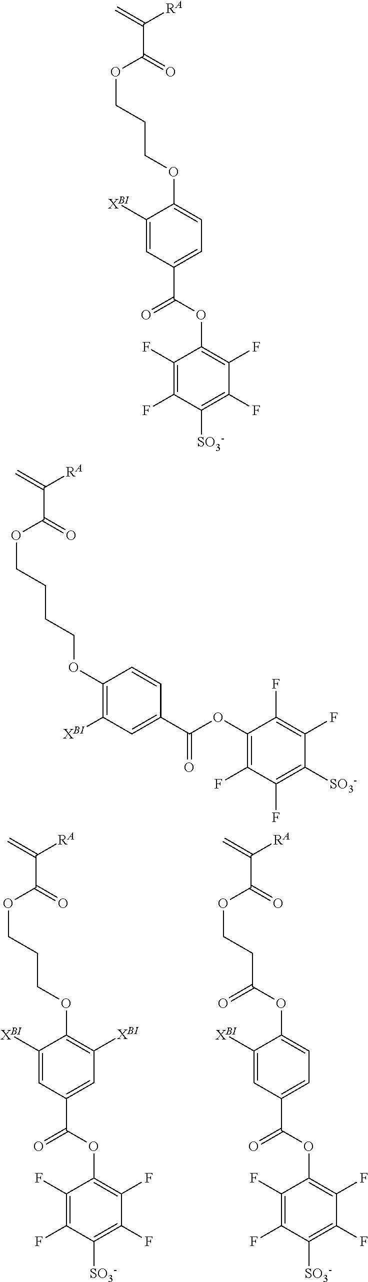

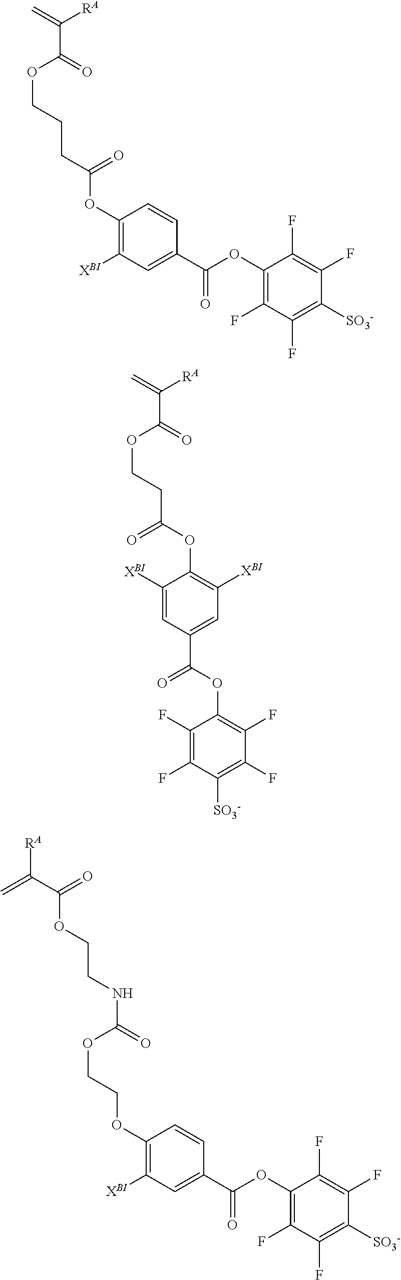

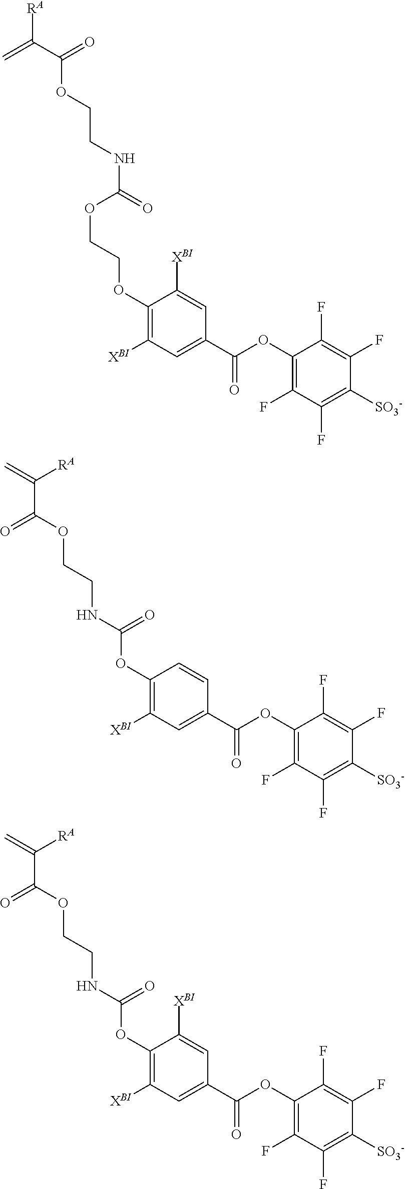

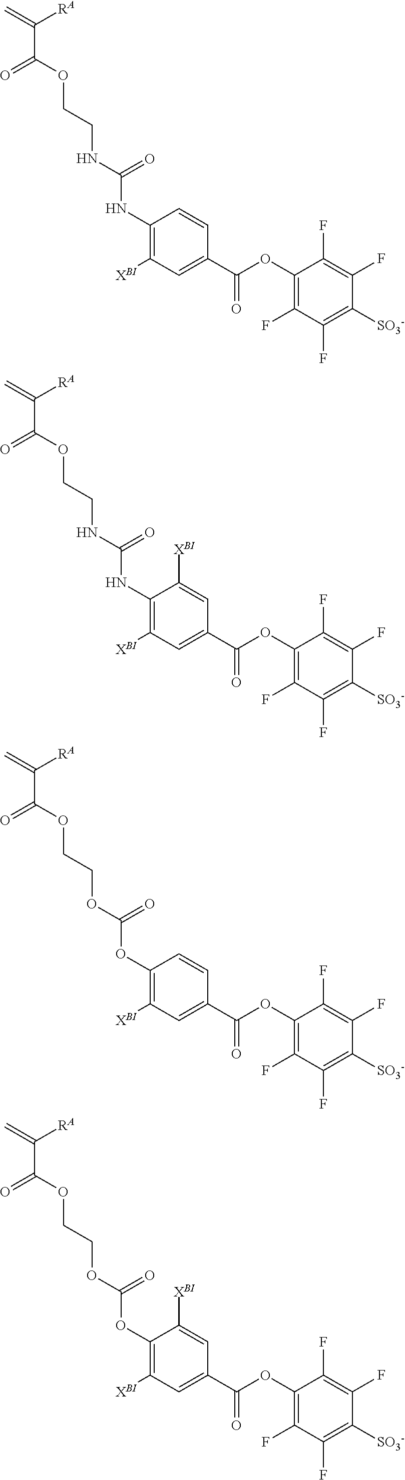

Repeat units (d1) to (d5) have the function of acid generator. The binding of an acid generator to the polymer backbone is effective in restraining acid diffusion, thereby preventing a reduction of resolution due to blur by acid diffusion. Also, LWR and CDU are improved since the acid generator is uniformly distributed. When a base polymer comprising repeat units (d1) to (d5) is used, that is, in the case of polymer-bound acid generator, an acid generator of addition type (to be described later) may be omitted.

The base polymer may further comprise a repeat unit (e) containing iodine, but not amino group. Examples of the monomer from which repeat unit (e) is derived are shown below, but not limited thereto. Herein R^{A} is as defined above.

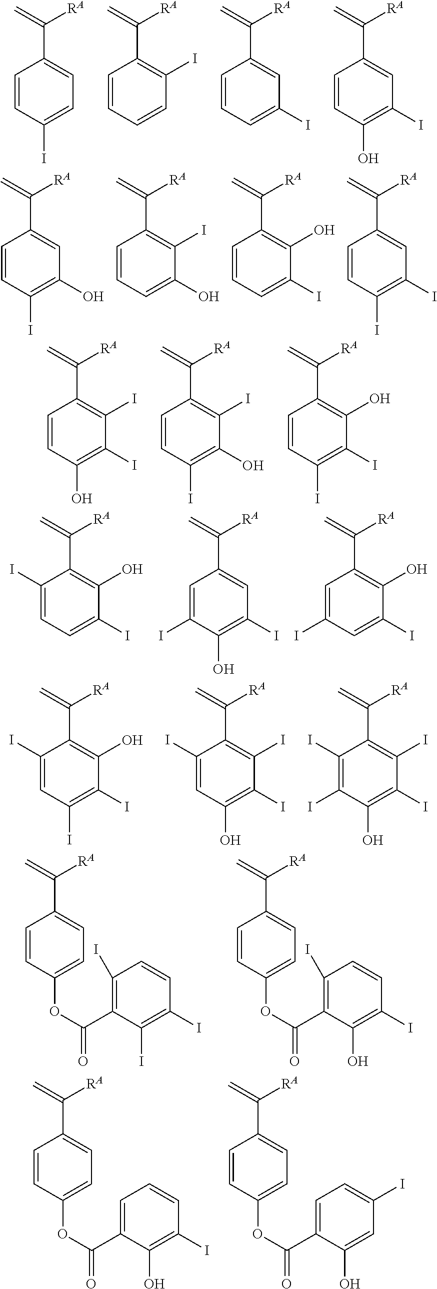

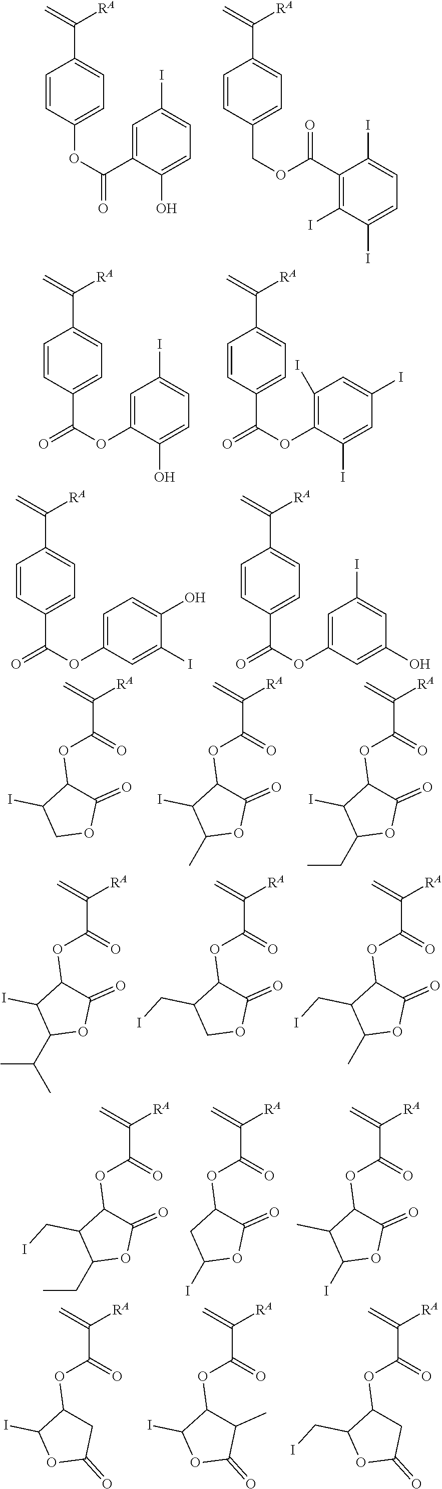

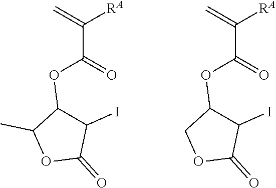

Besides the above-mentioned repeat units, the base polymer may further comprise a repeat unit (f) which is derived from styrene, vinylnaphthalene, indene, acenaphthylene, coumarin, and coumarone compounds.

In the base polymer comprising repeat units (a), (b1), (b2), (c), (d1), (d2), (d3), (d4), (d5), (e) and (f), a fraction of these units is:
preferably 0<a<1.0, 0≤b1≤0.9, 0≤b2≤0.9, 0≤b1+b2≤0.9, 0≤c≤0.9, 0≤d1≤0.5, 0≤d2≤0.5, 0≤d3≤0.5, 0≤d4≤0.5, 0≤d≤0.5, 0≤d1+d2+d3+d4+d≤0.5, 0≤e≤0.5, and 0≤f≤0.5;

more preferably 0.001≤a≤0.8, 0≤b≤0.8, 0≤b2≤0.8, 0≤b1+b2≤0.8, 0≤c≤0.8, 0≤d1≤0.4, 0≤d2≤0.4, 0≤d3≤0.4, 0≤d4≤0.4, 0≤d5≤0.4, 0≤d1+d2+d3+d4+d5≤0.4, 0≤e≤0.4, and 0≤f≤0.4; and
even more preferably 0.01≤a≤0.7, 0≤b1≤0.7, 0≤b2≤0.7, 0≤b1+b2≤0.7, 0≤c≤0.7, 0≤d1≤0.3, 0≤d2≤0.3, 0≤d3≤0.3, 0≤d4≤0.3, 0≤d5≤0.3, 0≤d1+d2+d3+d4+d5≤0.3, 0≤e≤0.3, and 0≤f≤0.3. Notably, a+b1+b2+c+d1+d2+d3+d4+d5+e+f=1.0.

The base polymer may be synthesized by any desired methods, for example, by dissolving monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, propylene glycol monomethyl ether, and y-butyrolactone. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the reaction temperature is 50 to 80° C., and the reaction time is 2 to 100 hours, more preferably 5 to 20 hours.

In the case of a monomer having a hydroxy group, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene. For alkaline hydrolysis, a base such as aqueous ammonia or triethylamine may be used. Preferably the reaction temperature is −20° C. to 100° C., more preferably 0° C. to 60° C., and the reaction time is 0.2 to 100 hours, more preferably 0.5 to 20 hours.

The base polymer should preferably have a weight average molecular weight (Mw) in the range of 1,000 to 500,000, and more preferably 2,000 to 30,000, as measured by GPC versus polystyrene standards using tetrahydrofuran (THF) solvent. A Mw in the range ensures that a resist film has heat resistance and a high solubility in alkaline developer.

If a base polymer has a wide molecular weight distribution or dispersity (Mw/Mn), which indicates the presence of lower and higher molecular weight polymer fractions, there is a possibility that foreign matter is left on the pattern or the pattern profile is degraded. The influences of Mw and Mw/Mn become stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

For forming a narrow dispersity polymer, not only ordinary radical polymerization, but living radical polymerization may also be employed. Suitable living radical polymerization processes include radical polymerization using nitroxide radicals, i.e., nitroxide-mediated radical polymerization (NMP), atom transfer radical polymerization (ATRP), and reversible addition-fragmentation chain transfer (RAFT) polymerization.

The base polymer may be a blend of two or more polymers which differ in compositional ratio, Mw or Mw/Mn. It may also be a blend of a polymer comprising repeat units (a) and a polymer comprising repeat units (b1) and/or (b2), but not repeat units (a).

### [Acid Generator]

The positive resist composition may contain an acid generator capable of generating a strong acid, also referred to as acid generator of addition type. As used herein, the “strong acid” is a compound having a sufficient acidity to induce deprotection reaction of acid labile groups on the base polymer.

The acid generator is typically a compound (PAG) capable of generating an acid upon exposure to actinic ray or radiation. Although the PAG used herein may be any compound capable of generating an acid upon exposure to high-energy radiation, those compounds capable of generating sulfonic acid, imidic acid (imide acid) or methide acid are preferred. Suitable PAGs include sulfonium salts, iodonium salts, sulfonyldiazomethane, N-sulfonyloxyimide, and oxime-O-sulfonate acid generators. Suitable PAGs are as exemplified in U.S. Pat. No. 7,537,880 (JP-A 2008-111103, paragraphs [0122]-[0142]).

As the PAG used herein, sulfonium salts having the formula (1-1) and iodonium salts having the formula (1-2) are also preferred.

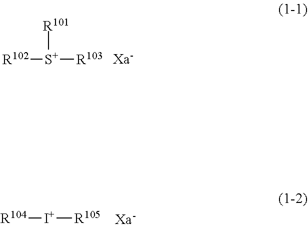

In formulae (1-1) and (1-2), R¹⁰¹ to R¹⁰⁵ are each independently halogen or a C₁-C₂₀ hydrocarbyl group which may contain a heteroatom. Suitable halogen atoms include fluorine, chlorine, bromine and iodine. The hydrocarbyl group may be saturated or unsaturated and straight, branched or cyclic. Examples thereof are as exemplified above for the hydrocarbyl groups R² to R⁴ in formula (a). In the hydrocarbyl group, some or all hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride, or haloalkyl moiety. R¹⁰¹ and R¹⁰² may bond together to form a ring with the sulfur atom to which they are attached. Examples of the ring are as exemplified above for the ring that R² and R³ in formula (a), taken together, form with the sulfur atom to which they are attached.

Examples of the cation in the sulfonium salt having formula (1-1) are as exemplified above for the cation in repeat units (a).

Examples of the cation in the iodonium salt having formula (1-2) are shown below, but not limited thereto.

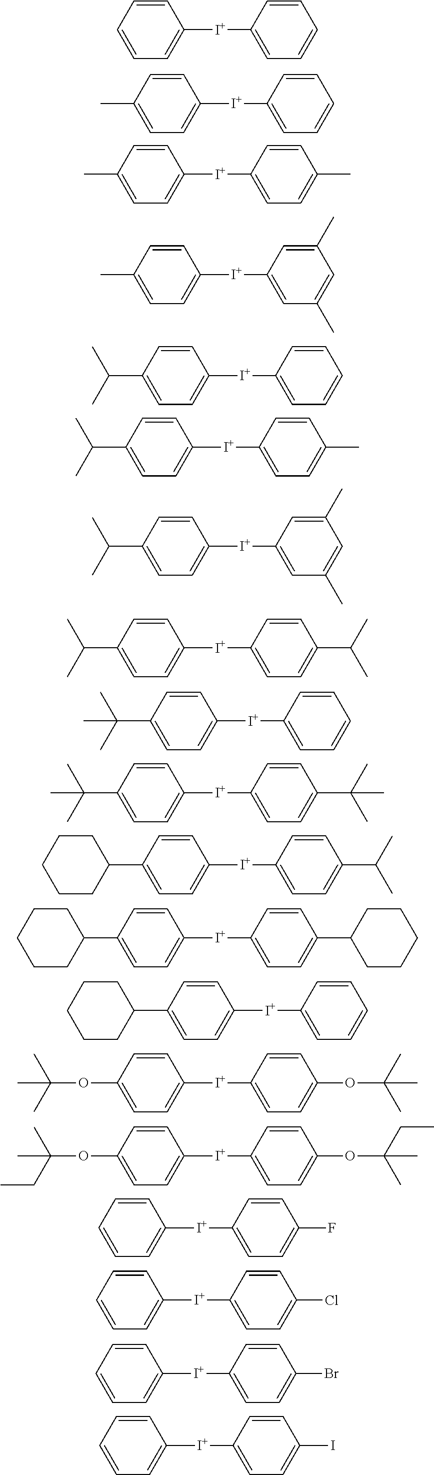

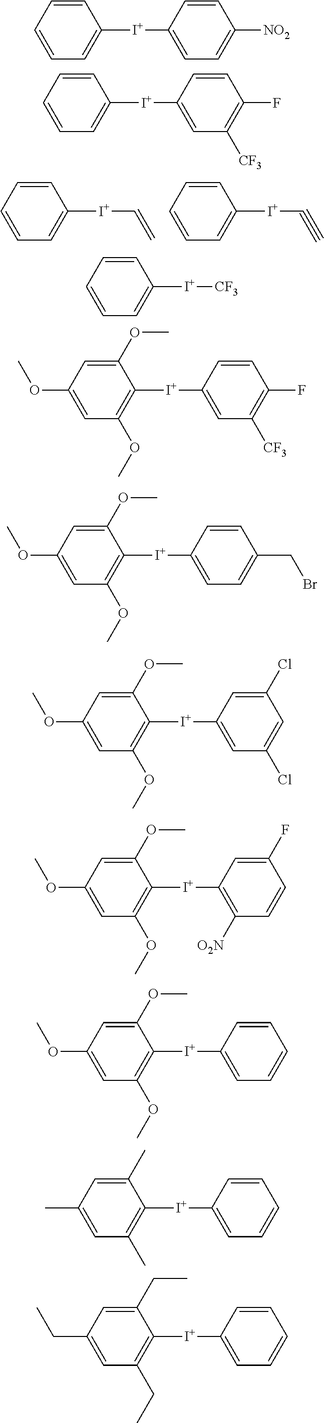

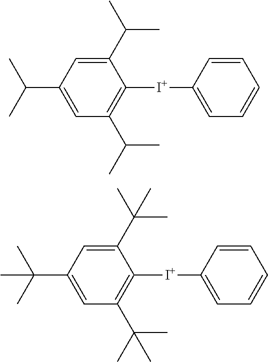 [SMILES: CC(C)c1cc(C(C)C)c([I+]c2ccccc2)c(C(C)C)c1 ; CC(C)(C)c1cc(C(C)(C)C)c([I+]c2ccccc2)c(C(C)(C)C)c1]

In formulae (1-1) and (1-2), Xa⁻ is an anion selected from the following formulae (1A) to (1D).

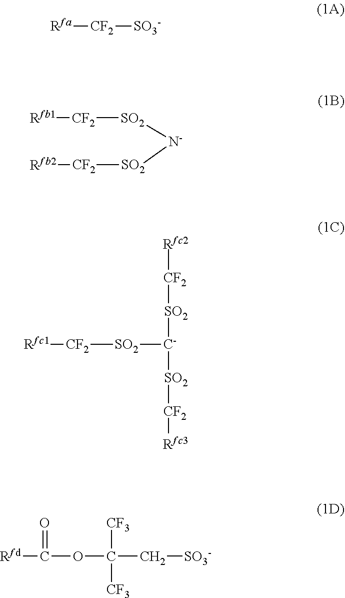

In formula (1A), R^{fa} is fluorine or a C₁-C₄₀ hydrocarbyl group which may contain a heteroatom. The hydrocarbyl group may be saturated or unsaturated and straight, branched or cyclic. Examples thereof are as will be exemplified later for the hydrocarbyl group R^{fa} in formula (1A′).

Of the anions having formula (1A), an anion having the formula (1A′) is preferred.

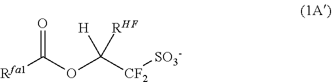

In formula (1A′), R^{HF} is hydrogen or trifluoromethyl, preferably trifluoromethyl.

R^{fa1} is a C₁-C₃₈ hydrocarbyl group which may contain a heteroatom. As the heteroatom, oxygen, nitrogen, sulfur and halogen atoms are preferred, with oxygen being most preferred. Of the hydrocarbyl groups represented by R^{fa1}, those groups of 6 to 30 carbon atoms are preferred from the aspect of achieving a high resolution in forming patterns of fine feature size. The hydrocarbyl group may be saturated or unsaturated and straight, branched or cyclic. Examples thereof include C₁-C₃₈ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl, and icosyl; C₃-C₃₈ cyclic saturated hydrocarbyl groups such as cyclopentyl, cyclohexyl, 1-adamantyl, 2-adamantyl, 1-adamantylmethyl, norbornyl, norbornylmethyl, tricyclodecanyl, tetracyclododecanyl, tetracyclododecanylmethyl, and dicyclohexylmethyl; C₂-C₃₈ unsaturated aliphatic hydrocarbyl groups such as allyl and 3-cyclohexenyl; C₆-C₃₈ aryl groups such as phenyl, 1-naphthyl and 2-naphthyl; C₇-C₃₈ aralkyl groups such as benzyl and diphenylmethyl; and combinations thereof.

In the foregoing hydrocarbyl groups, some or all hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—), or haloalkyl moiety. Examples of the heteroatom-containing hydrocarbyl group include tetrahydrofuryl, methoxymethyl, ethoxymethyl, methylthiomethyl, acetamidemethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

With respect to the synthesis of the sulfonium salt having an anion of formula (1A′), reference may be made to JP-A 2007-145797, JP-A 2008-106045, JP-A 2009-007327, and JP-A 2009-258695. Also useful are the sulfonium salts described in JP-A 2010-215608, JP-A 2012-041320, JP-A 2012-106986, and JP-A 2012-153644.

Examples of the anion having formula (1A) include those exemplified as the anion having formula (1A) in JP-A 2018-197853.

In formula (1B), R^{fb1} and R^{fb2} are each independently fluorine or a C₁-C₄₀ hydrocarbyl group which may contain a heteroatom. The hydrocarbyl group may be saturated or unsaturated and straight, branched or cyclic, and examples thereof are as exemplified above for R^{fa1} in formula (1A′). Preferably R^{fb1} and R^{fb2} are fluorine or C₁-C₄ straight fluorinated alkyl groups. Also, R^{fb1} and R^{fb2} may bond together to form a ring with the linkage: —CF₂—SO₂—N—SO₂—CF₂— to which they are attached. It is preferred that a combination of R^{fb1} and R^{fb2} be a fluorinated ethylene or fluorinated propylene group.

In formula (1C), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic, and examples thereof are as exemplified above for R^{fa1} in formula (1A′). Preferably R^{fc1}, R^{fc2} and R^{fc3} are fluorine or C₁-C₄ straight fluorinated alkyl groups. Also, R^{fc1} and R^{fc2} may bond together to form a ring with the linkage: —CF₂—SO₂—C—SO₂—CF₂— to which they are attached. It is preferred that a combination of R^{fc1} and R^{fc2} be a fluorinated ethylene or fluorinated propylene group.

In formula (1D), R^{fd} is a C₁-C₄₀ hydrocarbyl group which may contain a heteroatom. The hydrocarbyl group may be saturated or unsaturated and straight, branched or cyclic, and examples thereof are as exemplified above for R^{fa1} in formula (1A′).

With respect to the synthesis of the sulfonium salt having an anion of formula (1D), reference may be made to JP-A 2010-215608 and JP-A 2014-133723.

Examples of the anion having formula (1D) include those exemplified as the anion having formula (1D) in U.S. Pat. No. 11,022,883 (JP-A 2018-197853).

Notably, the compound having the anion of formula (1D) does not have fluorine at the α-position relative to the sulfo group, but two trifluoromethyl groups at the P-position. For this reason, it has a sufficient acidity to sever the acid labile groups in the base polymer. Thus the compound is an effective PAG.

Another preferred PAG is a compound having the formula (2).

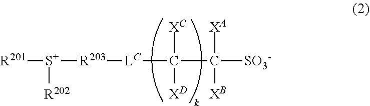

In formula (2), R²⁰¹ and R²⁰² are each independently halogen or a C₁-C₃₀ hydrocarbyl group which may contain a heteroatom. R²⁰³ is a C₁-C₃₀ hydrocarbylene group which may contain a heteroatom. Any two of R²⁰¹, R²⁰² and R²⁰³ may bond together to form a ring with the sulfur atom to which they are attached. Examples of the ring are as exemplified above for the ring that R² and R³ in formula (a), taken together, form with the sulfur atom to which they are attached.

The hydrocarbyl groups R²⁰¹ and R²⁰² may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, and adamantyl; C₆-C₃₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, tert-butylnaphthyl, and anthracenyl; and combinations thereof. In the foregoing hydrocarbyl groups, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety.

The hydrocarbylene group R²⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl and adamantanediyl; C₆-C₃₀ arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene; and combinations thereof. In the hydrocarbylene group, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety. Of the heteroatoms, oxygen is preferred.

In formula (2), L^{C} is a single bond, ether bond or a C₁-C₂₀ hydrocarbylene group which may contain a heteroatom. The hydrocarbylene group may be saturated or unsaturated and straight, branched or cyclic. Examples thereof are as exemplified above for R²⁰³.

In formula (2), X^{A}, X^{B}, X^{C} and X^{D} are each independently hydrogen, fluorine or trifluoromethyl. At least one of X^{A}, X^{B}, X^{C} and X^{D} is fluorine or trifluoromethyl.

In formula (2), k is an integer of 0 to 3.

Of the PAGs having formula (2), those having formula (2′) are preferred.

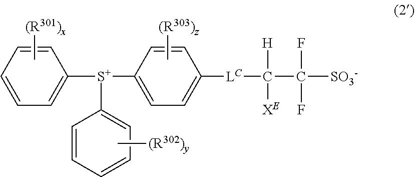

In formula (2′), L^{C} is as defined above. R^{HF} is hydrogen or trifluoromethyl, preferably trifluoromethyl. R³⁰¹, R³⁰² and R³⁰³ are each independently hydrogen or a C₁-C₂₀ hydrocarbyl group which may contain a heteroatom. The hydrocarbyl group may be saturated or unsaturated and straight, branched or cyclic. Examples thereof are as exemplified above for R^{fa1} in formula (1A′). The subscripts x and y are each independently an integer of 0 to 5, and z is an integer of 0 to 4.

Examples of the PAG having formula (2) are as exemplified as the PAG having formula (2) in U.S. Pat. No. 9,720,324 (JP-A 2017-026980).

Of the foregoing PAGs, those having an anion of formula (1A′) or (1D) are especially preferred because of reduced acid diffusion and high solubility in the solvent. Also those having formula (2′) are especially preferred because of extremely reduced acid diffusion.

A sulfonium or iodonium salt having an iodized or brominated aromatic ring-containing anion may also be used as the PAG. Suitable are sulfonium and iodonium salts having the formulae (3-1) and (3-2).

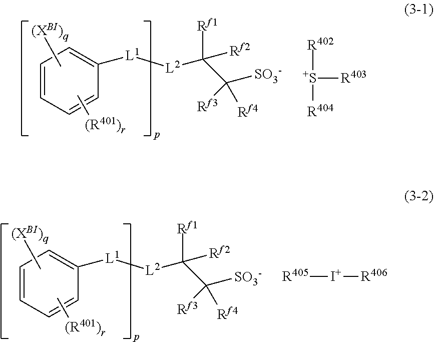

In formulae (3-1) and (3-2), p is an integer of 1 to 3, q is an integer of 1 to 5, r is an integer of 0 to 3, and 1≤q+r 5. Preferably, q is an integer of 1 to 3, more preferably 2 or 3, and r is an integer of 0 to 2.

X^{BI} is iodine or bromine, and may be the same or different when p and/or q is 2 or more.

L¹ is a single bond, ether bond, ester bond, or a C₁-C₆ saturated hydrocarbylene group which may contain an ether bond or ester bond. The saturated hydrocarbylene group may be straight, branched or cyclic.

L² is a single bond or a C₁-C₂₀ divalent linking group when p=1, or a C₁-C₂₀ (p+1)-valent linking group when p=2 or 3. The linking group may contain an oxygen, sulfur or nitrogen atom.

R⁴⁰¹ is a hydroxy group, carboxy group, fluorine, chlorine, bromine, amino group, or a C₁-C₂₀ hydrocarbyl, C₁-C₂₀ hydrocarbyloxy, C₂-C₂₀ hydrocarbylcarbonyl, C₂-C₂₀ hydrocarbyloxycarbonyl, C₂-C₂₀ hydrocarbylcarbonyloxy or C₁-C₂₀ hydrocarbylsulfonyloxy group, which may contain fluorine, chlorine, bromine, hydroxy, amino or ether bond, or —N(R^{401A})(R^{401B}), —N(R^{401C})—C(═O)—R^{401D} or —N(R^{401C})—C(═O)—O—R^{401D}. R^{401A} and R^{401B} are each independently hydrogen or a C₁-C₆ saturated hydrocarbyl group. R^{401C} is hydrogen or a C₁-C₆ saturated hydrocarbyl group which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. R^{401D} is a C₁-C₁₆ aliphatic hydrocarbyl, C₆-C₁₄ aryl or C₇-C₁₅ aralkyl group, which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarbylsulfonyloxy groups may be straight, branched or cyclic. A plurality of R⁴⁰¹ may be the same or different when p and/or r is 2 or more.

Of these, R⁴⁰¹ is preferably hydroxy, —N(R^{401C})—C(═O)—R^{401D}, —N(R^{401C})—C(═O)—O—R^{401D}, fluorine, chlorine, bromine, methyl or methoxy.

In formulae (3-1) and (3-2), Rf¹ to Rf⁴ are each independently hydrogen, fluorine or trifluoromethyl, at least one of Rf¹ to Rf⁴ is fluorine or trifluoromethyl. Rf¹ and Rf², taken together, may form a carbonyl group. Preferably, both Rf³ and Rf⁴ are fluorine.

R⁴⁰² to R⁴⁰⁶ are each independently halogen or a C₁-C₂₀ hydrocarbyl group which may contain a heteroatom. Suitable halogen atoms include fluorine, chlorine, bromine and iodine. The hydrocarbyl group may be saturated or unsaturated and straight, branched or cyclic. Examples thereof are as exemplified above for the hydrocarbyl groups R² to R⁴ in formula (a). In the hydrocarbyl group, some or all of the hydrogen atoms may be substituted by hydroxy, carboxy, halogen, cyano, nitro, mercapto, sultone ring, sulfo, or sulfonium salt-containing moiety, and some constituent —CH₂— may be replaced by an ether bond, ester bond, carbonyl moiety, amide bond, carbonate bond or sulfonate ester bond. R⁴⁰² and R⁴⁰³ may bond together to form a ring with the sulfur atom to which they are attached. Exemplary rings are the same as described above for the ring that R² and R³ in formula (a), taken together, form with the sulfur atom to which they are attached.

Examples of the cation in the sulfonium salt having formula (3-1) include those exemplified above as the cation in repeat unit (a). Examples of the cation in the iodonium salt having formula (3-2) include those exemplified above as the cation in the iodonium salt having formula (1-2).

Examples of the anion in the onium salts having formulae (3-1) and (3-2) are shown below, but not limited thereto. Herein X^{BI} is as defined above.

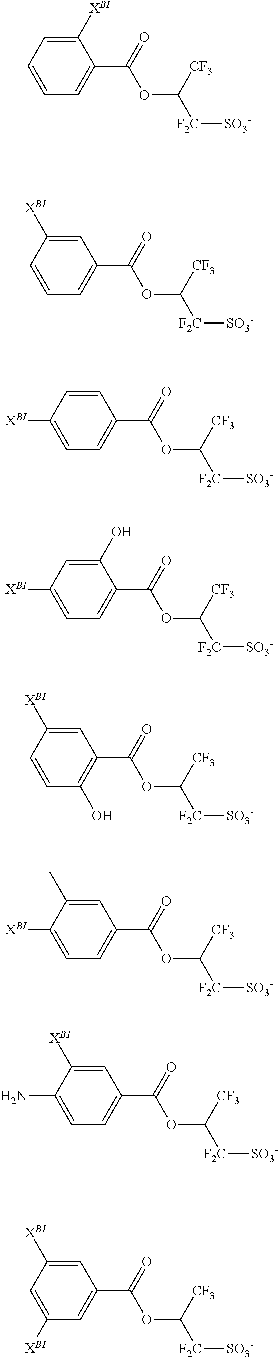

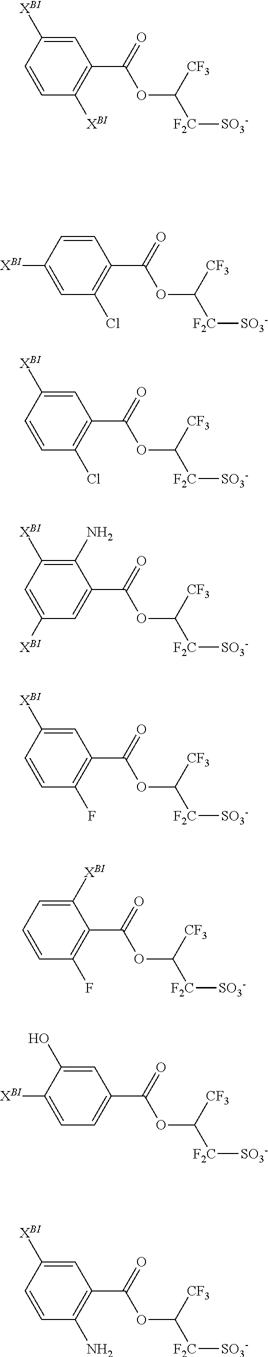

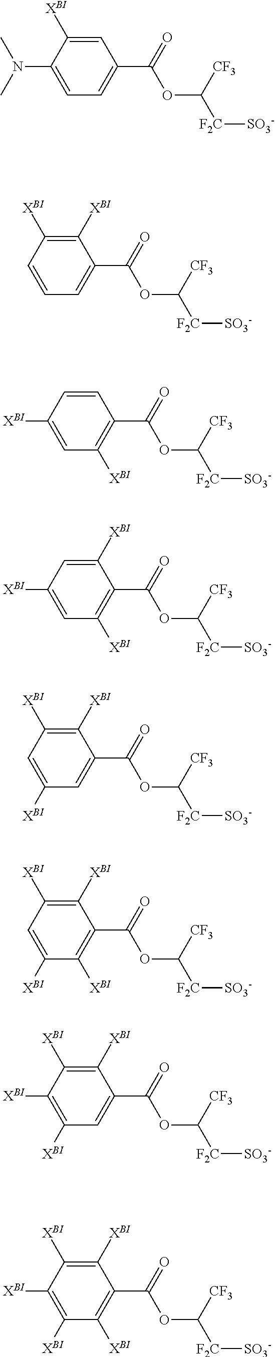

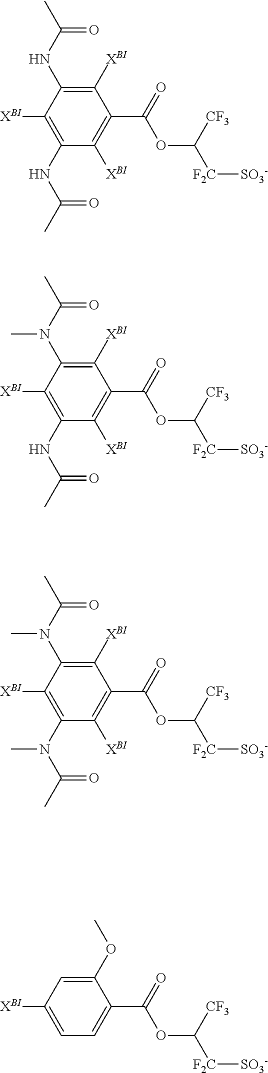

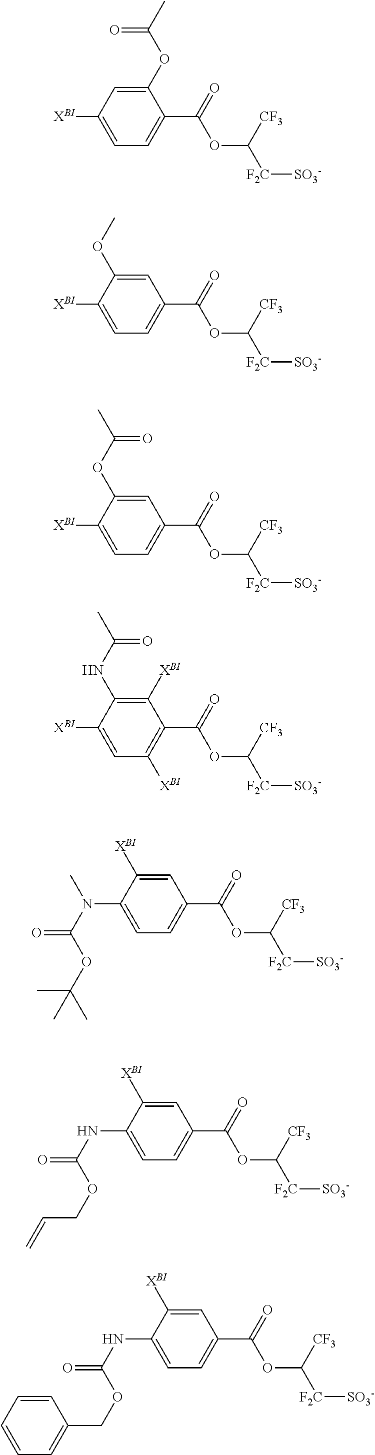

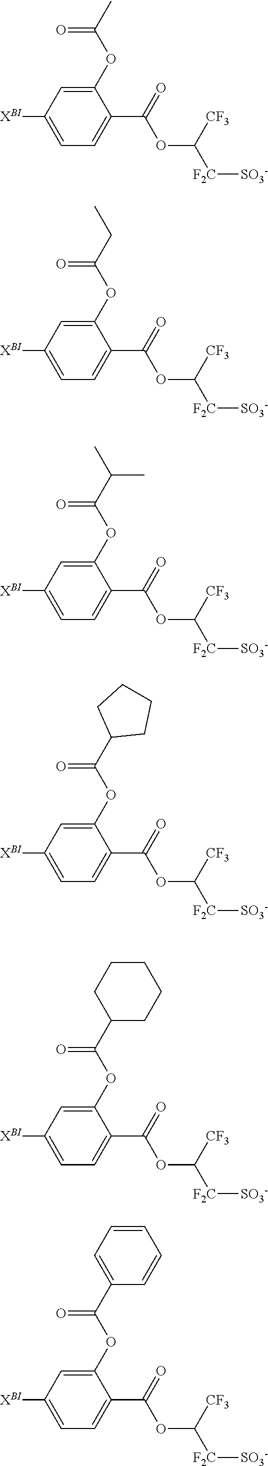

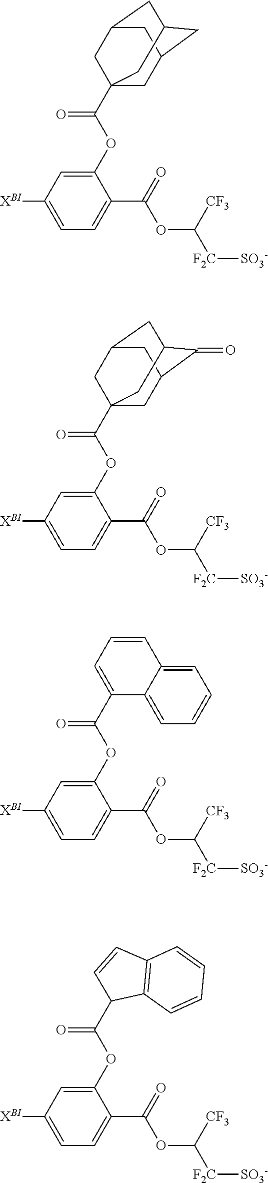

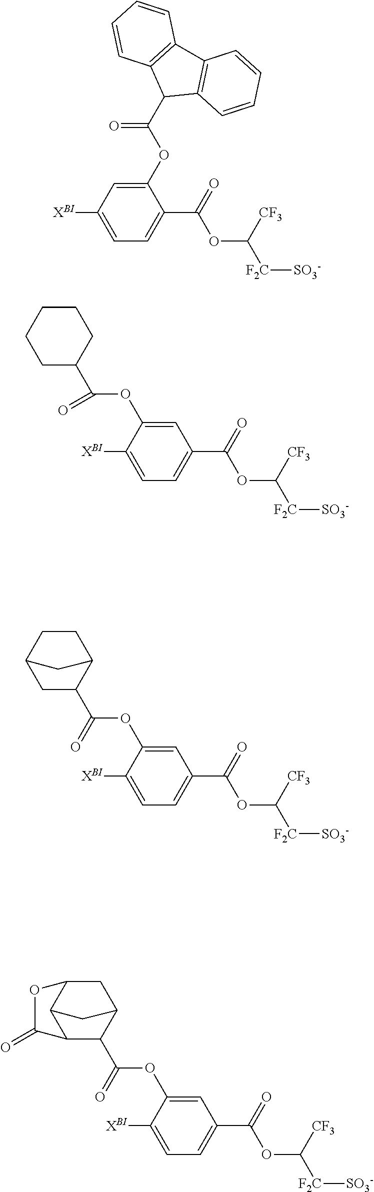

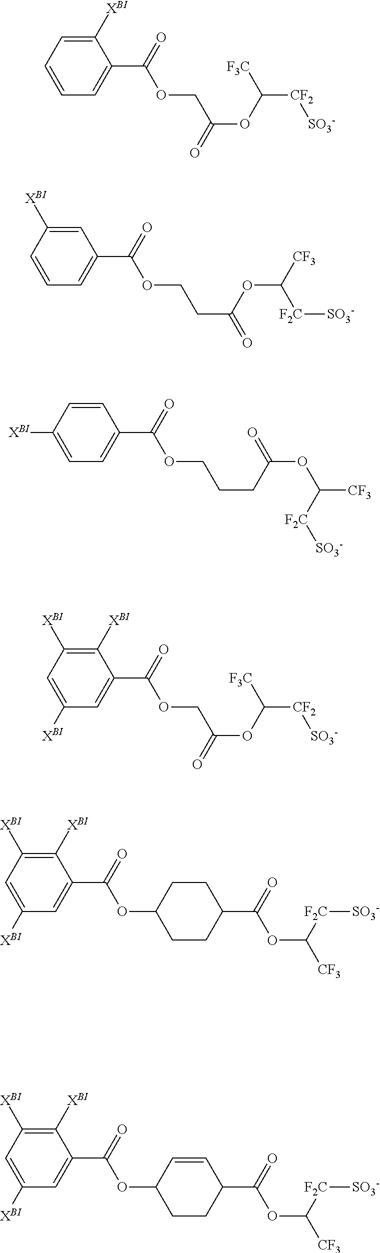

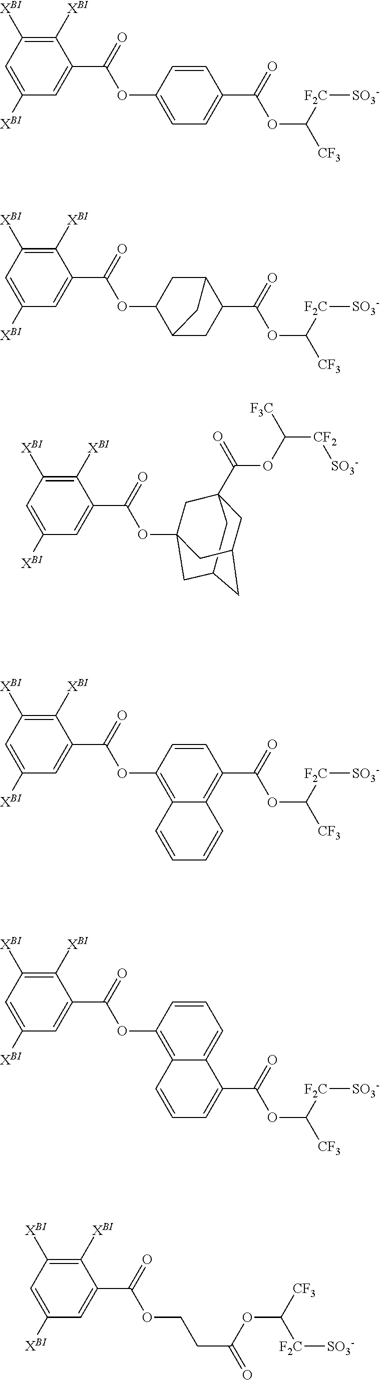

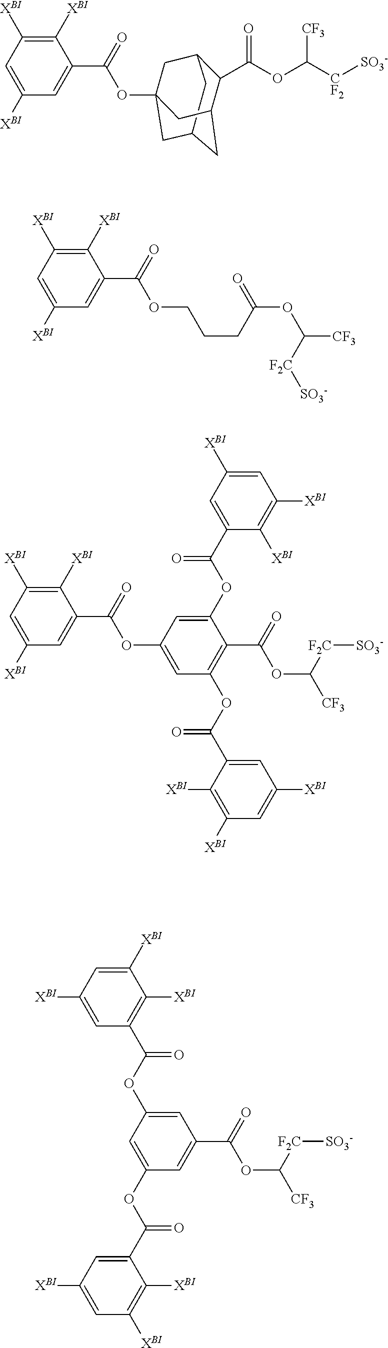

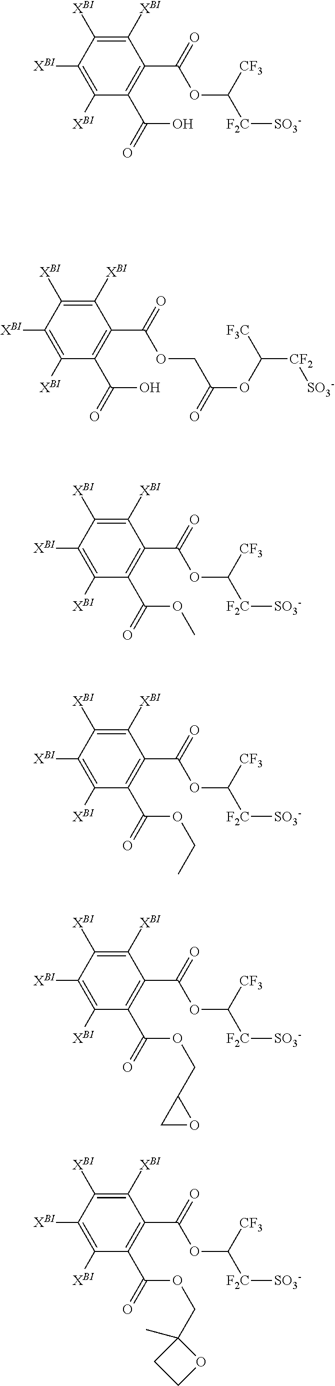

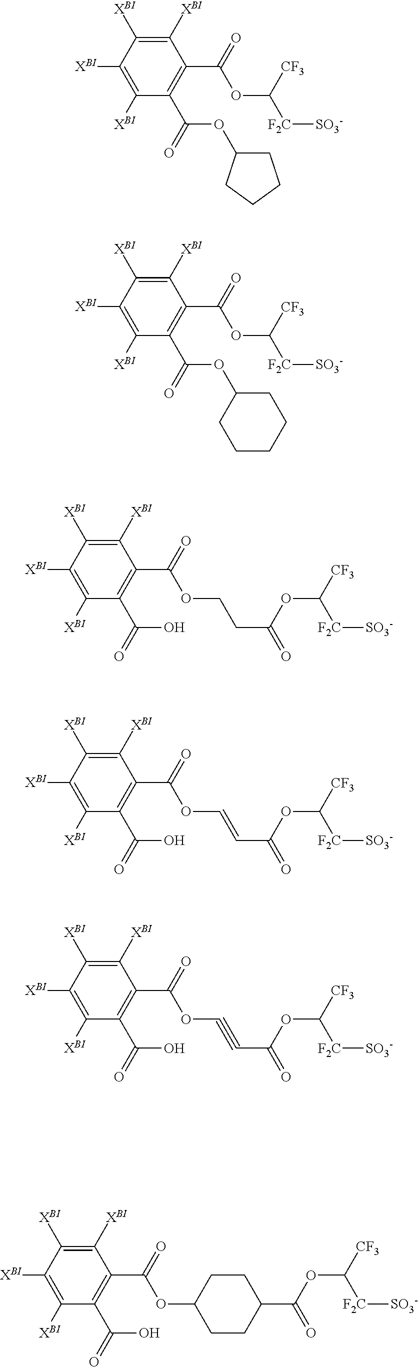

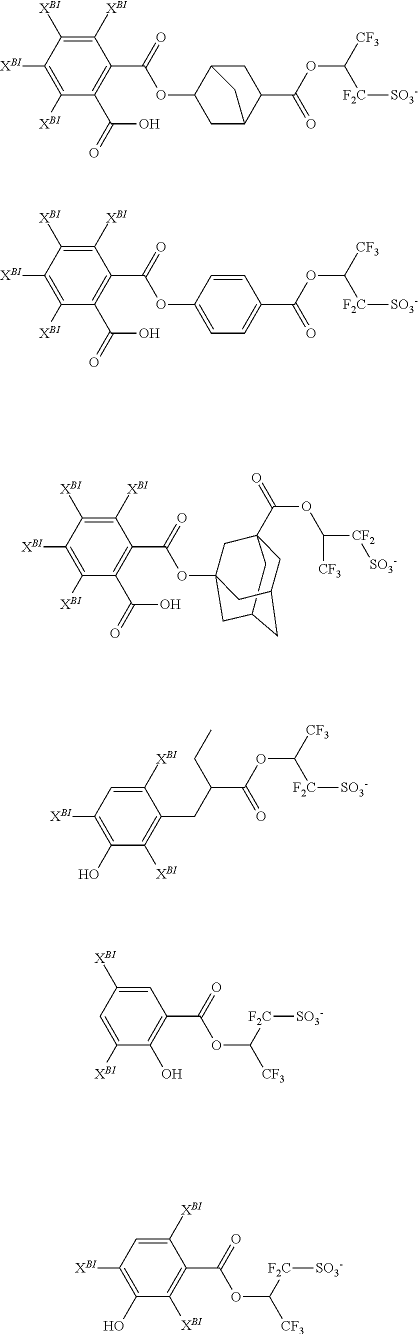

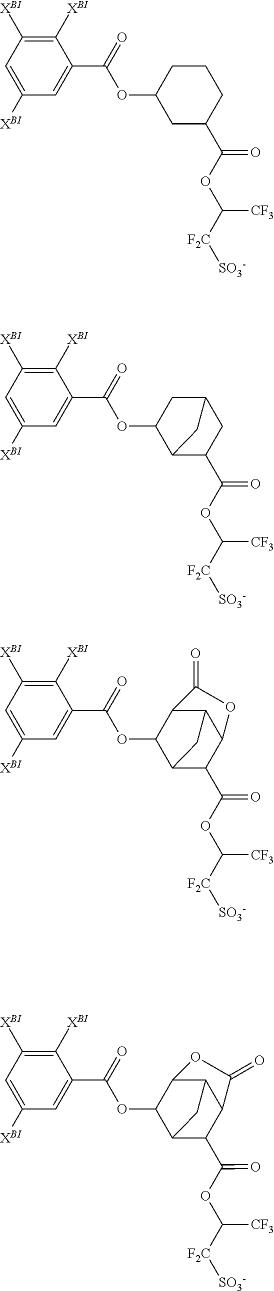

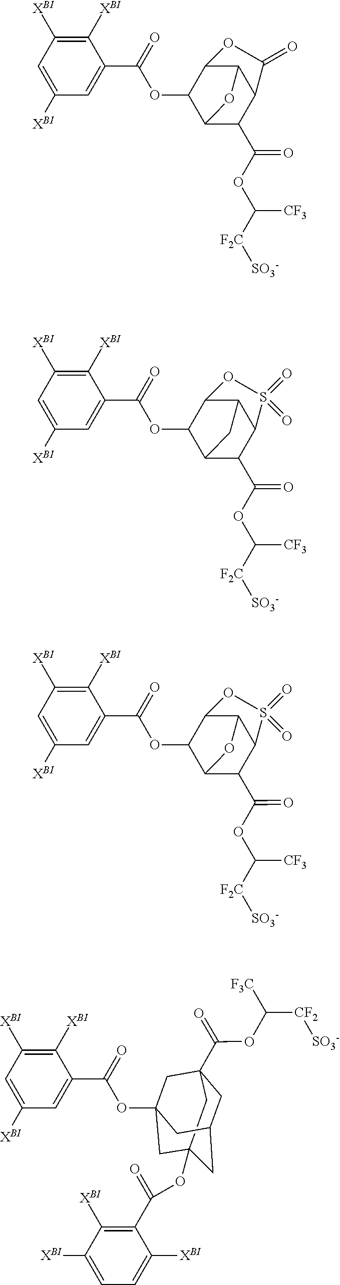

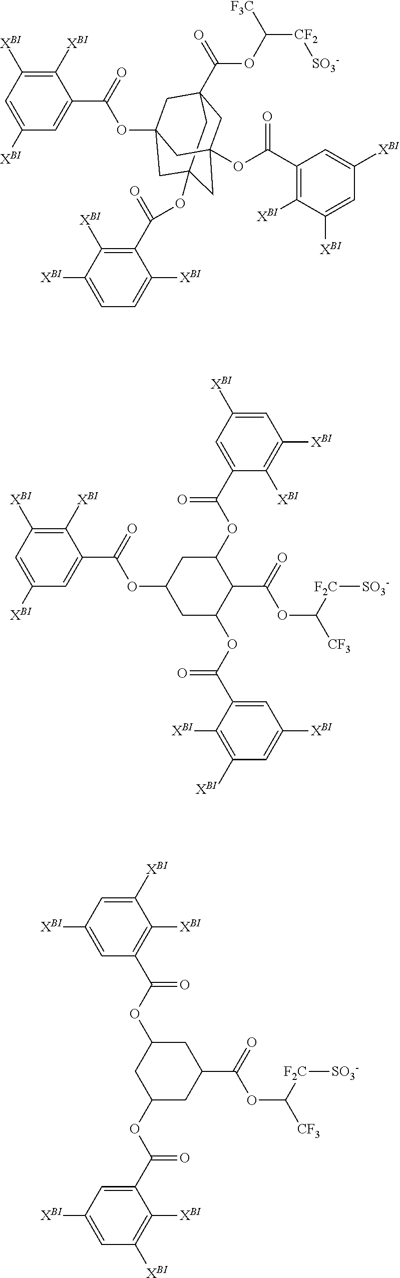

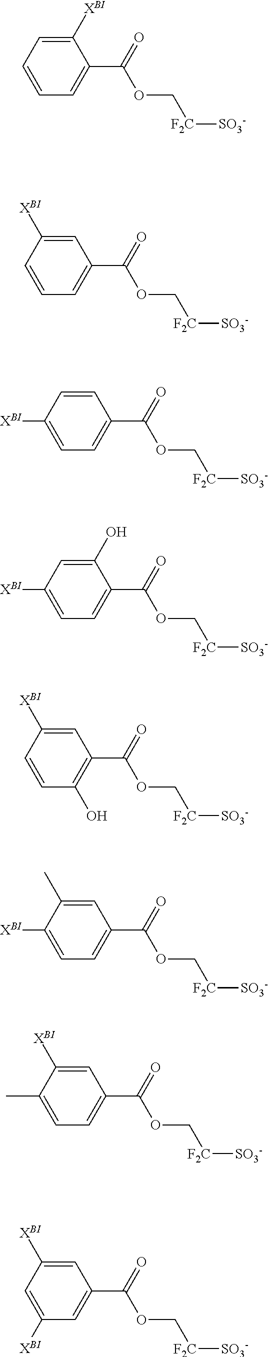

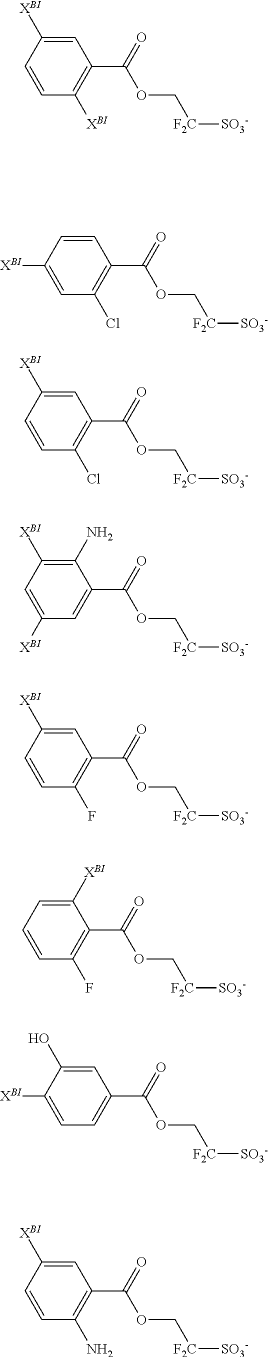

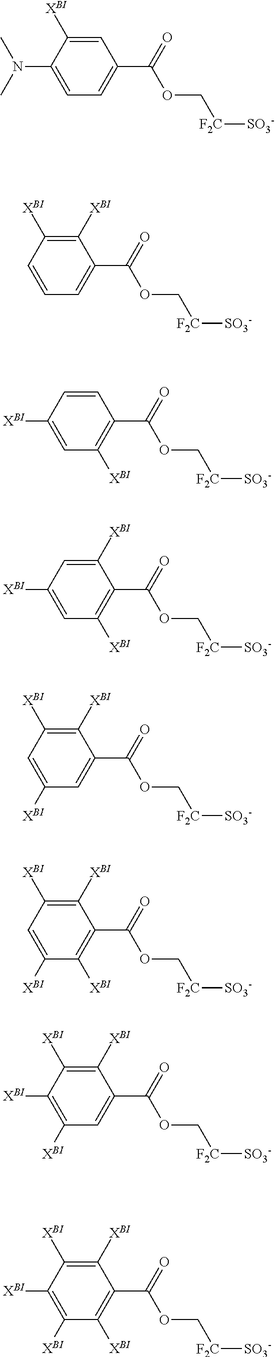

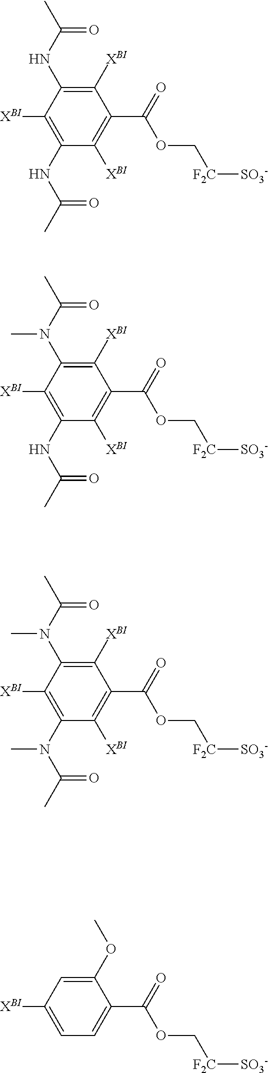

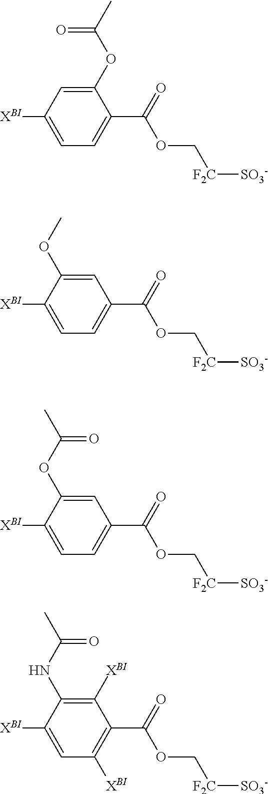

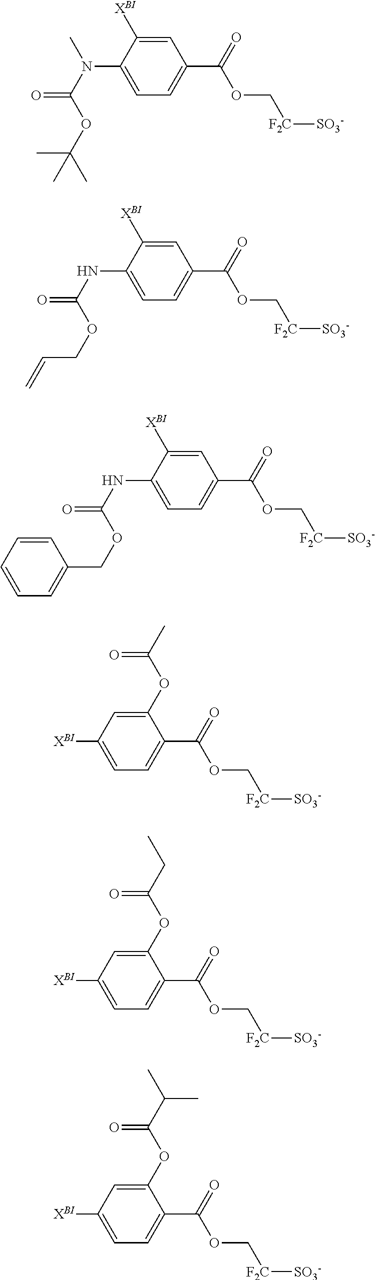

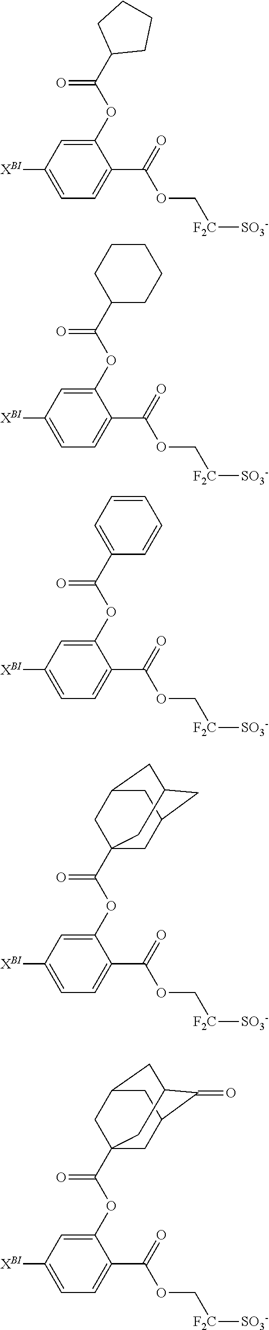

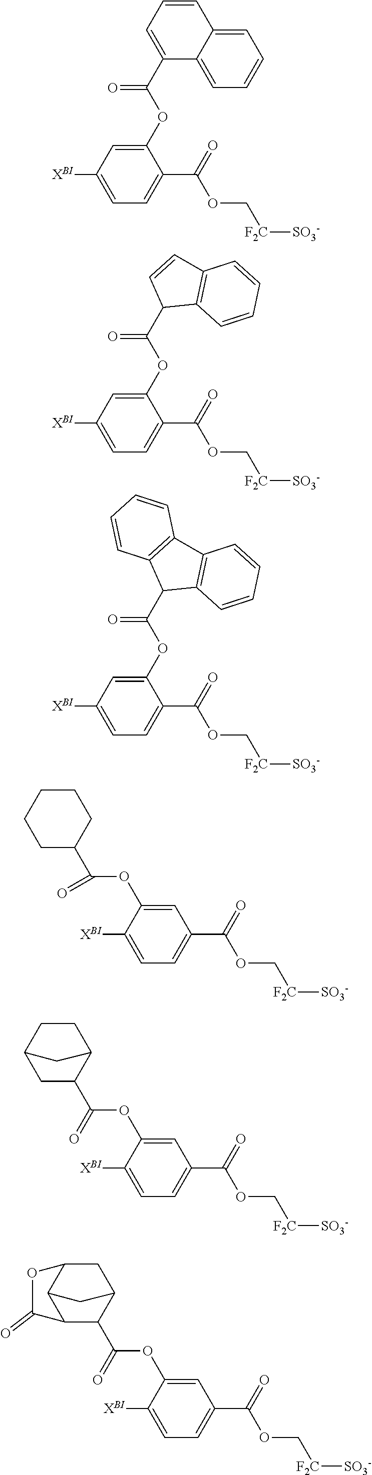

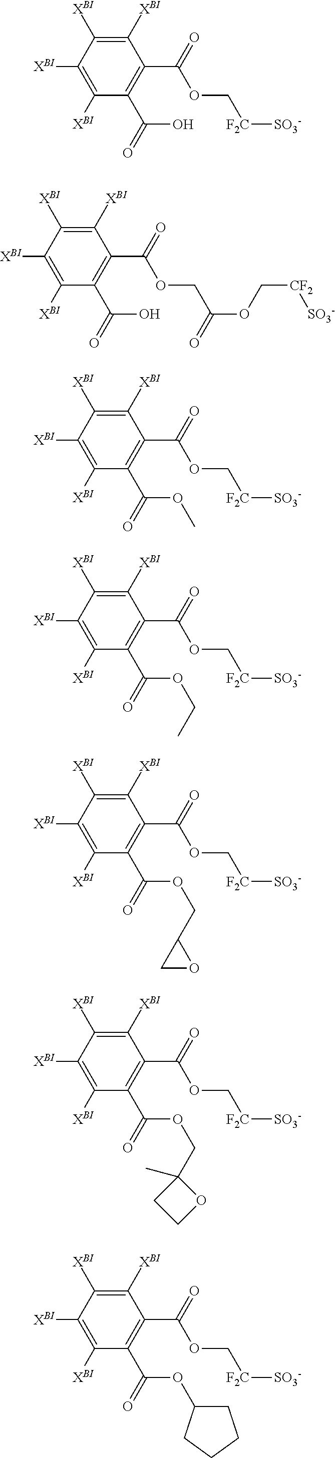

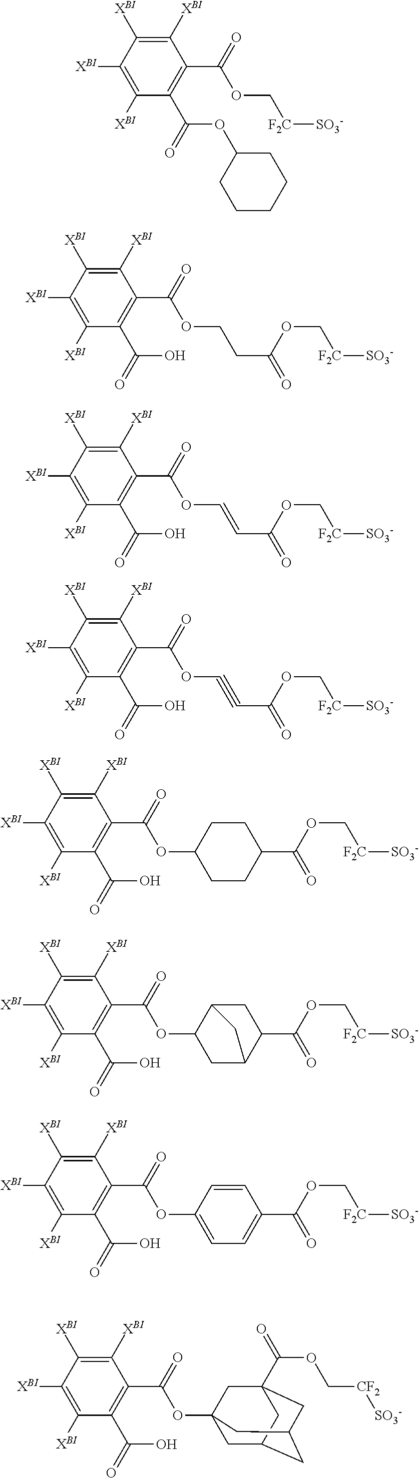

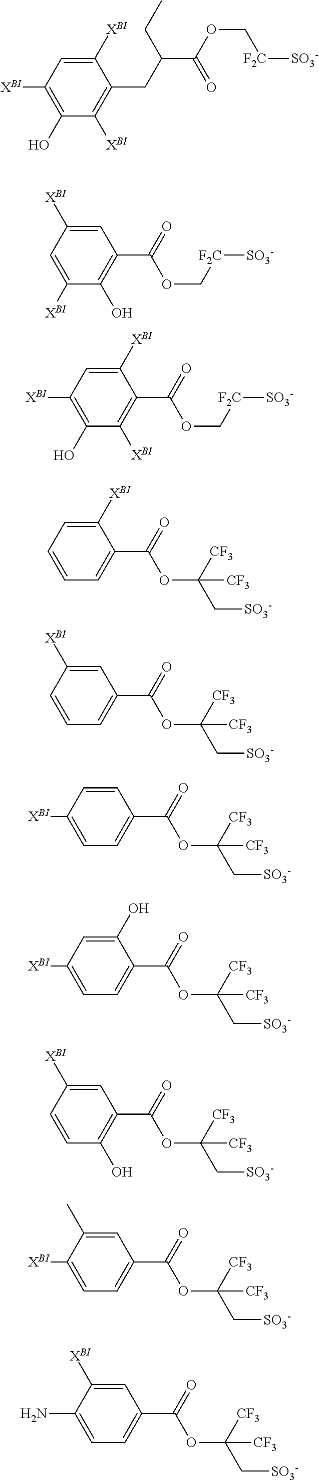

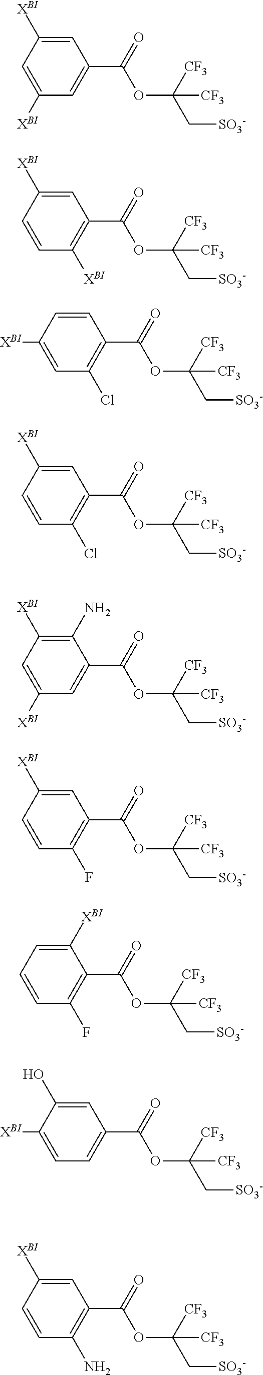

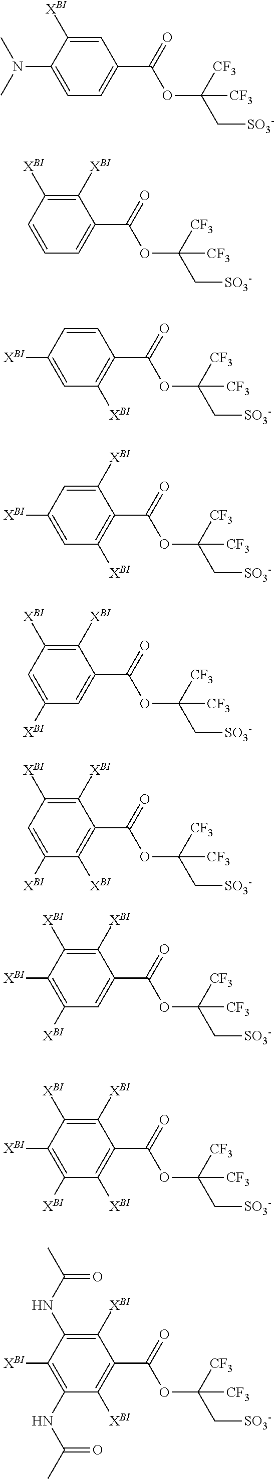

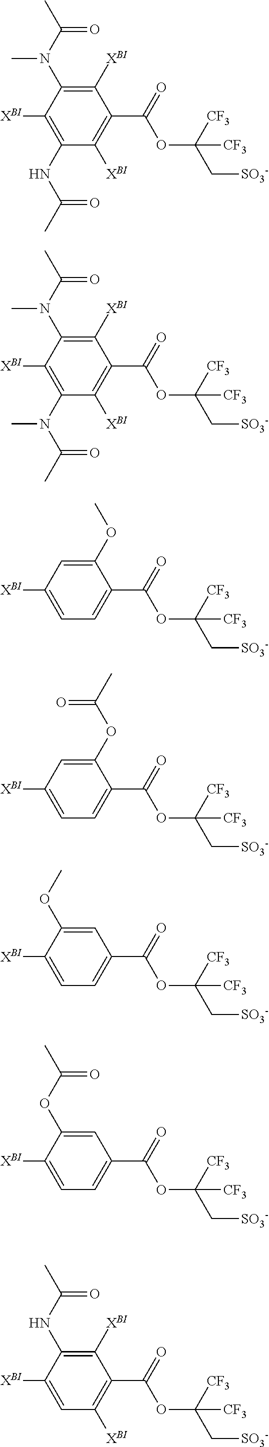

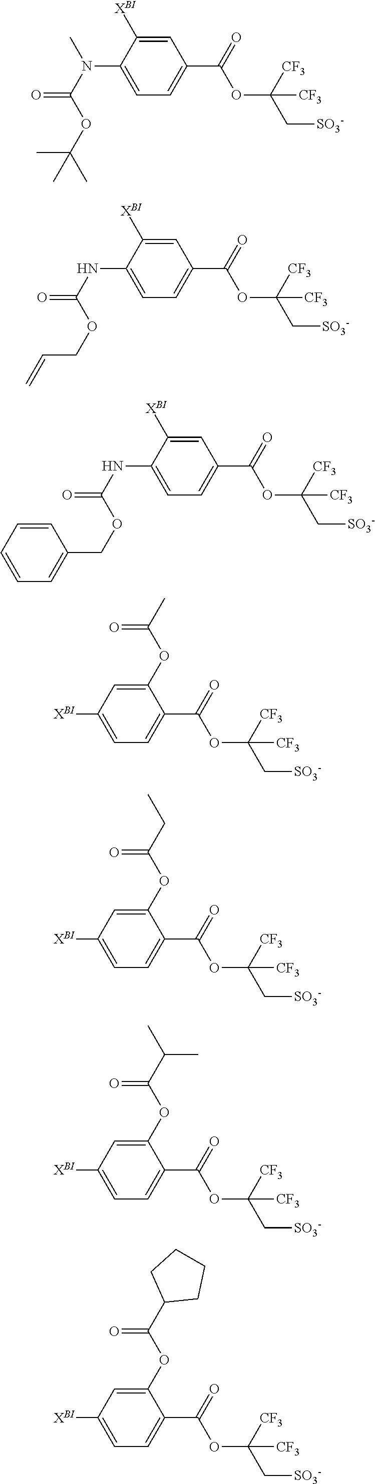

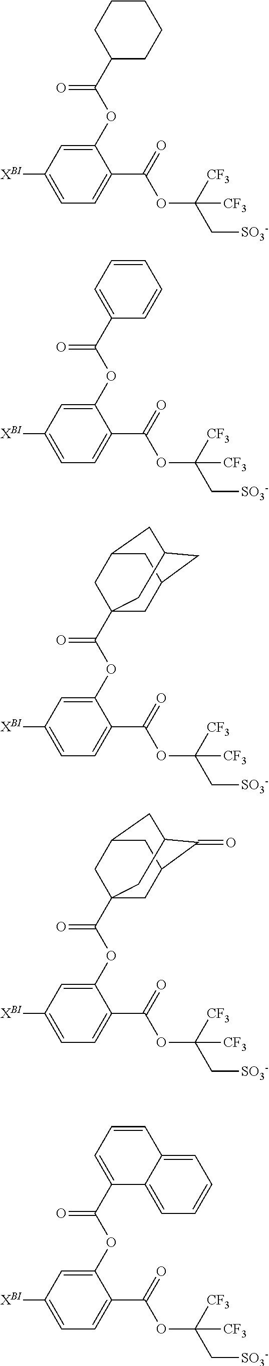

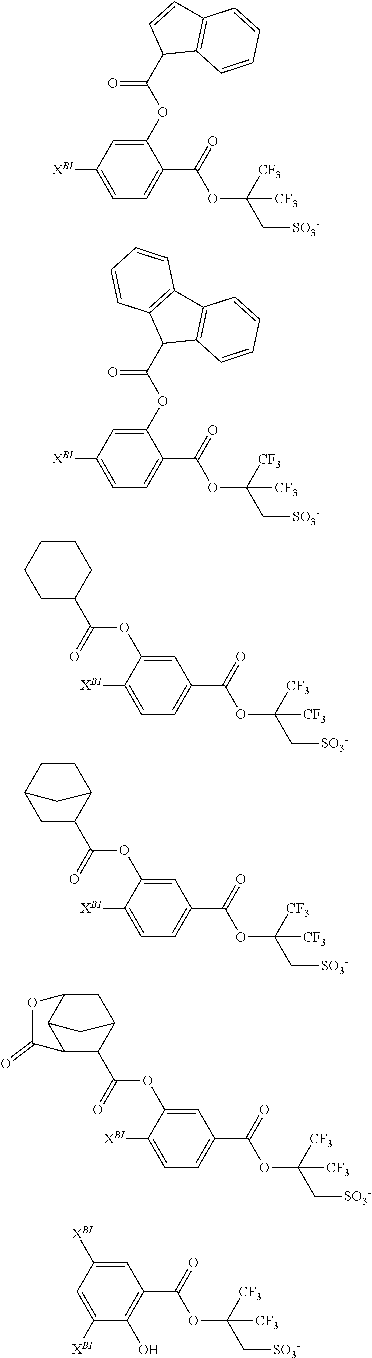

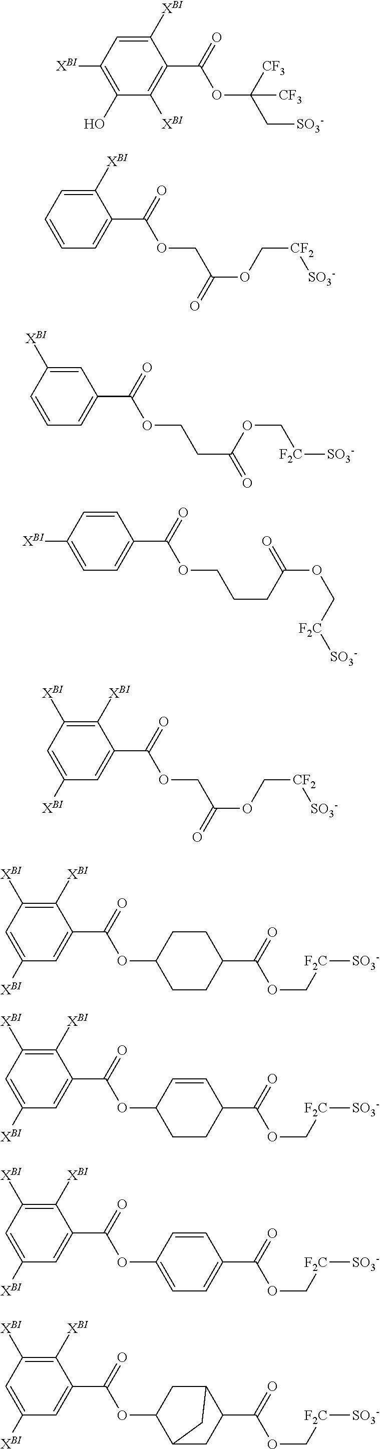

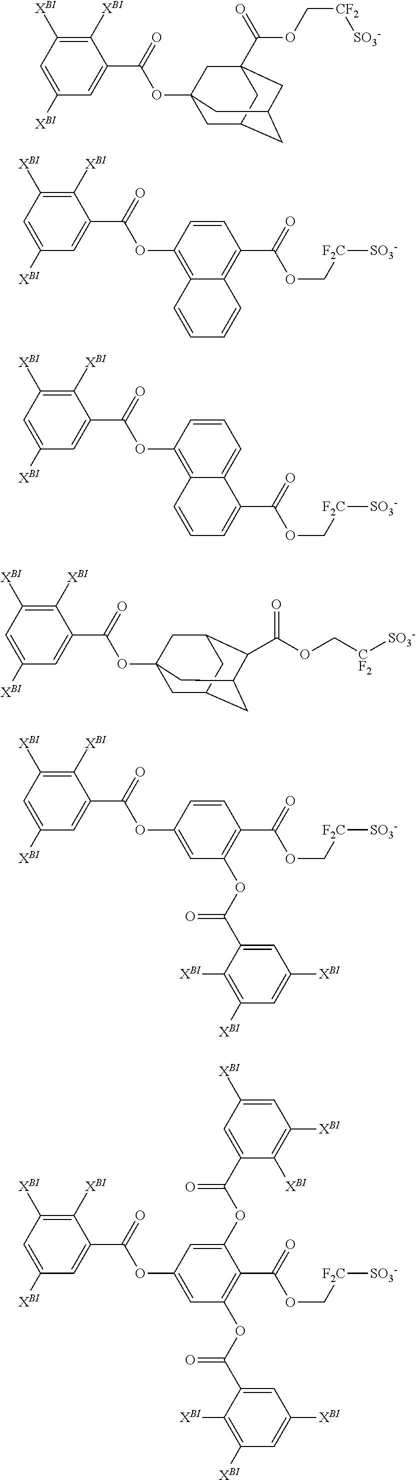

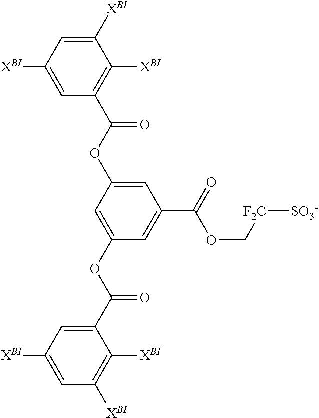

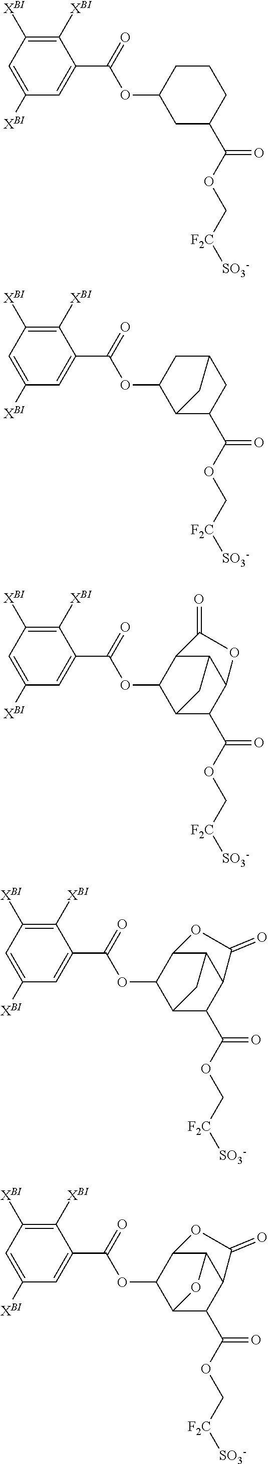

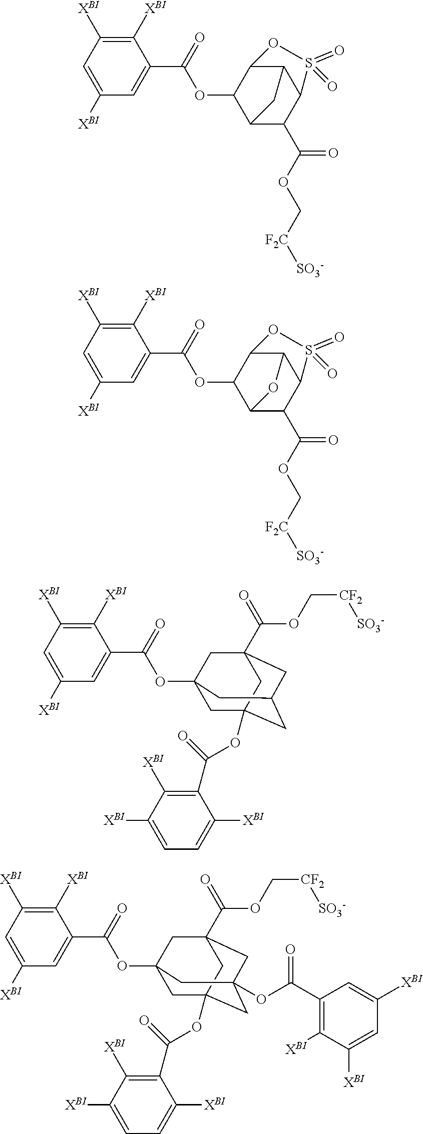

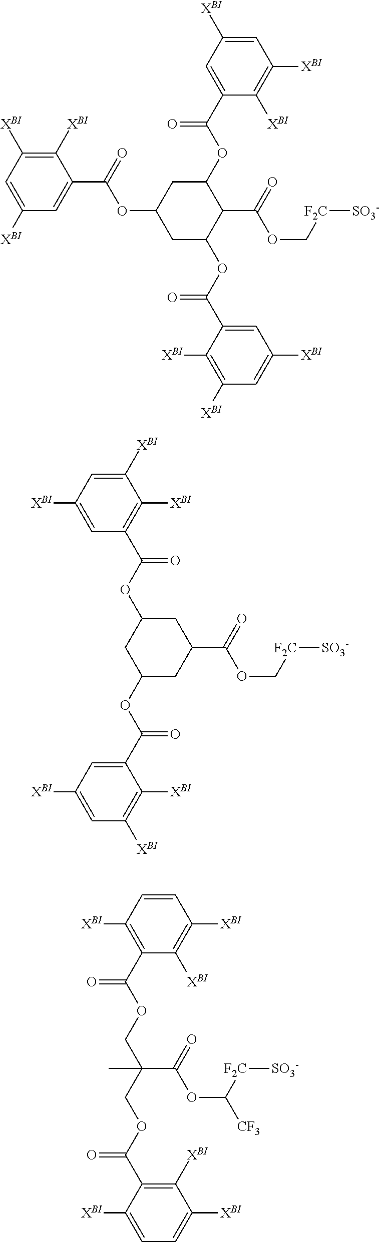

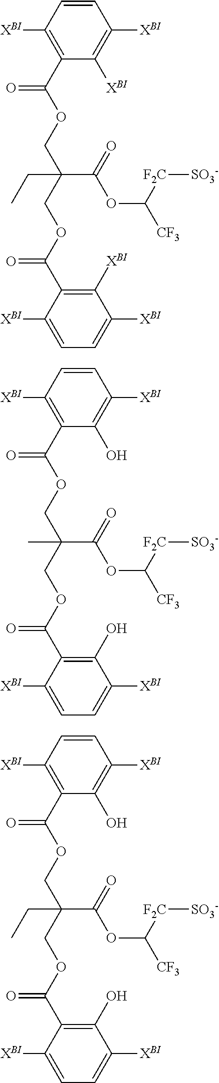

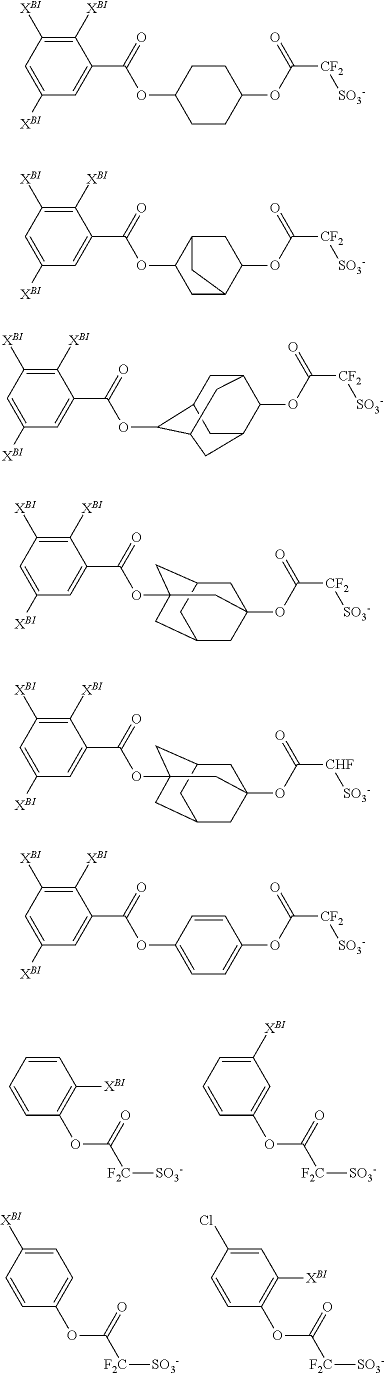

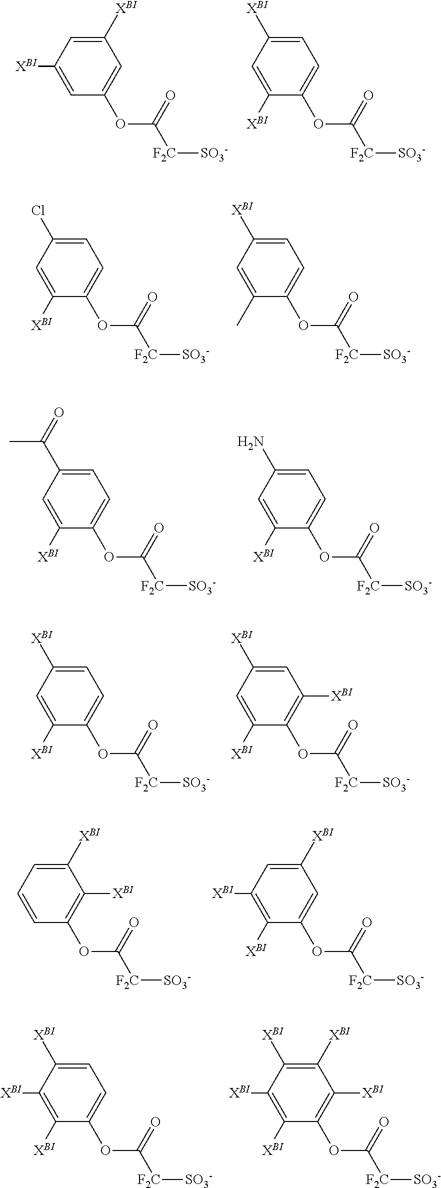

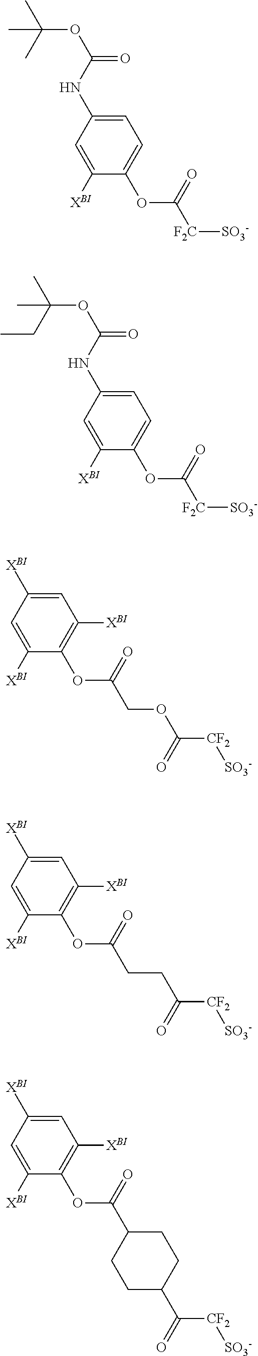

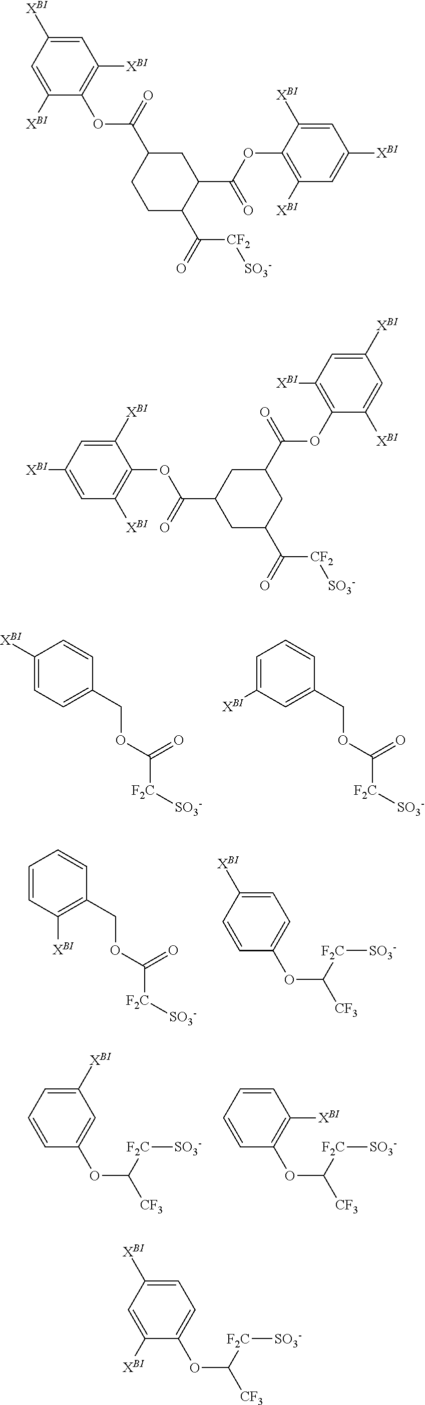

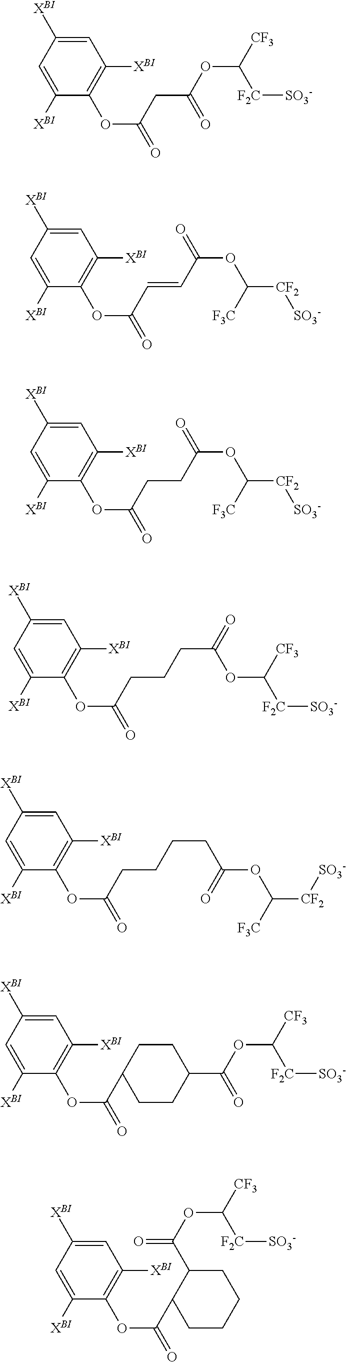

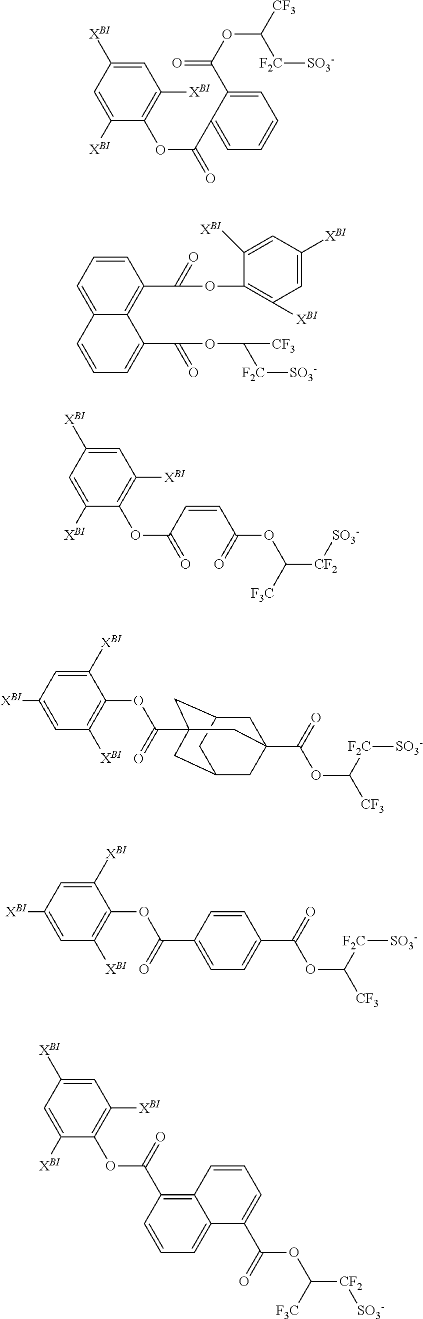

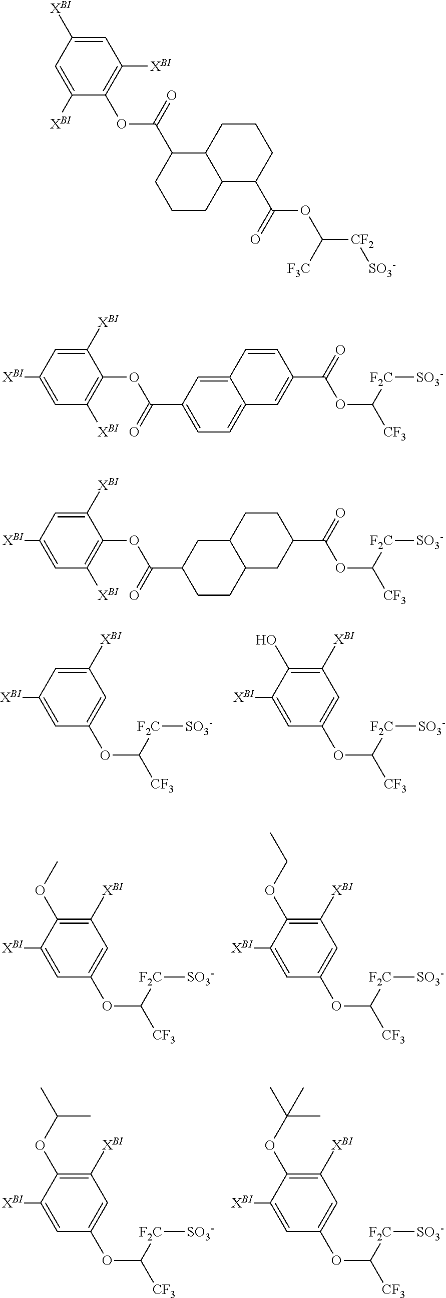

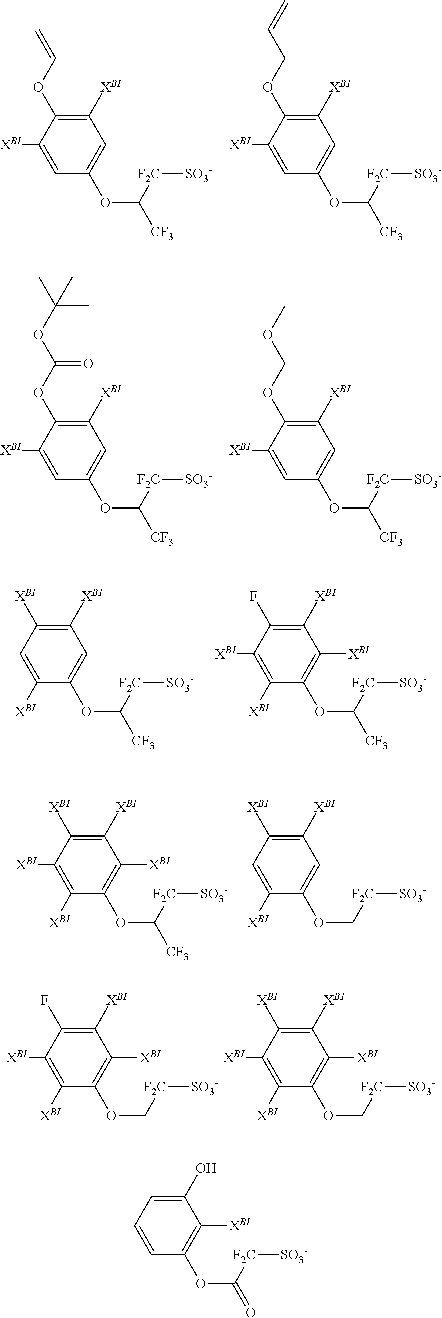

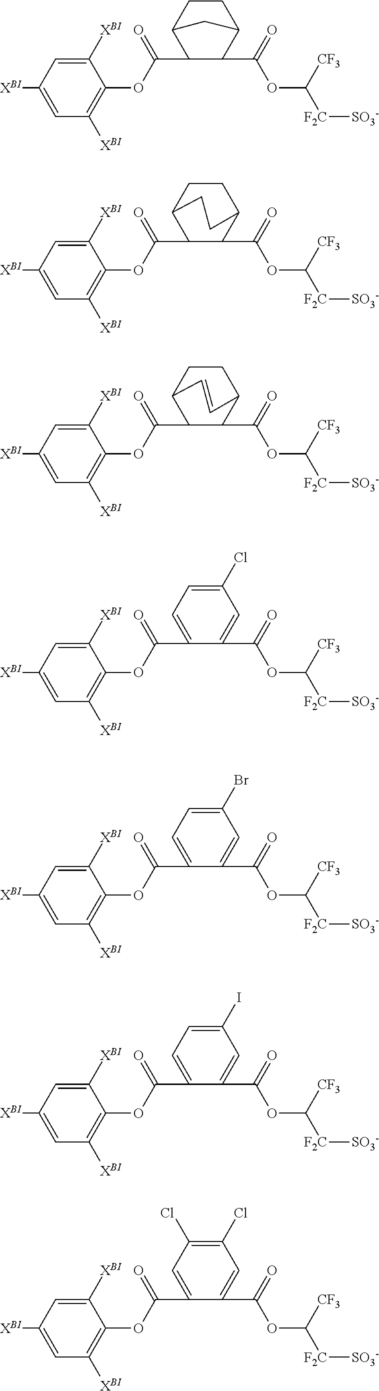

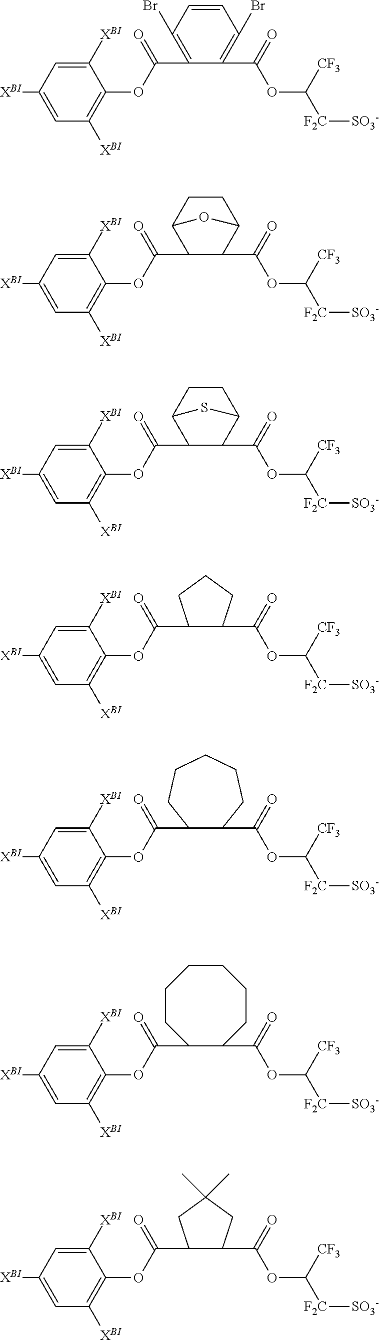

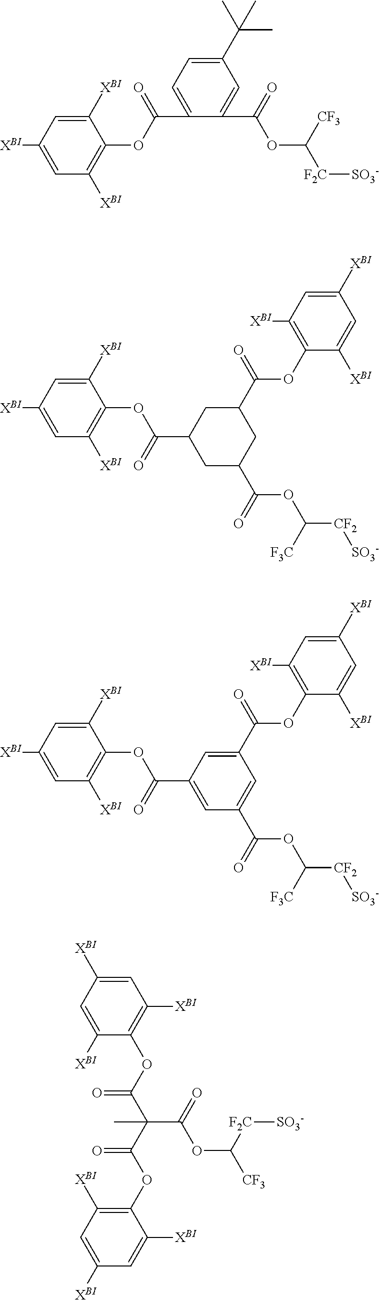

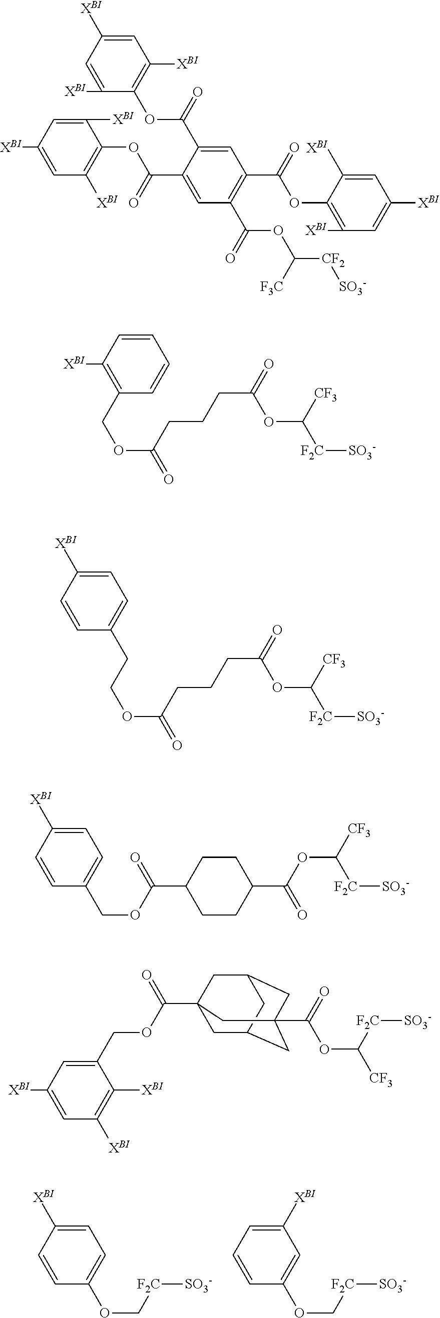

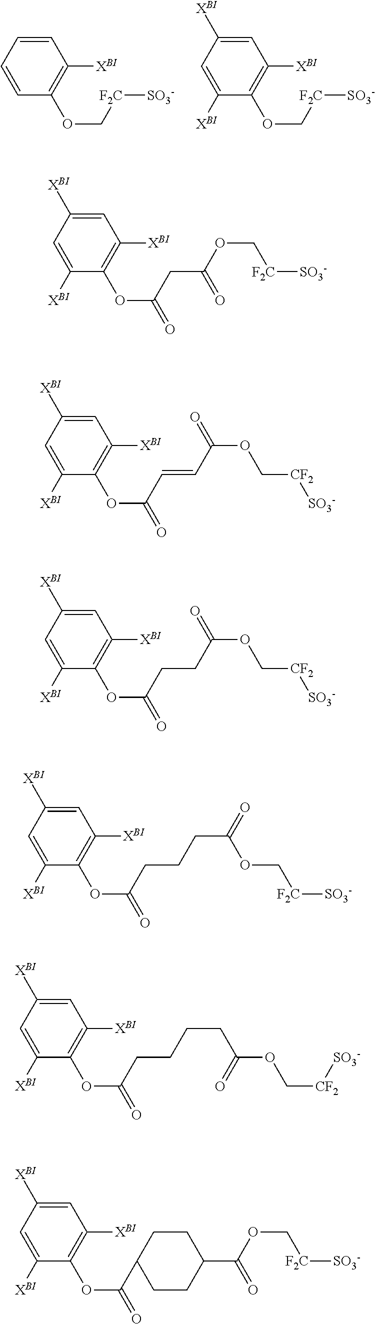

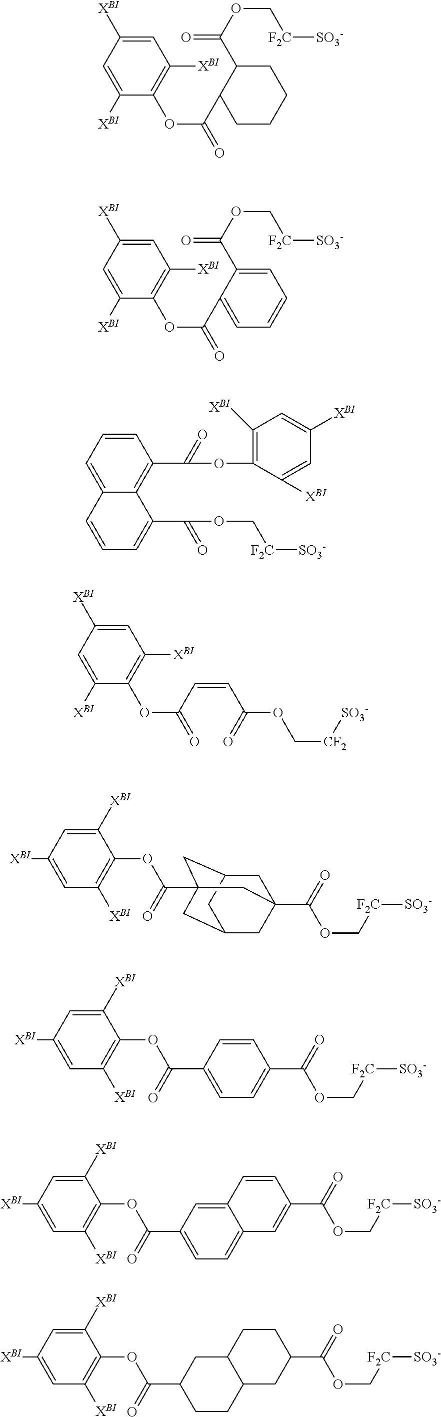

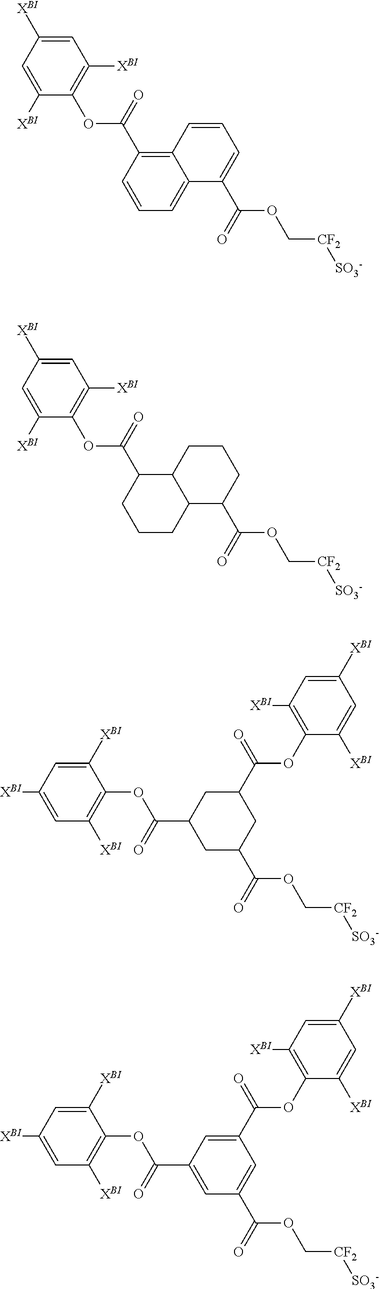

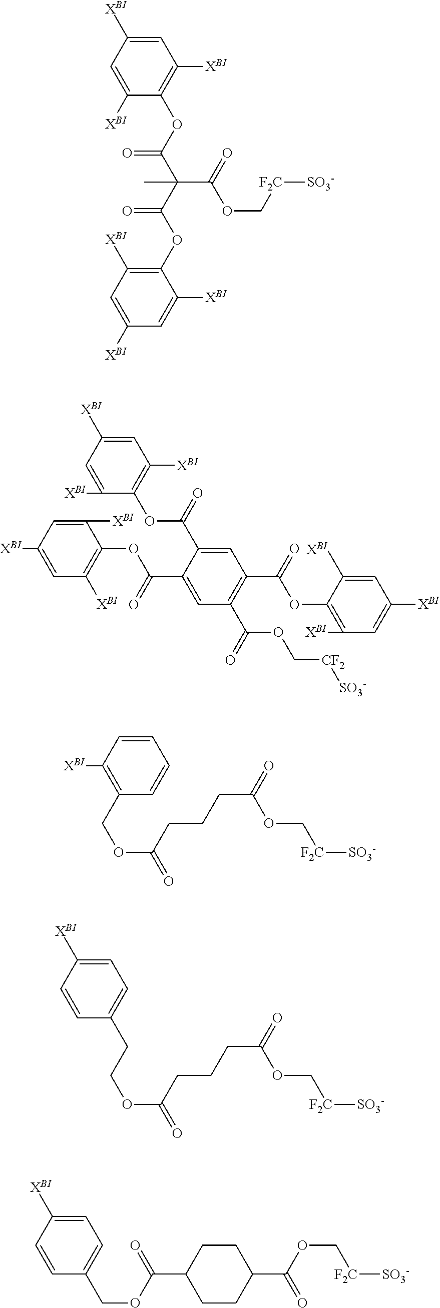

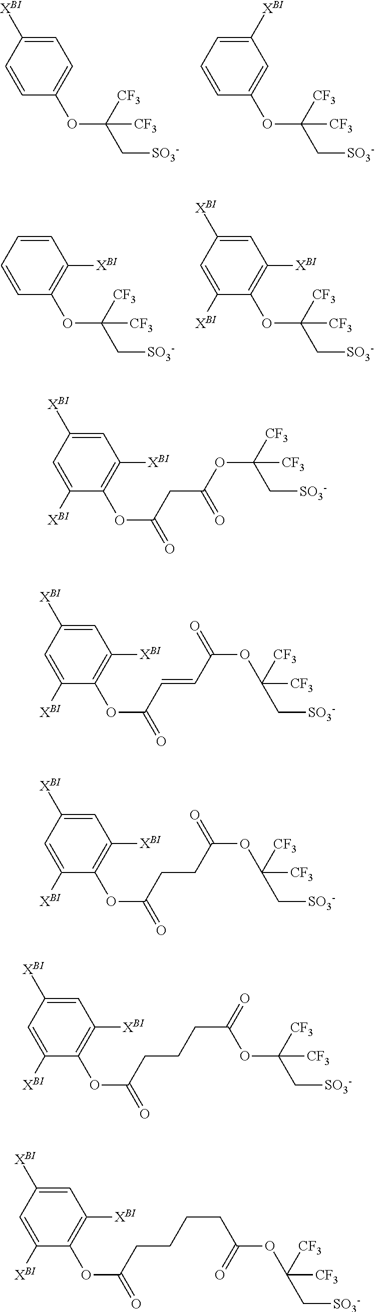

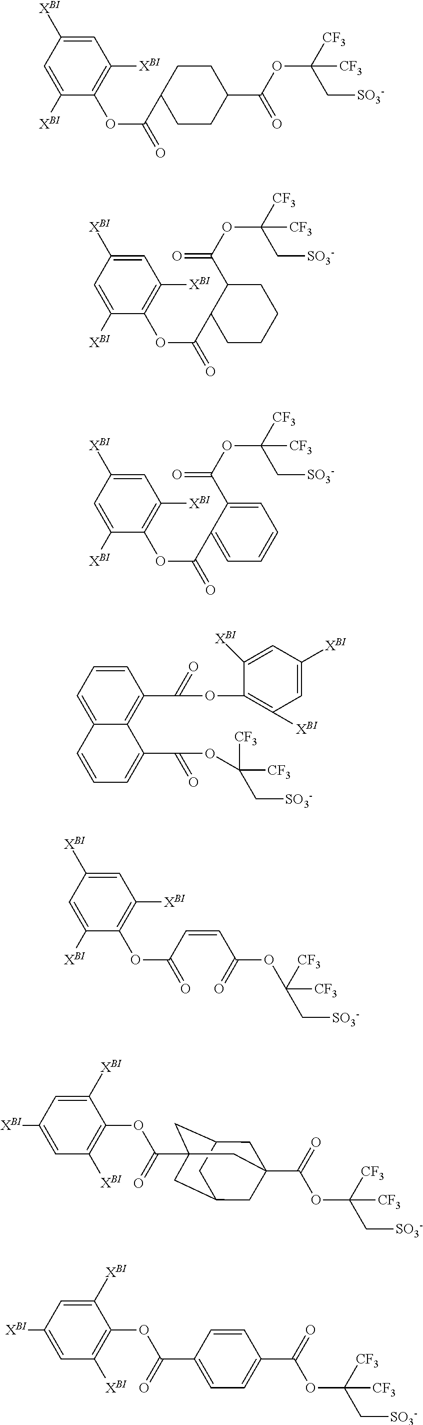

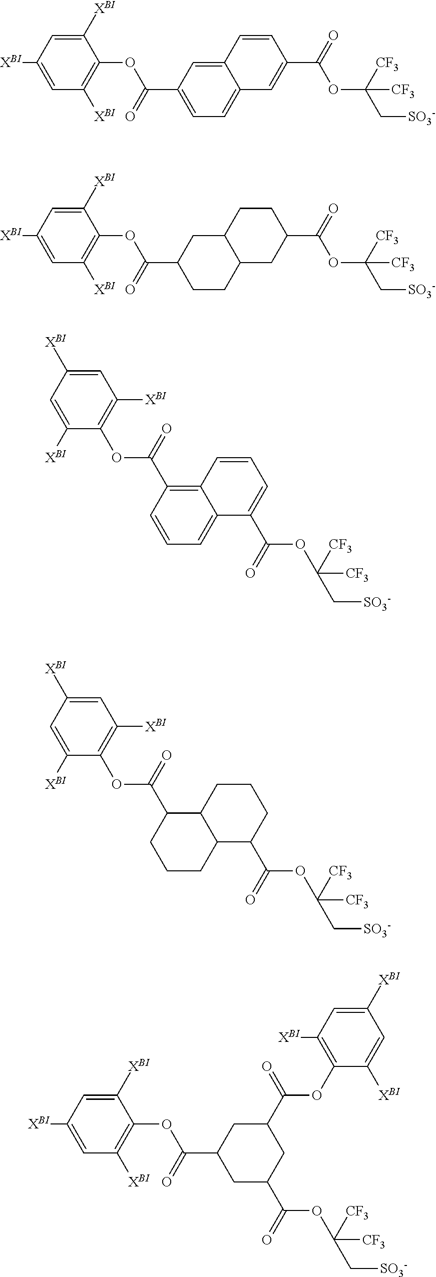

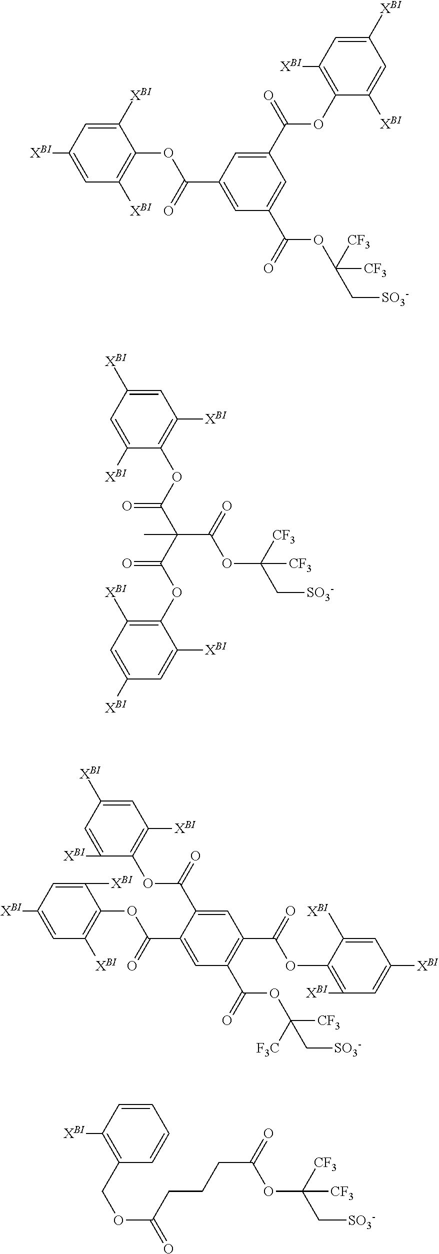

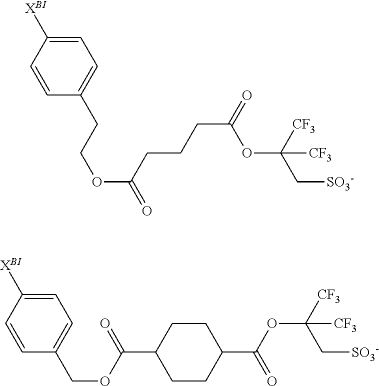

Sulfonium and iodonium salts of fluorobenzenesulfonic acid bonded with iodized benzoic acid as represented by the formulae (3-3) and (3-4) are also useful as the PAG.

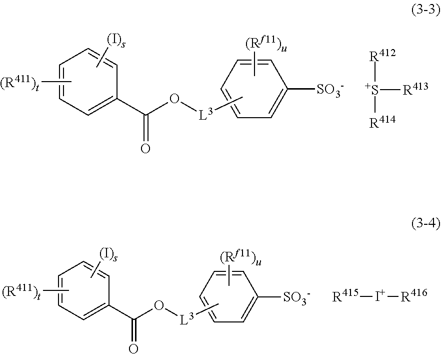

In formulae (3-3) and (3-4), s is an integer of 1 to 5, t is an integer of 0 to 3, and u is an integer of 1 to 4.

In formulae (3-3) and (3-4), R⁴ is hydroxy, carboxy, alkoxycarbonyl, fluorine, chlorine, bromine, amino or a C₁-C₂₀ saturated hydrocarbyl group, C₁-C₂₀ saturated hydrocarbyloxy group, or C₂-C₂₀ saturated hydrocarbylcarbonyloxy group, which may contain fluorine, chlorine, bromine, hydroxy, amino or alkoxy, or —N(R^{411A})—C(O)_R^{411B} or —N(R^{411A})—C(═O)—O—R^{411B}. R^{411A} is hydrogen or a C₁-C₆ saturated hydrocarbyl group. R^{411B} is a C₁-C₁₆ aliphatic hydrocarbyl group, C₆-C₁₄ aryl group, or C₇-C₁₅ aralkyl group, which may contain halogen, hydroxy, a C₁-C₆ saturated hydrocarbyloxy moiety, C₂-C₆ saturated hydrocarbylcarbonyl moiety, or C₂-C₆ saturated hydrocarbylcarbonyloxy moiety.

In formulae (3-3) and (3-4), L³ is a single bond or a C₁-C₂₀ divalent linking group which may contain oxygen, sulfur or nitrogen.

In formulae (3-3) and (3-4), Rf¹¹ is fluorine or trifluoromethyl.

In formulae (3-3) and (3-4), R⁴¹² to R⁴¹⁶ are each independently halogen or a C₁-C₂₀ hydrocarbyl group which may contain a heteroatom. Suitable halogen atoms include fluorine, chlorine, bromine and iodine. The hydrocarbyl group may be saturated or unsaturated and straight, branched or cyclic. Examples thereof are as exemplified above for R² to R⁴ in formula (a). In the hydrocarbyl group, some or all of the hydrogen atoms may be substituted by hydroxy, carboxy, halogen, cyano, nitro, mercapto, sultone ring, sulfo or sulfonium salt-containing moiety, and some —CH₂— may be replaced by an ether bond, ester bond, carbonyl, amide bond, carbonate bond or sulfonate ester bond. R⁴⁰² and R⁴⁰³ may bond together to form a ring with the sulfur atom to which they are attached. Examples of the ring are as exemplified above for the ring that R² and R³ in formula (a), taken together, form with the sulfur atom to which they are attached.

Examples of the cation in the sulfonium salt having formula (3-3) are as exemplified above for the cation in repeat unit (a). Examples of the cation in the iodonium salt having formula (3-4) are as exemplified above for the cation in the iodonium salt having formula (1-2).

Examples of the anion in the onium salt having formula (3-3) or (3-4) are shown below, but not limited thereto.

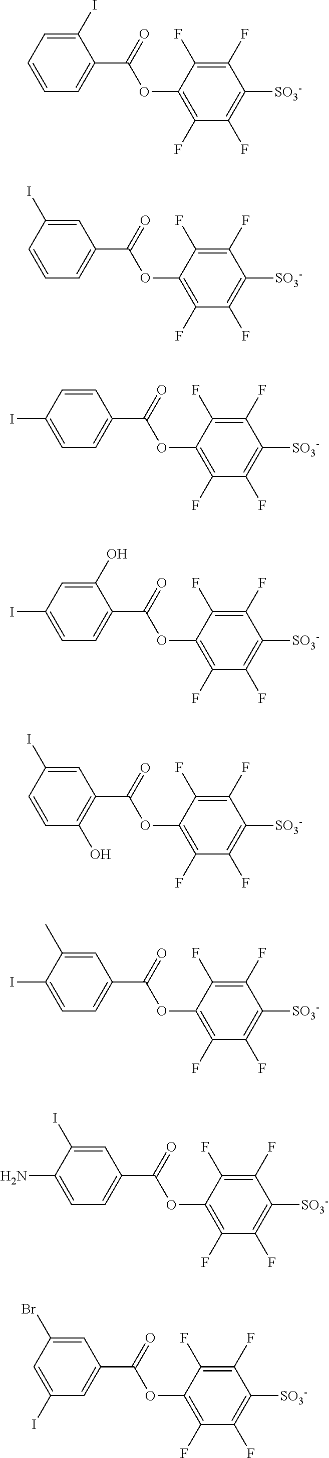

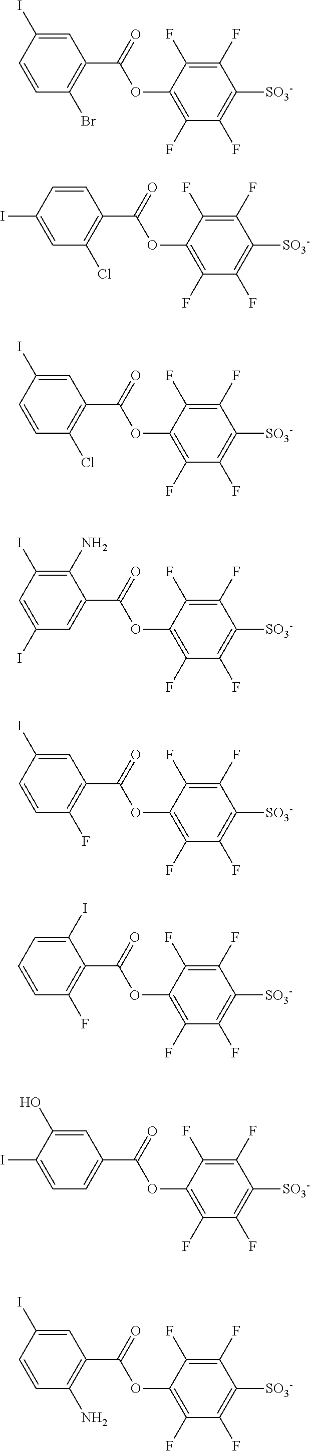

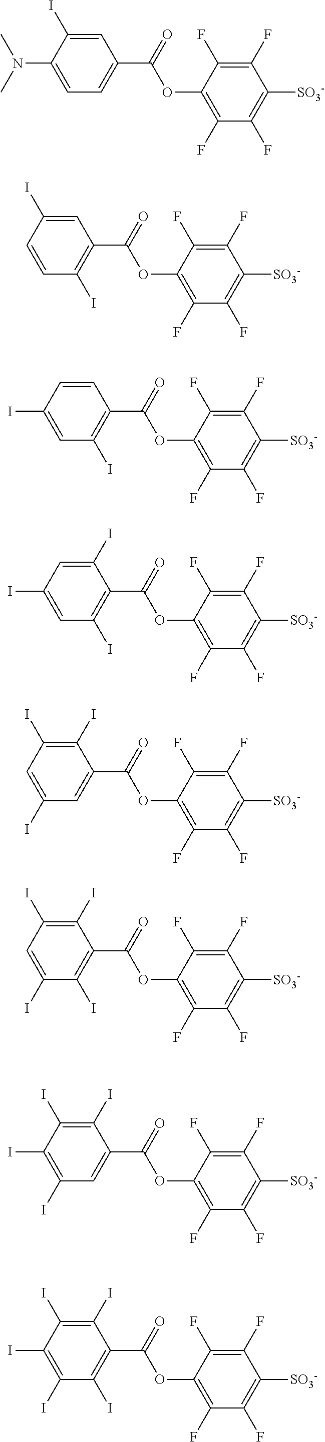

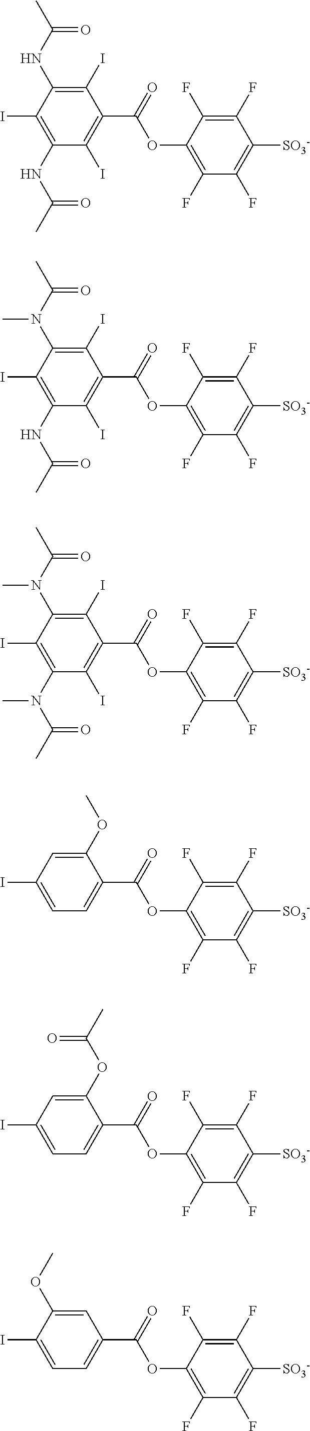

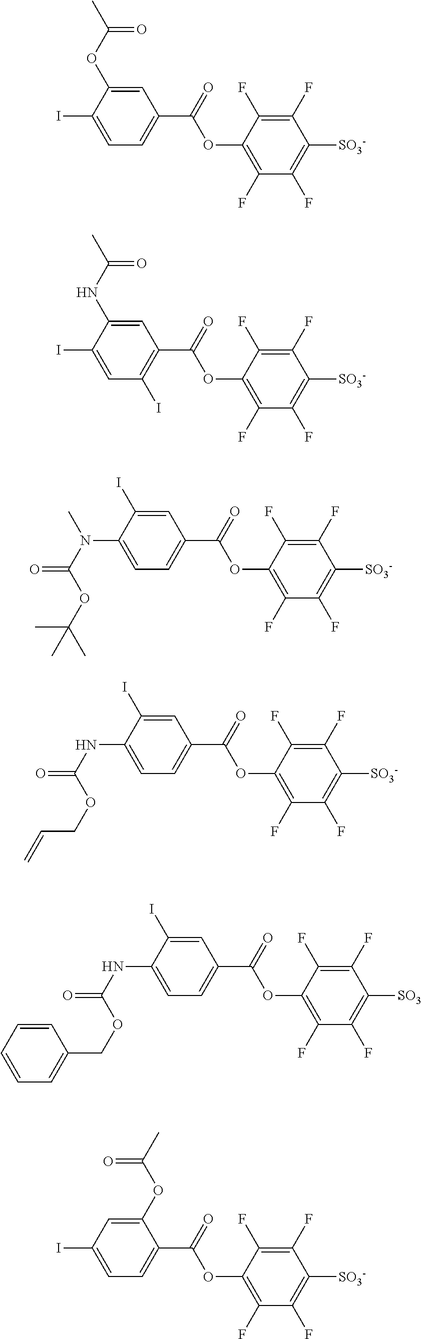

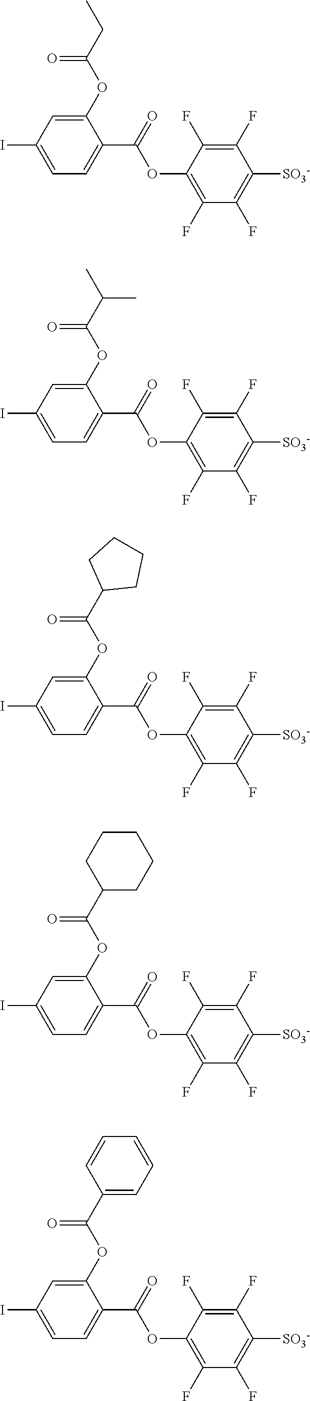

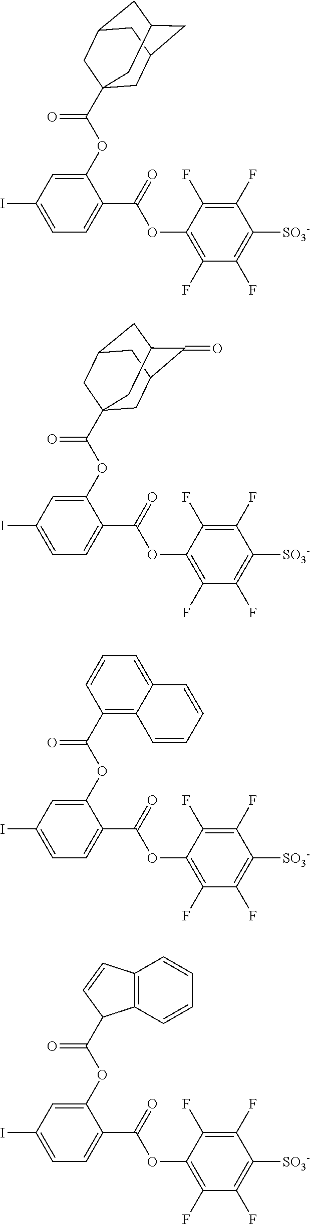

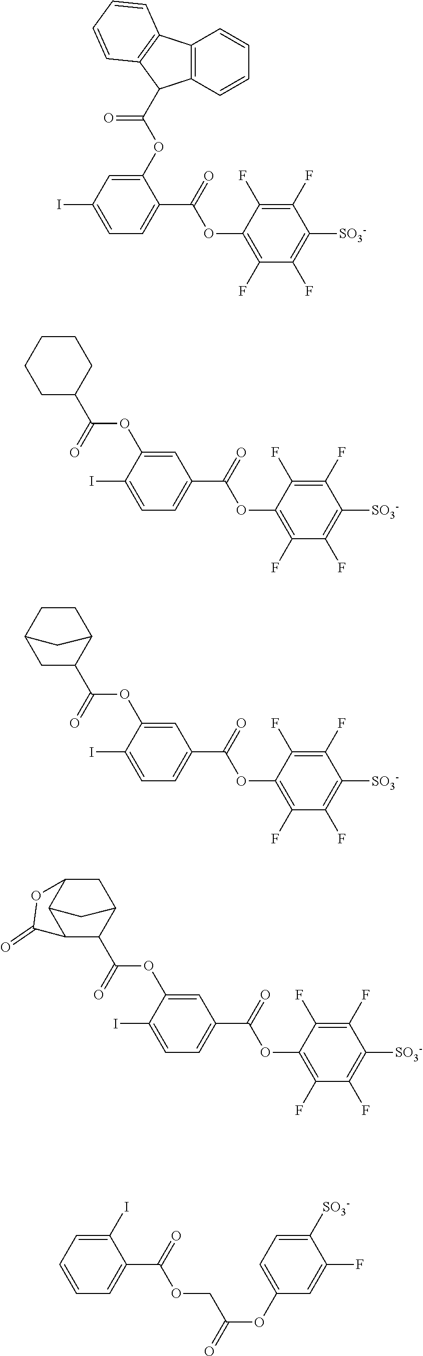

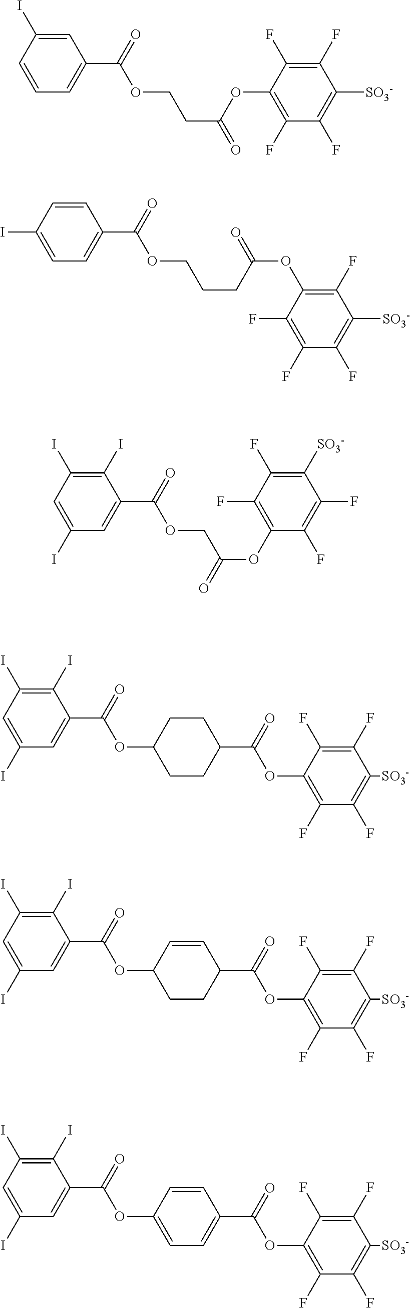

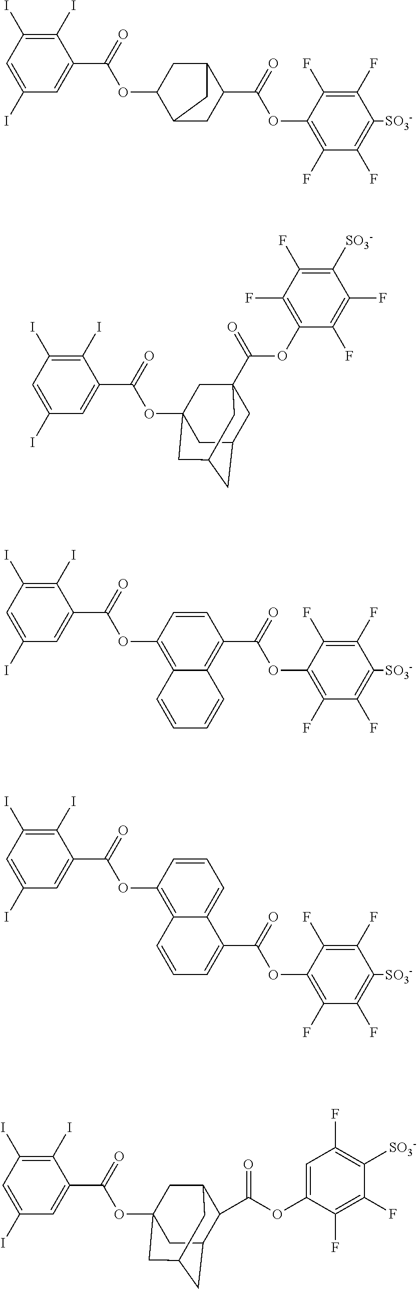

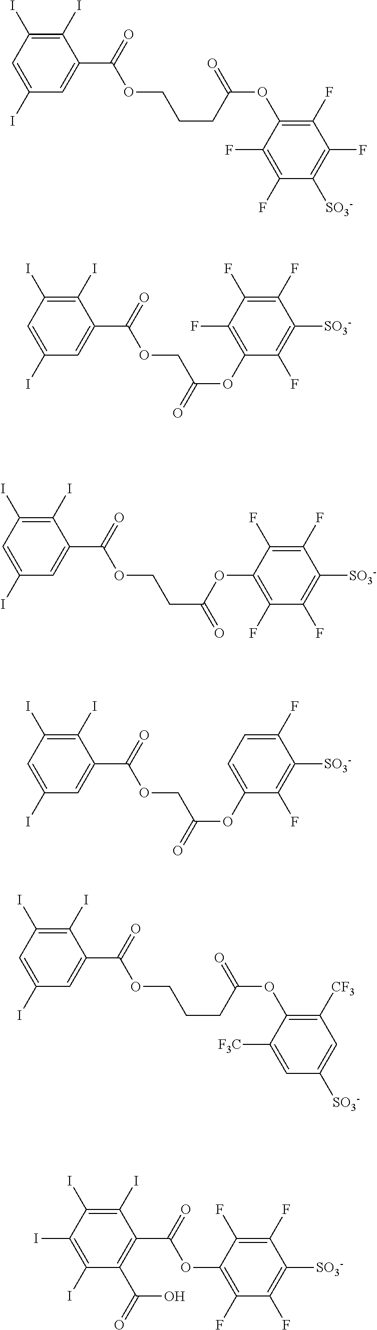

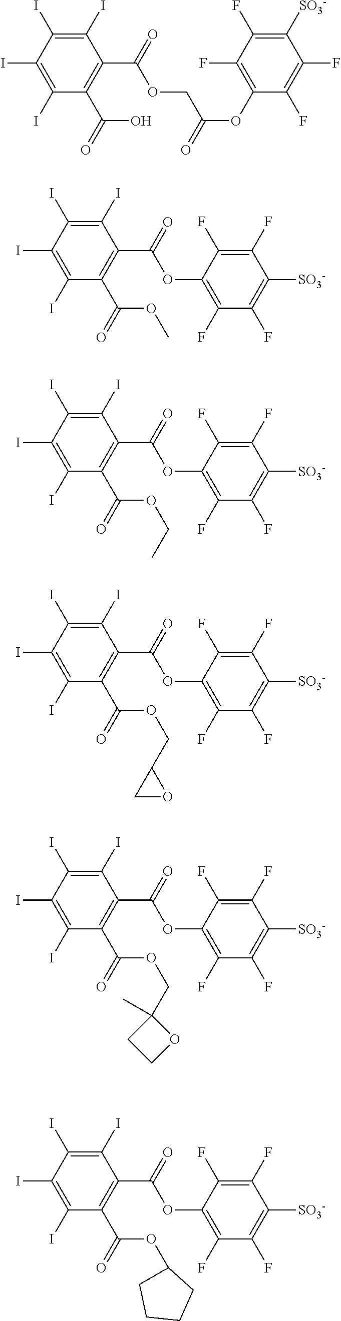

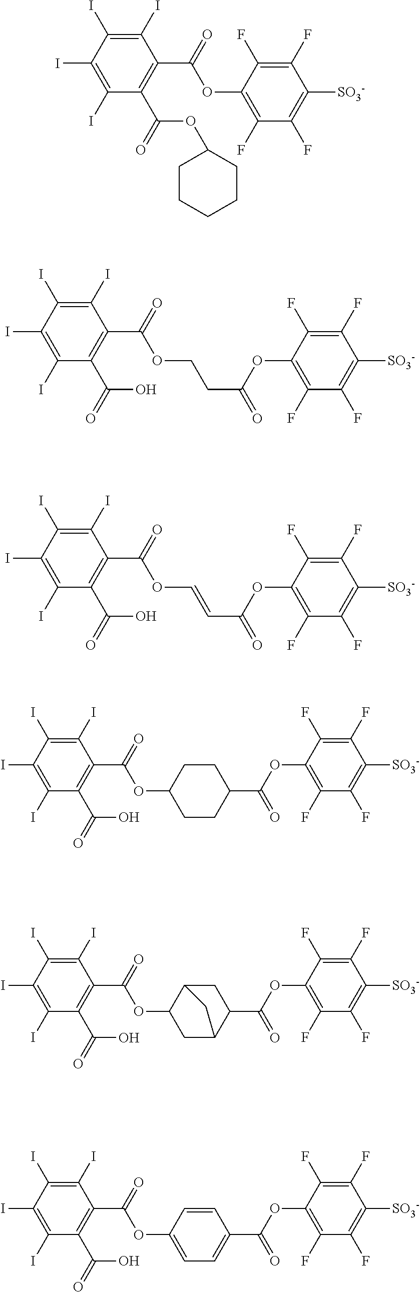

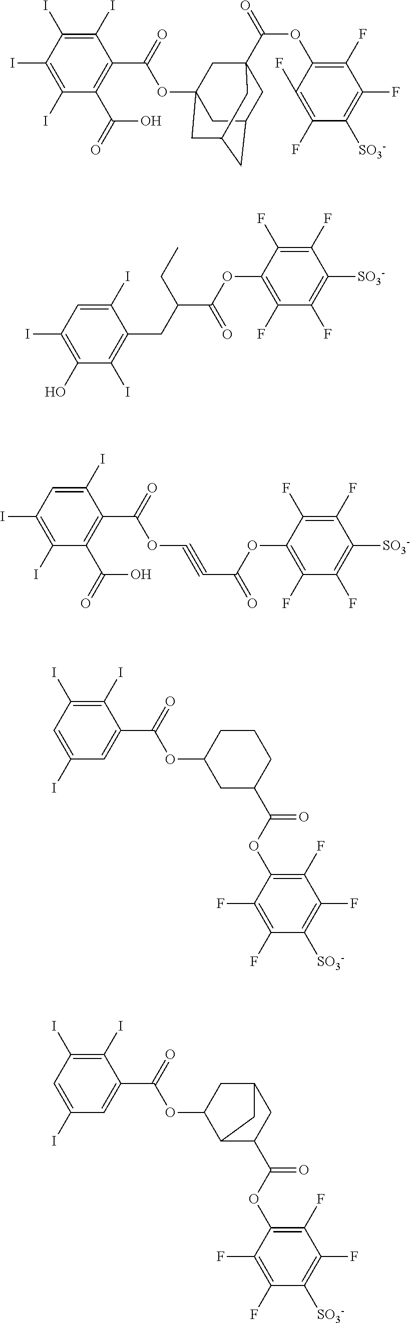

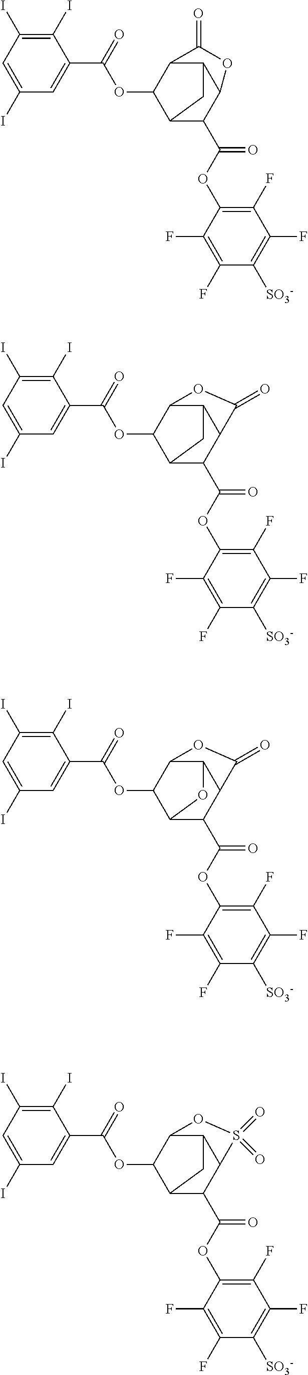

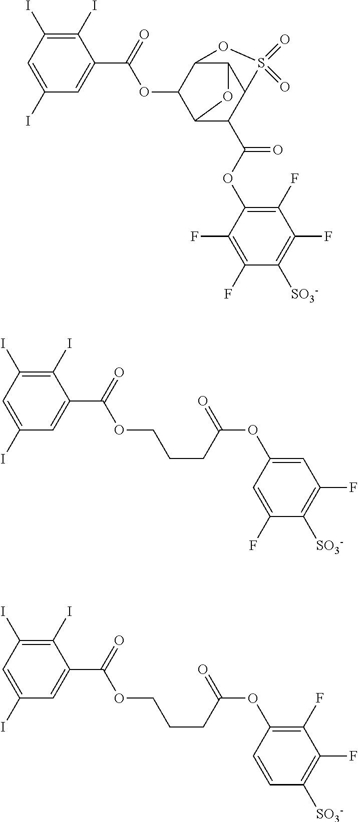

When used, the acid generator of addition type is preferably added in an amount of 0.1 to 50 parts, and more preferably 1 to 40 parts by weight per 100 parts by weight of the base polymer. The acid generator may be used alone or in admixture. The resist composition functions as a chemically amplified positive resist composition when the base polymer includes any of repeat units (d1) to (d5) and/or the resist composition contains the acid generator of addition type.

### [Organic Solvent]

An organic solvent may be added to the resist composition. The organic solvent used herein is not particularly limited as long as the foregoing and other components are soluble therein. Examples of the organic solvent are described in JP-A 2008-111103, paragraphs [0144]-[0145](U.S. Pat. No. 7,537,880). Exemplary solvents include ketones such as cyclohexanone, cyclopentanone, methyl-2-n-pentyl ketone and 2-heptanone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate (L-, D- and DL-form), ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, which may be used alone or in admixture.

The organic solvent is preferably added in an amount of 100 to 10,000 parts, and more preferably 200 to 8,000 parts by weight per 100 parts by weight of the base polymer.

### [Other Components]

In addition to the foregoing components, the resist composition may further comprise other components such as a surfactant, dissolution inhibitor, quencher, water repellency improver, and acetylene alcohol. Each of additional components may be used alone or in admixture of two or more.

Exemplary surfactants are described in JP-A 2008-111103, paragraphs [0165]-[0166]. Inclusion of a surfactant may improve or control the coating characteristics of the resist composition. When used, the surfactant is preferably added in an amount of 0.0001 to 10 parts by weight per 100 parts by weight of the base polymer.

The inclusion of a dissolution inhibitor in the resist composition leads to an increased difference in dissolution rate between exposed and unexposed areas and a further improvement in resolution. The dissolution inhibitor which can be used herein is a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in U.S. Pat. No. 7,771,914 (JP-A 2008-122932, paragraphs [0155]-[0178]).

When the resist composition contains a dissolution inhibitor, the dissolution inhibitor is preferably added in an amount of 0 to 50 parts, more preferably 5 to 40 parts by weight per 100 parts by weight of the base polymer.

The resist composition may contain a quencher which is referred to as quencher of addition type, hereinafter. The quencher of addition type is typically selected from conventional basic compounds. Conventional basic compounds include primary, secondary, and tertiary aliphatic amines, mixed amines, aromatic amines, heterocyclic amines, nitrogen-containing compounds with carboxy group, nitrogen-containing compounds with sulfonyl group, nitrogen-containing compounds with hydroxy group, nitrogen-containing compounds with hydroxyphenyl group, alcoholic nitrogen-containing compounds, amide derivatives, imide derivatives, and carbamate derivatives. Also included are primary, secondary, and tertiary amine compounds, specifically amine compounds having a hydroxy group, ether bond, ester bond, lactone ring, cyano group, or sulfonate ester bond as described in JP-A 2008-111103, paragraphs [0146]-[0164], and compounds having a carbamate group as described in JP 3790649. Addition of a basic compound may be effective for further suppressing the diffusion rate of acid in the resist film or correcting the pattern profile.

Onium salts such as sulfonium, iodonium and ammonium salts of sulfonic acids which are not fluorinated at α-position as described in U.S. Pat. No. 8,795,942 (JP-A 2008-158339) and similar onium salts of carboxylic acid may also be used as the quencher of addition type. While an a-fluorinated sulfonic acid, imide acid, and methide acid are necessary to deprotect the acid labile group of carboxylic acid ester, an a-non-fluorinated sulfonic acid and a carboxylic acid are released by salt exchange with an a-non-fluorinated onium salt. An a-non-fluorinated sulfonic acid and a carboxylic acid function as a quencher because they do not induce deprotection reaction.

Also useful are quenchers of polymer type as described in U.S. Pat. No. 7,598,016 (JP-A 2008-239918). The polymeric quencher segregates at the resist surface and thus enhances the rectangularity of resist pattern. When a protective film is applied as is often the case in the immersion lithography, the polymeric quencher is also effective for preventing a film thickness loss of resist pattern or rounding of pattern top.

When used, the quencher of addition type is preferably added in an amount of 0 to 5 parts, more preferably 0 to 4 parts by weight per 100 parts by weight of the base polymer.

To the resist composition, a water repellency improver may also be added for improving the water repellency on surface of a resist film. The water repellency improver may be used in the topcoatless immersion lithography. Suitable water repellency improvers include polymers having a fluoroalkyl group and polymers of specific structure having a 1,1,1,3,3,3-hexafluoro-2-propanol residue and are described in JP-A 2007-297590 and JP-A 2008-111103, for example. The water repellency improver should be soluble in the alkaline developer and organic solvent developer. The water repellency improver of specific structure having a 1,1,1,3,3,3-hexafluoro-2-propanol residue is well soluble in the developer. A polymer comprising repeat units having an amino group or amine salt may serve as the water repellent additive and is effective for preventing evaporation of acid during PEB, thus preventing any hole pattern opening failure after development. An appropriate amount of the water repellency improver is 0 to 20 parts, more preferably 0.5 to 10 parts by weight per 100 parts by weight of the base polymer.

Also, an acetylene alcohol may be blended in the resist composition. Suitable acetylene alcohols are described in JP-A 2008-122932, paragraphs [0179]-[0182]. An appropriate amount of the acetylene alcohol blended is 0 to 5 parts by weight per 100 parts by weight of the base polymer.

### [Process]

The positive resist composition is used in the fabrication of various integrated circuits. Pattern formation using the resist composition may be performed by well-known lithography processes. The process generally involves the steps of applying the resist composition onto a substrate to form a resist film thereon, exposing the resist film to high-energy radiation, and developing the exposed resist film in a developer. If necessary, any additional steps may be added.

Specifically, the resist composition is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying or doctor coating. The coating is prebaked on a hotplate preferably at a temperature of 60 to 150° C. for 10 seconds to 30 minutes, more preferably at 80 to 120° C. for 30 seconds to 20 minutes. The resulting resist film is generally 0.01 to 2 μm thick.

The resist film is then exposed to a desired pattern of high-energy radiation such as UV, deep-UV, EB, EUV of wavelength 3 to 15 nm, x-ray, soft x-ray, excimer laser light, y-ray or synchrotron radiation. When UV, deep-UV, EUV, x-ray, soft x-ray, excimer laser light, y-ray or synchrotron radiation is used as the high-energy radiation, the resist film is exposed thereto directly or through a mask having a desired pattern in a dose of preferably about 1 to 200 mJ/cm², more preferably about 10 to 100 mJ/cm². When EB is used as the high-energy radiation, the resist film is exposed thereto directly or through a mask having a desired pattern in a dose of preferably about 0.1 to 100 μC/cm², more preferably about 0.5 to 50 μC/cm². It is appreciated that the inventive resist composition is suited in micropatterning using i-line of wavelength 365 nm, KrF excimer laser, ArF excimer laser, EB, EUV, x-ray, soft x-ray, γ-ray or synchrotron radiation, especially in micropatterning using EB or EUV.

After the exposure, the resist film may be baked (PEB) on a hotplate or in an oven preferably at 50 to 150° C. for 10 seconds to 30 minutes, more preferably at 60 to 120° C. for 30 seconds to 20 minutes.

After the exposure or PEB, the resist film is developed in a developer in the form of an aqueous base solution for 3 seconds to 3 minutes, preferably 5 seconds to 2 minutes by conventional techniques such as dip, puddle and spray techniques. A typical developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). Typically, the resist film in the exposed area is dissolved in the developer whereas the resist film in the unexposed area is not dissolved. In this way, the desired positive pattern is formed on the substrate.

In an alternative embodiment, a negative pattern can be obtained from the positive resist composition by effecting organic solvent development. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate, and mixtures thereof.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, t-butylbenzene and mesitylene.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation. All parts are by weight (pbw).

### [1] Synthesis of Monomers

### Synthesis Examples 1-1 to 1-7 and Comparative Synthesis Example 1-1

Monomers M-1 to M-7 and comparative monomer cM-1 were obtained by ion exchange between a sulfonium salt chloride and an iodophenol compound or carboxylic acid compound having a polymerizable double bond.

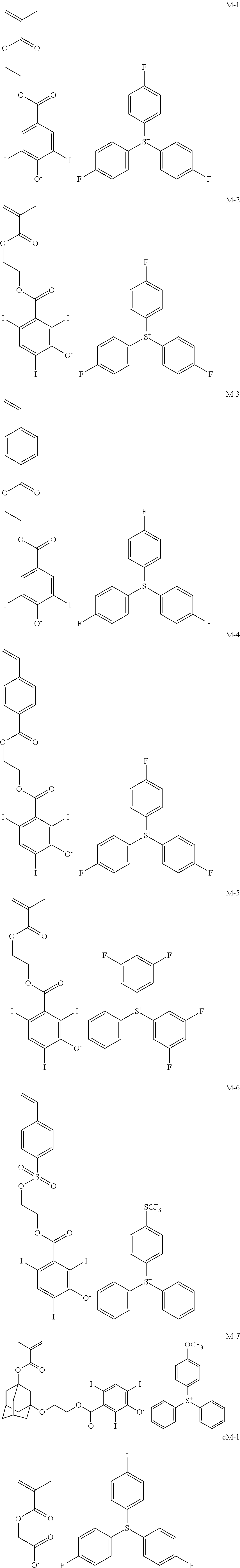

### [2] Synthesis of Base Polymers

Monomers PM-1 to PM-3 shown below were also used in the synthesis of base polymers. The polymers were analyzed for composition by NMR spectroscopy and for Mw and Mw/Mn by GPC versus polystyrene standards using THE solvent.

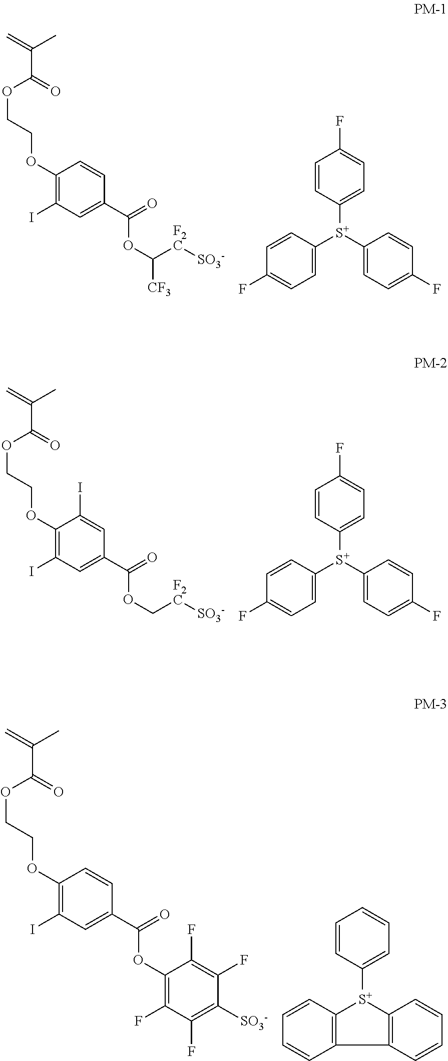

### [Synthesis Example 2-1] Synthesis of Polymer P-1

A 2-L flask was charged with 4.1 g of Monomer M-1, 8.4 g of 1-methyl-1-cyclopentyl methacrylate, 5.4 g of 4-hydroxystyrene, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of azobisisobutyronitrile (AIBN) as polymerization initiator was added. The reactor was heated at 60° C. and held at the temperature for 15 hours for reaction. The reaction solution was poured into 1 L of isopropyl alcohol (IPA) for precipitation. The resulting white solid was collected by filtration and dried in vacuum at 60° C., obtaining Polymer P-1. The polymer was analyzed by ¹³C- and ¹H-NMR spectroscopy and GPC.

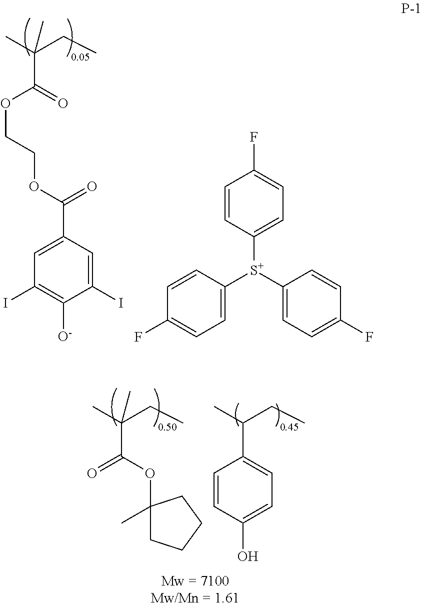

### [Synthesis Example 2-2] Synthesis of Polymer P-2

A 2-L flask was charged with 4.7 g of Monomer M-2, 8.8 g of 1-methyl-1-cyclohexyl methacrylate, 4.2 g of 4-hydroxystyrene, 9.0 g of Monomer PM-1, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-2. The polymer was analyzed by ¹³C- and ¹H-NMR spectroscopy and GPC.

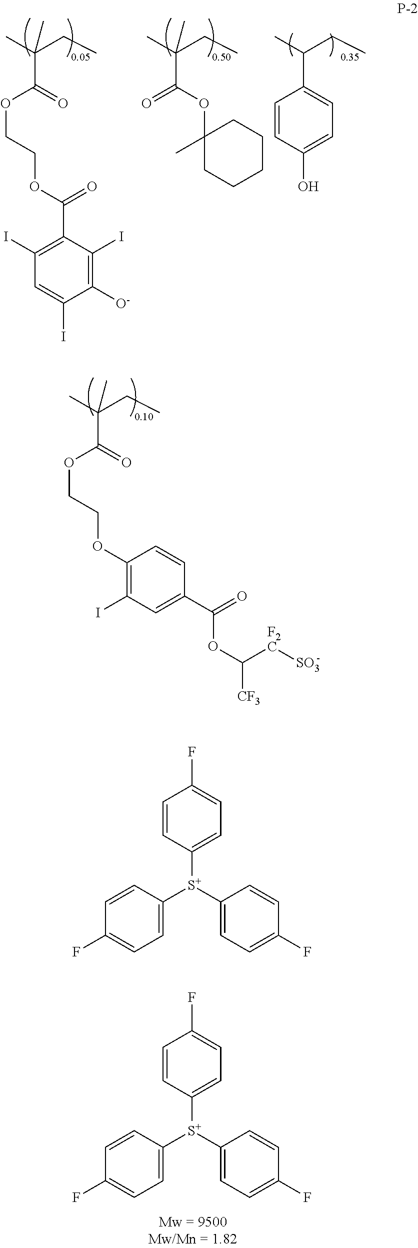

### [Synthesis Example 2-3] Synthesis of Polymer P-3

A 2-L flask was charged with 4.4 g of Monomer M-3, 8.4 g of 1-methyl-1-cyclopentyl methacrylate, 4.2 g of 3-hydroxystyrene, 9.0 g of Monomer PM-1, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-3. The polymer was analyzed by ¹³C- and ¹H-NMR spectroscopy and GPC.

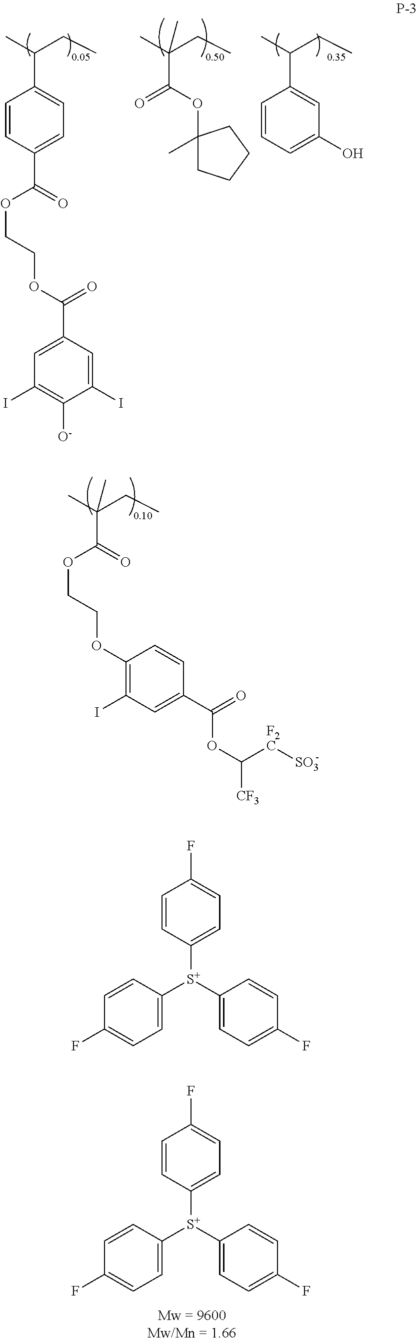

### [Synthesis Example 2-4] Synthesis of Polymer P-4

A 2-L flask was charged with 5.0 g of Monomer M-4, 8.4 g of 1-methyl-1-cyclopentyl methacrylate, 4.2 g of 3-hydroxystyrene, 9.0 g of Monomer PM-1, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-4. The polymer was analyzed by ¹³C- and ¹H-NMR spectroscopy and GPC.

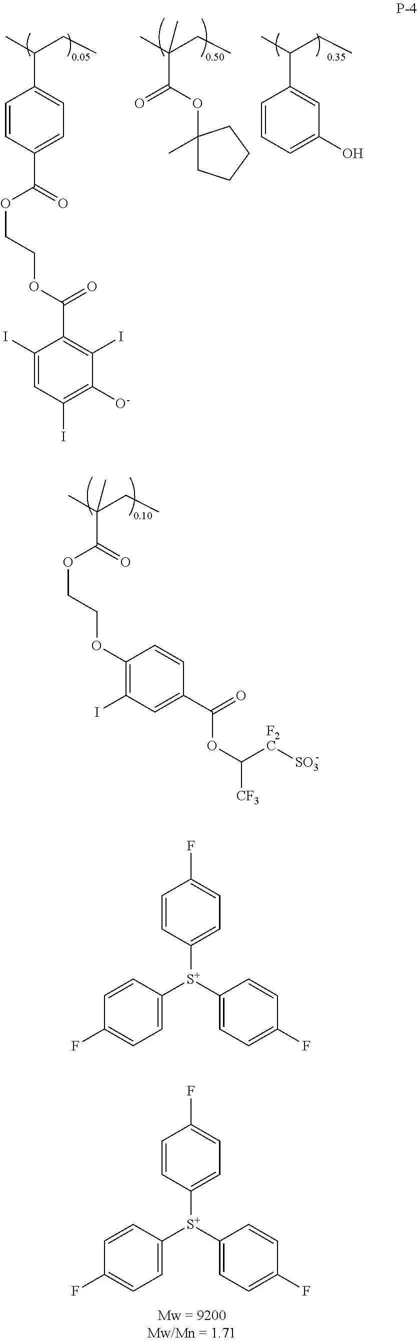

### [Synthesis Example 2-5] Synthesis of Polymer P-5

A 2-L flask was charged with 4.8 g of Monomer M-5, 8.4 g of 1-methyl-1-cyclopentyl methacrylate, 4.2 g of 3-hydroxystyrene, 9.6 g of Monomer PM-2, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-5. The polymer was analyzed by ¹³C- and ¹H-NMR spectroscopy and GPC.

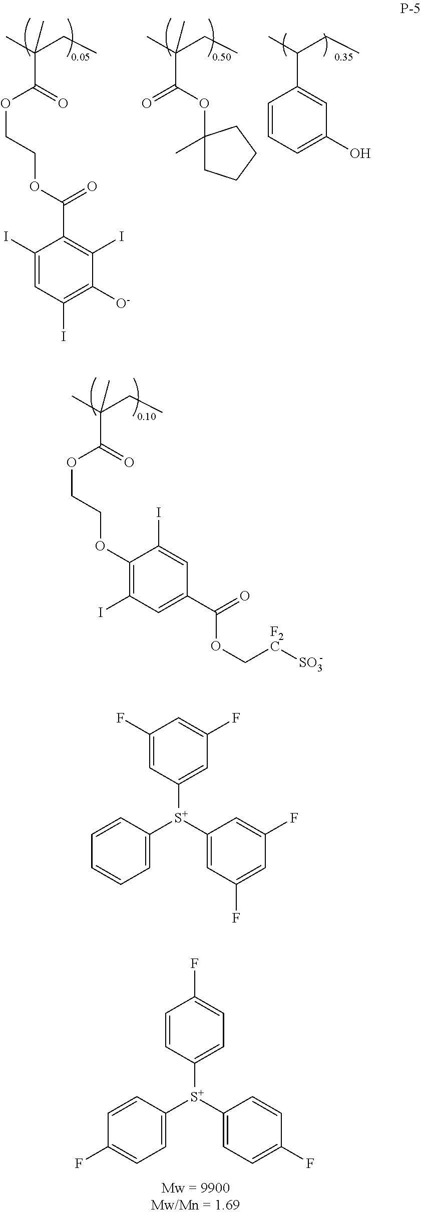

### [Synthesis Example 2-6] Synthesis of Polymer P-6

A 2-L flask was charged with 5.4 g of Monomer M-6, 8.4 g of 1-methyl-1-cyclopentyl methacrylate, 4.2 g of 4-hydroxystyrene, 8.6 g of Monomer PM-3, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-6. The polymer was analyzed by ¹³C- and ¹H-NMR spectroscopy and GPC.

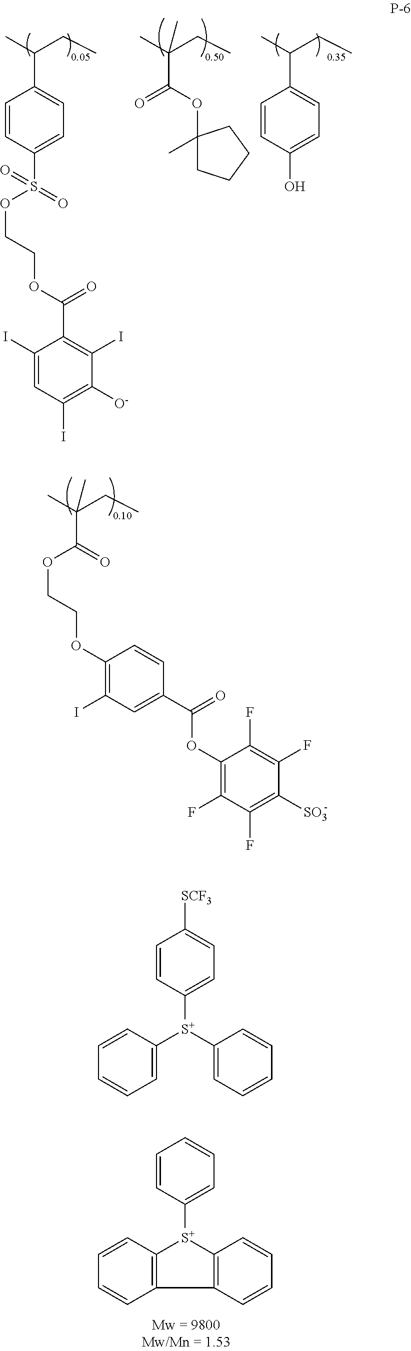

### [Synthesis Example 2-7] Synthesis of Polymer P-7

A 2-L flask was charged with 5.6 g of Monomer M-7, 8.4 g of 1-methyl-1-cyclopentyl methacrylate, 4.2 g of 3-hydroxystyrene, 8.6 g of Monomer PM-3, and 40 g of THF solvent. The reactor was cooled at −70° C. in a nitrogen atmosphere, after which vacuum pumping and nitrogen blow were repeated three times. The reactor was warmed up to room temperature, whereupon 1.2 g of AIBN as polymerization initiator was added. The reactor was heated at 60° C. and held at the temperature for 15 hours for reaction. The reaction solution was poured into 1 L of IPA for precipitation. The resulting white solid was collected by filtration and dried in vacuum at 60° C., obtaining Polymer P-7. The polymer was analyzed by ¹³C- and ¹H-NMR spectroscopy and GPC.

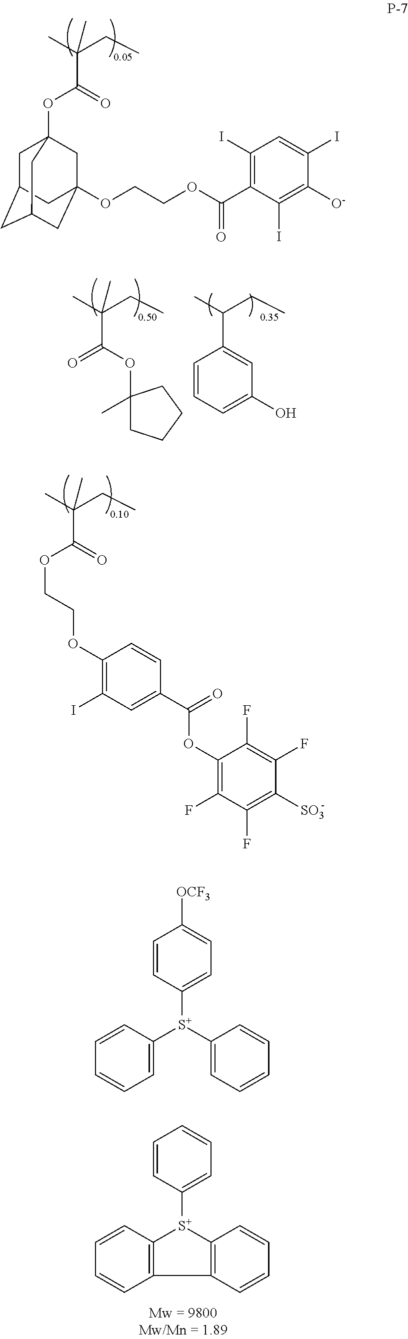

### [Comparative Synthesis Example 2-1] Synthesis of Comparative Polymer cP-1

Comparative Polymer cP-1 was synthesized by the same procedure as in Synthesis Example 2-1 aside from using comparative Monomer cM-1 instead of Monomer M-1. The polymer was analyzed by NMR spectroscopy and GPC.

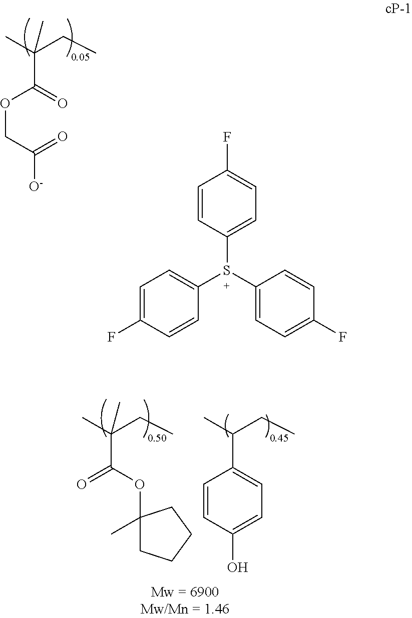

### [Comparative Synthesis Example 2-2] Synthesis of Comparative Polymer cP-2

Comparative Polymer cP-2 was synthesized by the same procedure as in Synthesis Example 2-2 aside from omitting Monomer M-1. The polymer was analyzed by NMR spectroscopy and GPC.

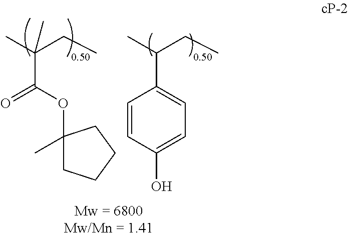

### [Comparative Synthesis Example 2-3] Synthesis of Comparative Polymer cP-3

Comparative Polymer cP-3 was synthesized by the same procedure as in Synthesis Example 2-3 aside from omitting Monomer M-3. The polymer was analyzed by NMR spectroscopy and GPC.

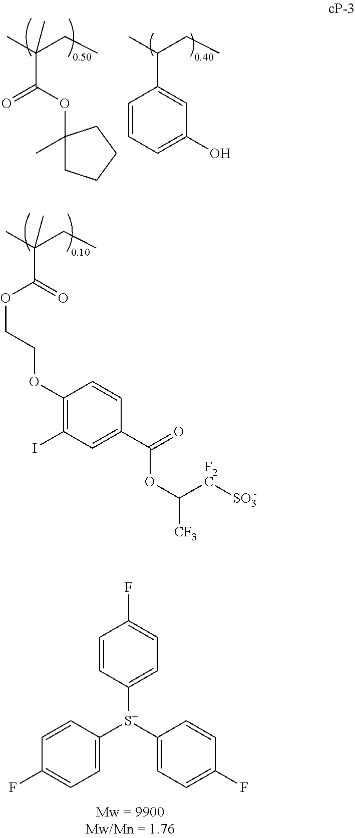

### Preparation and Evaluation of Positive Resist Compositions

### Examples 1 to 10 and Comparative Examples 1 to 3

### (1) Preparation of Positive Resist Compositions

Positive resist compositions were prepared by dissolving the selected components in a solvent in accordance with the recipe shown in Table 1, and filtering through a filter having a pore size of 0.2 μm. The solvent contained 50 ppm of surfactant PolyFox PF-636 (Omnova Solutions Inc.).

The components in Table 1 are as identified below.

### Organic Solvents:

PGMEA (propylene glycol monomethyl ether acetate)
DAA (diacetone alcohol)
EL (ethyl lactate)

### Acid Generator: PAG-1 and PAG-2

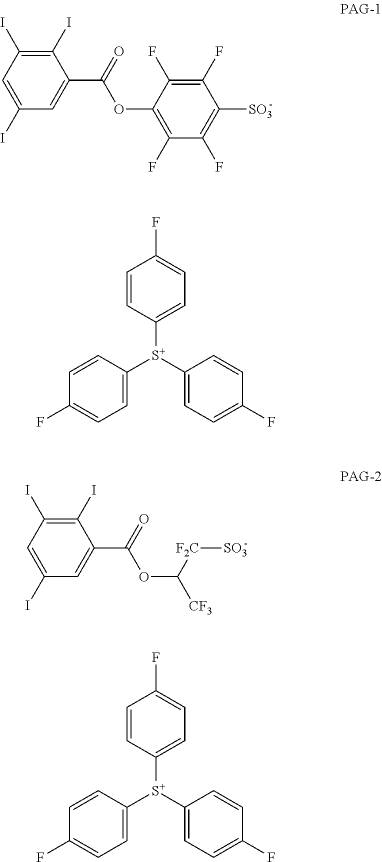

### Quencher: Q-1

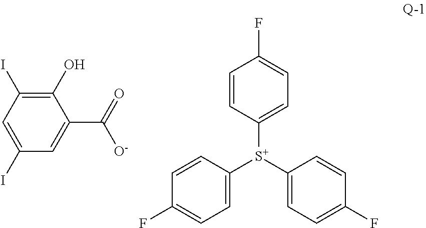 [SMILES: O=C([O-])c1cc(I)cc(I)c1O ; Fc1ccc([S+](c2ccc(F)cc2)c2ccc(F)cc2)cc1]

### (2) EUV Lithography Test

Each of the positive resist compositions in Table 1 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 105° C. for 60 seconds to form a resist film of 60 nm thick. Using an EUV scanner NXE3400 (ASML, NA 0.33, σ 0.9/0.6, quadrupole illumination), the resist film was exposed to EUV through a mask bearing a hole pattern having a pitch (on-wafer size) of 46 nm+20% bias. The resist film was baked (PEB) on a hotplate at the temperature shown in Table 1 for 60 seconds and developed in a 2.38 wt % TMAH aqueous solution for 30 seconds to form a hole pattern having a size of 23 nm.

The resist pattern was observed under CD-SEM (CG5000, Hitachi High-Technologies Corp.). The exposure dose that provides a hole pattern of 23 nm size is reported as sensitivity. The size of 50 holes was measured, from which a 3-fold value (36) of the standard deviation (σ) was computed and reported as CDU.

The resist composition is shown in Table 1 together with the sensitivity and CDU of EUV lithography.

TABLE 1

| | | Base polymer | Acid generator | Quencher | Organic solvent | PEB temp. | Sensitivity | CDU |
|---|---|---|---|---|---|---|---|---|
| | | (pbw) | (pbw) | (pbw) | (pbw) | (° C.) | (mJ/cm²) | (nm) |
| Example | 1 | P-1 | PAG-1 | — | PGMEA (2000) | 80 | 29 | 3.0 |
| | | (100) | (25.0) | | DAA (500) | | | |
| | 2 | P-2 | — | — | PGMEA (2000) | 90 | 27 | 2.4 |
| | | (100) | | | DAA (500) | | | |
| | 3 | P-3 | — | — | PGMEA (2000) | 90 | 26 | 2.3 |
| | | (100) | | | DAA (500) | | | |
| | 4 | P-4 | — | — | PGMEA (2000) | 90 | 26 | 2.4 |
| | | (100) | | | DAA (500) | | | |
| | 5 | P-5 | — | — | PGMEA (2000) | 90 | 25 | 2.6 |
| | | (100) | | | DAA (500) | | | |
| | 6 | P-6 | — | — | PGMEA (2000) | 90 | 27 | 2.3 |
| | | (100) | | | DAA (500) | | | |
| | 7 | P-7 | — | — | PGMEA (2000) | 90 | 26 | 2.5 |
| | | (100) | | | DAA (500) | | | |
| | 8 | P-2 | PAG-1 | — | EL (2000) | 85 | 25 | 2.6 |
| | | (100) | (10.0) | | PGMEA (500) | | | |
| | 9 | P-2 | PAG-2 | — | EL (2000) | 85 | 24 | 2.7 |
| | | (100) | (9.0) | | PGMEA (500) | | | |
| | 10 | P-2 | — | Q-1 | PGMEA (2000) | 90 | 29 | 2.3 |
| | | (100) | | (3.24) | DAA (500) | | | |
| Comparative | 1 | cP-1 | PAG-1 | — | PGMEA (2000) | 80 | 36 | 4.0 |
| Example | | (100) | (25.0) | | DAA (500) | | | |
| | 2 | cP-2 | PAG-1 | Q-1 | PGMEA (2000) | 80 | 38 | 4.3 |
| | | (100) | (25.0) | (6.49) | DAA (500) | | | |
| | 3 | cP-3 | — | Q-1 | PGMEA (2000) | 90 | 31 | 3.2 |
| | | (100) | | (6.49) | DAA (500) | | | |

It is demonstrated in Table 1 that positive resist compositions comprising a polymer comprising repeat units having a sulfonium salt structure of an iodized phenol compound have a high sensitivity and form patterns with improved CDU.

Japanese Patent Application No. 2023-195593 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A positive resist composition comprising a base polymer comprising repeat units (a) having a sulfonium salt structure of an iodized phenol compound.

2. The positive resist composition of claim 1 wherein the repeat units (a) have the formula (a): 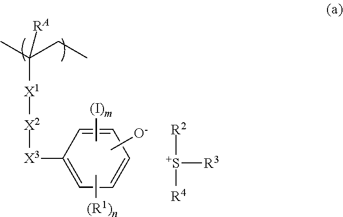
wherein R^{A} is hydrogen or methyl,
X¹ is a single bond, ester bond, ether bond, phenylene group or naphthylene group,
X² is a single bond, C₁-C₁₂ saturated hydrocarbylene group or phenylene group, the saturated hydrocarbylene group may contain at least one moiety selected from ether bond, ester bond, amide bond, lactone ring and sultone ring,
X³ is a single bond, ester bond or ether bond,
R¹ is hydrogen, a C₁-C₄ alkyl group, halogen exclusive of iodine, nitro group or cyano group,
R² to R⁴ are each independently halogen or a C₁-C₂₀ hydrocarbyl group which may contain a heteroatom, R² and R³ may bond together to form a ring with the sulfur atom to which they are attached,
m is an integer of 1 to 4, n is an integer of 0 to 3, and m+n is from 1 to 4.

3. The positive resist composition of claim 1 wherein the base polymer comprises repeat units of at least one type selected from repeat units (b1) having a carboxy group whose hydrogen is substituted by an acid labile group and repeat units (b2) having a phenolic hydroxy group whose hydrogen is substituted by an acid labile group.

4. The positive resist composition of claim 3 wherein the repeat units (b1) have the formula (b1) and the repeat units (b2) have the formula (b2): 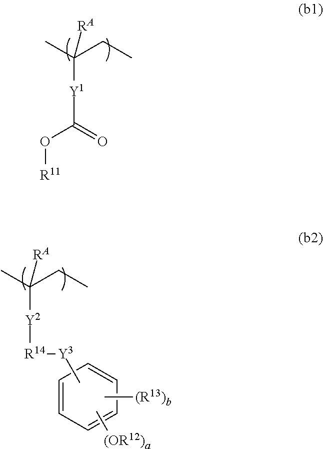
wherein R^{A} is each independently hydrogen or methyl,
Y¹ is a single bond, phenylene, naphthylene, or a C₁-C₁₂ linking group containing at least one moiety selected from ester bond, ether bond and lactone ring, the phenylene, naphthylene and linking groups may have at least one moiety selected from halogen, hydroxy, C₁-C₈ saturated hydrocarbyloxy moiety, and C₂-C₈ saturated hydrocarbylcarbonyloxy moiety,
Y² is a single bond, ester bond or amide bond,
Y³ is a single bond, ether bond or ester bond,
R¹¹ and R¹² are each independently an acid labile group,
R¹³ is hydroxy, halogen, trifluoromethyl, cyano, a C₁-C₆ saturated hydrocarbyl group, C₁-C₆ saturated hydrocarbyloxy group, or C₂-C₇ saturated hydrocarbylcarbonyloxy group,
R¹⁴ is a single bond or a C₁-C₆ alkanediyl group in which some —CH₂— may be replaced by an ether bond or ester bond,
a is 1 or 2, b is an integer of 0 to 4, and a+b is from 1 to 5.

5. The positive resist composition of claim 3 wherein the base polymer further comprises repeat units (c) having an adhesive group selected from hydroxy group, carboxy group, lactone ring, carbonate bond, thiocarbonate bond, carbonyl group, cyclic acetal group, ether bond, ester bond, sulfonate ester bond, cyano group, amide bond, —O—C(═O)—S—, and —O—C(═O)—NH—.

6. The positive resist composition of claim 3 wherein the base polymer further comprises repeat units of at least one type selected from repeat units having the formula (d1), repeat units having the formula (d2), repeat units having the formula (d3), repeat units having the formula (d4), and repeat units having the formula (d5): 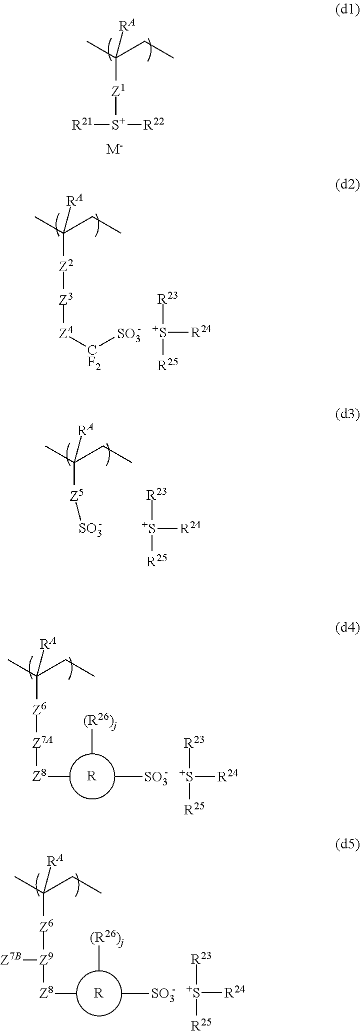
wherein R^{A} is each independently hydrogen or methyl,
Z¹ is a single bond, a C₁-C₆ aliphatic hydrocarbylene group, phenylene group, naphthylene group, or C₇-C₁₈ group obtained by combining the foregoing, or —O—Z¹¹—, —C(═O)—O—Z¹¹— or —C(═O)—NH—Z¹¹—, Z¹¹ is a C₁-C₆ aliphatic hydrocarbylene group, phenylene group, naphthylene group, or C₇-C₁₈ group obtained by combining the foregoing, which may contain a carbonyl moiety, ester bond, ether bond or hydroxy moiety,
Z² is a single bond or ester bond,
Z³ is a single bond, —Z³¹—C(═O)—O—, —Z³¹—O— or —Z³¹—O—C(═O)—, Z³¹ is a C₁-C₁₂ aliphatic hydrocarbylene group, phenylene group, or C₇-C₁₈ group obtained by combining the foregoing, which may contain a carbonyl moiety, ester bond, ether bond, iodine or bromine,
Z⁴ is methylene, 2,2,2-trifluoro-1,1-ethanediyl or carbonyl,
Z⁵ is a single bond, methylene, ethylene, phenylene, fluorinated phenylene, trifluoromethyl-substituted phenylene group, —O—Z¹¹—, —C(═O)—O—Z¹¹—, or —C(═O)—NH—Z⁵¹—, Z⁵¹ is a C₁-C₆ aliphatic hydrocarbylene group, phenylene group, fluorinated phenylene group, or trifluoromethyl-substituted phenylene group, which may contain a carbonyl moiety, ester bond, ether bond, halogen or hydroxy moiety,
Z⁶ is a single bond, phenylene, naphthylene, ester bond or amide bond,
Z^{7A} is a single bond or a C₁-C₂₄ divalent organic group which may contain at least one element selected from halogen, oxygen, nitrogen and sulfur,
Z^{7B} is a C₁-C₁₀ monovalent organic group which may contain at least one element selected from halogen, oxygen, nitrogen and sulfur,
Z⁸ is a single bond, ether bond, ester bond, thioether bond, or C₁-C₆ alkanediyl group,
Z⁹ is a C₁-C₁₂ trivalent organic group which may contain at least one element selected from oxygen, nitrogen and sulfur,
R²¹ to R²⁵ are each independently halogen or a C₁-C₂₀ hydrocarbyl group which may contain a heteroatom, R²³ and R²⁴ may bond together to form a ring with the sulfur atom to which they are attached,
R²⁶ is each independently a C₁-C₁₀ saturated hydrocarbyl group, C₆-C₁₀ aryl group, fluorine, iodine, trifluoromethoxy, difluoromethoxy, cyano or nitro group,
the circle R is a C₆-C₁₀ (j+2)-valent aromatic hydrocarbon group,
j is each independently an integer of 0 to 5, and
M⁻ is a non-nucleophilic counter ion.

7. The resist composition of claim 3, further comprising an acid generator capable of generating a strong acid.

8. The resist composition of claim 3, further comprising an organic solvent.

9. The resist composition of claim 3, further comprising a quencher.

10. The resist composition of claim 3, further comprising a surfactant.

11. A pattern forming process comprising the steps of applying the positive resist composition of claim 1 onto a substrate to form a resist film thereon, exposing the resist film to high-energy radiation, and developing the exposed resist film in a developer.

12. The process of claim 11 wherein the high-energy radiation is i-line, KrF excimer laser, ArF excimer laser, EB or EUV of wavelength 3 to 15 nm.
